(19) United States
(12) Patent Application Publication
(10) Pub. No.: US 2023/0133149 A1
(43) Pub. Date: May 4, 2023

(54) HETEROCYCLIC COMPOUND, ORGANIC LIGHT-EMITTING DEVICE INCLUDING THE SAME, AND ELECTRONIC APPARATUS INCLUDING THE ORGANIC LIGHT-EMITTING DEVICE

(71) Applicant: Samsung Electronics Co., Ltd., Suwon-si (KR)

(72) Inventors: Keisuke KORAI, Kanagawa (JP); Rie SAKURAI, Kanagawa (JP); Atsushi IMAMURA, Kanagawa (JP); Eigo MIYAZAKI, Kanagawa (JP); Wataru SOTOYAMA, Kanagawa (JP)

(21) Appl. No.: 17/713,284

(22) Filed: Apr. 5, 2022

(30) Foreign Application Priority Data
Sep. 15, 2021 (JP) 2021-149949
Nov. 11, 2021 (KR) 10-2021-0155166

(51) Int. Cl. C07F 5/02; H01L 51/00

(52) U.S. Cl. CPC C07F 5/027; H01L 51/008; H01L 51/0072; H01L 51/5004

(57) ABSTRACT

Provided are a heterocyclic compound, an organic light-emitting device including the heterocyclic compound, and an electronic apparatus including the organic light-emitting device, the heterocyclic compound including: a group represented by Formula 1; a group represented by Formula 2; and one to four groups each independently represented by Formula 3 or 4:

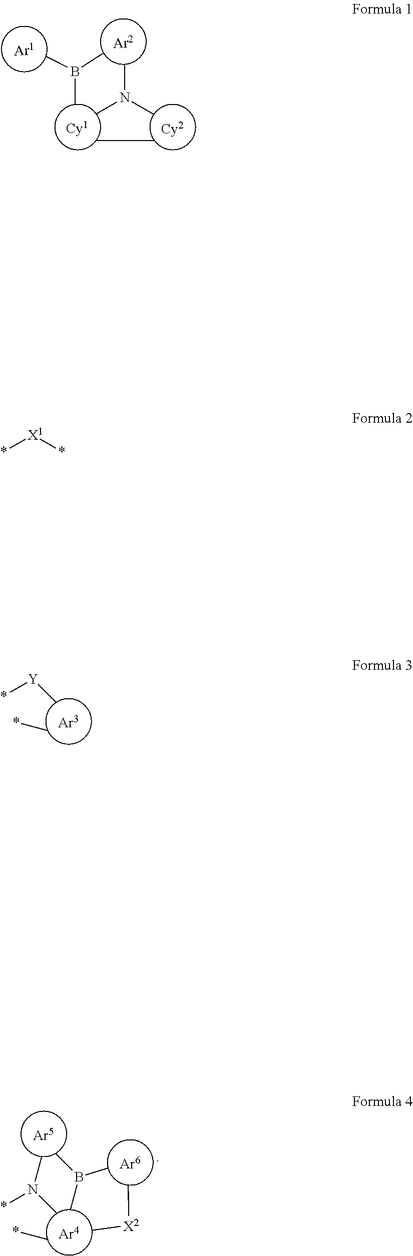

The substituents in Formulae 1 to 4 are the same as described in the detailed description.

### CROSS-REFERENCE TO RELATED APPLICATIONS

This application is based on and claims priority under 35 U.S.C. § 119 to Korean Patent Application No. 10-2021-0155166, filed on Nov. 11, 2021, in the Korean Intellectual Property Office, and to Japanese Patent Application No. 2021-149949, filed on Sep. 15, 2021, in the Japanese Patent Office, the disclosures of which are incorporated by reference herein in their entirety.

### BACKGROUND

### 1. Field

The present disclosure relates to a heterocyclic compound, an organic light-emitting device including the same, and an electronic apparatus including the organic light-emitting device.

### 2. Description of the Related Art

Organic light-emitting devices (OLEDs) are self-emissive devices that, as compared with devices of the related art, have wide viewing angles, high contrast ratios, short response times, and excellent characteristics in terms of luminance, driving voltage, and response speed, and produce full-color images.

OLEDs may include an anode, a cathode, and an organic layer that is located between the anode and the cathode and includes an emission layer. A hole transport region may be located between the anode and the emission layer, and an electron transport region may be located between the emission layer and the cathode. Holes provided from the anode may move toward the emission layer through the hole transport region, and electrons provided from the cathode may move toward the emission layer through the electron transport region. The holes and the electrons recombine in the emission layer to produce excitons. These excitons transition from an excited state to a ground state, thereby generating light.

### SUMMARY

Provided are a heterocyclic compound, an organic light-emitting device including the same, and an electronic apparatus including the organic light-emitting device. In detail, provided is a heterocyclic compound having a maximum emission wavelength of about 440 nm to about 480 nm, having improved color purity, and being capable of improving luminescence efficiency of an organic light-emitting device.

Additional aspects will be set forth in part in the description which follows and, in part, will be apparent from the description, or may be learned by practice of the presented embodiments of the disclosure.

According to an aspect of an embodiment, a heterocyclic compound includes: a group represented by Formula 1; a group represented by Formula 2; and one to four groups each independently represented by Formula 3 or 4:

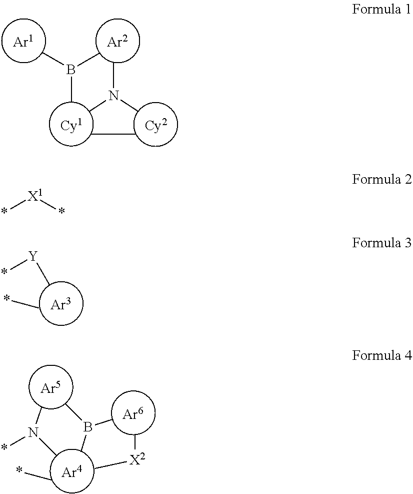

wherein, in Formulae 1 to 4,

at least one of: Ar¹ and Ar²; Ar¹ and Cy¹, or a combination thereof is linked to each other via the group represented by Formula 2,

Cy¹, Cy² and Ar¹ to Ar⁶ are each independently a substituted or unsubstituted aromatic hydrocarbon ring having 6 to 30 ring-forming atoms or a substituted or unsubstituted aromatic hetero ring having 5 to 30 ring-forming atoms,

X¹ and X² are each independently O, S, NR, CR′R″, or a single bond, wherein R, R′, and R″ may each independently be a substituted or unsubstituted alkyl group, a substituted or unsubstituted aryl group, or a substituted or unsubstituted heteroaryl group,

Y is O, S, NZ, or CZ′Z″, wherein Z, Z′, and Z″ are each independently a substituted or unsubstituted alkyl group, a substituted or unsubstituted aryl group, or a substituted or unsubstituted heteroaryl group,

Z in NZ are optionally bonded to Cy¹, Cy², or Ara via O, S, NZ, CZ′Z″, or a single bond,

* in Formula 2 indicates a binding site to Ar¹, Ar², or Cy¹, and

two *(s) in Formulae 3 and 4 each indicate a binding site to Cy¹ or Cy² in Formula 1.

According to an aspect of another embodiment, an organic light-emitting device includes: a first electrode; a second electrode; an organic layer including an emission layer between the first electrode and the second electrode; and the heterocyclic compound.

According to an aspect of another embodiment, an electronic apparatus includes the organic light-emitting device.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an organic light-emitting device according to an exemplary embodiment;

FIG. 2 is a schematic cross-sectional view of an organic light-emitting device according to an exemplary embodiment;

FIG. 3 is a schematic cross-sectional view of an organic light-emitting device according to an exemplary embodiment;

FIG. 4 is an explanatory diagram qualitatively illustrating each energy relationship; and

FIG. 5 is a graph of full width at half maximum (FWHM) of emission in photoluminescence (PL) measured in Compounds R1 to R3 versus reorganization energy (eV) calculated by density functional theory (DFT).

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Unless otherwise specified, measurements of operation and physical properties are performed at room temperature (20° C. or more and 25° C. or less) and at relative humidity of 40% RH or more and 50% RH or less.

It will be understood that when an element is referred to as being “on” another element, it can be directly on the other element or intervening elements may be present therebetween. In contrast, when an element is referred to as being “directly on” another element, there are no intervening elements present

It will be understood that, although the terms “first,” “second,” “third” etc. may be used herein to describe various elements, components, regions, layers and/or sections, these elements, components, regions, layers and/or sections should not be limited by these terms These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a,” “an,” “the,” and “at least one” do not denote a limitation of quantity, and are intended to cover both the singular and plural, unless the context clearly indicates otherwise. For example, “an element” has the same meaning as “at least one element,” unless the context clearly indicates otherwise.

“Or” means “and/or.” As used herein, the term “and/or” includes any and all combinations of one or more of the associated listed items It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded Thus, the regions illustrated in the figures are schematic in nature and their shapes are not intended to illustrate the precise shape of a region and are not intended to limit the scope of the present claims.

In the present specification, the term “X and Y may each independently be” may be understood that X and Y may be identical to or different from each other.

In the present specification, the term “group derived from a ring” refers to a group obtained by removing a hydrogen atom bonded to a ring-forming atom in a ring structure.

In the present specification, the term “number of ring-forming atoms” refers to the number of atoms constituting the ring itself of a compound (for example, a monocyclic compound, a condensed cyclic compound, a cross-linked compound, a carbocyclic compound, and a heterocyclic compound) having a structure (for example, a monocyclic ring, a condensed ring, and a ring assembly) in which atoms are bonded in a ring-like manner. The number of ring-forming atoms excludes the number of atoms that do not constitute the ring (for example, a hydrogen atom that terminates a bond of atoms constituting the ring), and the number of atoms included in a substituent when the ring is substituted with the substituent. Unless otherwise specified, the same definition of the number of ring-forming atoms applies to descriptions provided below.

For example, a benzene ring has 6 ring-forming atoms, a naphthalene ring has 10 ring-forming atoms, a pyridine ring has 6 ring-forming atoms, and a furan ring has 5 ring-forming atoms.

When a benzene ring is substituted with, for example, an alkyl group as a substituent, the number of carbon atoms in the alkyl group is not included in the number of ring-forming atoms of the benzene ring. Accordingly, a benzene ring substituted with an alkyl group has 6 ring-forming atoms. In addition, when a naphthalene ring is substituted with, for example, an alkyl group as a substituent, the number of atoms in the alkyl group is not included in the number of ring-forming atoms of the naphthalene ring. Accordingly, a naphthalene ring substituted with an alkyl group has 10 ring-forming atoms. For example, the number of hydrogen atoms bonded to a pyridine ring or the number of atoms constituting a substituent is not included in the number of ring-forming atoms of the pyridine ring. Accordingly, a pyridine ring to which a hydrogen atom or a substituent is bonded has 6 ring-forming atoms.

Examples of the aromatic hydrocarbon ring having 6 to 30 ring-forming atoms may include, but are not particularly limited to, a benzene ring, a pentalene ring, an indene ring, a naphthalene ring, an anthracene ring, an azulene ring, a heptalene ring, an acenaphthalene ring, a phenalene ring, a fluorene ring, a phenanthrene ring, a phenyl ring, a biphenyl ring, a triphenylene ring, a pyrene ring, a chrysene ring, a picene ring, a perylene ring, a pentaphene ring, a pentacene ring, a tetraphene ring, a hexacene ring, a rubicene ring, a trinaphthylene ring, a heptaphene ring, and a pyranthrene ring.

The aromatic hetero ring has one or more heteroatoms (for example, nitrogen atoms (N), oxygen atoms (O), phosphorus atoms (P), sulfur atoms (S), and silicon atoms (Si)) as ring forming atoms, and the remaining ring-forming atoms are carbon atoms (C). Examples of the aromatic hetero ring having 5 to 30 ring-forming atoms may include, but are not particularly limited to, a pyridine ring, a pyrazine ring, a pyridazine ring, a pyrimidine ring, a triazine ring, a quinoline ring, an isoquinoline ring, a quinoxaline ring, a quinazoline ring, a naphthyridine ring, an acridine ring, a phenazine ring, a benzoquinoline ring, a benzoisoquinoline ring, a phenanthridine ring, a phenanthroline ring, a benzo ring, a coumarin ring, an anthraquinone ring, a fluorenone ring, a furan ring, a thiophene ring, a benzofuran ring, a benzothiophene ring, a dibenzofuran ring, a dibenzothiophene ring, a pyrrole ring, an indole ring, a carbazole ring, an indolocarbazole ring, an imidazole ring, an benzimidazole ring, a pyrazole ring, an indazole ring, an oxazole ring, an isoxazole ring, a benzoxazole ring, a benzoisoxazole ring, a thiazole ring, an isothiazole ring, a benzothiazole ring, a benzoisothiazole ring, an imidazolinone ring, a benzimidazolinone ring, an imidazopyridine ring, an imidazopyrimidine ring, an imidazophenanthridine ring, a benzimidazophenanthridine ring, an azadibenzofuran ring, an azacarbazole ring, an azadibenzothiophene ring, a diazadibenzofuran ring, a diazadibenzothiophene ring, a diazacarbazole ring, a xanthone ring, and a thioxane ring.

One or more hydrogen atoms in the aromatic hydrocarbon ring and the aromatic hetero ring may be replaced with a substituent. In this case, the type of a substituent may be, but is not particularly limited to, a deuterium atom, a halogen atom, a substituted or unsubstituted alkyl group, a substituted or unsubstituted aryl group, a substituted or unsubstituted heteroaryl group, a substituted or unsubstituted alkoxy group, a substituted or unsubstituted aryloxy group, a substituted or unsubstituted heteroaryloxy group, a substituted or unsubstituted diaryl amino group, a substituted or unsubstituted diheteroaryl amino group, or a substituted or unsubstituted arylheteroaryl amino group. When two or more hydrogen atoms are replaced with substituents, the substituents may be the same as or different from each other. In addition, the substituents are not substituted with groups of the same type. For example, a substituent of an alkyl group does not include an alkyl group.

The alkyl group as a substituent may be linear, branched, or cyclic. The number of carbon atoms in the alkyl group may be, but is not particularly limited to, 1 or more and 30 or less, or 1 or more and 20 or less. In addition, the number of carbons in the alkyl group may be 1 or more and 10 or less, or 1 or more and 6 or less. Examples of the alkyl group may include, but are not particularly limited to, a methyl group, an ethyl group, an n-propyl group, an isopropyl group, an n-butyl group, a sec-butyl group, a tert-butyl group, an isobutyl group, a 2-ethylbutyl group, a 3,3-dimethylbutyl group, an n-pentyl group, an isopentyl group, a neopentyl group, a tert-pentyl group (a t-pentyl group), a pentyl group, a 1-methylpentyl group, a 3-methylpentyl group, a 2-ethylpentyl group, a 4-methyl pentyl group, an n-hexyl group, a 1-methylhexyl group, a 2-ethylhexyl group, a 2-butylhexyl group, a cyclohexyl group, a 4-methylcyclo hexyl group, a 4-tert-butylcyclohexyl group (a 4-t-butylcyclohexyl group), an n-heptyl group, a 1-methylheptyl group, a 2,2-dimethylheptyl group, a 2-ethylheptyl group, a 2-butylheptyl group, an n-octyl group, a tert-octyl group (a t-octyl group), a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldecyl group, a 2-octyldecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, and an n-triacontyl group.

The aryl group as a substituent may be, but is not particularly limited to, a monovalent group derived from a hydrocarbon ring including one or more aromatic rings. In addition, the hydrocarbon ring constituting the aryl group may be a condensed ring. In addition, when the aryl group includes two or more aromatic rings, the two or more aromatic rings may be bonded to each other via a single bond (in the form of a ring assembly of aromatic hydrocarbon rings).

The number of ring-forming atoms in the aryl group may be, but is not particularly limited to, 6 or more and 30 or less. In an embodiment, the number of ring-forming atoms in the aryl group may be 6 or more and 20 or less, or 6 or more and 18 or less.

Examples of the aryl group may include, but are not particularly limited to, a phenyl group, a naphthyl group, a phenanthryl group, a biphenyl group, a triphenylene group, an anthryl group, a pyrenyl group, a fluorenyl group, an azulenyl group, an acenaphthyl group, a fluoranthenyl group, a naphthacenyl group, a phenylenyl group, a pentacenyl group, a quaterphenyl group, and a chrysenyl group.

The heteroaryl group as a substituent may be, but is not particularly limited to, a monovalent group derived from a ring including one or more aromatic hetero rings having one or more heteroatoms (for example, nitrogen atoms (N), oxygen atoms (O), phosphorus atoms (P), sulfur atoms (S), and silicon atoms (Si)) as ring-forming atoms, wherein the remaining ring-forming atoms are carbon atoms (C). When the heteroaryl group includes two or more heteroatoms, the heteroatoms may be the same as or different from each other. In addition, a ring constituting the heteroaryl group may be a condensed ring. In addition, when the heteroaryl group includes two or more aromatic hetero rings, the two or more aromatic hetero rings may be bonded to each other via a single bond. As such, the heteroaryl group may be a monocyclic heteroaryl group or a polycyclic heteroaryl group.

The number of ring-forming atoms in the heteroaryl group may be, but is not particularly limited to, 5 or more and 30 or less. In an embodiment, the number of ring-forming atoms in the heteroaryl group may be 5 or more and 20 or less, or 5 or more and 18 or less. Examples of the heteroaryl group may include, but are not limited to, a thienyl group, a furanyl group, a pyrrolyl group, an imidazole group, a thiazolyl group, an oxazolyl group, an oxadiazolyl group, a triazolyl group, a pyridyl group, a bipyridyl group, a pyrimidyl group, a triazinyl group, a triazolyl group, an acridinyl group, a pyridazinyl group, a pyridinyl group, a quinolinyl group, a quinazolinyl group, a quinoxalinyl group, a phenoxadinyl group, a phthalazinyl group, a pyrazinyl group, a pyridopyrazinyl group, a pyrazinopyrazinyl group, an isoquinolinyl group, an indolyl group, a carbazolyl group, an N-arylcarbazolyl group, an N-heteroarylcarbazolyl group, an N-alkylcarbazolyl group, a benzoxazolyl group, a benzoimidazolyl group, a benzothiazolyl group, a benzocarbazolyl group, a dibenzocarbazolyl group, a dibenzothienyl group, a thienothienyl group, a benzofuranyl group, a phenanthrolinyl group, a thiazolyl group, an isoxazolyl group, an oxadiazolyl group, a thiadiazolyl group, a phenothiazinyl group, a dibenzosilolyl group, and a dibenzofuranyl group.

The alkoxy group as a substituent may be linear, branched, or cyclic. The alkyl group constituting the alkoxy group is not particularly limited, and examples thereof may the same as those mentioned in the above description of the alkyl group as a substituent. The number of carbon atoms in the alkoxy group may be, but is not particularly limited to, 1 or more. In addition, the number of carbon atoms in the alkoxy group may be 20 or less, 10 or less, or 4 or less. Examples of the alkoxy group may include, but are not particularly limited to, a methoxy group, an ethoxy group, an n-propyloxy group, an isopropyloxy group, an n-butyloxy group, a sec-butyloxy group, a tert-butyloxy group, an isobutyloxy group, a 2-ethylbutyloxy group, a 3,3-dimethylbutyloxy group, an n-pentyloxy group, an isopentyloxy group, a neopentyloxy group, a tert-pentyloxy group, a cyclopentyloxy group, a 1-methylpentyloxy group, a 3-methylpentyloxy group, a 2-ethylpentyloxy group, a 4-methyl-2-pentyloxy group, an n-hexyloxy group, a 1-methylhexyloxy group, a 2-ethylhexyloxy group, a 2-butylhexyloxy group, a hexyloxy group, a 4-methylcyclohexyloxy group, a 4-tert-butylcyclohexyloxy group, an n-heptyloxy group, a 1-methyl heptyloxy group, a 2,2-dimethylheptyloxy group, a 2-ethylheptyloxy group, a 2-butylheptyloxy group, an n-octyloxy group, a tert-octyloxy group, a 2-ethyloctyloxy group, a 2-butyloctyloxy group, a 2-hexyloctyloxy group, a 3,7-dimethyloctyloxy group, a cyclooctyloxy group, an n-nonyloxy group, an n-decyloxy group, and an adamantyloxy group.

The aryloxy group as a substituent is not particularly limited. The number of carbon atoms in the aryloxy group may be, but is not particularly limited to, 6 or more and 30 or less. The number of carbon atoms in the aryloxy group may be 6 or more and 12 or less, and may be 6. Examples of the aryloxy group may include, but are not particularly limited to, a phenyloxy group, a biphenyloxy group, a terphenyloxy group, a naphthyloxy group, a fluorenyloxy group, an anthracenyloxy group, a quaterphenyloxy group, a pentaphenyloxy group, a triphenylenyloxy group, a pyrenyloxy group, a benzofluorenyloxy group, and a chrysenyloxy group.

The heteroaryloxy group as a substituent is not particularly limited. The heteroaryl group constituting the heteroaryloxy group is not particularly limited, and examples thereof may be the same as those mentioned in the above description of the heteroaryl group. The number of ring-forming atoms in the heteroaryloxy group may be, but is not particularly limited to, 5 or more and 30 or less. In addition, the number of ring-forming atoms in the heteroaryloxy group may be 5 or more and 14 or less, and 5 or more and 13 or less. The number of heteroatoms as ring-forming atoms in the heteroaryloxy group may be, but is not particularly limited to, 1 or more and 3 or less. In addition, the number of heteroatoms as ring-forming atoms in the heteroaryloxy group may be 1 or more and 2 or less, and may be 1. Examples of the heteroaryloxy group may include, but are not particularly limited to, a thienyloxy group, a furanyloxy group, a pyrrolyloxy group, an imidazolyloxy group, a thiazolyloxy group, an oxazolyloxy group, an oxadiazolyloxy group, a triazolyloxy group, a pyridyloxy group, a bipyridyloxy group, a pyrimidyloxy group, a triazinyloxy group, a triazolyloxy group, an acridinyloxy group, a pyridazinyloxy group, a pyridinyloxy group, a quinolinyloxy group, a quinazolinyloxy group, a quinoxalinyloxy group, a phenoxazinyloxy group, a phthalazinyloxy group, a pyridopyrimidinyloxy group, a pyridopyrazinyloxy group, a pyrazinopyrazinyloxy group, an isoquinolinyloxy group, an indolyloxy group, a carbazolyloxy group, a benzoxazolyloxy group, a benzimidazolyloxy group, a benzothiazolyloxy group, a benzocarbazolyloxy group, a benzothiophenyloxy group, a dibenzothienyloxy group, a thienothienylethyloxy group, a benzofuranyloxy group, a phenanthrolinyloxy group, a thiazolyloxy group, an isoxazolyloxy group, an oxadiazolyloxy group, a thiadiazolyloxy group, a phenothiazinyloxy group, a dibenzosilolyloxy group, a dibenzofuranyloxy group, and a xanthonyloxy group.

The diaryl amino group, the diheteroaryl amino group, and the arylheteroaryl amino group as substituents are not particularly limited. The aryl group and the heteroaryl group constituting the diaryl amino group, the diheteroaryl amino group, and the arylheteroaryl amino group are the same as described above. Examples of the diaryl amino group may include, but are particularly limited to, a diphenyl amino group, a bis(4-tert-butylphenyl) amino group, a phenyl(naphthyl) amino group, a di(phenyl) amino group, and a di(p-terphenyl) amino group. An example of the arylheteroaryl amino group may be, but is not particularly limited to, a phenyl(2-pyridyl) amino group. An example of the diheteroaryl amino group may be, but is not particularly limited to, a di(2-pyridyl) amino group.

Examples of the halogen atom as a substituent may include a fluorine atom (F), a chlorine atom (Cl), a bromine atom (Br), and an iodine atom (I).

When the substituent is further substituted, the type of a substituent thereof is not particularly limited. When the substituent is further substituted, the substituent thereof may be, for example, a deuterium atom, a halogen atom, a substituted or unsubstituted alkyl group, a substituted or unsubstituted aryl group, a substituted or unsubstituted heteroaryl group, a substituted or unsubstituted alkoxy group, a substituted or unsubstituted aryloxy group, a substituted or unsubstituted heteroaryloxy group, a substituted or unsubstituted diaryl amino group, a substituted or unsubstituted diheteroaryl amino group, or a substituted or unsubstituted arylheteroaryl amino group. When two or more hydrogen atoms are substituted, the types of substituents may be the same as or different from each other.

### Heterocyclic Compound

The heterocyclic compound may include: a group represented by Formula 1; a group represented by Formula 2; and one to four groups each independently represented by Formula 3 or 4:

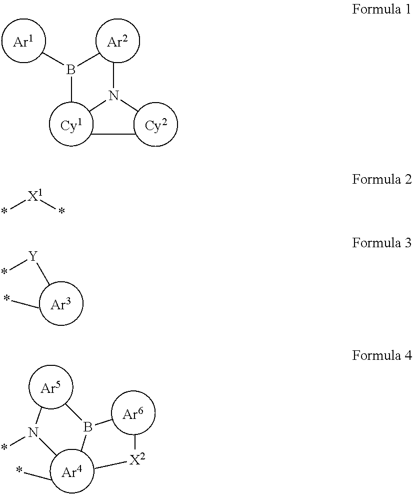

wherein, in Formulae 1 to 4,

at least one of: Ar¹ and Ar²; Ar¹ and Cy¹, or a combination thereof may be linked to each other via the group represented by Formula 2,

Cy¹, Cy² and Ar¹ to Ar⁶ may each independently be a substituted or unsubstituted aromatic hydrocarbon ring having 6 to 30 ring-forming atoms or a substituted or unsubstituted aromatic hetero ring having 5 to 30 ring-forming atoms,

X¹ and X² may each independently be O, S, NR, CR′R″, or a single bond, wherein R, R′, and R″ may each independently be a substituted or unsubstituted alkyl group, a substituted or unsubstituted aryl group, or a substituted or unsubstituted heteroaryl group,

Y may be O, S, NZ, or CZ′Z″, wherein Z, Z′, and Z″ may each independently be a substituted or unsubstituted alkyl group, a substituted or unsubstituted aryl group, or a substituted or unsubstituted heteroaryl group,

Z in NZ may optionally be bonded to Cy¹, Cy², or Ara via O, S, NZ, CZ′Z″, or a single bond, and

* in Formula 2 indicates a binding site to Ar¹, Ar², or Cy¹, and

two *(s) in Formulae 3 and 4 each indicate a binding site to Cy¹ or Cy² in Formula 1.

That is, in the heterocyclic compound, at least one of: Ar¹ and Ar²; Ar¹ and Cy¹, or a combination thereof may be linked to each other via the group represented by Formula 2, and the two *(s) in Formulae 3 and 4 Formula may each have a structure in which one to four moieties each independently represented by Formula 3 or 4 are linked to at least one of Cy¹, Cy², or a combination thereof in Formula 1.

In an embodiment, in the heterocyclic compound, Ar¹ and Ar² may be linked to each other via the group represented by Formula 2.

In one or more embodiments, in the heterocyclic compound, Ar¹ and Cy¹ may be linked to each other via the group represented by Formula 2.

In one or more embodiments, in the heterocyclic compound, Ar¹ and Ar² may be linked to each other via the group represented by Formula 2, and Ar¹ and Cy¹ may be linked to each other via the group represented by Formula 2.

In the heterocyclic compound, one to four moieties represented by Formula 3 may be present, and one to four moieties represented by Formula 4 may be present. The form of a bond between Formula 1 and Formulae 3 and 4 is not particularly limited. For example, the heterocyclic compound may have one to four moieties represented by Formula 3 only, one to four moieties represented by Formula 4 only, or a total of two to four moieties represented by Formulae 3 and 4.

For example, Cy¹, Cy², and Ar¹ to Ar⁶ in the above formulae may each independently be an aromatic hydrocarbon ring having 6 to 10 ring-forming atoms, or for example, an aromatic hydrocarbon ring having 6 ring-forming atoms.

For example, Cy¹, Cy², and Ar¹ to Ar⁶ in the formulae above may each independently be an aromatic hetero ring having 5 to 20 ring-forming atoms, or for example, 5 to 18 ring-forming atoms.

For example, the substituent on each of the substituted aromatic hydrocarbon ring and the substituted aromatic hetero ring may be a deuterium atom, a halogen atom, a substituted or unsubstituted alkyl group, a substituted or unsubstituted aryl group, a substituted or unsubstituted heteroaryl group, a substituted or unsubstituted alkoxy group, a substituted or unsubstituted aryloxy group, a substituted or unsubstituted heteroaryloxy group, a substituted or unsubstituted diarylamino group, a substituted or unsubstituted diheteroaryl amino group, or a substituted or unsubstituted arylheteroaryl amino group.

In an embodiment, the substituent on each of the substituted aromatic hydrocarbon ring and the substituted aromatic hetero ring may be a tert-butyl group, a phenyl group, a 4-tert-butylphenyl group, a 2,4,6-trimethylphenyl group, a 4-(2,4,6-tri methylphenyl)phenyl group, a 2,5-diphenylphenyl group, a 3,5-diphenylphenyl group, a biphenyl group, a 2-pyridyl group, a 3-pyridyl group, a 4-pyridyl group, a carbazolyl group, a 3,6-di-tert-butyla carbazolyl group, a diphenylamino group, or a bis(4-tert-butylphenyl)amino group.

In an embodiment, a moiety consisting of groups represented by Formulae 1 and 2 may be represented by one of Formulae 5-1 to 5-3:

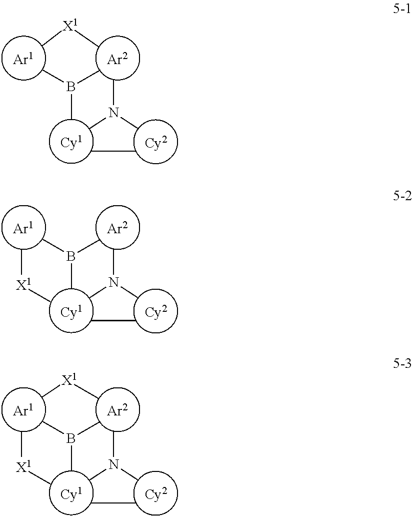

wherein, in Formulae 5-1 to 5-3,

one to four groups represented by at least one of Formulae 3, 4, or a combination thereof may be bonded to at least one of Cy¹, Cy², or a combination thereof,

two *(s) in Formulae 3 and 4 each indicate a binding site to Cy¹ or Cy² in Formulae 5-1 to 5-3, and

Cy¹, Cy², Ar¹, Ar², X¹, X², and Y are the same as described above.

In one or more embodiments, in the heterocyclic compound, one or two of Formula 4 may be bonded to at least one of Cy¹, Cy², or a combination thereof.

In an embodiment, the heterocyclic compound may be represented by one of Formulae 6-1 to 6-4:

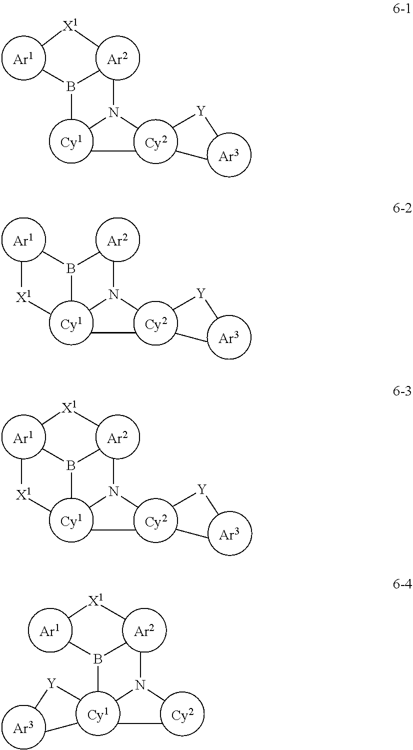

wherein, in Formulae 6-1 to 6-4,

Cy¹, Cy², Ar¹, Ar², X¹, X², and Y are the same as described above.

In an embodiment, the heterocyclic compound may be represented by one of Formulae 1 to 43:

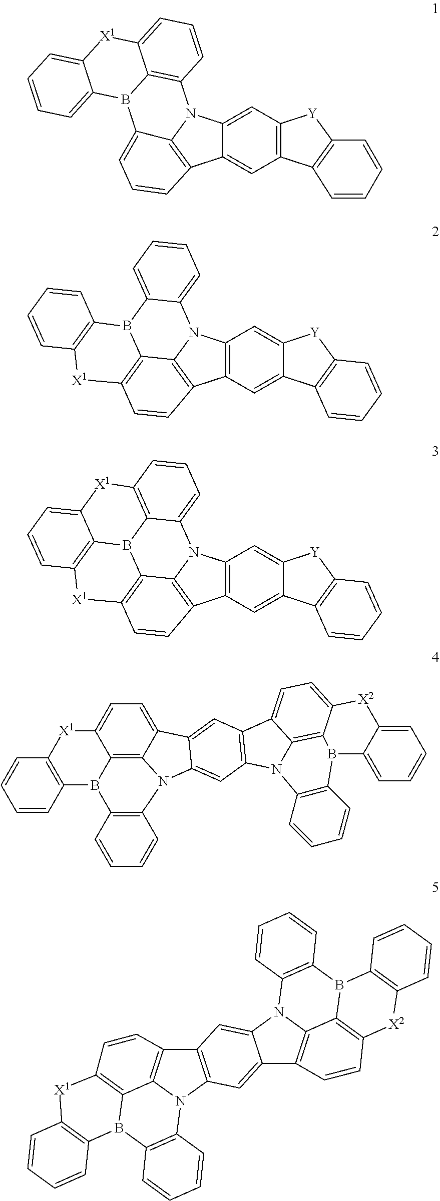

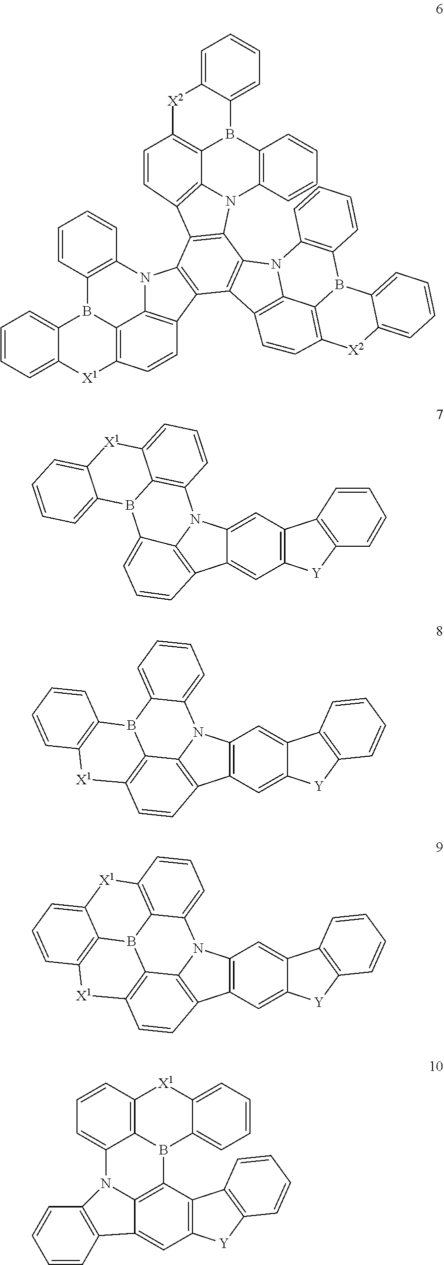

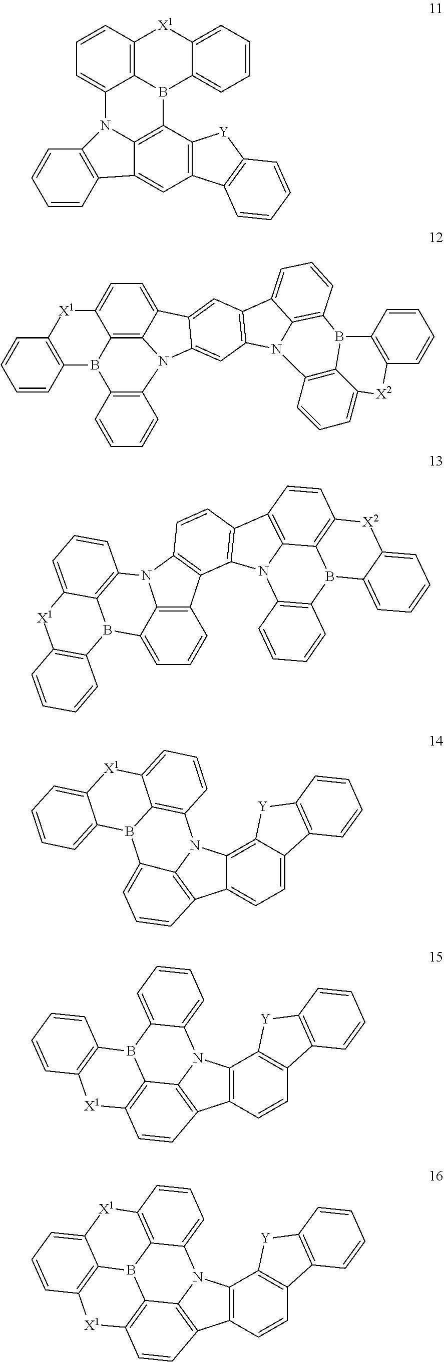

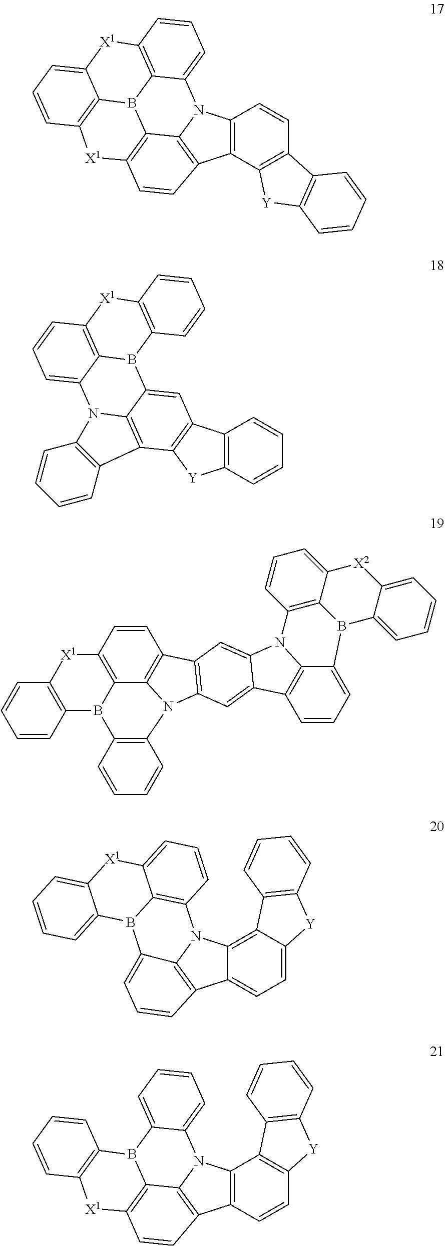

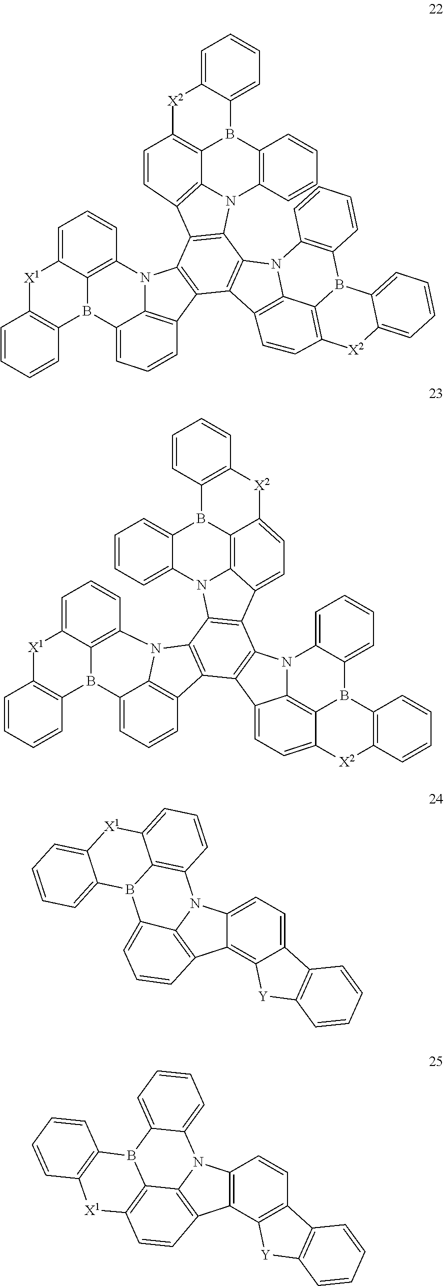

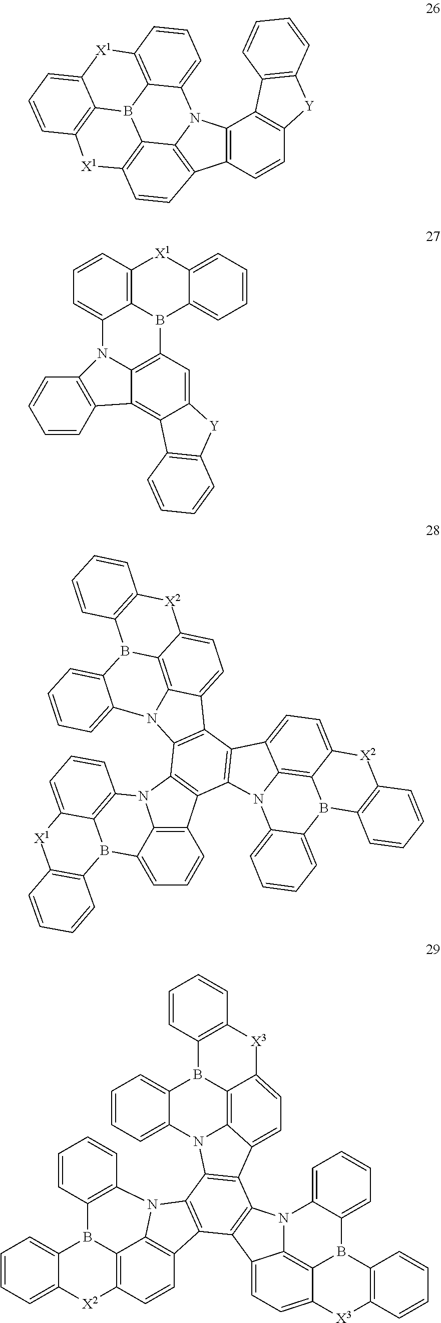

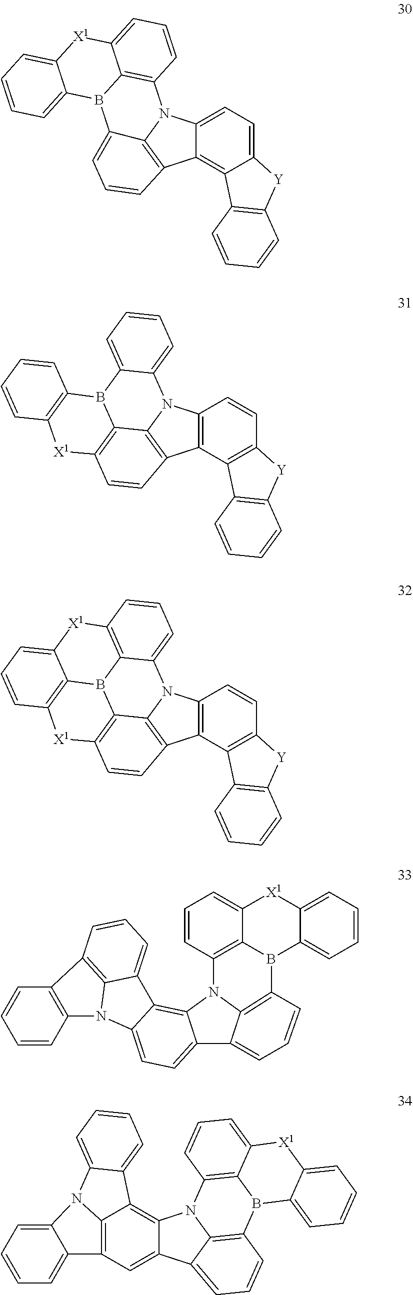

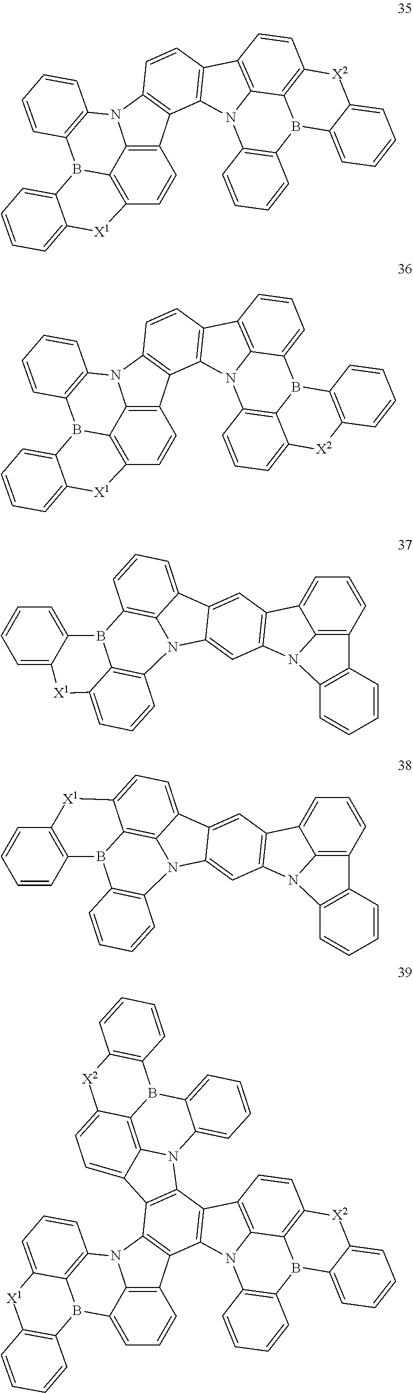

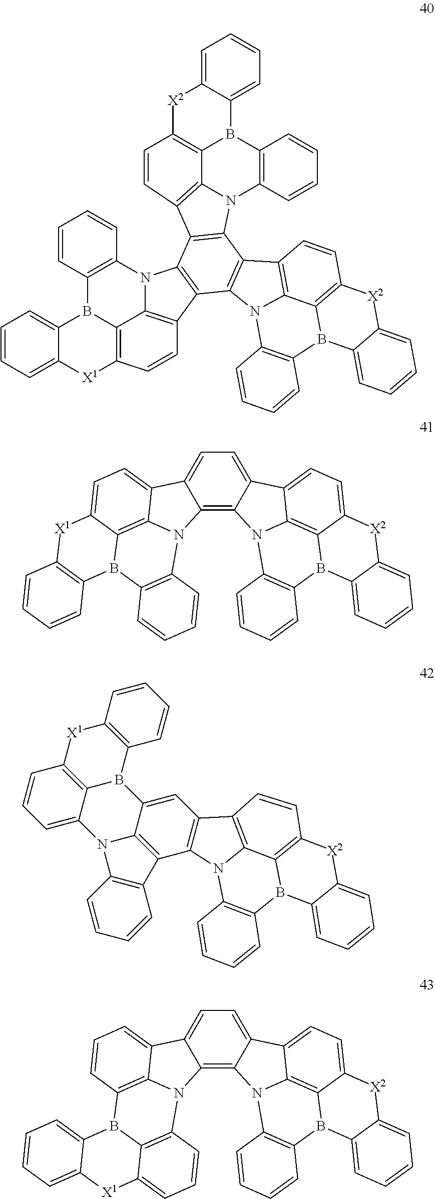

wherein, in Formulae 1 to 43,

X¹ and X² may each independently be O, S, NR, CR′R″, or a single bond, wherein R, R′, and R″ may each independently be a substituted or unsubstituted alkyl group, a substituted or unsubstituted aryl group, or a substituted or unsubstituted heteroaryl group,

Y may be O, S, NZ, or CZ′Z″, wherein Z, Z′, and Z″ may each independently be a substituted or unsubstituted alkyl group, a substituted or unsubstituted aryl group, or a substituted or unsubstituted heteroaryl group,

Z in NZ may optionally be bonded to Cy¹, Cy², or Ar³ via O, S, NZ, CZ′Z″, or a single bond, and

at least one hydrogen atom of Formulae 1 to 43 may be substituted with a deuterium atom, a halogen atom, a substituted or unsubstituted alkyl group, a substituted or unsubstituted aryl group, a substituted or unsubstituted heteroaryl group, or a substituted or unsubstituted diarylamino group.

Examples of the alkyl group, the aryl group, the heteroaryl group, and the diarylamino group are the same as described above.

In an embodiment, the heterocyclic compound may be a compound represented by Formula 1, a compound represented by Formula 4, a compound represented by Formula 5, a compound represented by Formula 7, a compound represented by Formula 11, a compound represented by Formula 12, a compound represented by Formula 18, a compound represented by Formula 19, a compound represented by Formula 20, a compound represented by Formula 24, a compound represented by Formula 30, a compound represented by Formula 33, a compound represented by Formula 34, a compound represented by Formula 37, or a compound represented by Formula 42.

In one or more embodiments, the heterocyclic compound may be a compound of Group I:

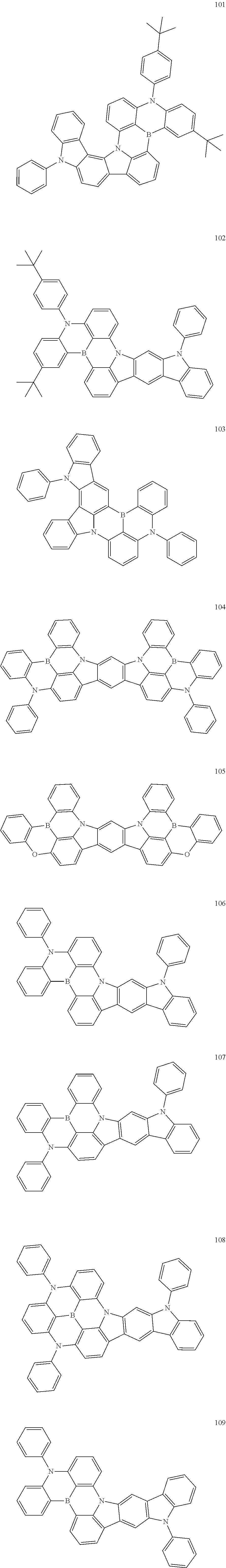

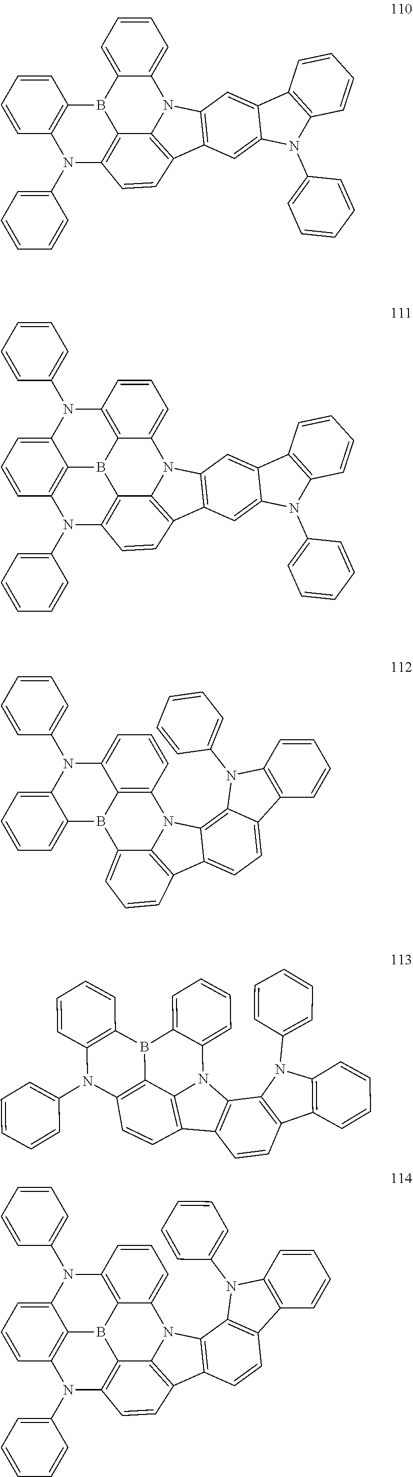

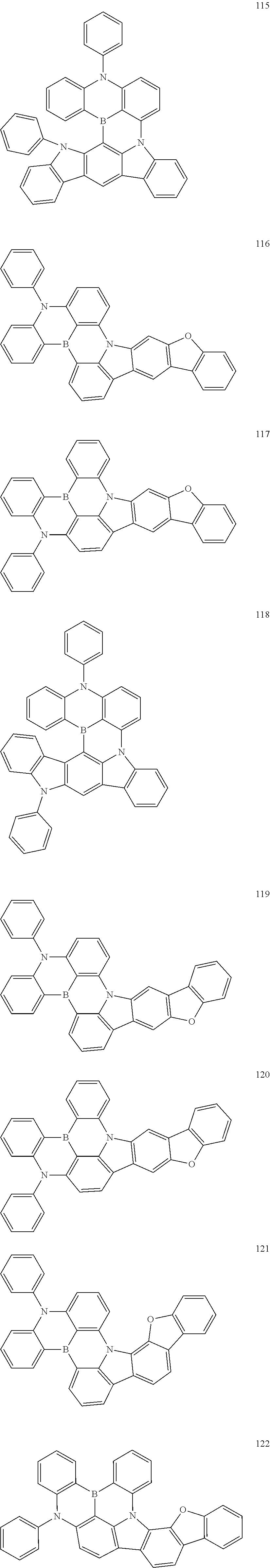

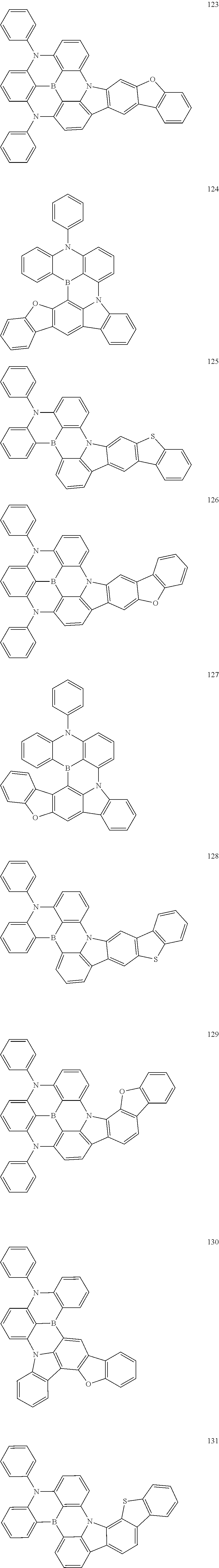

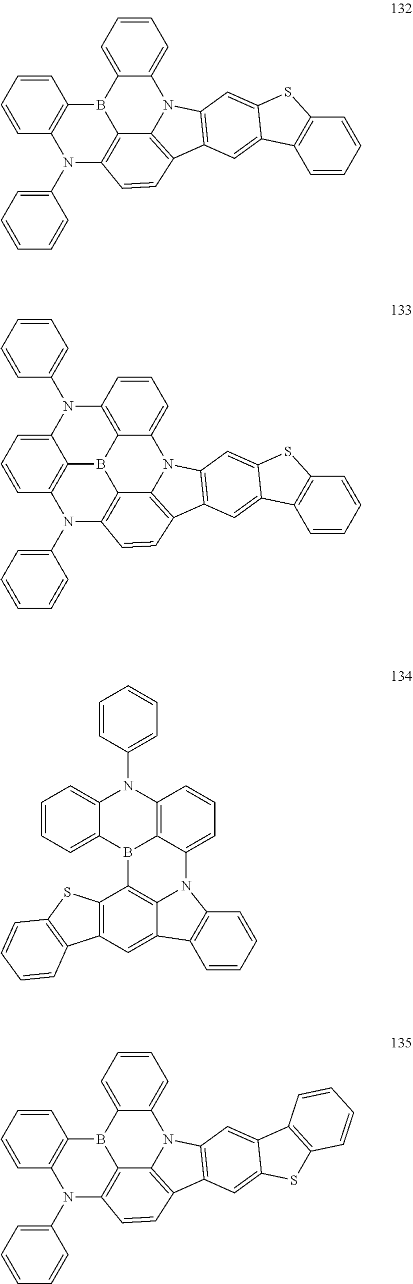 [SMILES: c1ccc(N2c3ccccc3B3c4ccccc4-n4c5cc6sc7ccccc7c6cc5c5ccc2c3c54)cc1 ; c1ccc(N2c3cccc4c3B3c5c2cccc5-n2c5cc6sc7ccccc7c6cc5c5ccc(c3c52)N4c2ccccc2)cc1 ; c1ccc(N2c3ccccc3B3c4c2cccc4-n2c4ccccc4c4cc5c(sc6ccccc65)c3c42)cc1 ; c1ccc(N2c3ccccc3B3c4ccccc4-n4c5cc6c(cc5c5ccc2c3c54)sc2ccccc26)cc1]

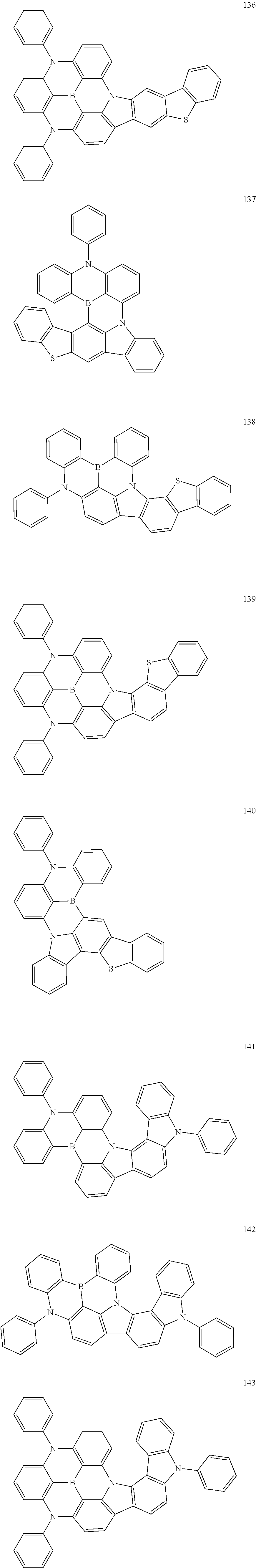

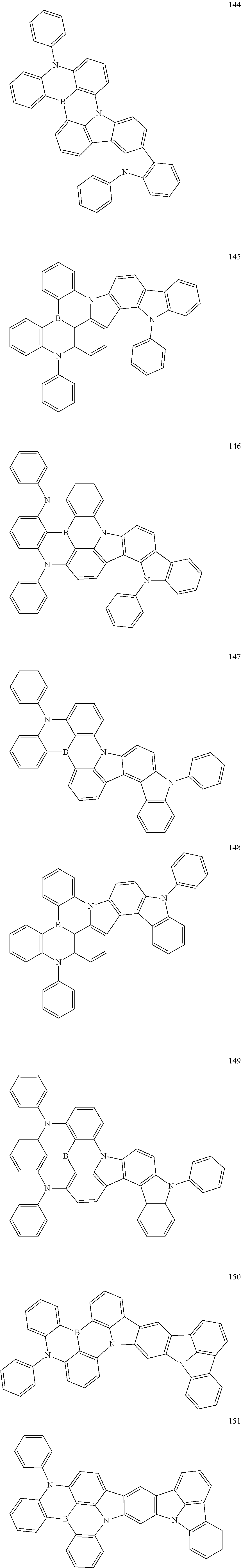

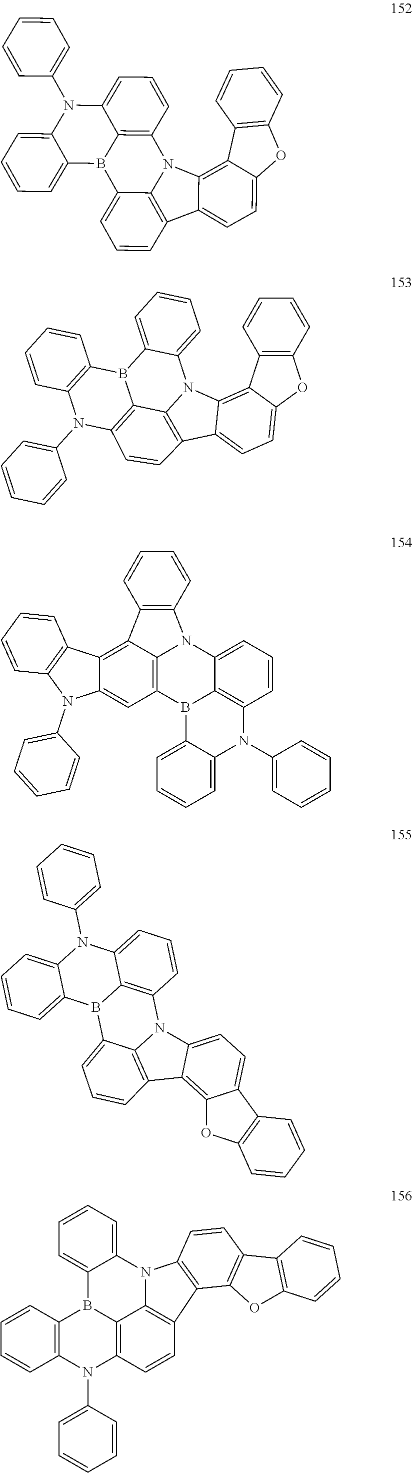

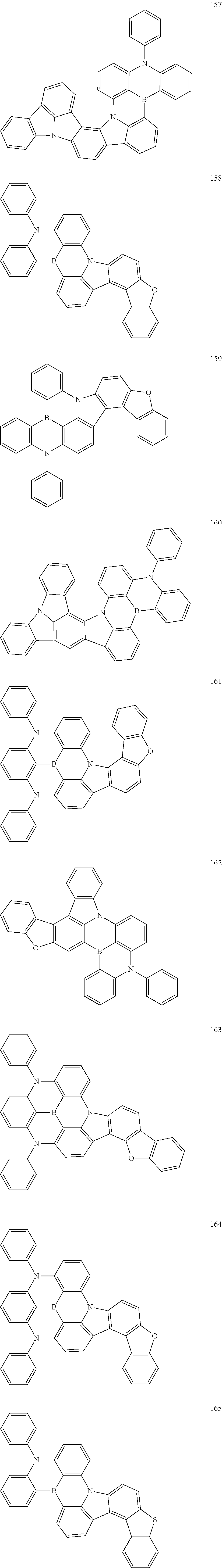

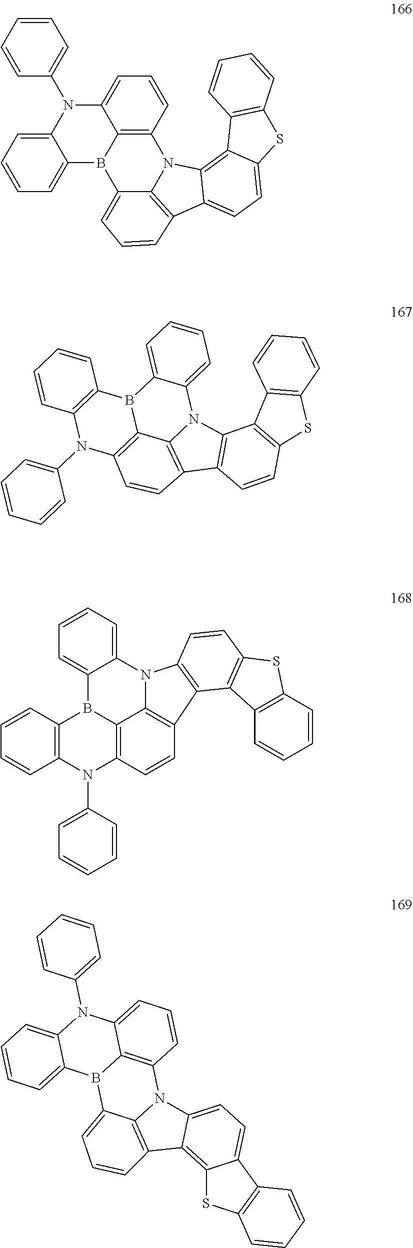 [SMILES: c1ccc(N2c3ccccc3B3c4c2cccc4-n2c4c3cccc4c3ccc4sc5ccccc5c4c32)cc1 ; c1ccc(N2c3ccccc3B3c4ccccc4-n4c5c3c2ccc5c2ccc3sc5ccccc5c3c24)cc1 ; c1ccc(N2c3ccccc3B3c4ccccc4-n4c5ccc6sc7ccccc7c6c5c5ccc2c3c54)cc1 ; c1ccc(N2c3ccccc3B3c4c2cccc4-n2c4ccc5c6ccccc6sc5c4c4cccc3c42)cc1]

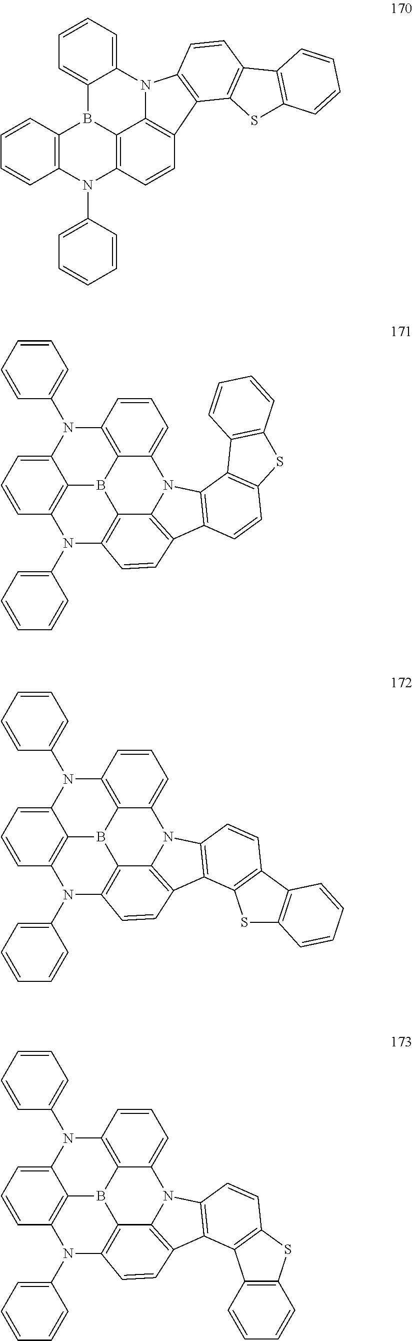 [SMILES: c1ccc(N2c3ccccc3B3c4ccccc4-n4c5ccc6c7ccccc7sc6c5c5ccc2c3c54)cc1 ; c1ccc(N2c3cccc4c3B3c5c2cccc5-n2c5c3c(ccc5c3ccc5sc6ccccc6c5c32)N4c2ccccc2)cc1 ; c1ccc(N2c3cccc4c3B3c5c2cccc5-n2c5ccc6c7ccccc7sc6c5c5ccc(c3c52)N4c2ccccc2)cc1 ; c1ccc(N2c3cccc4c3B3c5c2cccc5-n2c5ccc6sc7ccccc7c6c5c5ccc(c3c52)N4c2ccccc2)cc1]

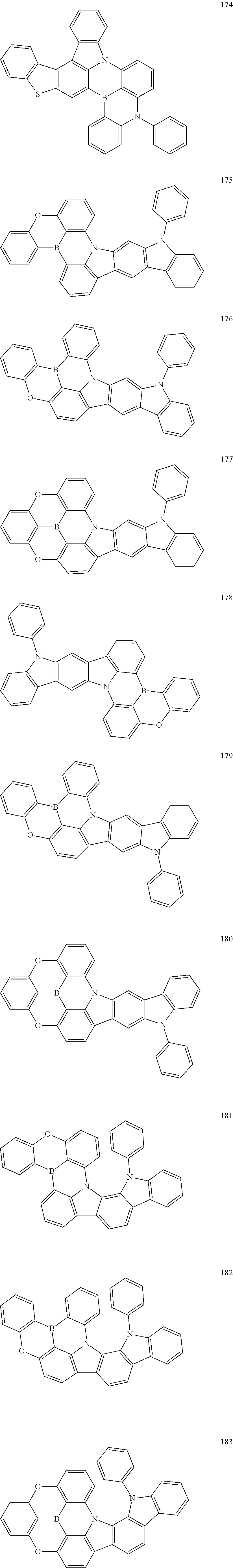

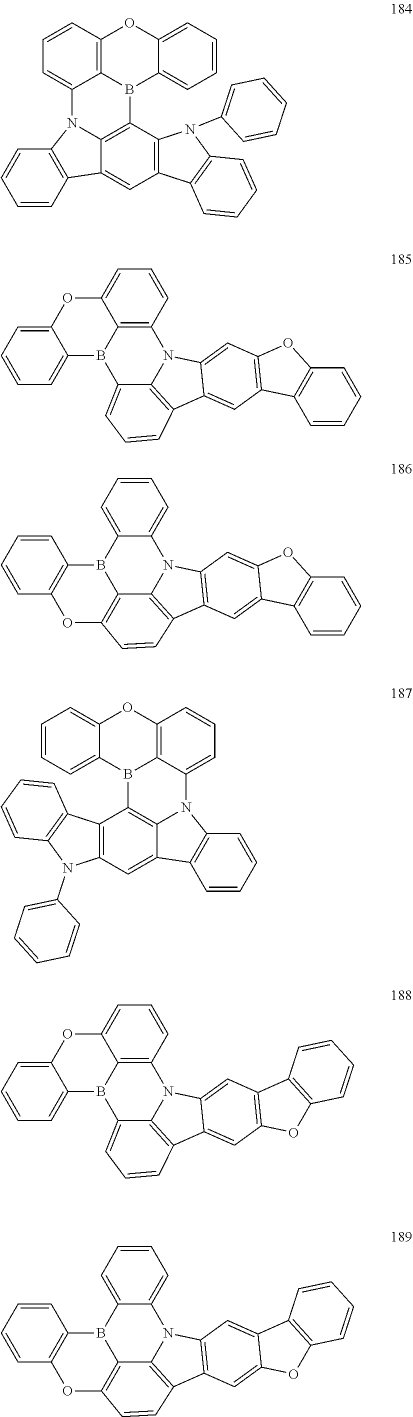

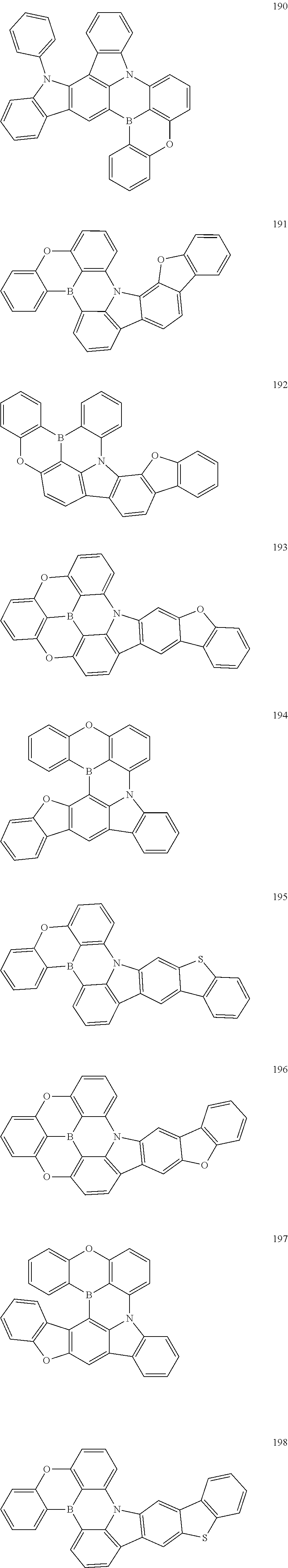

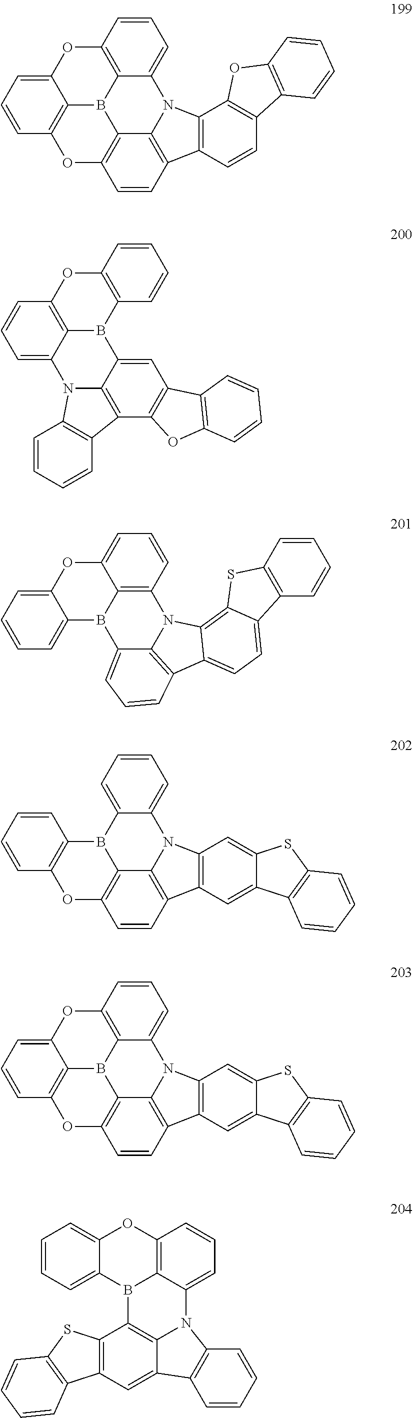 [SMILES: c1cc2c3c(c1)Oc1ccc4c5ccc6c7ccccc7oc6c5n5c4c1B3c1c(cccc1-5)O2 ; c1ccc2c(c1)Oc1cccc3c1B2c1cc2c4ccccc4oc2c2c4ccccc4n-3c12 ; c1ccc2c(c1)Oc1cccc3c1B2c1cccc2c4ccc5c6ccccc6sc5c4n-3c12 ; c1ccc2c(c1)Oc1ccc3c4cc5c(cc4n4c3c1B2c1ccccc1-4)sc1ccccc15 ; c1cc2c3c(c1)Oc1ccc4c5cc6c(cc5n5c4c1B3c1c(cccc1-5)O2)sc1ccccc16 ; c1ccc2c(c1)Oc1cccc3c1B2c1c2sc4ccccc4c2cc2c4ccccc4n-3c12]

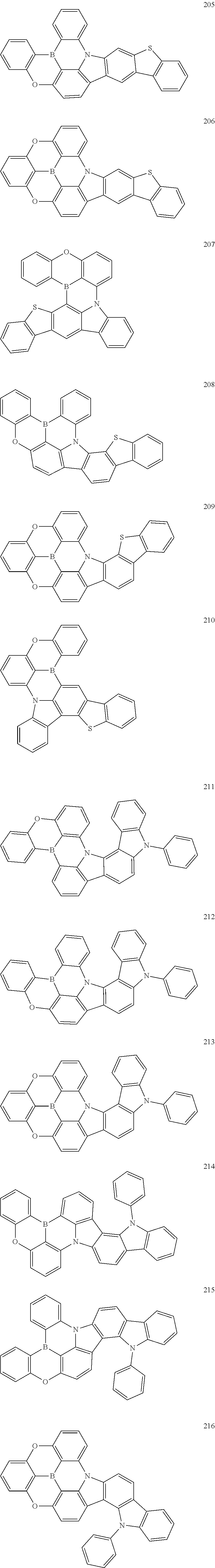

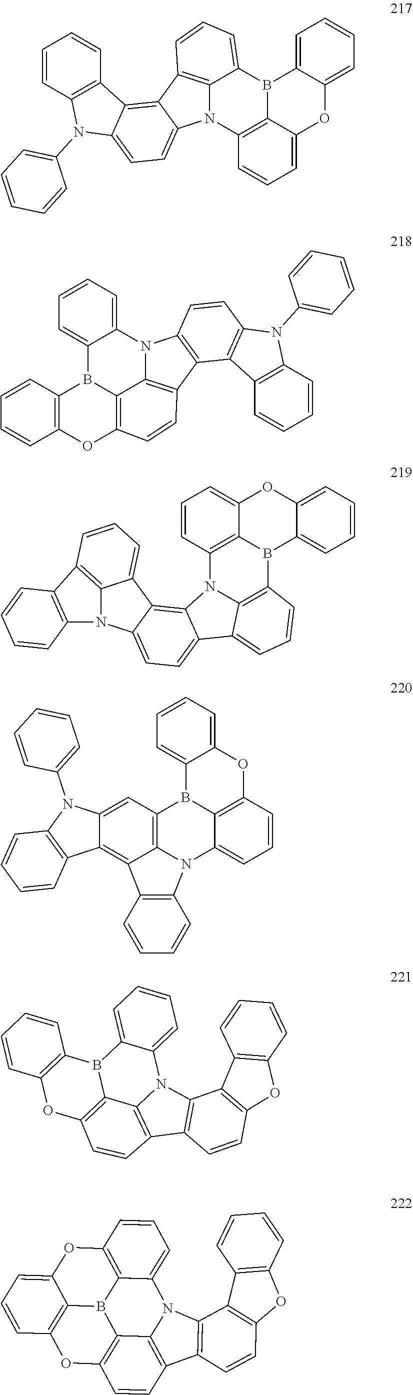

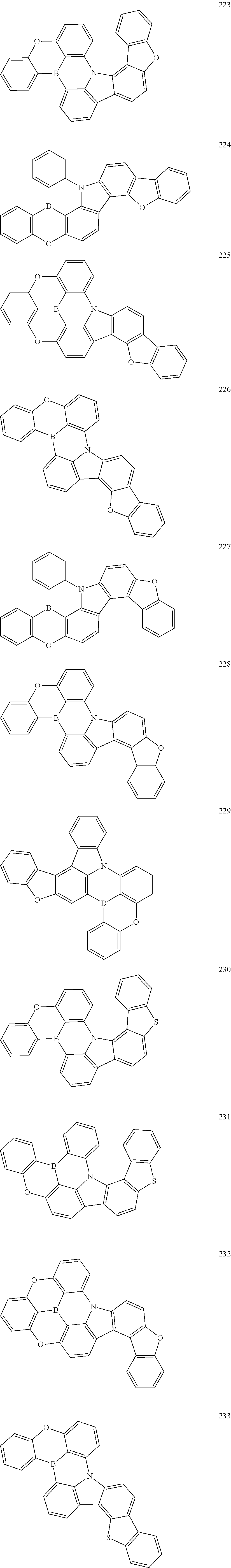

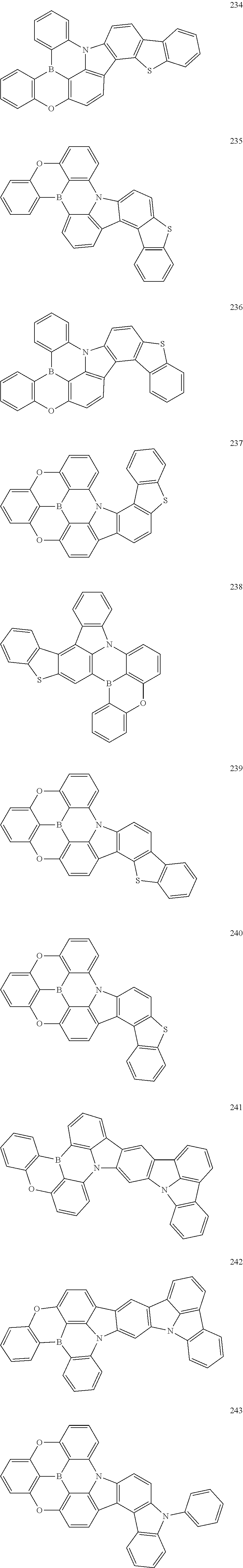

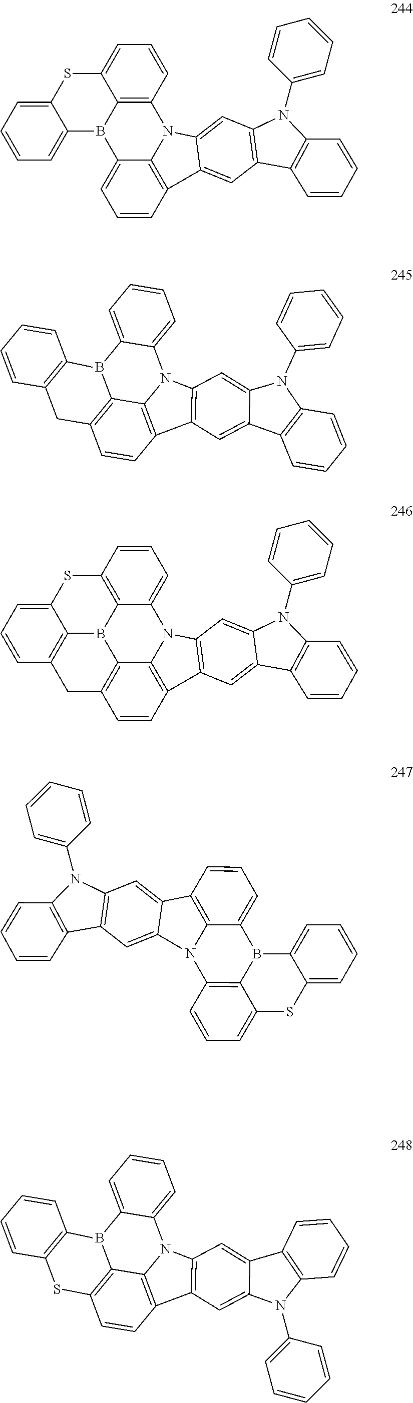 [SMILES: c1ccc(-n2c3ccccc3c3cc4c5cccc6c5n(c4cc32)-c2cccc3c2B6c2ccccc2S3)cc1 ; c1ccc(-n2c3ccccc3c3cc4c5ccc6c7c5n(c4cc32)-c2ccccc2B7c2ccccc2C6)cc1 ; c1ccc(-n2c3ccccc3c3cc4c5ccc6c7c5n(c4cc32)-c2cccc3c2B7c2c(cccc2S3)C6)cc1 ; c1ccc(-n2c3ccccc3c3cc4c(cc32)c2cccc3c2n4-c2cccc4c2B3c2ccccc2S4)cc1 ; c1ccc(-n2c3ccccc3c3cc4c(cc32)c2ccc3c5c2n4-c2ccccc2B5c2ccccc2S3)cc1]

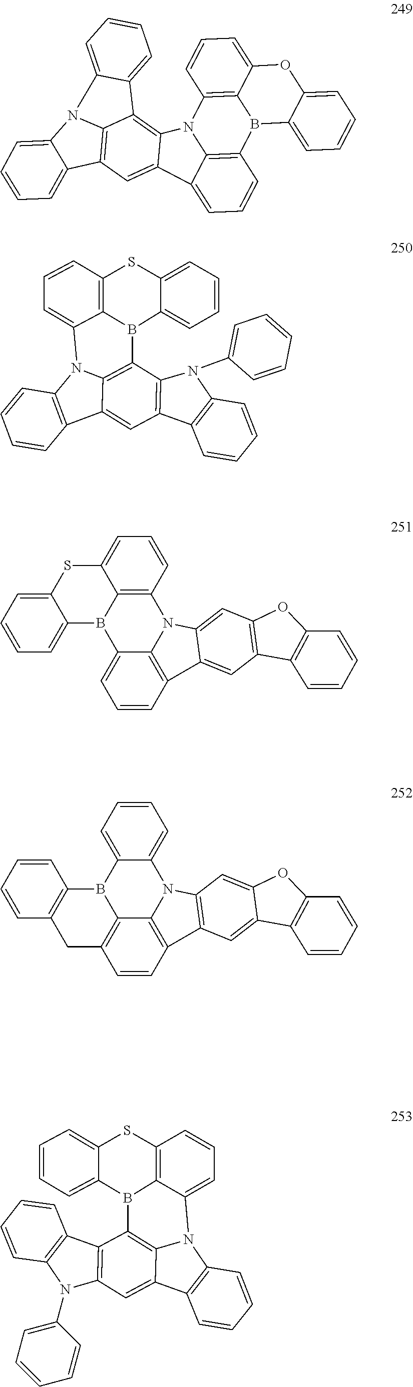 [SMILES: c1ccc2c(c1)Oc1cccc3c1B2c1cccc2c4cc5c6ccccc6n6c7ccccc7c(c4n-3c12)c56 ; c1ccc(-n2c3ccccc3c3cc4c5ccccc5n5c4c(c32)B2c3ccccc3Sc3cccc-5c32)cc1 ; c1ccc2c(c1)Sc1cccc3c1B2c1cccc2c4cc5c(cc4n-3c12)oc1ccccc15 ; c1ccc2c(c1)Cc1ccc3c4cc5c(cc4n4c3c1B2c1ccccc1-4)oc1ccccc15 ; c1ccc(-n2c3ccccc3c3c4c5c(cc32)c2ccccc2n5-c2cccc3c2B4c2ccccc2S3)cc1]

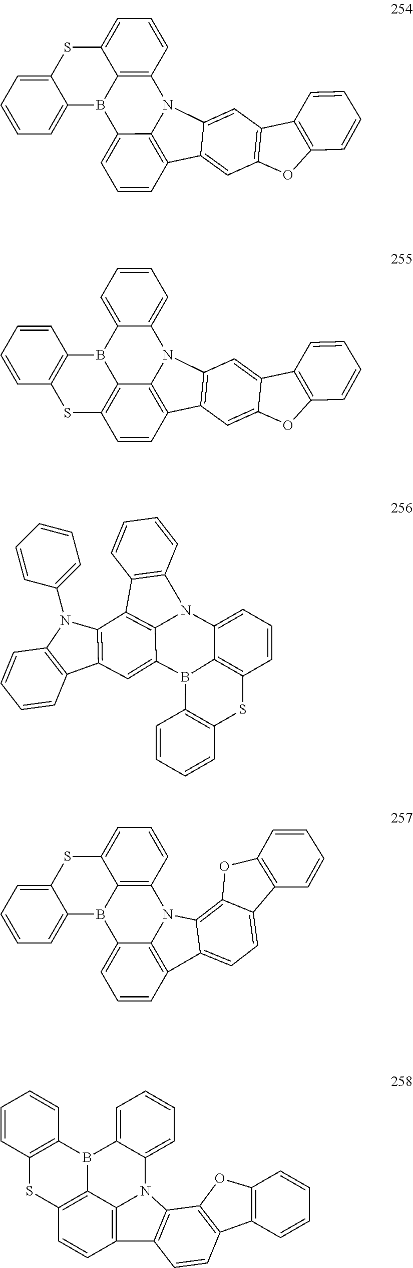 [SMILES: c1ccc2c(c1)Sc1cccc3c1B2c1cccc2c4cc5oc6ccccc6c5cc4n-3c12 ; c1ccc2c(c1)Sc1ccc3c4cc5oc6ccccc6c5cc4n4c3c1B2c1ccccc1-4 ; c1ccc(-n2c3ccccc3c3cc4c5c(c6ccccc6n5-c5cccc6c5B4c4ccccc4S6)c32)cc1 ; c1ccc2c(c1)Sc1cccc3c1B2c1cccc2c4ccc5c6ccccc6oc5c4n-3c12 ; c1ccc2c(c1)Sc1ccc3c4ccc5c6ccccc6oc5c4n4c3c1B2c1ccccc1-4]

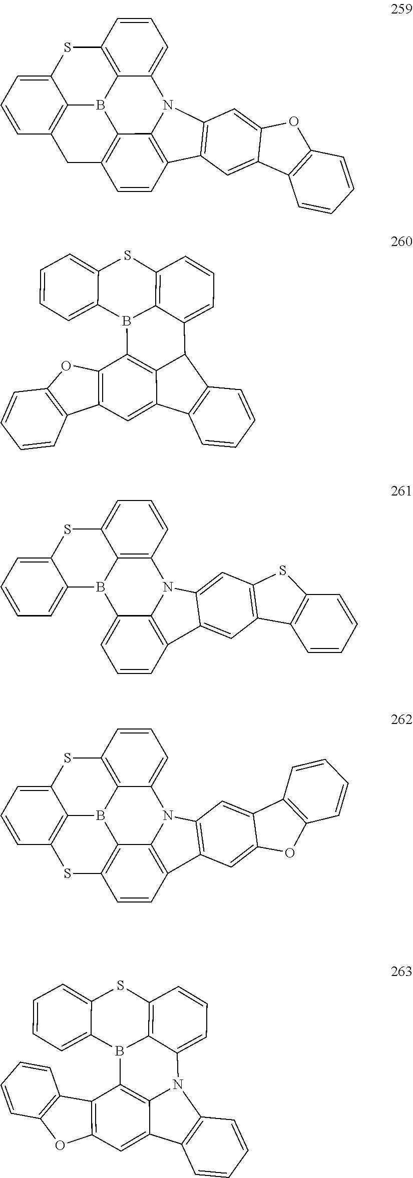 [SMILES: c1cc2c3c(c1)Sc1cccc4c1B3c1c(ccc3c5cc6c(cc5n-4c13)oc1ccccc16)C2 ; c1ccc2c(c1)Sc1cccc3c1B2c1c2c(cc4c1oc1ccccc14)-c1ccccc1C32 ; c1ccc2c(c1)Sc1cccc3c1B2c1cccc2c4cc5c(cc4n-3c12)sc1ccccc15 ; c1cc2c3c(c1)Sc1ccc4c5cc6oc7ccccc7c6cc5n5c4c1B3c1c(cccc1-5)S2 ; c1ccc2c(c1)Sc1cccc3c1B2c1c2c(cc4c5ccccc5n-3c14)oc1ccccc12]

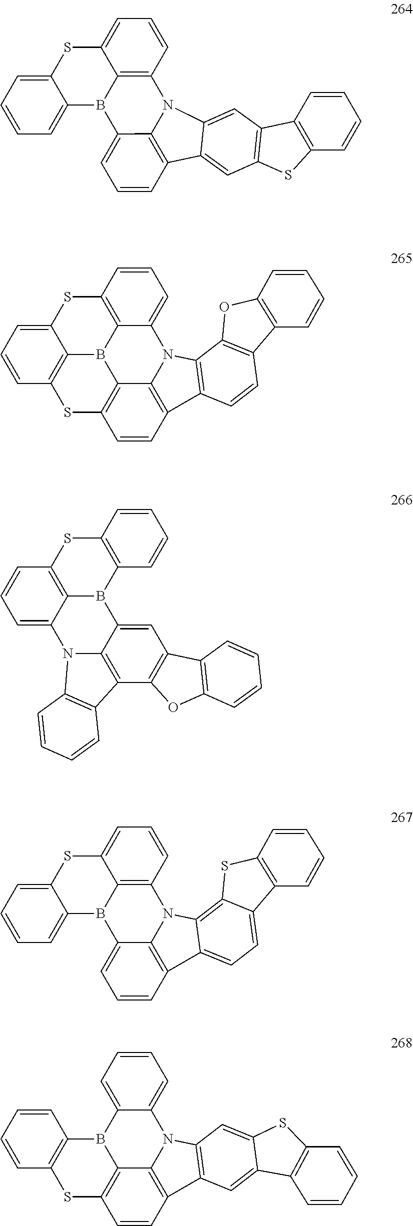 [SMILES: c1ccc2c(c1)Sc1cccc3c1B2c1cccc2c4cc5sc6ccccc6c5cc4n-3c12 ; c1cc2c3c(c1)Sc1ccc4c5ccc6c7ccccc7oc6c5n5c4c1B3c1c(cccc1-5)S2 ; c1ccc2c(c1)Sc1cccc3c1B2c1cc2c4ccccc4oc2c2c4ccccc4n-3c12 ; c1ccc2c(c1)Sc1cccc3c1B2c1cccc2c4ccc5c6ccccc6sc5c4n-3c12 ; c1ccc2c(c1)Sc1ccc3c4cc5c(cc4n4c3c1B2c1ccccc1-4)sc1ccccc15]

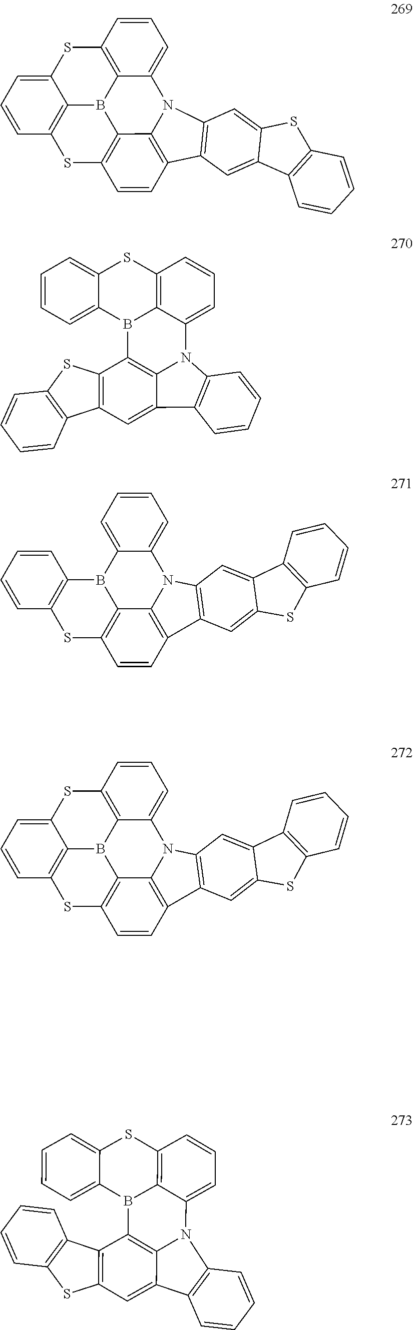 [SMILES: c1cc2c3c(c1)Sc1ccc4c5cc6c(cc5n5c4c1B3c1c(cccc1-5)S2)sc1ccccc16 ; c1ccc2c(c1)Sc1cccc3c1B2c1c2sc4ccccc4c2cc2c4ccccc4n-3c12 ; c1ccc2c(c1)Sc1ccc3c4cc5sc6ccccc6c5cc4n4c3c1B2c1ccccc1-4 ; c1cc2c3c(c1)Sc1ccc4c5cc6sc7ccccc7c6cc5n5c4c1B3c1c(cccc1-5)S2 ; c1ccc2c(c1)Sc1cccc3c1B2c1c2c(cc4c5ccccc5n-3c14)sc1ccccc12]

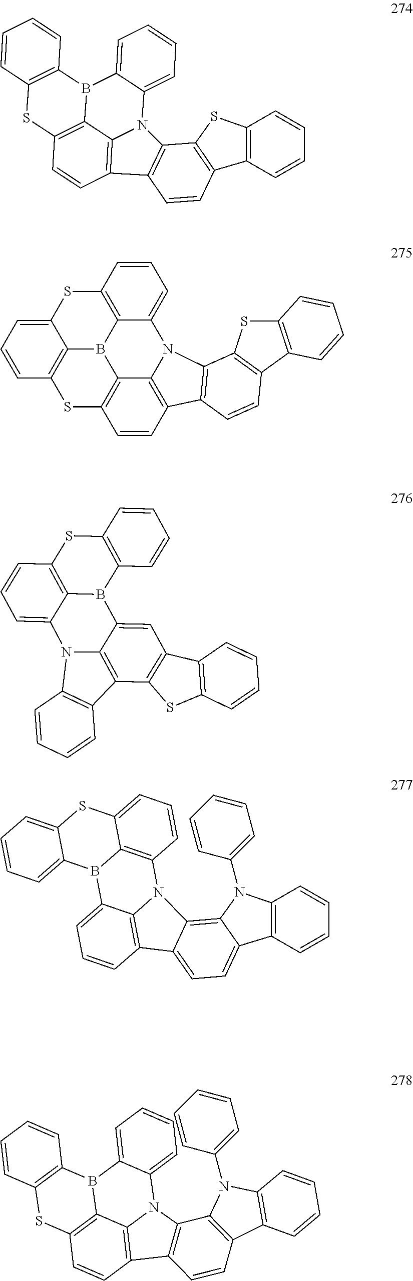 [SMILES: c1ccc2c(c1)Sc1ccc3c4ccc5c6ccccc6sc5c4n4c3c1B2c1ccccc1-4 ; c1cc2c3c(c1)Sc1ccc4c5ccc6c7ccccc7sc6c5n5c4c1B3c1c(cccc1-5)S2 ; c1ccc2c(c1)Sc1cccc3c1B2c1cc2c4ccccc4sc2c2c4ccccc4n-3c12 ; c1ccc(-n2c3ccccc3c3ccc4c5cccc6c5n(c4c32)-c2cccc3c2B6c2ccccc2S3)cc1 ; c1ccc(-n2c3ccccc3c3ccc4c5ccc6c7c5n(c4c32)-c2ccccc2B7c2ccccc2S6)cc1]

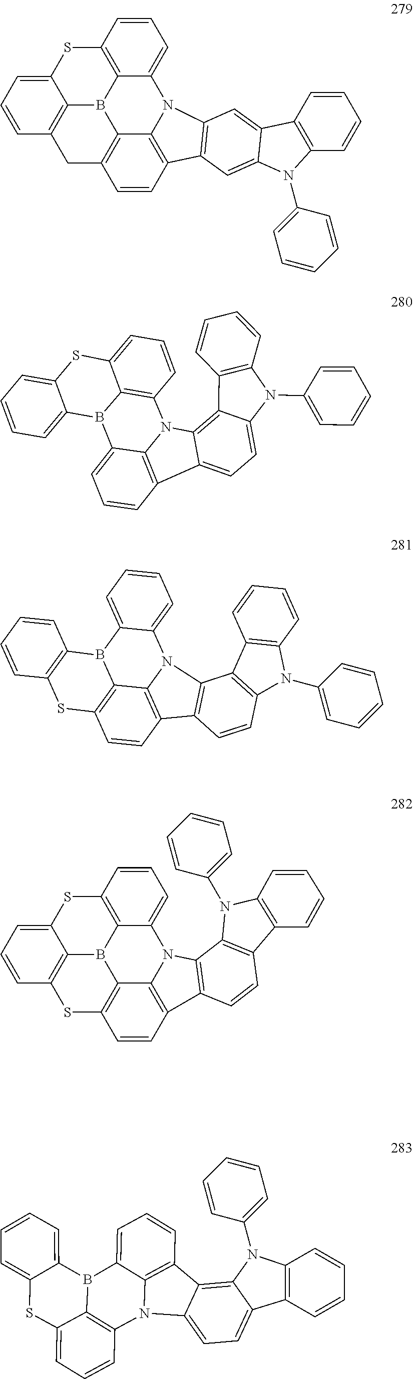 [SMILES: c1ccc(-n2c3ccccc3c3cc4c(cc32)c2ccc3c5c2n4-c2cccc4c2B5c2c(cccc2S4)C3)cc1 ; c1ccc(-n2c3ccccc3c3c2ccc2c4cccc5c4n(c23)-c2cccc3c2B5c2ccccc2S3)cc1 ; c1ccc(-n2c3ccccc3c3c2ccc2c4ccc5c6c4n(c23)-c2ccccc2B6c2ccccc2S5)cc1 ; c1ccc(-n2c3ccccc3c3ccc4c5ccc6c7c5n(c4c32)-c2cccc3c2B7c2c(cccc2S6)S3)cc1 ; c1ccc(-n2c3ccccc3c3ccc4c(c5cccc6c5n4-c4cccc5c4B6c4ccccc4S5)c32)cc1]

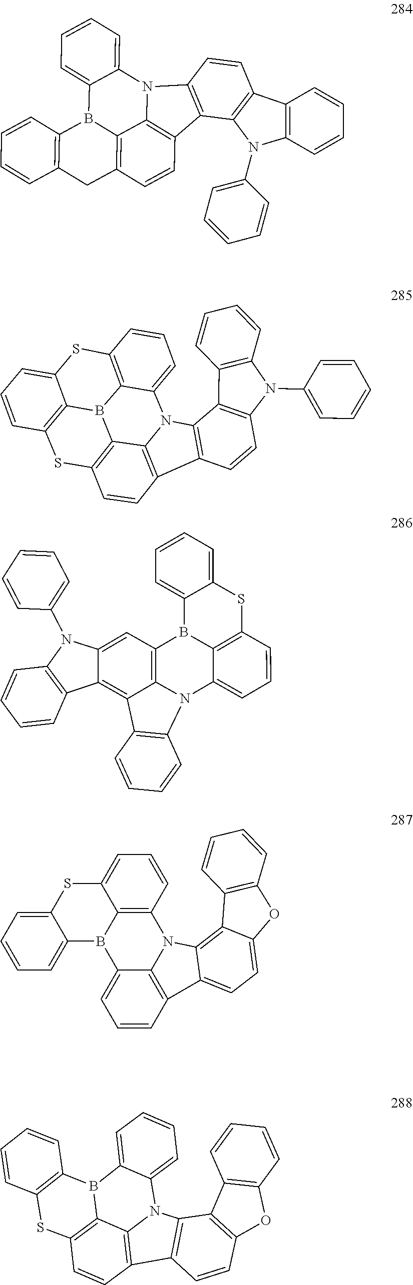 [SMILES: c1ccc(-n2c3ccccc3c3ccc4c(c5ccc6c7c5n4-c4ccccc4B7c4ccccc4C6)c32)cc1 ; c1ccc(-n2c3ccccc3c3c2ccc2c4ccc5c6c4n(c23)-c2cccc3c2B6c2c(cccc2S5)S3)cc1 ; c1ccc(-n2c3ccccc3c3c4c5ccccc5n5c4c(cc32)B2c3ccccc3Sc3cccc-5c32)cc1 ; c1ccc2c(c1)Sc1cccc3c1B2c1cccc2c4ccc5oc6ccccc6c5c4n-3c12 ; c1ccc2c(c1)Sc1ccc3c4ccc5oc6ccccc6c5c4n4c3c1B2c1ccccc1-4]

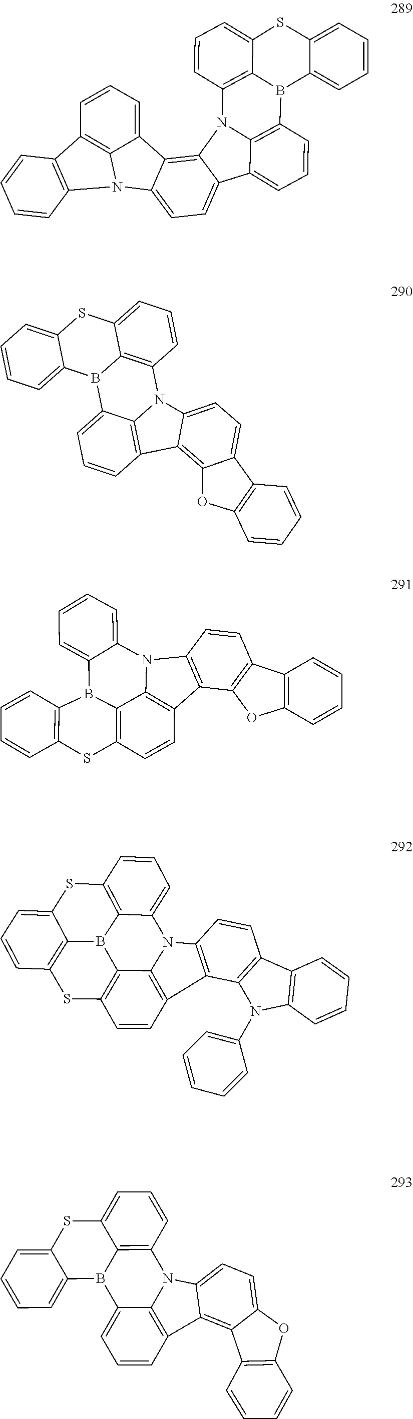 [SMILES: c1ccc2c(c1)Sc1cccc3c1B2c1cccc2c4ccc5c(c6cccc7c8ccccc8n5c76)c4n-3c12 ; c1ccc2c(c1)Sc1cccc3c1B2c1cccc2c4c5oc6ccccc6c5ccc4n-3c12 ; c1ccc2c(c1)Sc1ccc3c4c5oc6ccccc6c5ccc4n4c3c1B2c1ccccc1-4 ; c1ccc(-n2c3ccccc3c3ccc4c(c5ccc6c7c5n4-c4cccc5c4B7c4c(cccc4S6)S5)c32)cc1 ; c1ccc2c(c1)Sc1cccc3c1B2c1cccc2c4c5c(ccc4n-3c12)oc1ccccc15]

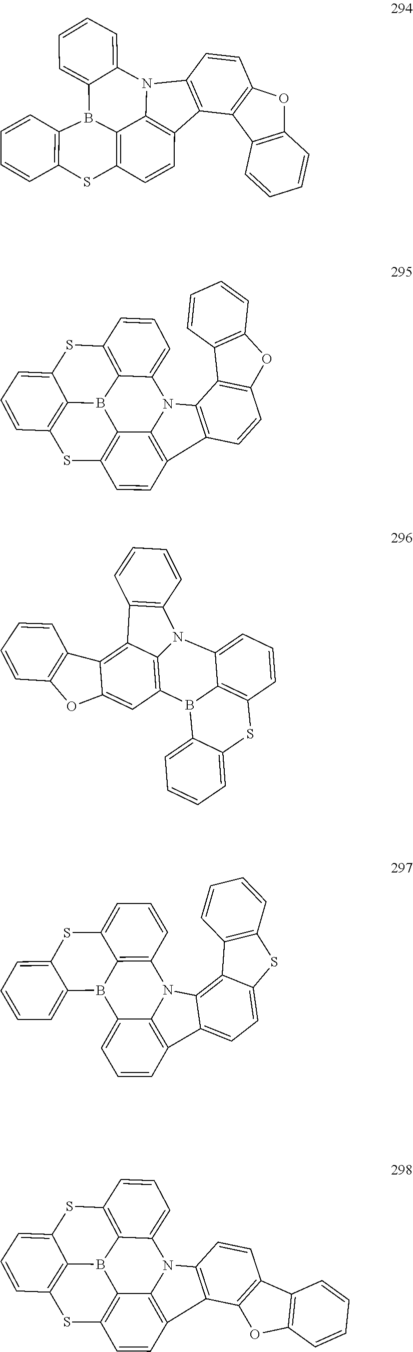 [SMILES: c1ccc2c(c1)Sc1ccc3c4c5c(ccc4n4c3c1B2c1ccccc1-4)oc1ccccc15 ; c1cc2c3c(c1)Sc1ccc4c5ccc6oc7ccccc7c6c5n5c4c1B3c1c(cccc1-5)S2 ; c1ccc2c(c1)Sc1cccc3c1B2c1cc2oc4ccccc4c2c2c4ccccc4n-3c12 ; c1ccc2c(c1)Sc1cccc3c1B2c1cccc2c4ccc5sc6ccccc6c5c4n-3c12 ; c1cc2c3c(c1)Sc1ccc4c5c6oc7ccccc7c6ccc5n5c4c1B3c1c(cccc1-5)S2]

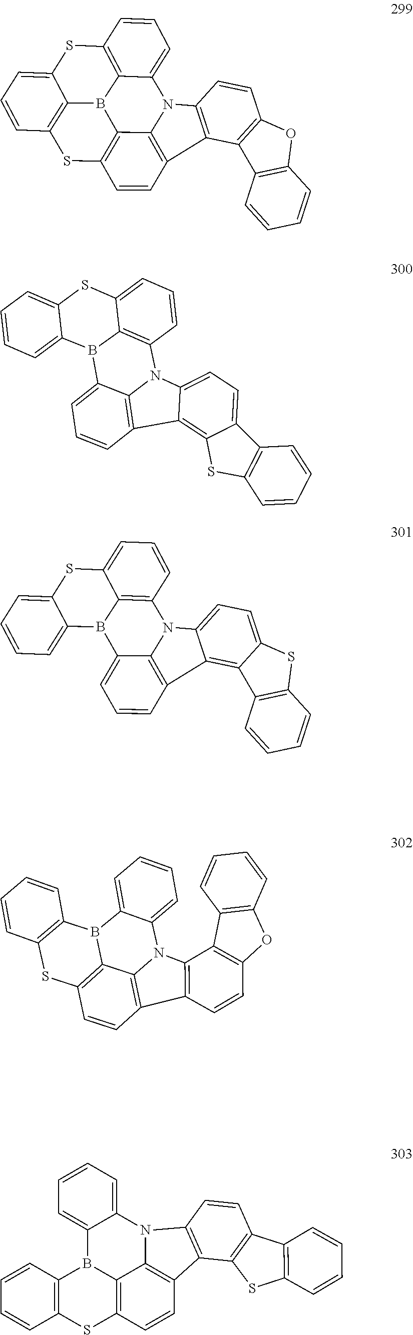 [SMILES: c1cc2c3c(c1)Sc1ccc4c5c6c(ccc5n5c4c1B3c1c(cccc1-5)S2)oc1ccccc16 ; c1ccc2c(c1)Sc1cccc3c1B2c1cccc2c4c5sc6ccccc6c5ccc4n-3c12 ; c1ccc2c(c1)Sc1cccc3c1B2c1cccc2c4c5c(ccc4n-3c12)sc1ccccc15 ; c1ccc2c(c1)Sc1ccc3c4ccc5oc6ccccc6c5c4n4c3c1B2c1ccccc1-4 ; c1ccc2c(c1)Sc1ccc3c4c5sc6ccccc6c5ccc4n4c3c1B2c1ccccc1-4]

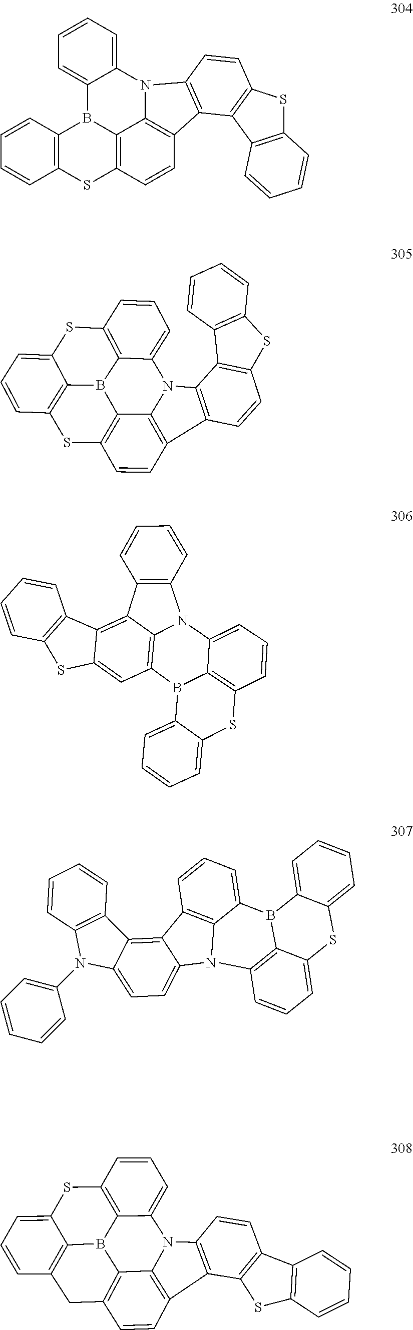 [SMILES: c1ccc2c(c1)Sc1ccc3c4c5c(ccc4n4c3c1B2c1ccccc1-4)sc1ccccc15 ; c1cc2c3c(c1)Sc1ccc4c5ccc6sc7ccccc7c6c5n5c4c1B3c1c(cccc1-5)S2 ; c1ccc2c(c1)Sc1cccc3c1B2c1cc2sc4ccccc4c2c2c4ccccc4n-3c12 ; c1ccc(-n2c3ccccc3c3c4c5cccc6c5n(c4ccc32)-c2cccc3c2B6c2ccccc2S3)cc1 ; c1cc2c3c(c1)Sc1cccc4c1B3c1c(ccc3c5c6sc7ccccc7c6ccc5n-4c13)C2]

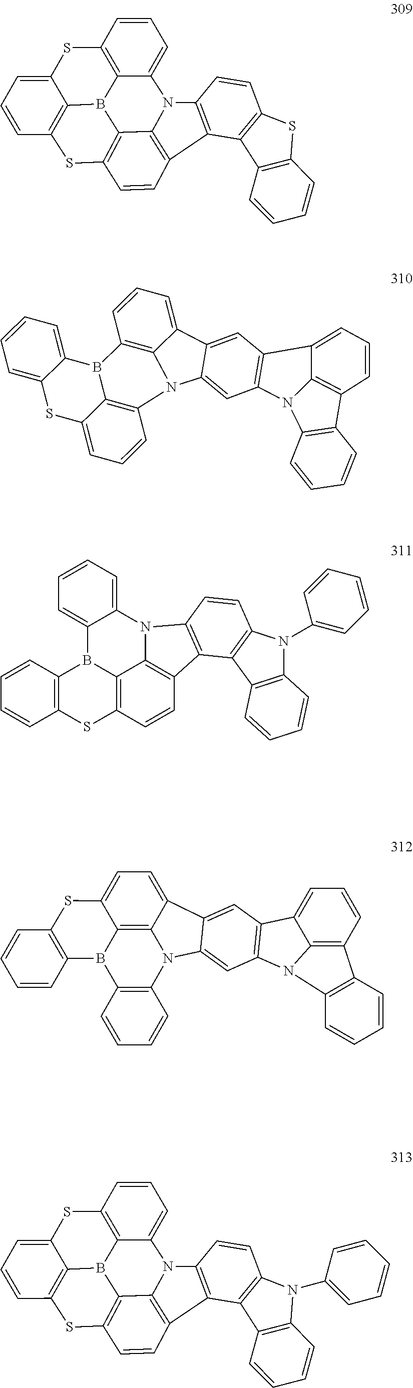 [SMILES: c1cc2c3c(c1)Sc1ccc4c5c6c(ccc5n5c4c1B3c1c(cccc1-5)S2)sc1ccccc16 ; c1ccc2c(c1)Sc1cccc3c1B2c1cccc2c4cc5c6cccc7c8ccccc8n(c5cc4n-3c12)c76 ; c1ccc(-n2c3ccccc3c3c4c5ccc6c7c5n(c4ccc32)-c2ccccc2B7c2ccccc2S6)cc1 ; c1ccc2c(c1)Sc1ccc3c4cc5c6cccc7c8ccccc8n(c5cc4n4c3c1B2c1ccccc1-4)c76 ; c1ccc(-n2c3ccccc3c3c4c5ccc6c7c5n(c4ccc32)-c2cccc3c2B7c2c(cccc2S6)S3)cc1]

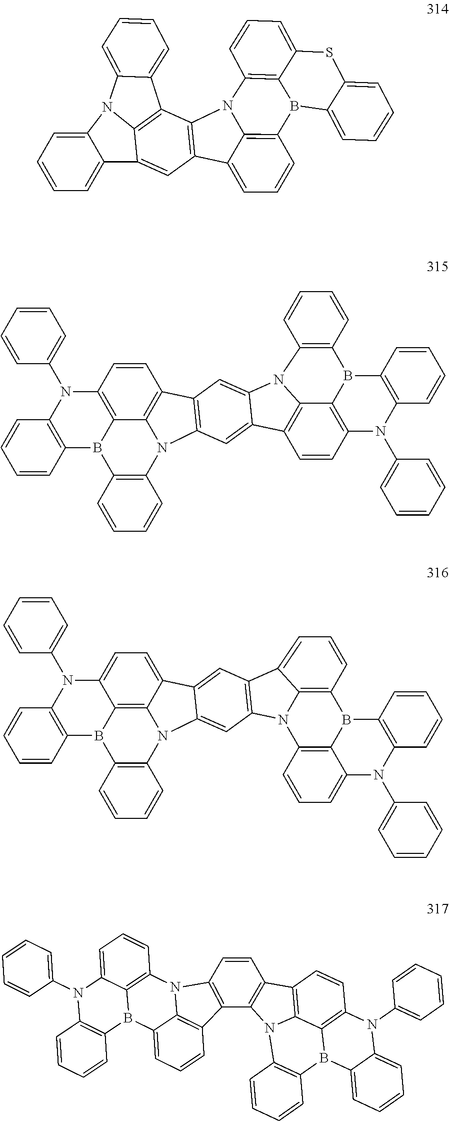 [SMILES: c1ccc2c(c1)Sc1cccc3c1B2c1cccc2c4cc5c6ccccc6n6c7ccccc7c(c4n-3c12)c56 ; c1ccc(N2c3ccccc3B3c4ccccc4-n4c5cc6c7ccc8c9c7n(c6cc5c5ccc2c3c54)-c2ccccc2B9c2ccccc2N8c2ccccc2)cc1 ; c1ccc(N2c3ccccc3B3c4c2cccc4-n2c4cc5c(cc4c4cccc3c42)c2ccc3c4c2n5-c2ccccc2B4c2ccccc2N3c2ccccc2)cc1 ; c1ccc(N2c3ccccc3B3c4c2cccc4-n2c4ccc5c6ccc7c8c6n(c5c4c4cccc3c42)-c2ccccc2B8c2ccccc2N7c2ccccc2)cc1]

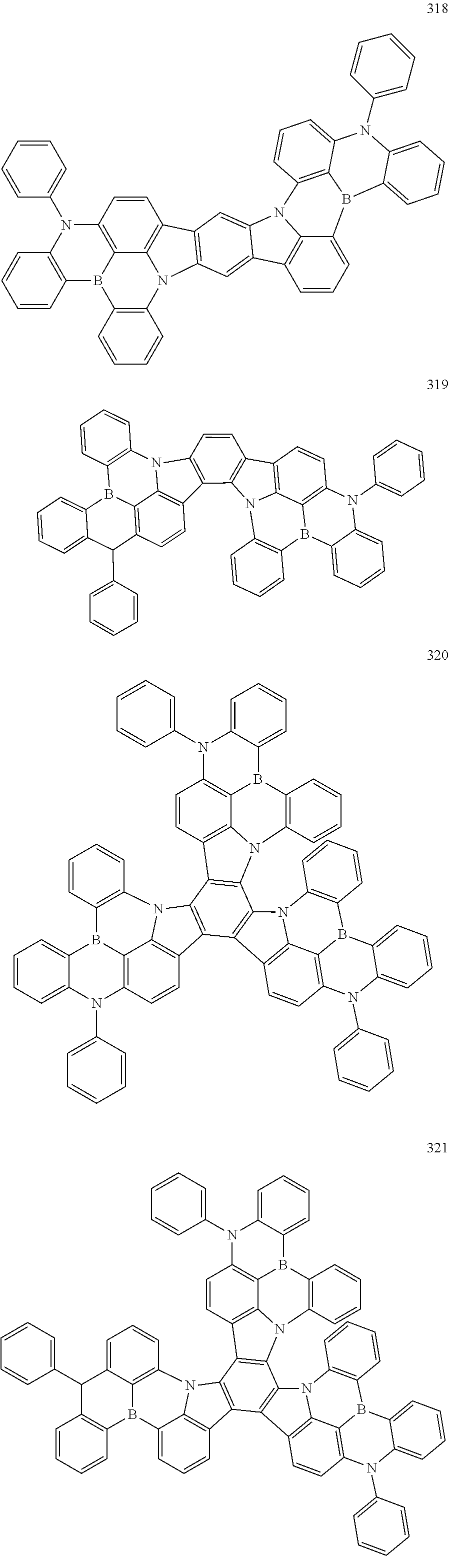 [SMILES: c1ccc(N2c3ccccc3B3c4c2cccc4-n2c4cc5c6ccc7c8c6n(c5cc4c4cccc3c42)-c2ccccc2B8c2ccccc2N7c2ccccc2)cc1 ; c1ccc(C2c3ccccc3B3c4ccccc4-n4c5ccc6c7ccc8c9c7n(c6c5c5ccc2c3c54)-c2ccccc2B9c2ccccc2N8c2ccccc2)cc1 ; c1ccc(N2c3ccccc3B3c4ccccc4-n4c5c3c2ccc5c2c3c5ccc6c7c5n(c3c3c(c5ccc8c9c5n3-c3ccccc3B9c3ccccc3N8c3ccccc3)c24)-c2ccccc2B7c2ccccc2N6c2ccccc2)cc1 ; c1ccc(C2c3ccccc3B3c4c2cccc4-n2c4c3cccc4c3c4c5ccc6c7c5n(c4c4c(c5ccc8c9c5n4-c4ccccc4B9c4ccccc4N8c4ccccc4)c32)-c2ccccc2B7c2ccccc2N6c2ccccc2)cc1]

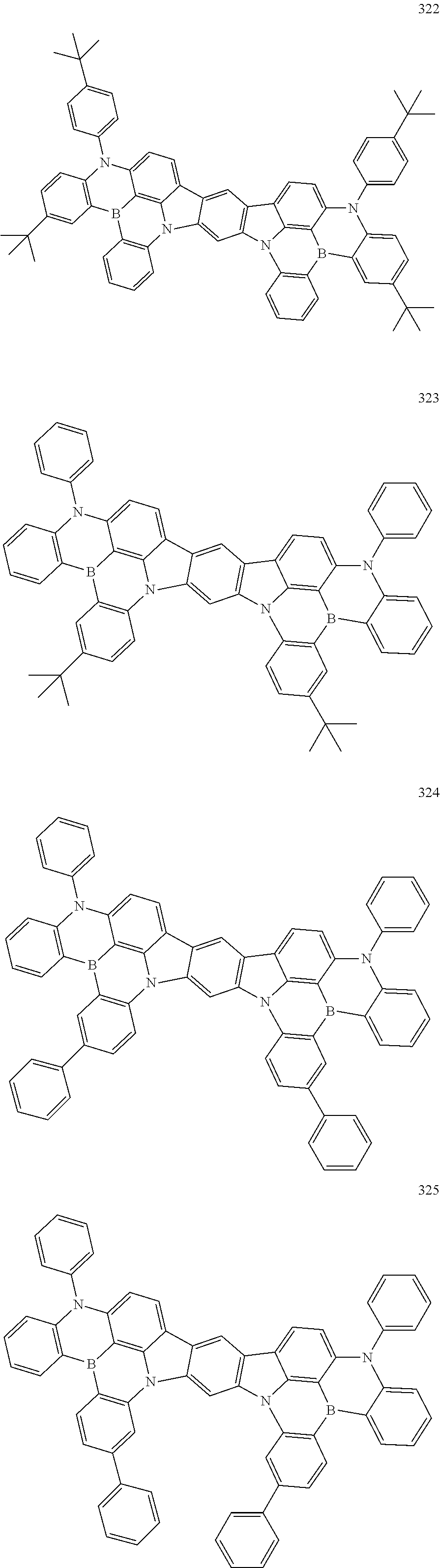

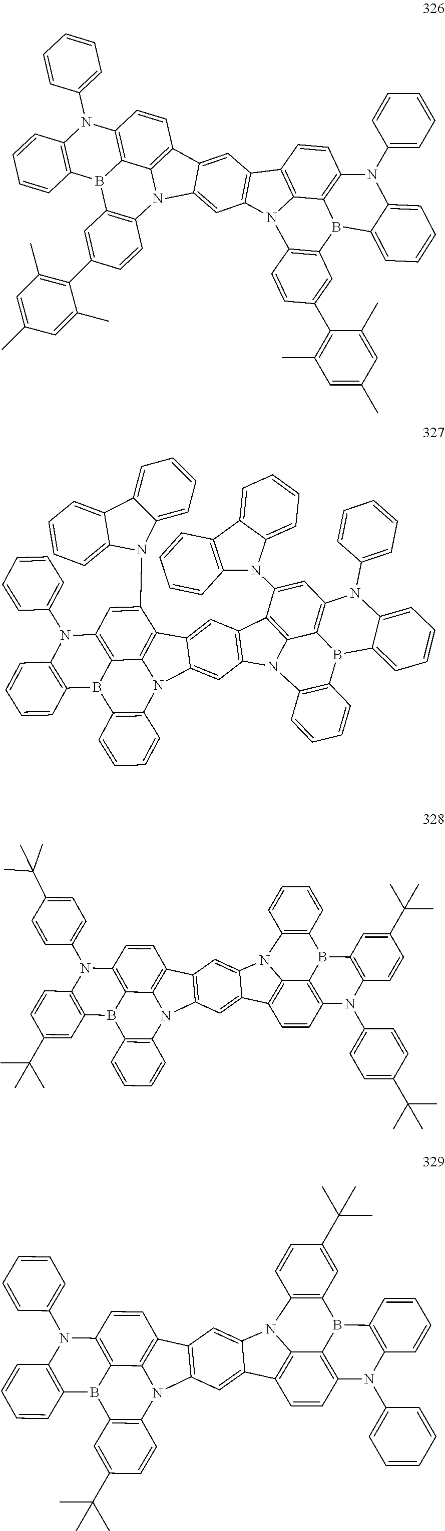

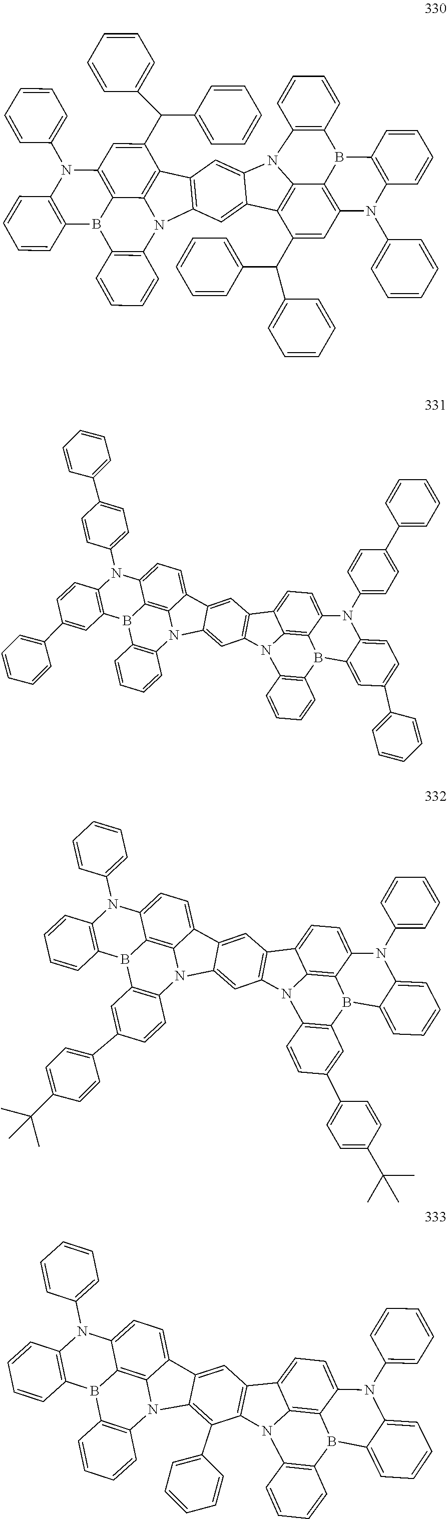

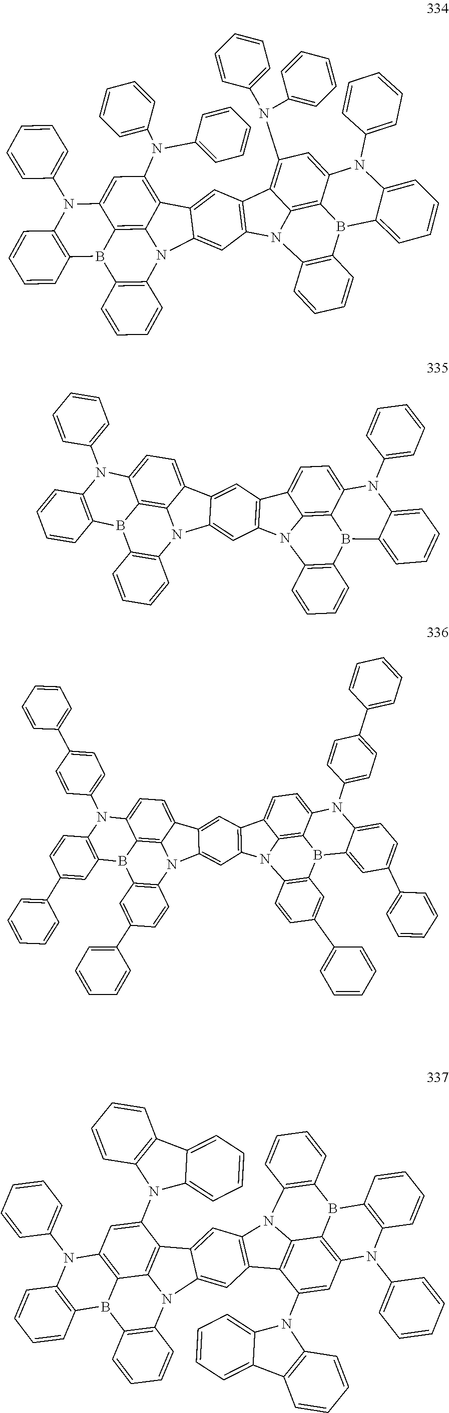

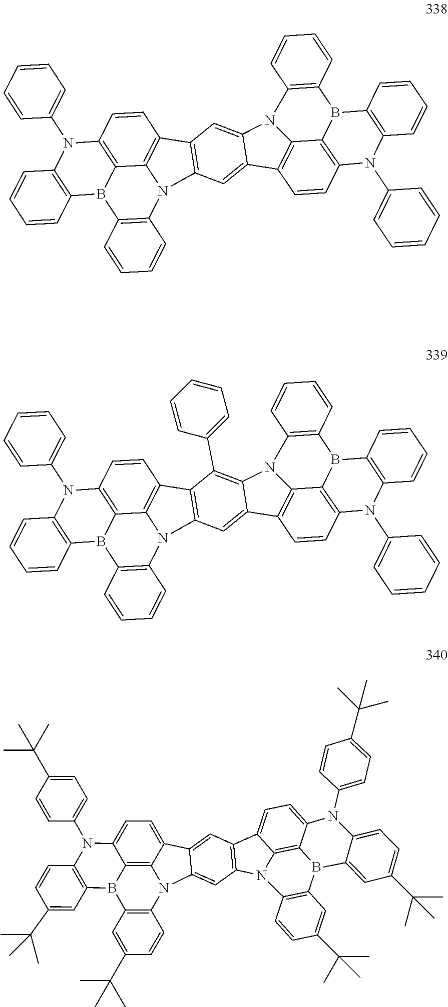 [SMILES: c1ccc(N2c3ccccc3B3c4ccccc4-n4c5cc6c7ccc8c9c7n(c6cc5c5ccc2c3c54)-c2ccccc2B9c2ccccc2N8c2ccccc2)cc1 ; c1ccc(-c2c3c4ccc5c6c4n(c3cc3c4ccc7c8c4n(c23)-c2ccccc2B8c2ccccc2N7c2ccccc2)-c2ccccc2B6c2ccccc2N5c2ccccc2)cc1 ; CC(C)(C)c1ccc(N2c3ccc(C(C)(C)C)cc3B3c4cc(C(C)(C)C)ccc4-n4c5cc6c(cc5c5ccc2c3c54)c2ccc3c4c2n6-c2ccc(C(C)(C)C)cc2B4c2cc(C(C)(C)C)ccc2N3c2ccc(C(C)(C)C)cc2)cc1]

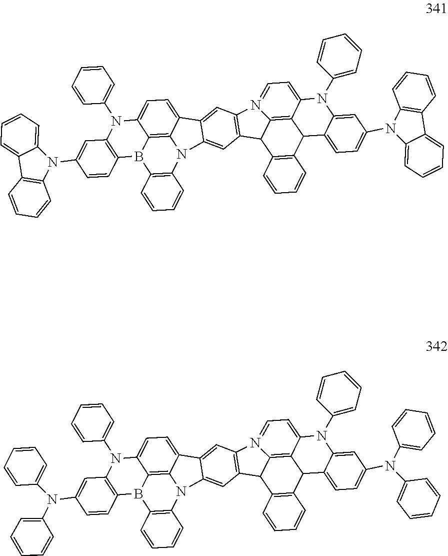

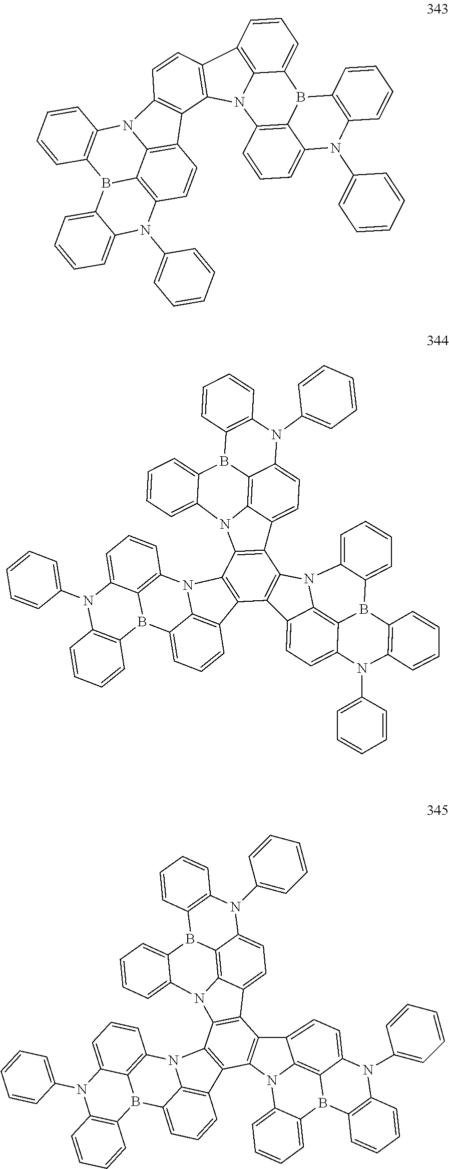 [SMILES: c1ccc(N2c3ccccc3B3c4c2cccc4-n2c4c3cccc4c3ccc4c(c5ccc6c7c5n4-c4ccccc4B7c4ccccc4N6c4ccccc4)c32)cc1 ; c1ccc(N2c3ccccc3B3c4c2cccc4-n2c4c3cccc4c3c4c5ccc6c7c5n(c4c4c5ccc8c9c5n(c4c32)-c2ccccc2B9c2ccccc2N8c2ccccc2)-c2ccccc2B7c2ccccc2N6c2ccccc2)cc1 ; c1ccc(N2c3ccccc3B3c4c2cccc4-n2c4c3cccc4c3c4c(c5ccc6c7c5n4-c4ccccc4B7c4ccccc4N6c4ccccc4)c4c5ccc6c7c5n(c4c32)-c2ccccc2B7c2ccccc2N6c2ccccc2)cc1]

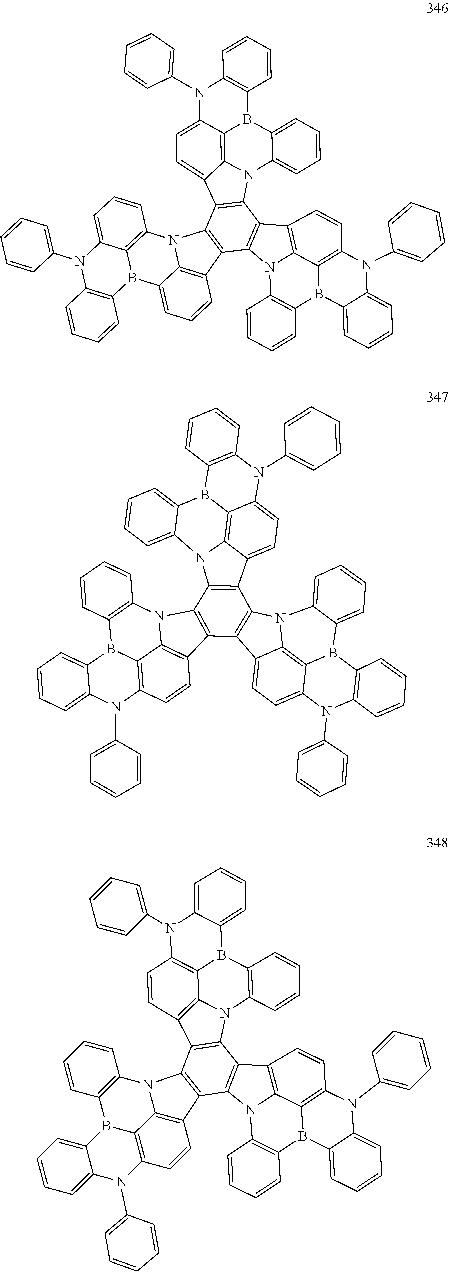 [SMILES: c1ccc(N2c3ccccc3B3c4c2cccc4-n2c4c3cccc4c3c2c2c4ccc5c6c4n(c2c2c4ccc7c8c4n(c32)-c2ccccc2B8c2ccccc2N7c2ccccc2)-c2ccccc2B6c2ccccc2N5c2ccccc2)cc1 ; c1ccc(N2c3ccccc3B3c4ccccc4-n4c5c3c2ccc5c2c3c5ccc6c7c5n(c3c3c(c5ccc8c9c5n3-c3ccccc3B9c3ccccc3N8c3ccccc3)c24)-c2ccccc2B7c2ccccc2N6c2ccccc2)cc1 ; c1ccc(N2c3ccccc3B3c4ccccc4-n4c5c3c2ccc5c2c4c3c4ccc5c6c4n(c3c3c4ccc7c8c4n(c23)-c2ccccc2B8c2ccccc2N7c2ccccc2)-c2ccccc2B6c2ccccc2N5c2ccccc2)cc1]

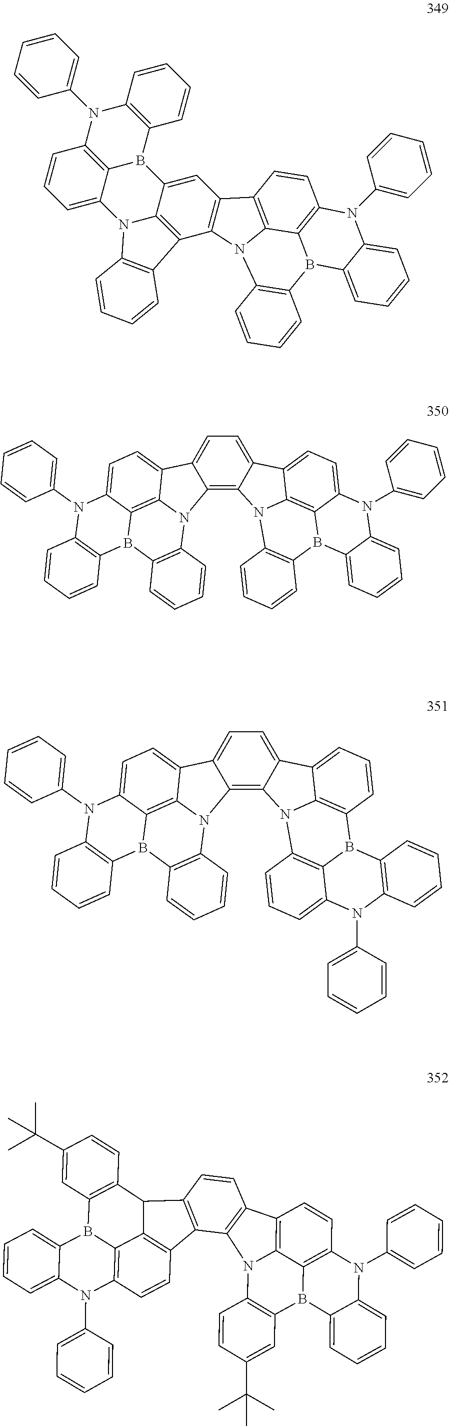 [SMILES: c1ccc(N2c3ccccc3B3c4c2cccc4-n2c4ccccc4c4c2c3cc2c3ccc5c6c3n(c24)-c2ccccc2B6c2ccccc2N5c2ccccc2)cc1 ; c1ccc(N2c3ccccc3B3c4ccccc4-n4c5c3c2ccc5c2ccc3c5ccc6c7c5n(c3c24)-c2ccccc2B7c2ccccc2N6c2ccccc2)cc1 ; c1ccc(N2c3ccccc3B3c4c2cccc4-n2c4c3cccc4c3ccc4c5ccc6c7c5n(c4c32)-c2ccccc2B7c2ccccc2N6c2ccccc2)cc1 ; CC(C)(C)c1ccc2c(c1)B1c3ccccc3N(c3ccccc3)c3ccc4c(c31)C2c1ccc2c3ccc5c6c3n(c2c1-4)-c1ccc(C(C)(C)C)cc1B6c1ccccc1N5c1ccccc1]

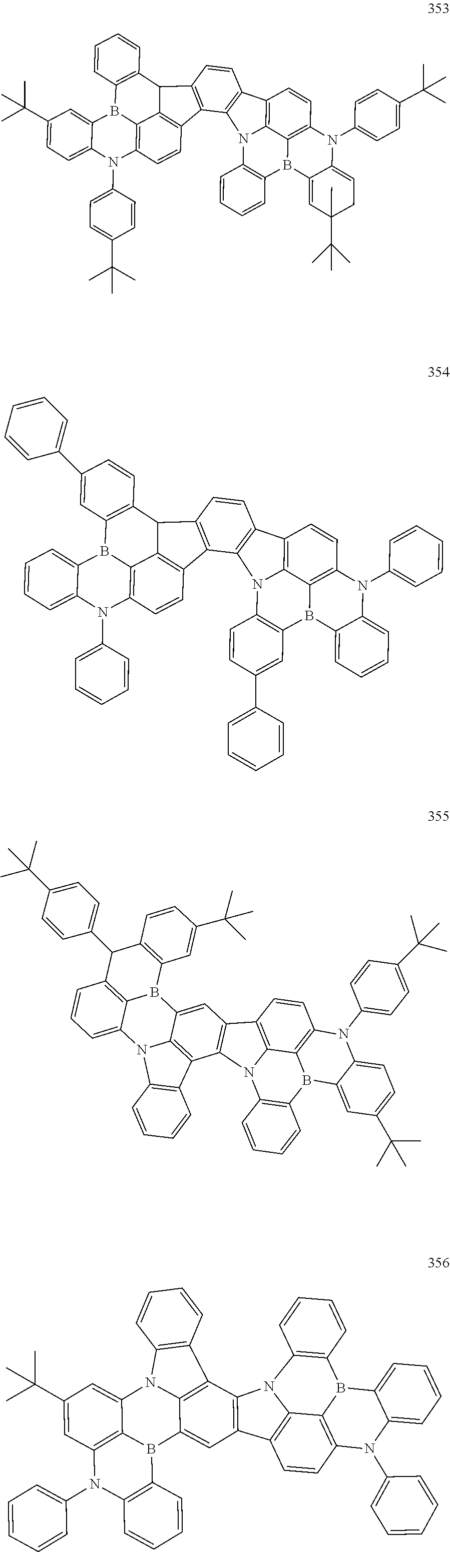

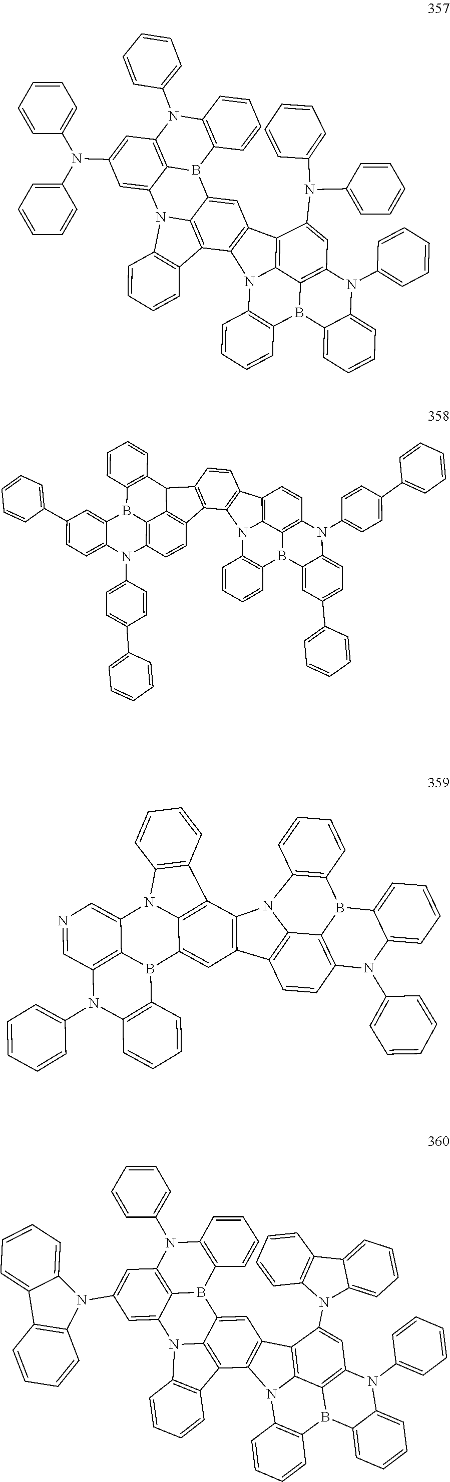

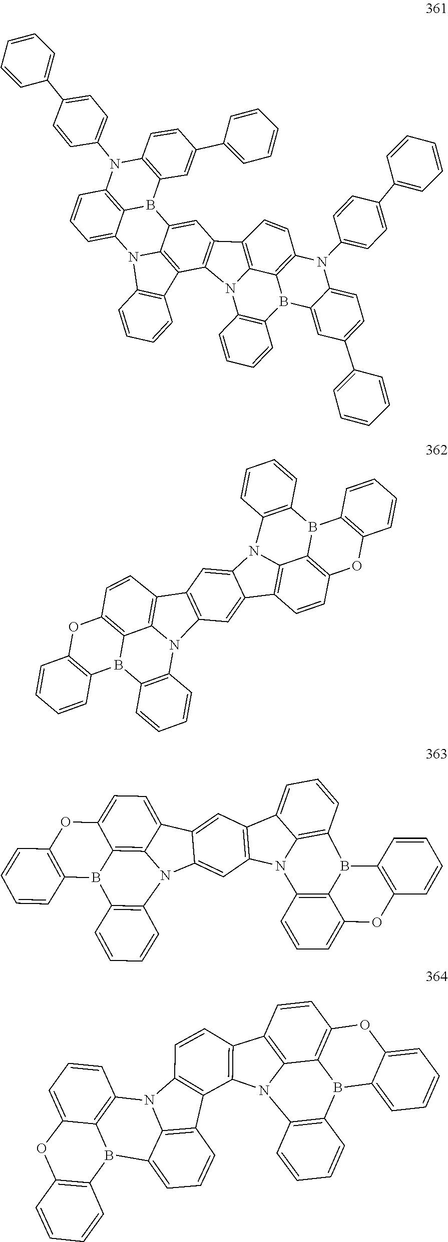 [SMILES: c1ccc(-c2ccc(N3c4ccc(-c5ccccc5)cc4B4c5c3cccc5-n3c5ccccc5c5c3c4cc3c4ccc6c7c4n(c35)-c3ccccc3B7c3cc(-c4ccccc4)ccc3N6c3ccc(-c4ccccc4)cc3)cc2)cc1 ; c1ccc2c(c1)Oc1ccc3c4cc5c(cc4n4c3c1B2c1ccccc1-4)c1ccc2c3c1n5-c1ccccc1B3c1ccccc1O2 ; c1ccc2c(c1)Oc1cccc3c1B2c1cccc2c4cc5c6ccc7c8c6n(c5cc4n-3c12)-c1ccccc1B8c1ccccc1O7 ; c1ccc2c(c1)Oc1cccc3c1B2c1cccc2c4c(ccc5c6ccc7c8c6n(c54)-c4ccccc4B8c4ccccc4O7)n-3c12]

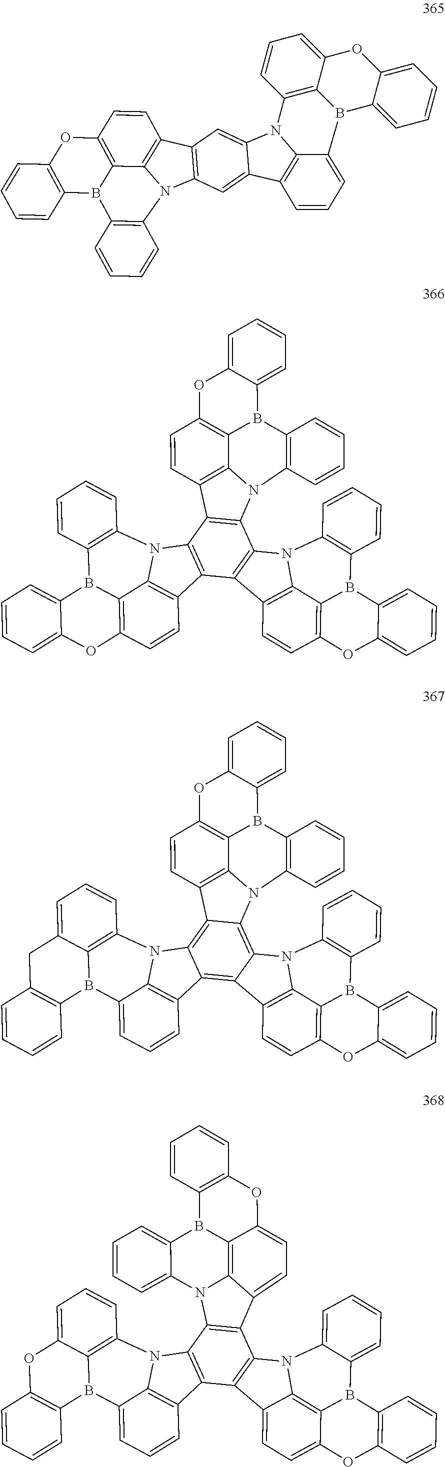 [SMILES: c1ccc2c(c1)Oc1cccc3c1B2c1cccc2c4cc5c(cc4n-3c12)c1ccc2c3c1n5-c1ccccc1B3c1ccccc1O2 ; c1ccc2c(c1)Oc1ccc3c4c5c6ccc7c8c6n(c5c5c(c6ccc9c%10c6n5-c5ccccc5B%10c5ccccc5O9)c4n4c3c1B2c1ccccc1-4)-c1ccccc1B8c1ccccc1O7 ; c1ccc2c(c1)Cc1cccc3c1B2c1cccc2c4c5c6ccc7c8c6n(c5c5c(c6ccc9c%10c6n5-c5ccccc5B%10c5ccccc5O9)c4n-3c12)-c1ccccc1B8c1ccccc1O7 ; c1ccc2c(c1)Oc1ccc3c4c5c6cccc7c6n(c5c5c(c6ccc8c9c6n5-c5ccccc5B9c5ccccc5O8)c4n4c3c1B2c1ccccc1-4)-c1cccc2c1B7c1ccccc1O2]

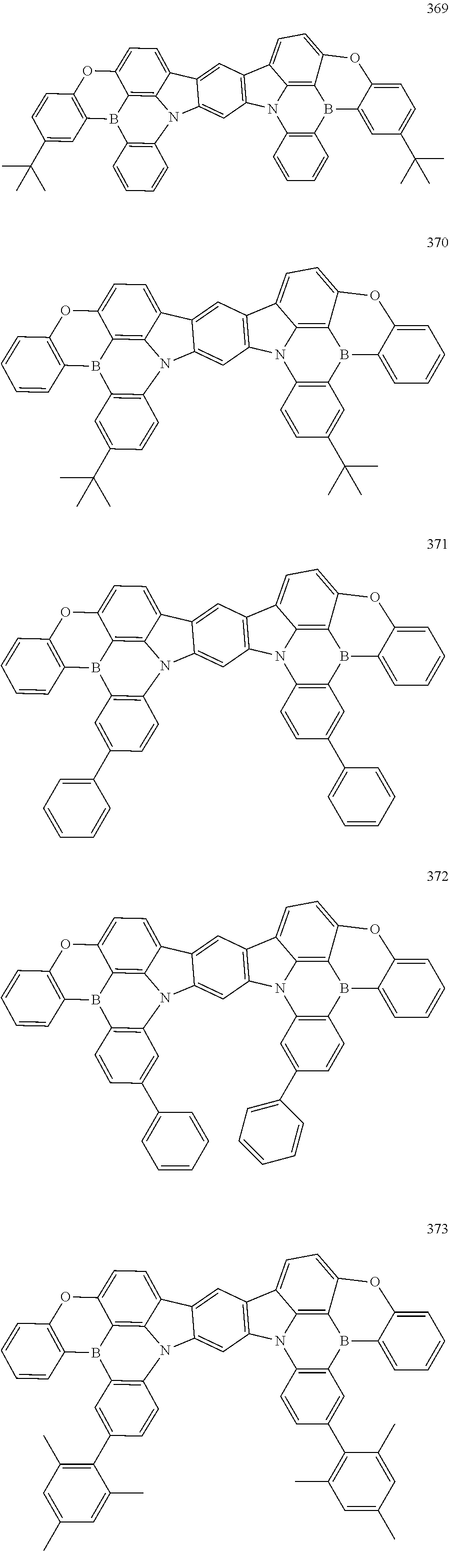

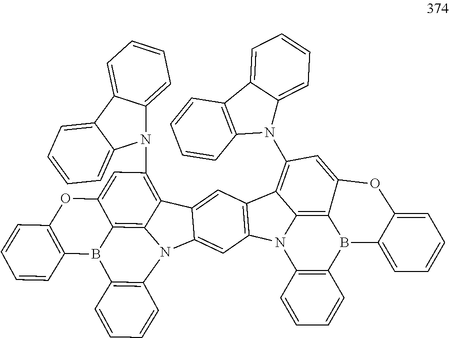 [SMILES: c1ccc2c(c1)Oc1cc(-n3c4ccccc4c4ccccc43)c3c4cc5c6c(-n7c8ccccc8c8ccccc87)cc7c8c6n(c5cc4n4c3c1B2c1ccccc1-4)-c1ccccc1B8c1ccccc1O7]

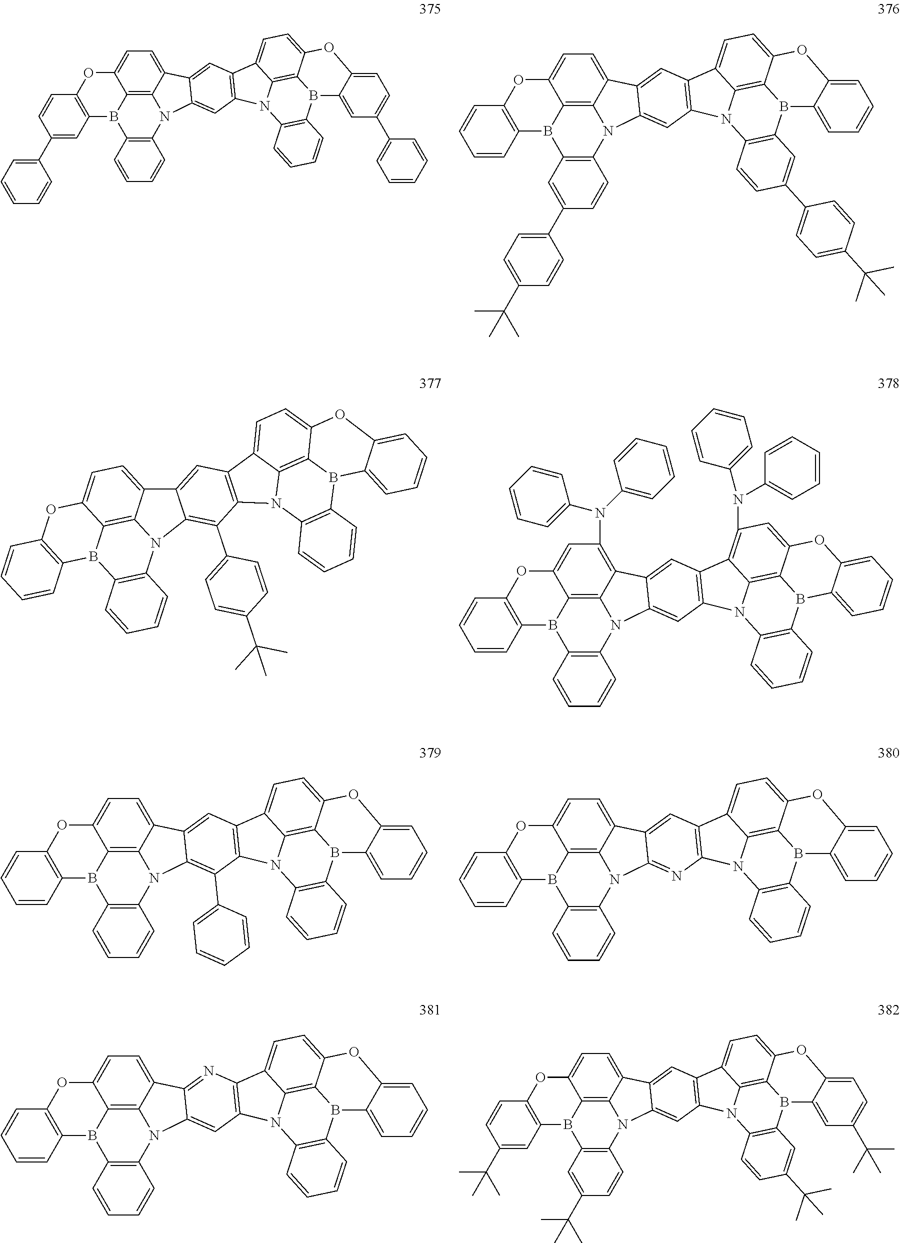

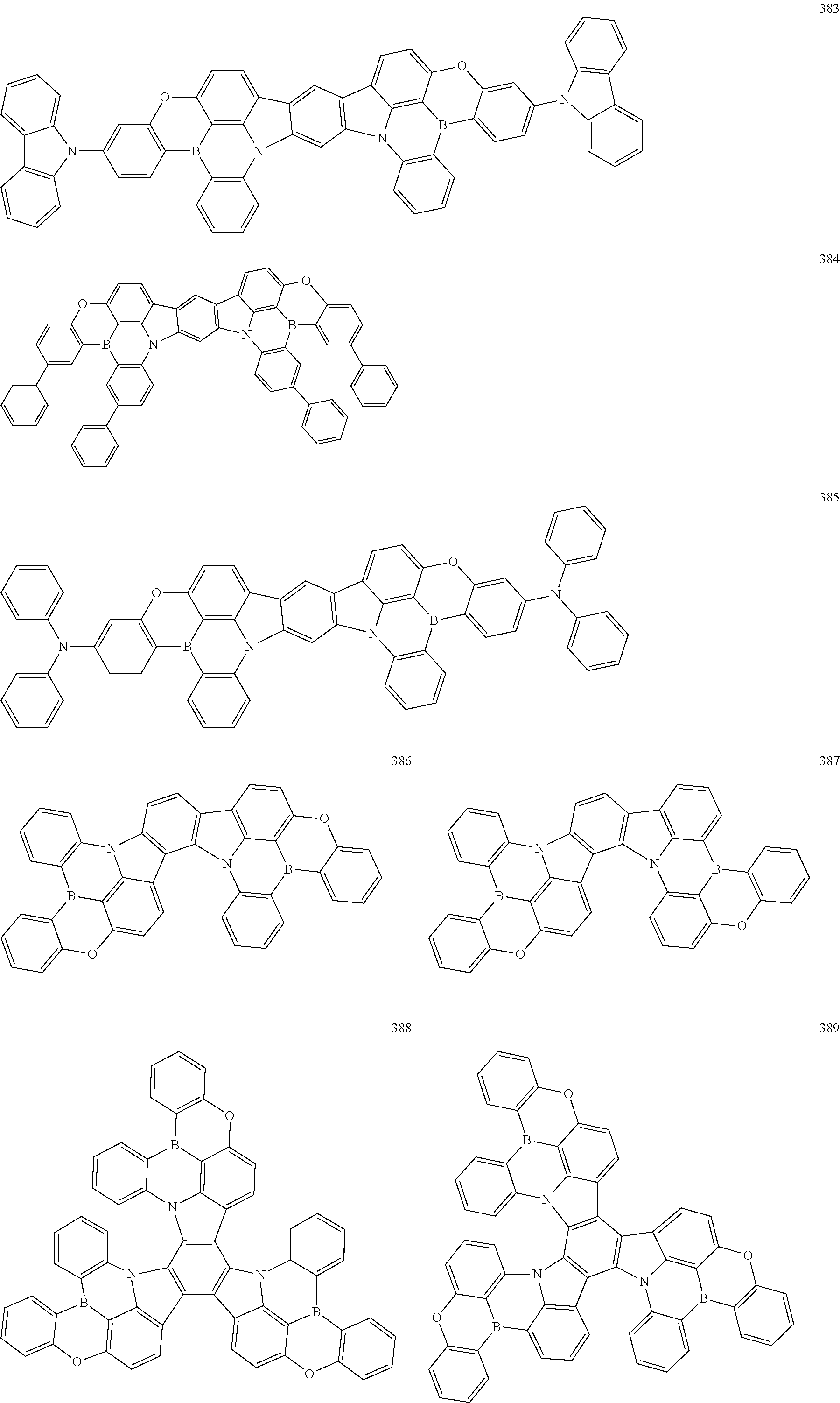

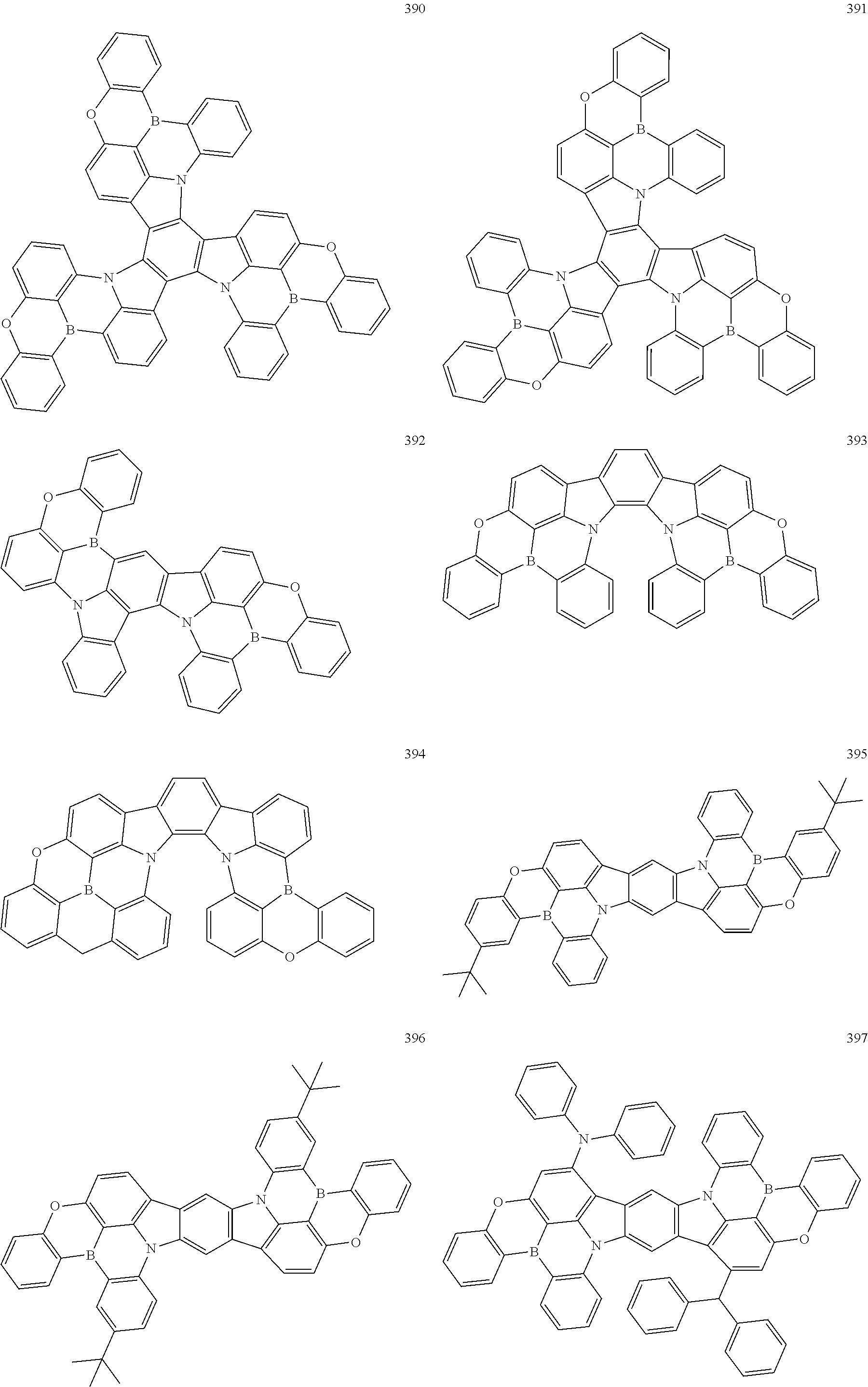

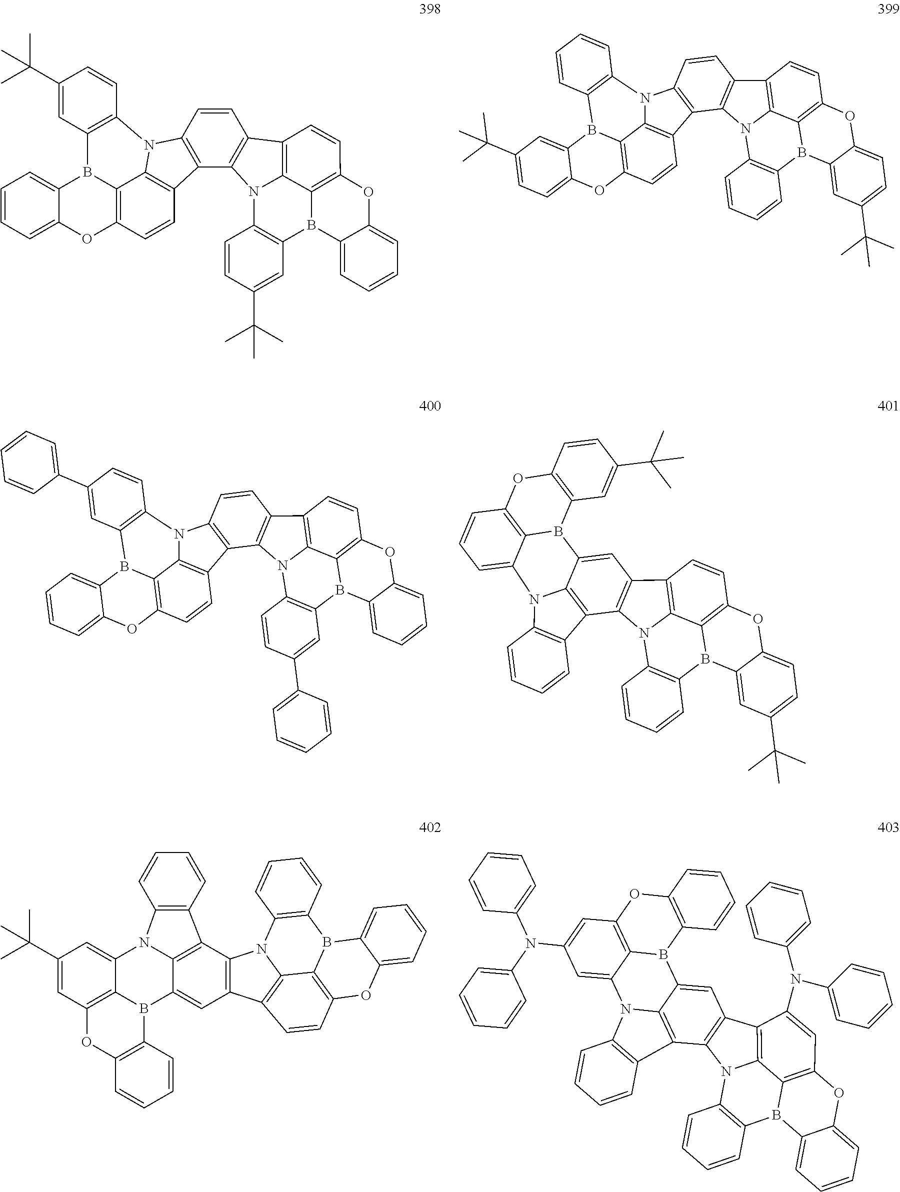

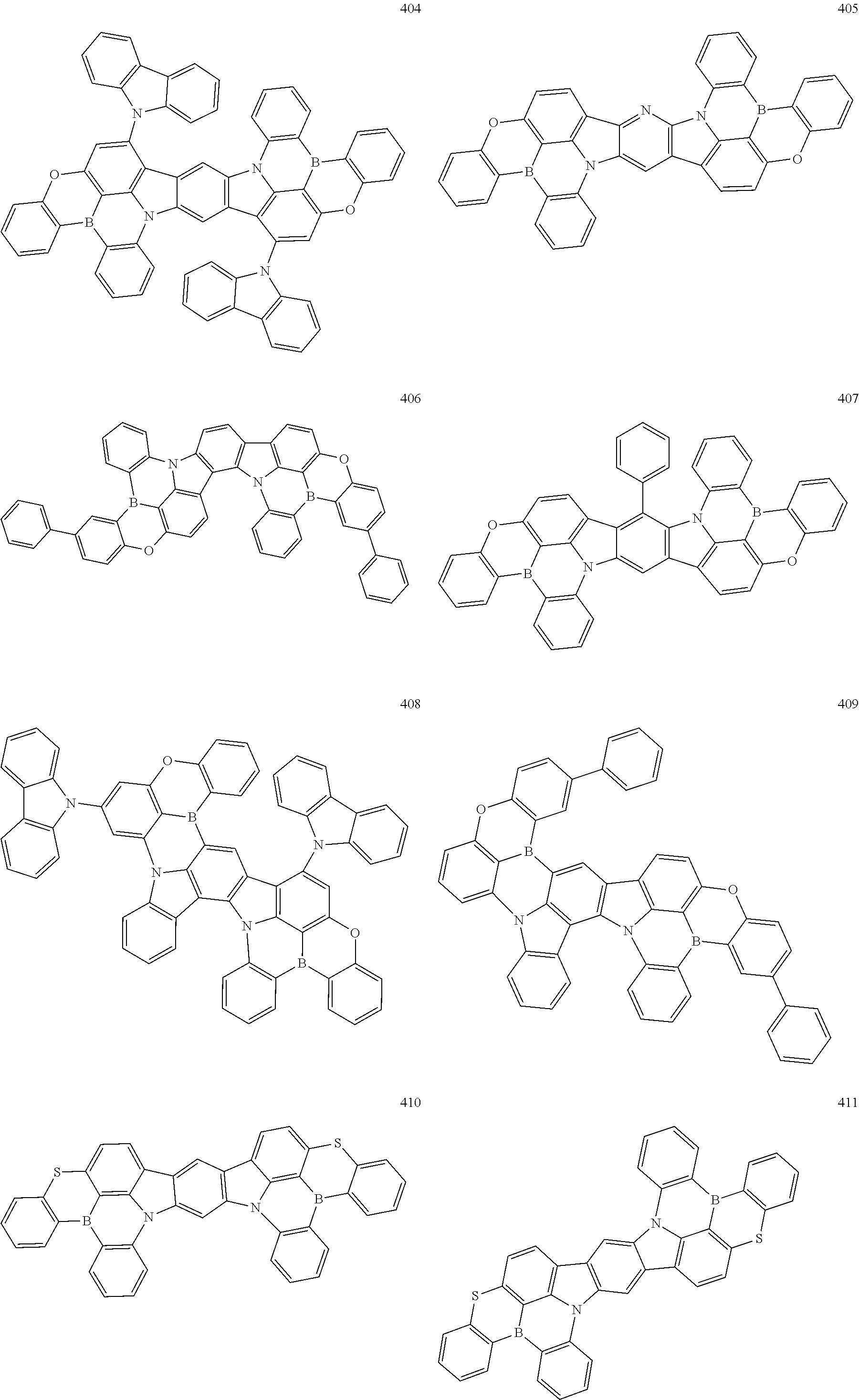

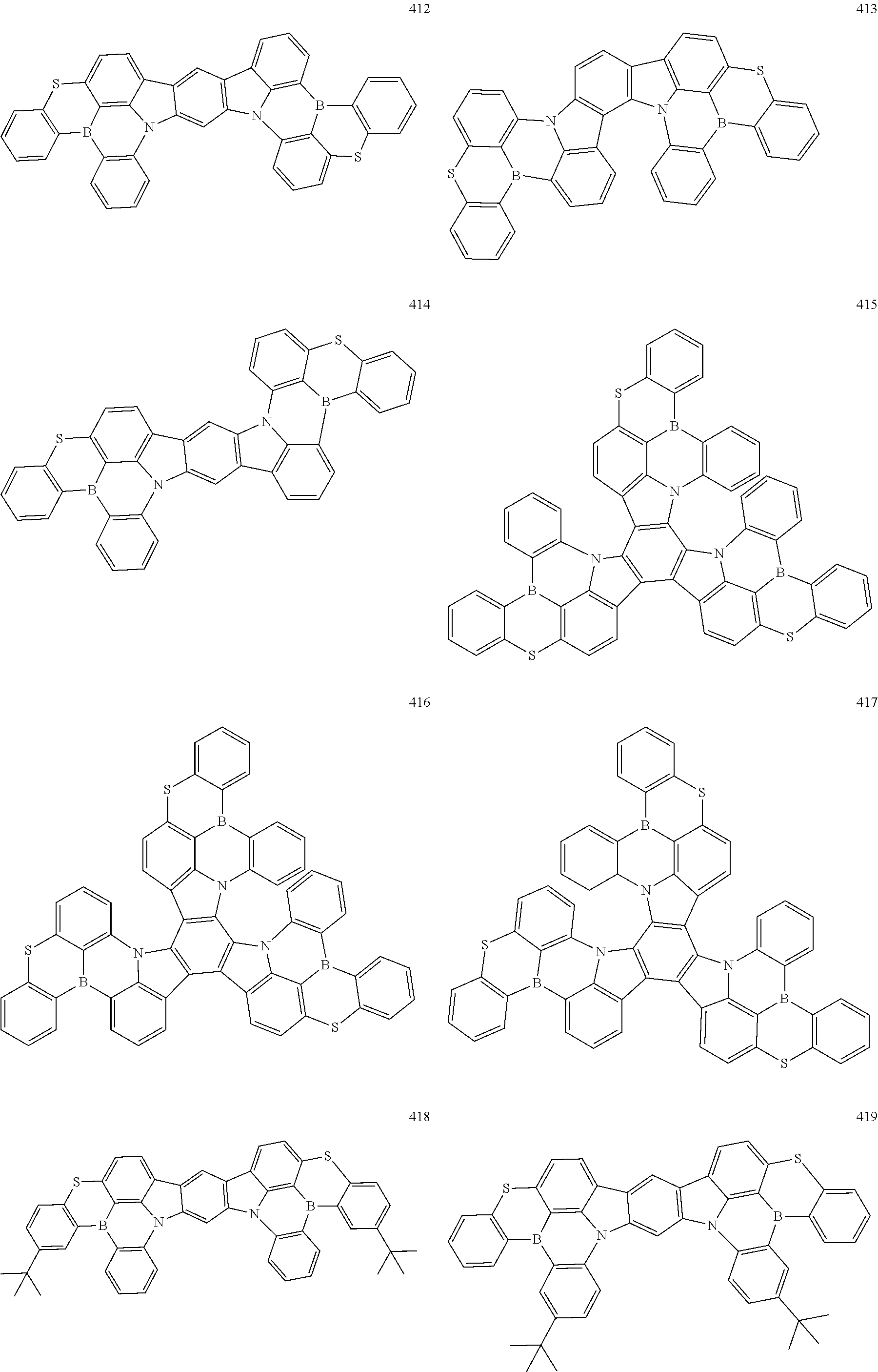

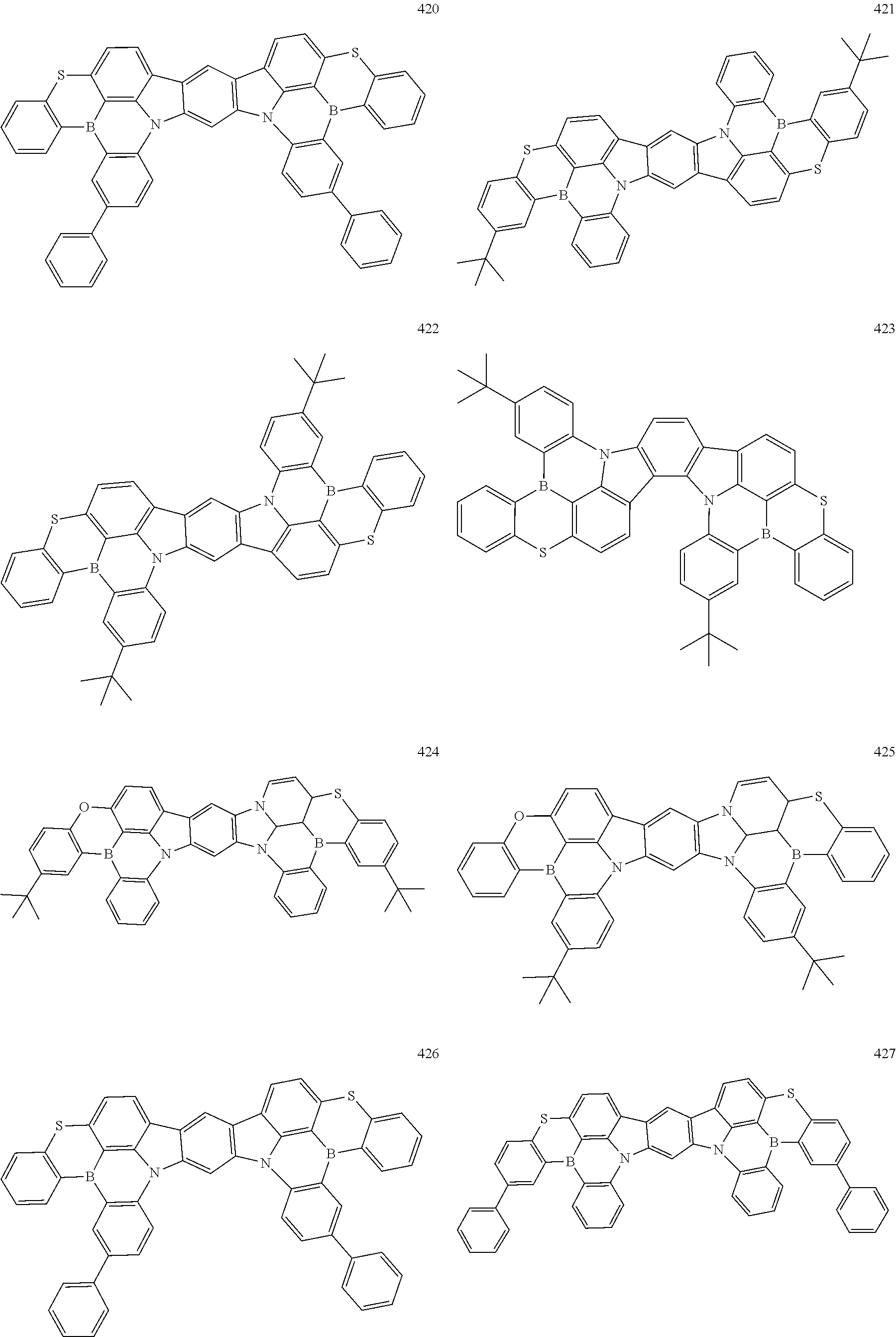

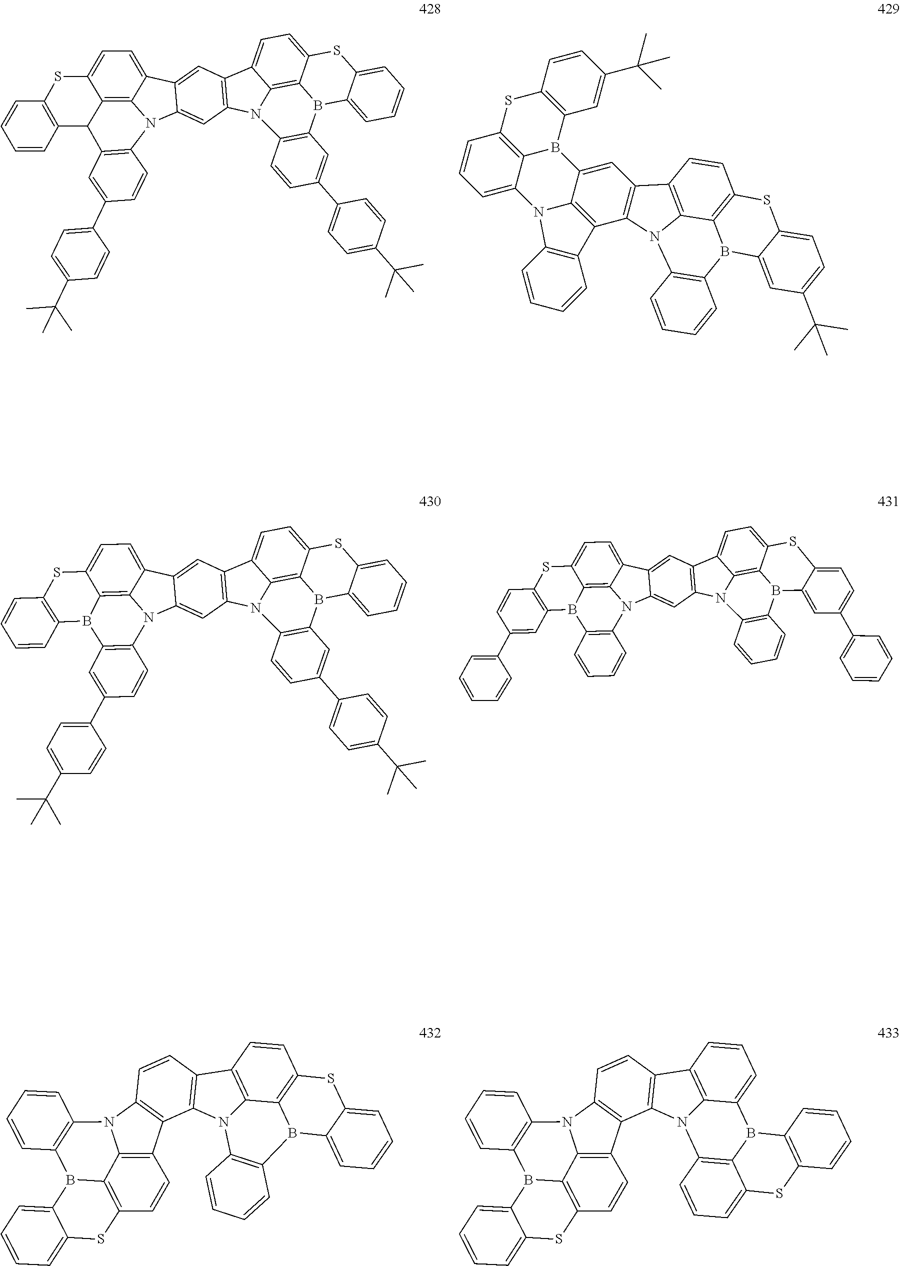

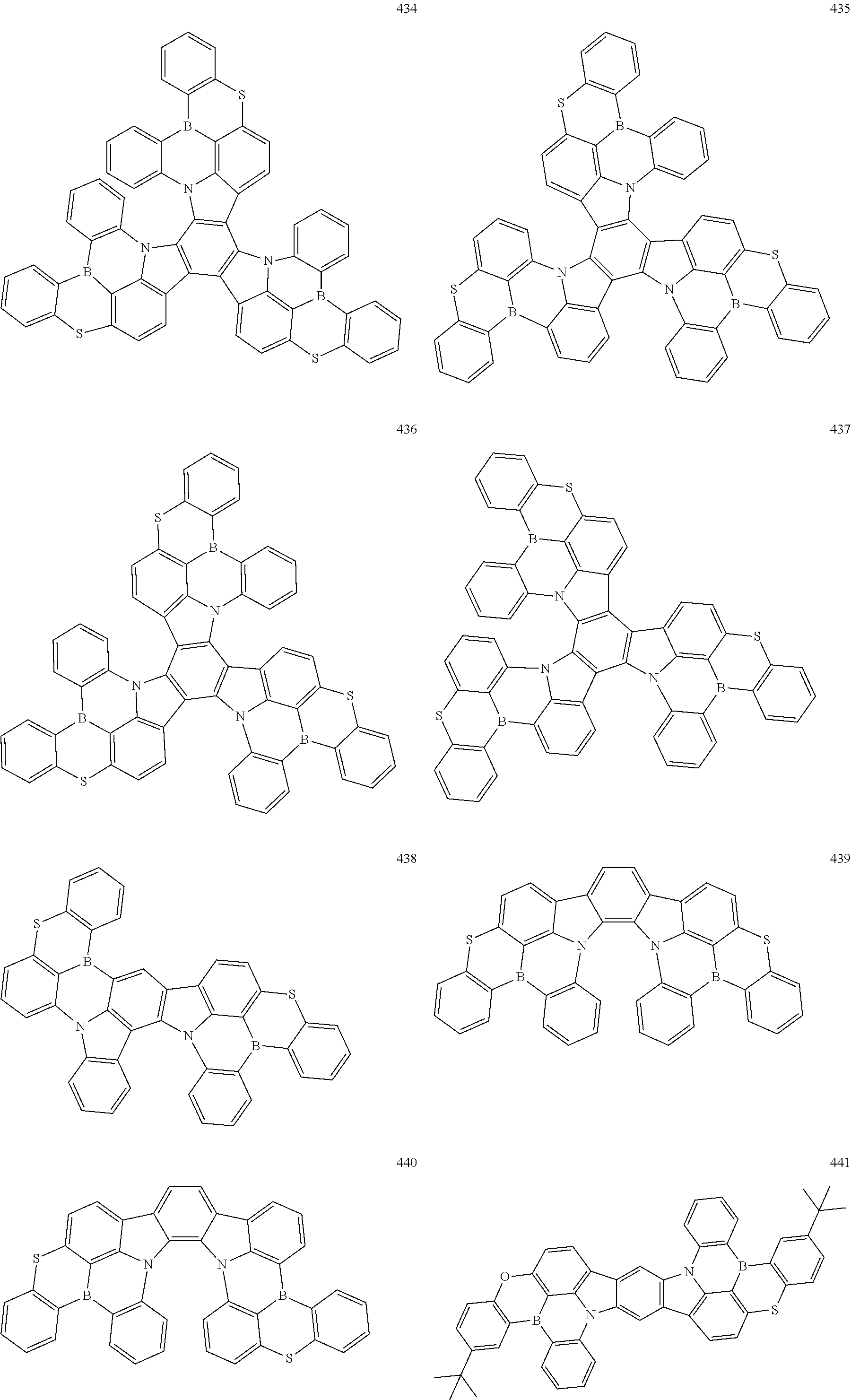

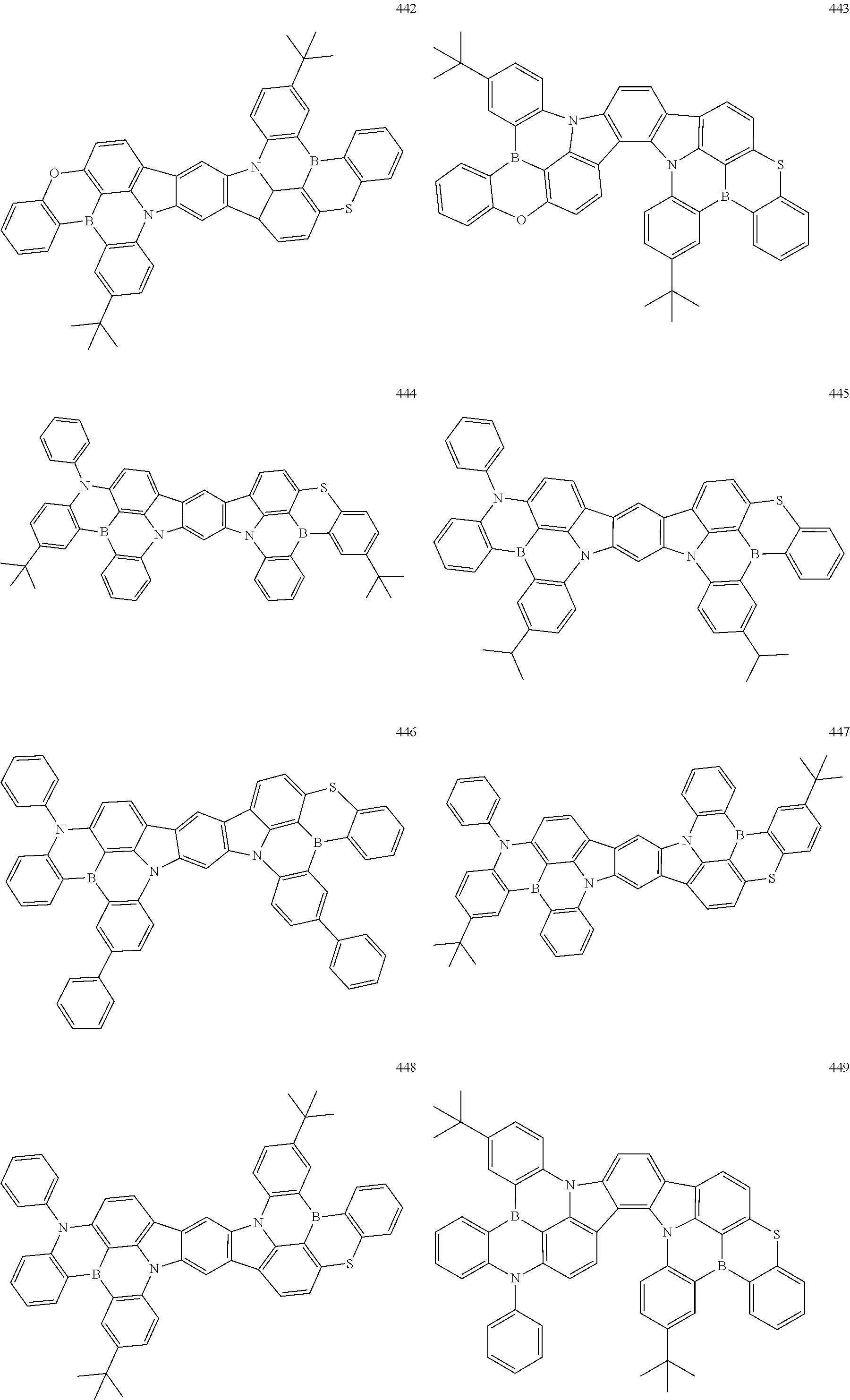

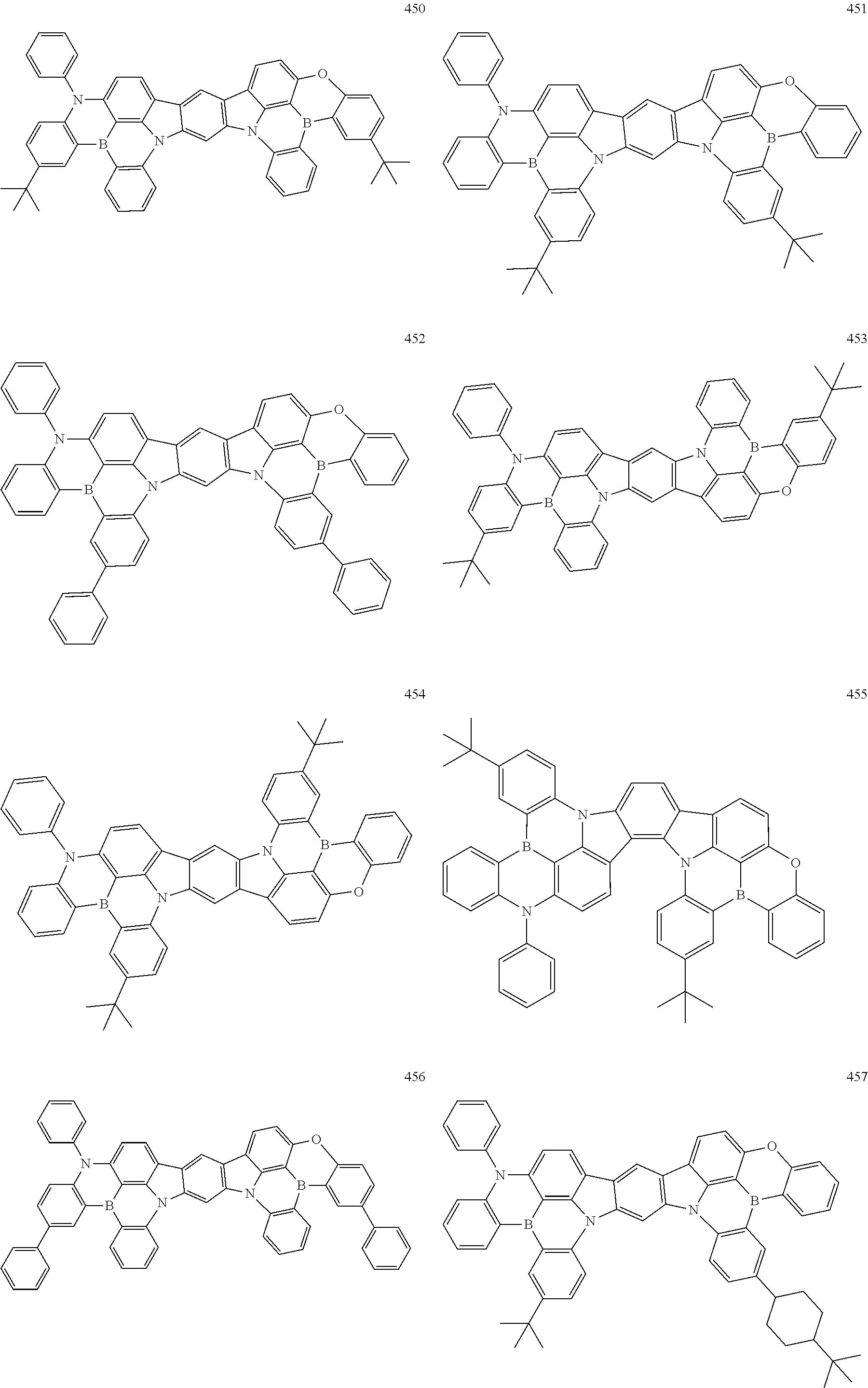

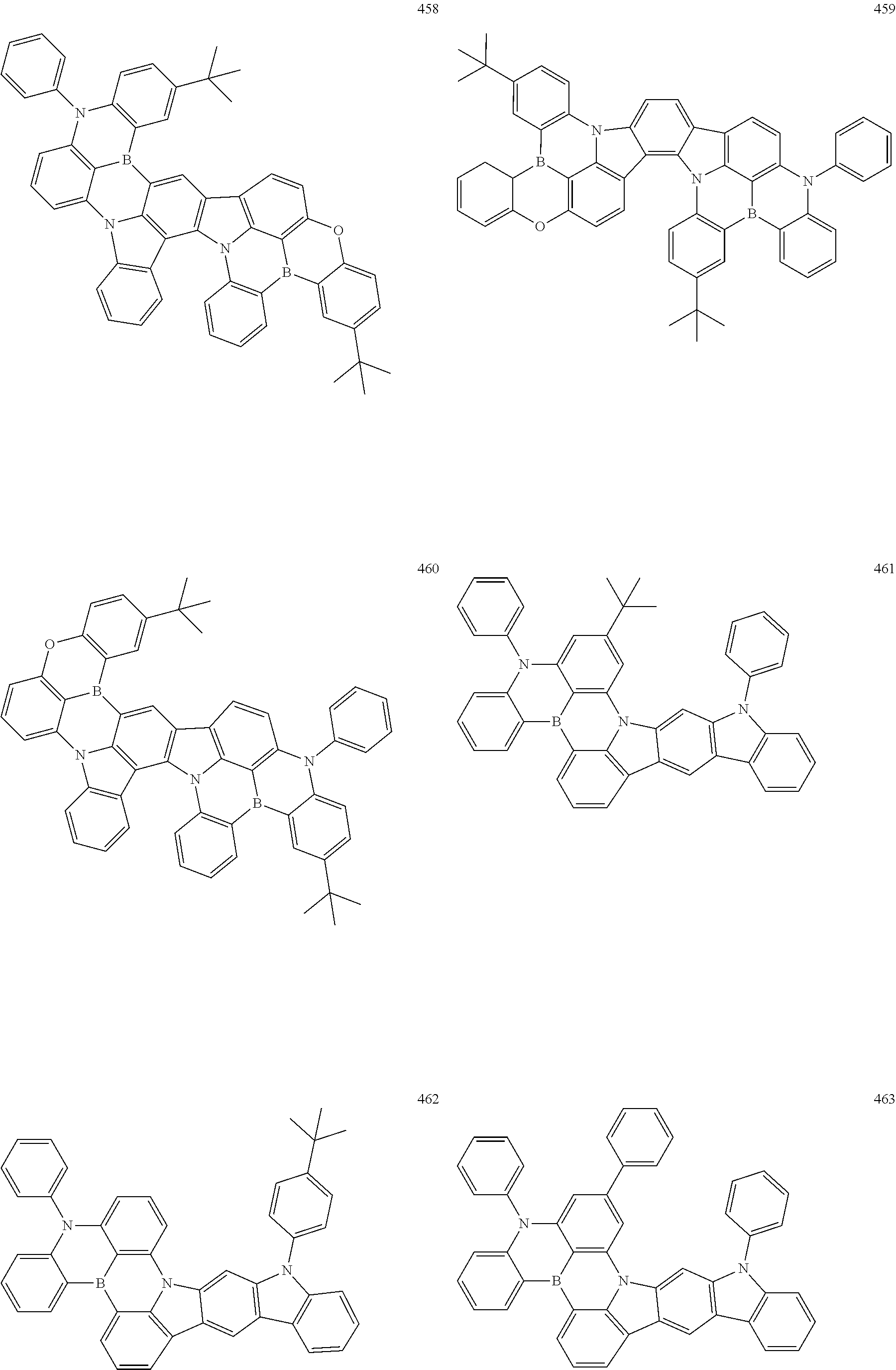

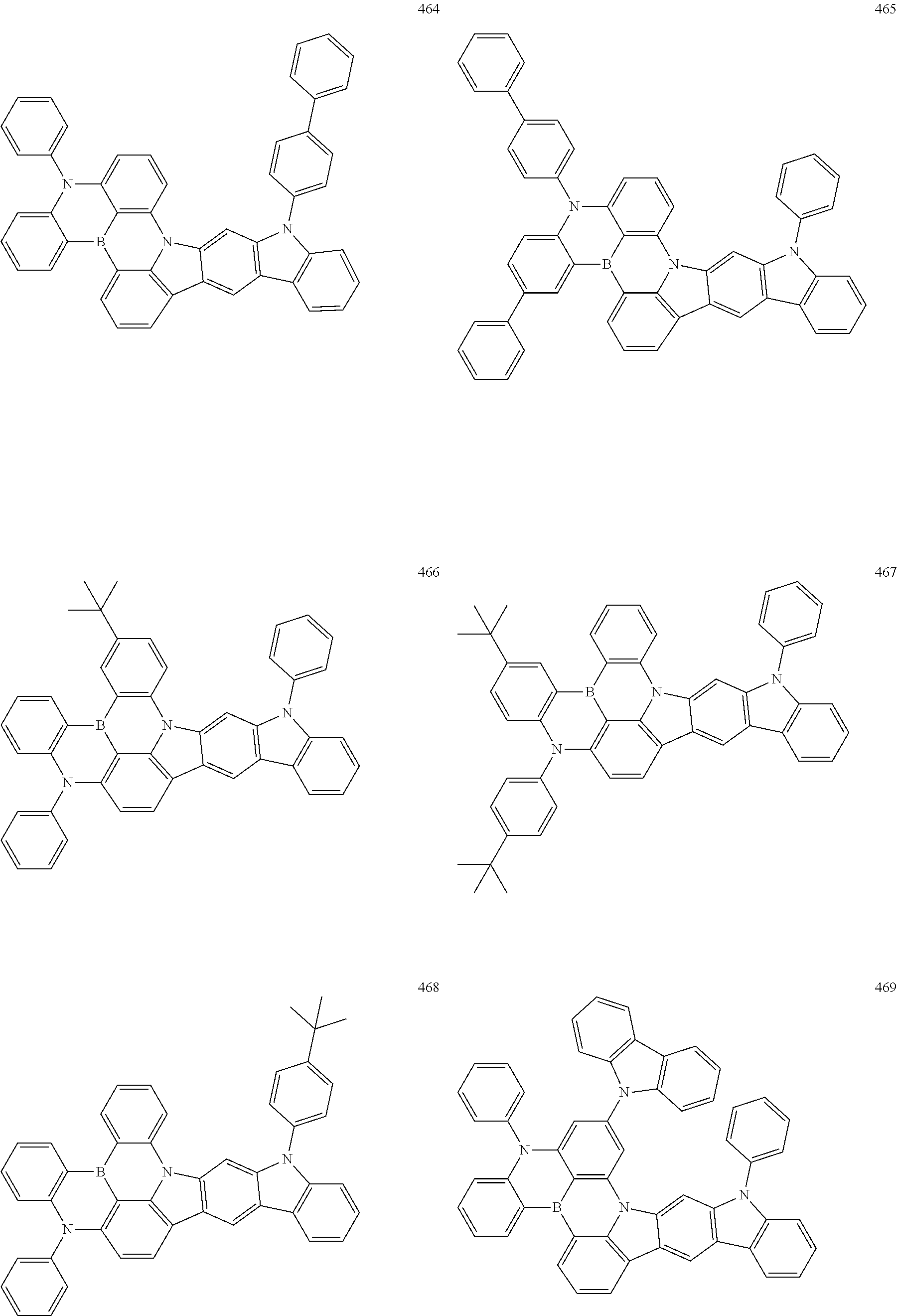

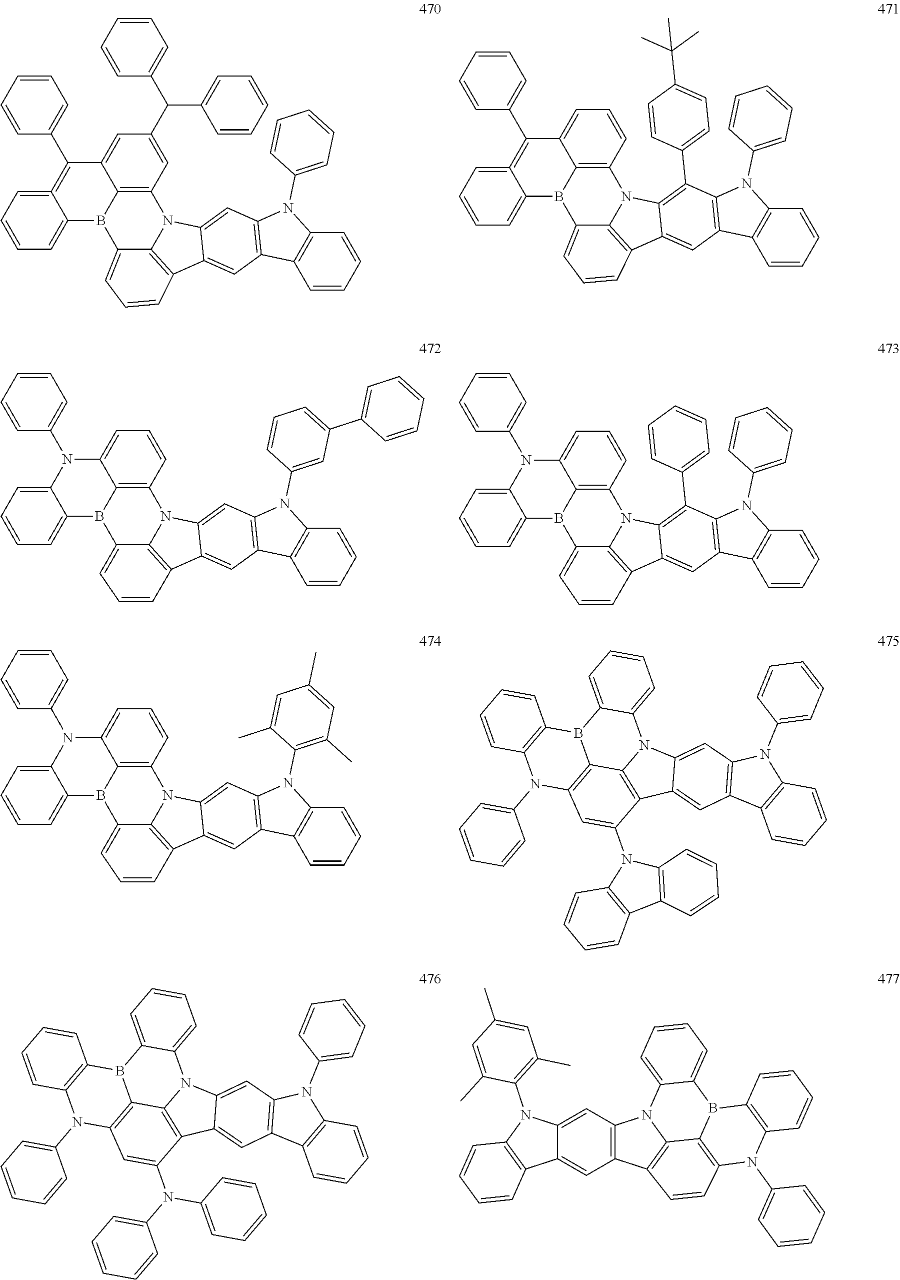

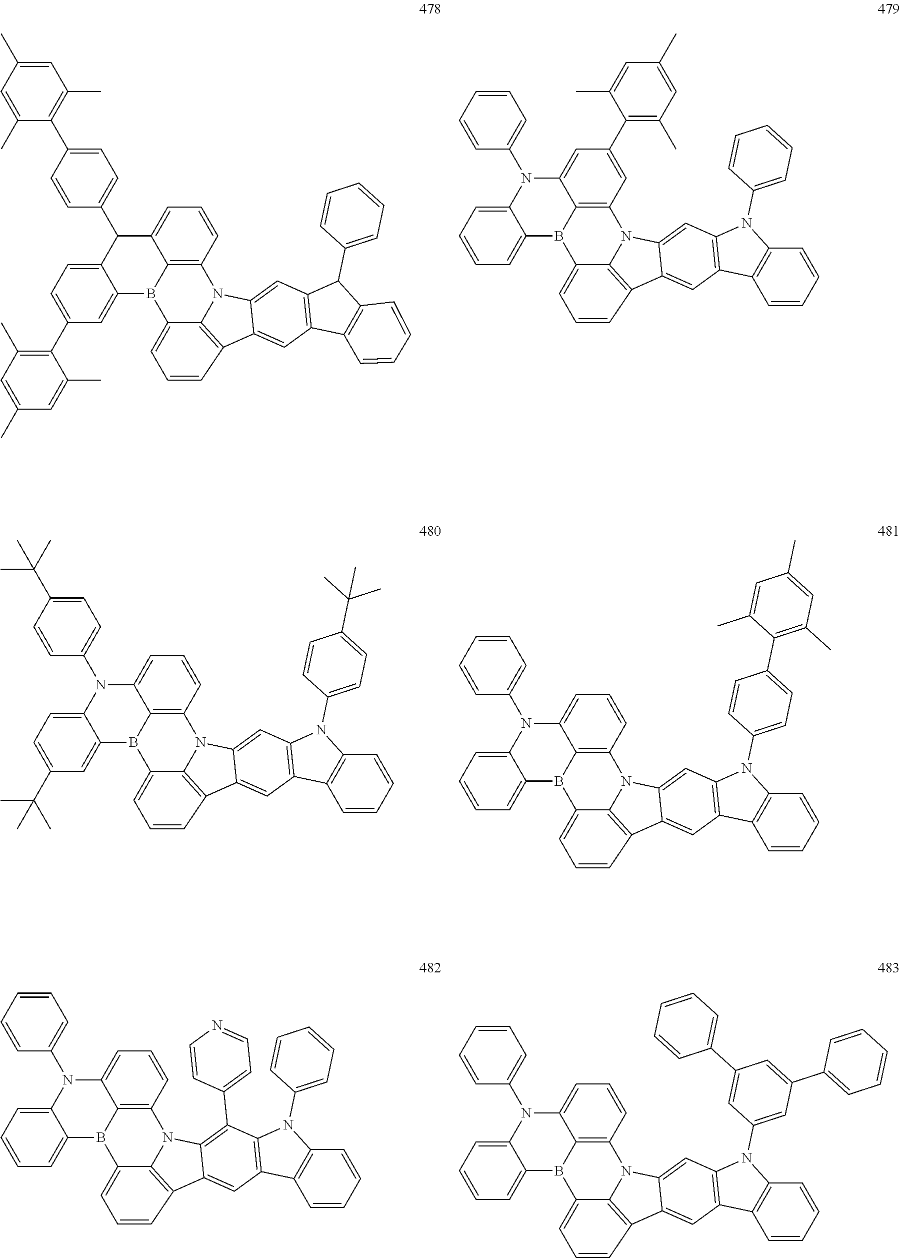

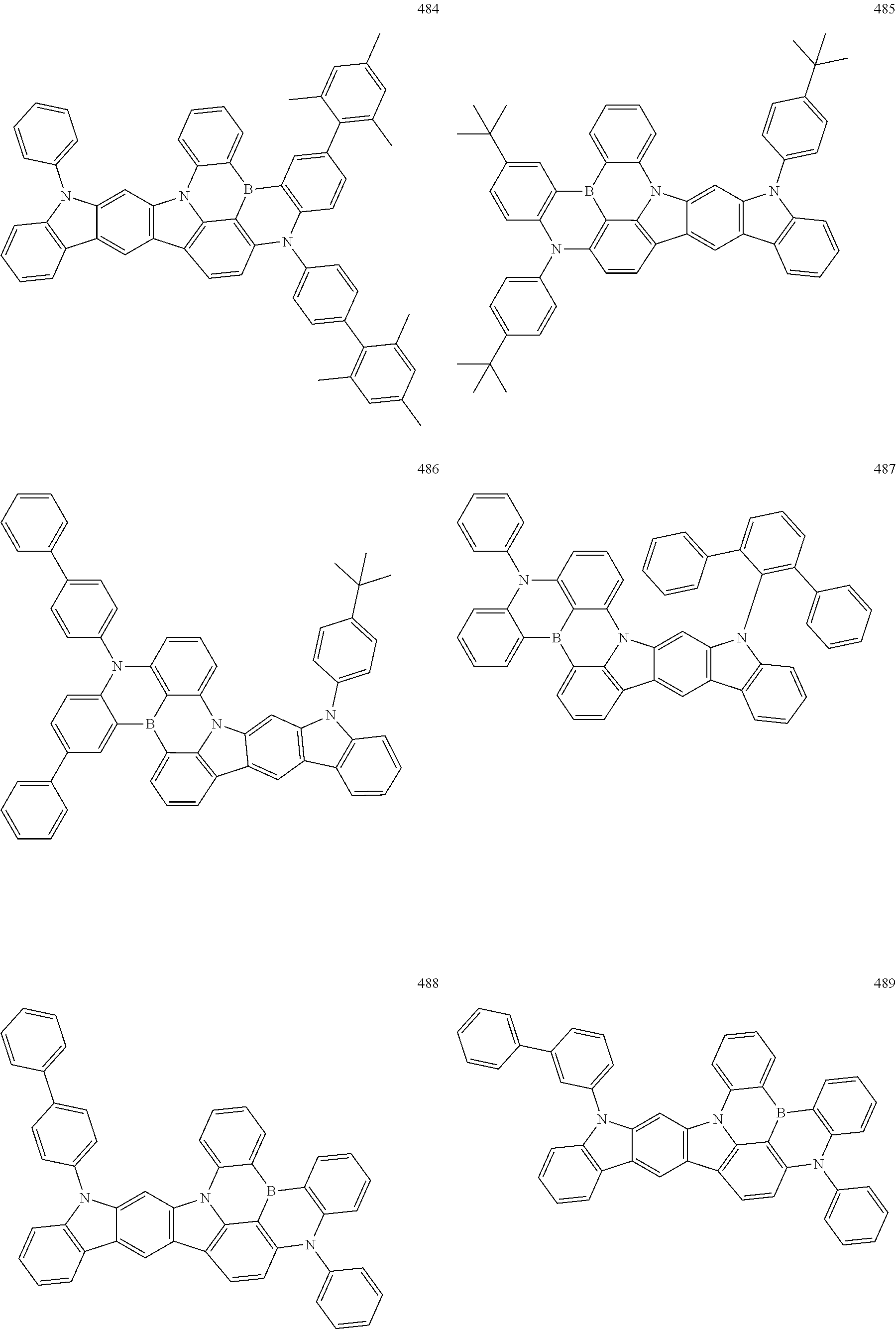

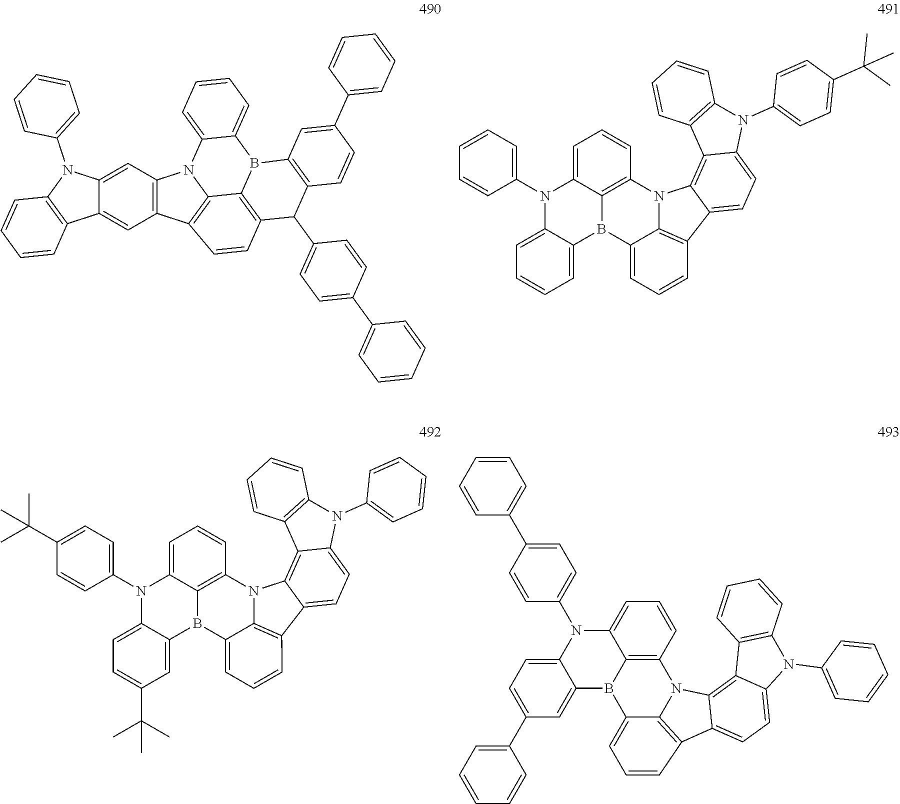

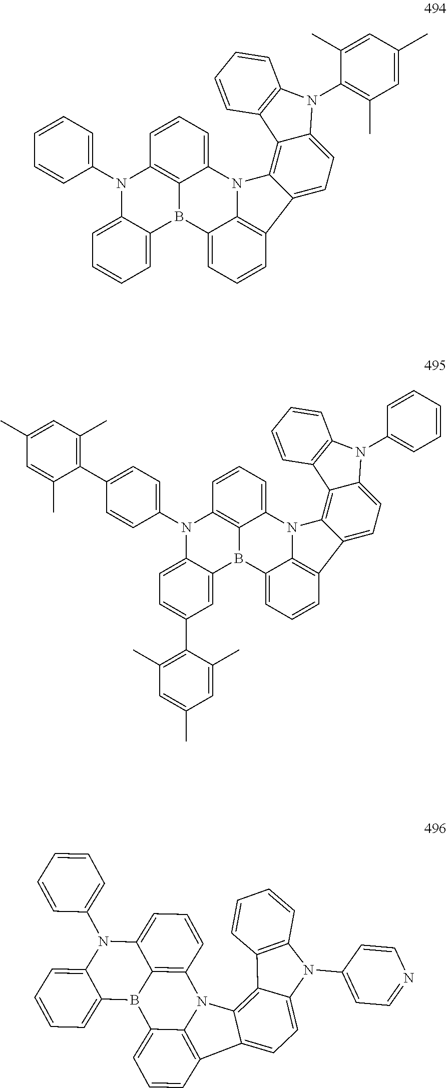

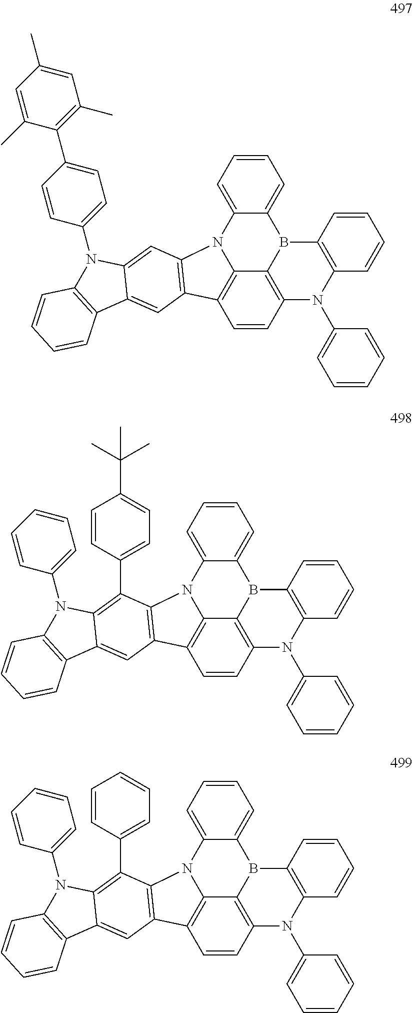 [SMILES: Cc1cc(C)c(-c2ccc(-n3c4ccccc4c4cc5c6ccc7c8c6n(c5cc43)-c3ccccc3B8c3ccccc3N7c3ccccc3)cc2)c(C)c1 ; CC(C)(C)c1ccc(-c2c3c(cc4c5ccc6c7c5n(c24)-c2ccccc2B7c2ccccc2N6c2ccccc2)c2ccccc2n3-c2ccccc2)cc1 ; c1ccc(-c2c3c(cc4c5ccc6c7c5n(c24)-c2ccccc2B7c2ccccc2N6c2ccccc2)c2ccccc2n3-c2ccccc2)cc1]

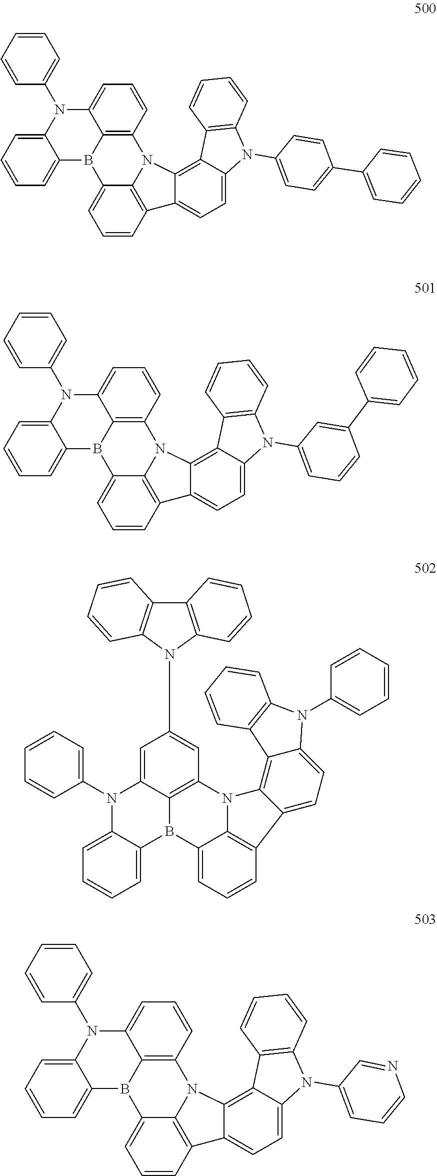 [SMILES: c1ccc(-c2ccc(-n3c4ccccc4c4c3ccc3c5cccc6c5n(c34)-c3cccc4c3B6c3ccccc3N4c3ccccc3)cc2)cc1 ; c1ccc(-c2cccc(-n3c4ccccc4c4c3ccc3c5cccc6c5n(c34)-c3cccc4c3B6c3ccccc3N4c3ccccc3)c2)cc1 ; c1ccc(N2c3ccccc3B3c4c2cc(-n2c5ccccc5c5ccccc52)cc4-n2c4c3cccc4c3ccc4c(c5ccccc5n4-c4ccccc4)c32)cc1 ; c1ccc(N2c3ccccc3B3c4c2cccc4-n2c4c3cccc4c3ccc4c(c5ccccc5n4-c4cccnc4)c32)cc1]

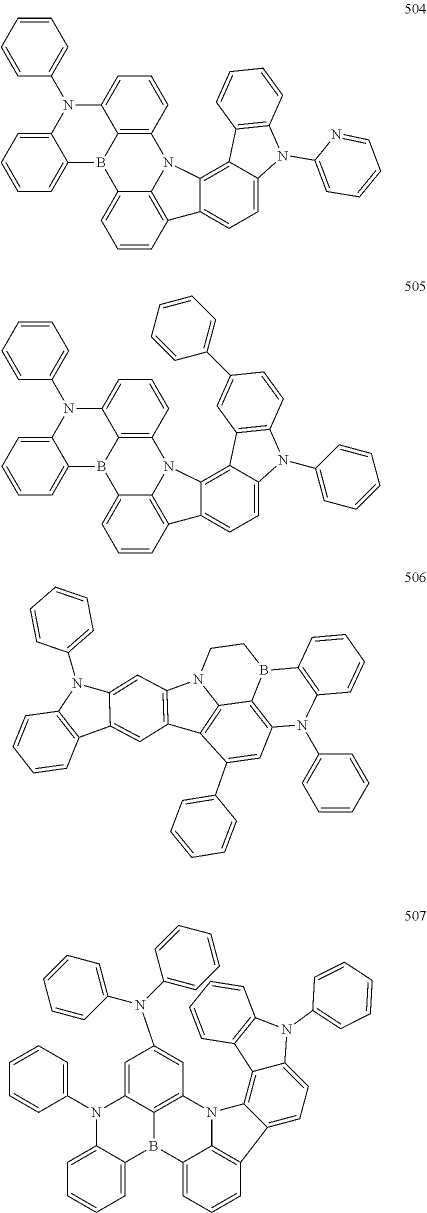 [SMILES: c1ccc(N2c3ccccc3B3c4c2cccc4-n2c4c3cccc4c3ccc4c(c5ccccc5n4-c4ccccn4)c32)cc1 ; c1ccc(-c2ccc3c(c2)c2c(ccc4c5cccc6c5n(c42)-c2cccc4c2B6c2ccccc2N4c2ccccc2)n3-c2ccccc2)cc1 ; c1ccc(-c2cc3c4c5c2c2cc6c7ccccc7n(-c7ccccc7)c6cc2n5CCB4c2ccccc2N3c2ccccc2)cc1 ; c1ccc(N(c2ccccc2)c2cc3c4c(c2)-n2c5c(cccc5c5ccc6c(c7ccccc7n6-c6ccccc6)c52)B4c2ccccc2N3c2ccccc2)cc1]

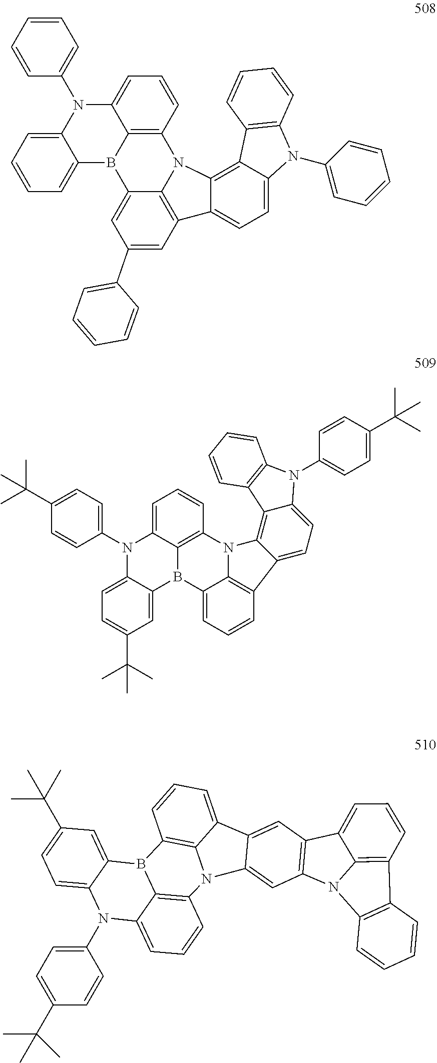

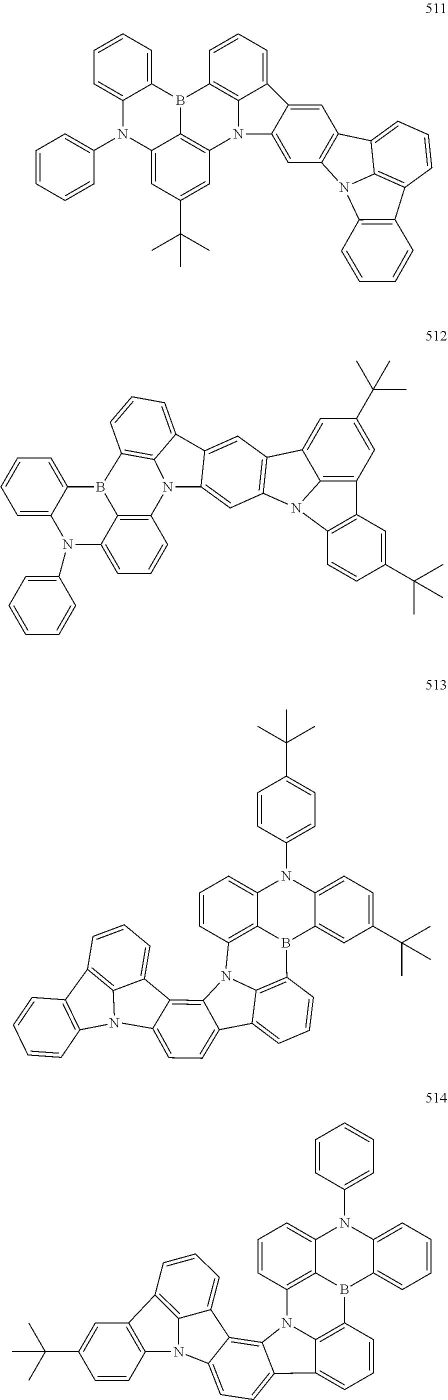

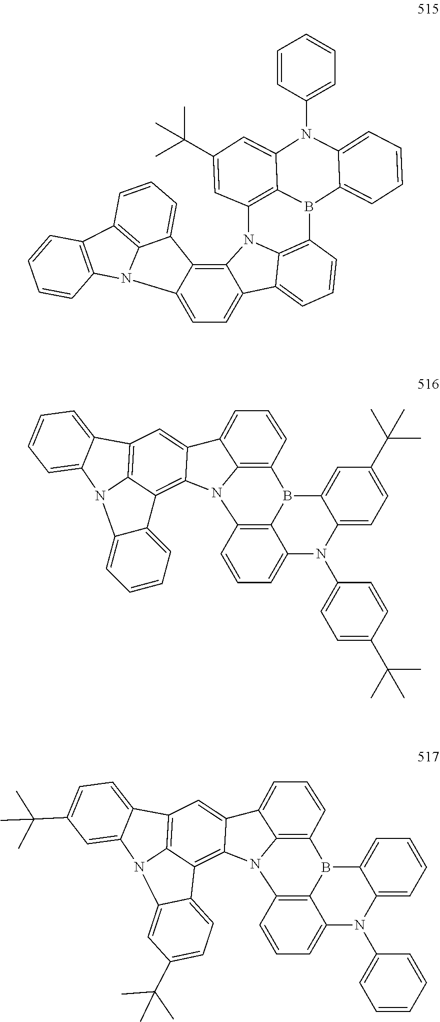

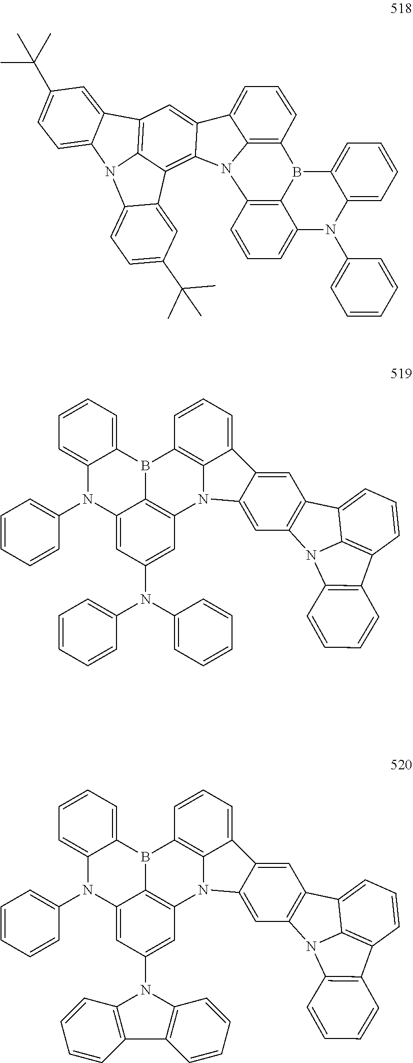 [SMILES: CC(C)(C)c1ccc2c(c1)c1cc3c4cccc5c4n(c3c3c4cc(C(C)(C)C)ccc4n2c13)-c1cccc2c1B5c1ccccc1N2c1ccccc1 ; c1ccc(N(c2ccccc2)c2cc3c4c(c2)-n2c5cc6c(cc5c5cccc(c52)B4c2ccccc2N3c2ccccc2)c2cccc3c4ccccc4n6c32)cc1 ; c1ccc(N2c3ccccc3B3c4c2cc(-n2c5ccccc5c5ccccc52)cc4-n2c4cc5c(cc4c4cccc3c42)c2cccc3c4ccccc4n5c32)cc1]

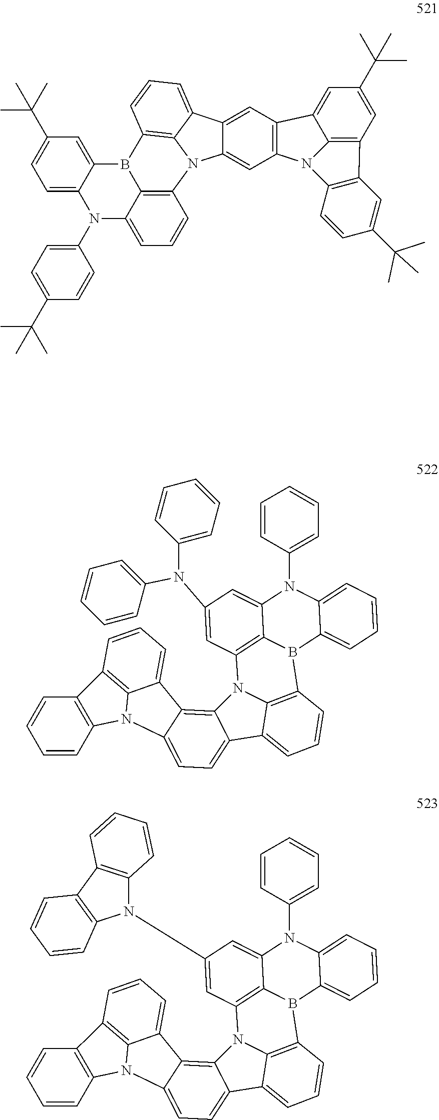 [SMILES: CC(C)(C)c1ccc(N2c3ccc(C(C)(C)C)cc3B3c4c2cccc4-n2c4cc5c(cc4c4cccc3c42)c2cc(C(C)(C)C)cc3c4cc(C(C)(C)C)ccc4n5c32)cc1 ; c1ccc(N(c2ccccc2)c2cc3c4c(c2)-n2c5c(cccc5c5ccc6c(c7cccc8c9ccccc9n6c87)c52)B4c2ccccc2N3c2ccccc2)cc1 ; c1ccc(N2c3ccccc3B3c4c2cc(-n2c5ccccc5c5ccccc52)cc4-n2c4c3cccc4c3ccc4c(c5cccc6c7ccccc7n4c65)c32)cc1]

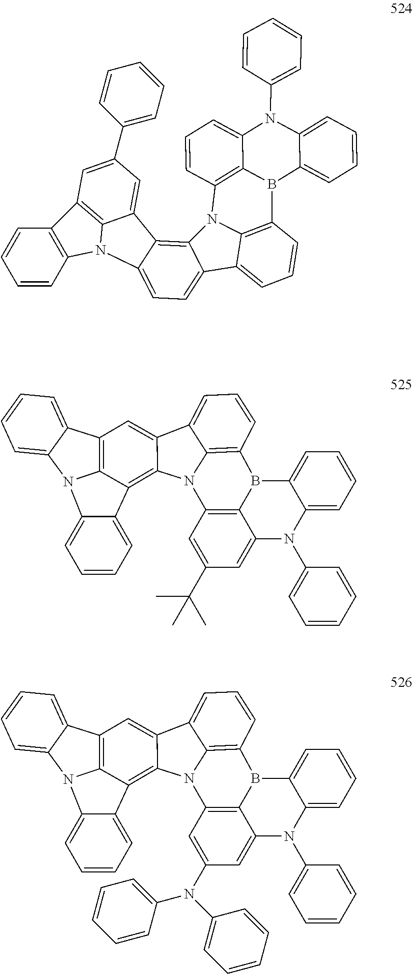 [SMILES: c1ccc(-c2cc3c4ccccc4n4c5ccc6c7cccc8c7n(c6c5c(c2)c34)-c2cccc3c2B8c2ccccc2N3c2ccccc2)cc1 ; CC(C)(C)c1cc2c3c(c1)-n1c4c(cccc4c4cc5c6ccccc6n6c7ccccc7c(c41)c56)B3c1ccccc1N2c1ccccc1 ; c1ccc(N(c2ccccc2)c2cc3c4c(c2)-n2c5c(cccc5c5cc6c7ccccc7n7c8ccccc8c(c52)c67)B4c2ccccc2N3c2ccccc2)cc1]

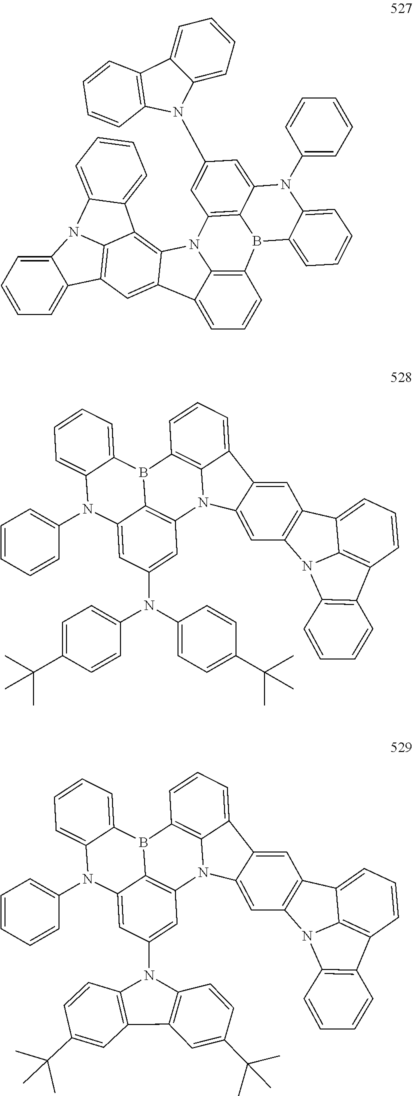 [SMILES: c1ccc(N2c3ccccc3B3c4c2cc(-n2c5ccccc5c5ccccc52)cc4-n2c4c3cccc4c3cc4c5ccccc5n5c6ccccc6c(c32)c45)cc1 ; CC(C)(C)c1ccc(N(c2ccc(C(C)(C)C)cc2)c2cc3c4c(c2)-n2c5cc6c(cc5c5cccc(c52)B4c2ccccc2N3c2ccccc2)c2cccc3c4ccccc4n6c32)cc1 ; CC(C)(C)c1ccc2c(c1)c1cc(C(C)(C)C)ccc1n2-c1cc2c3c(c1)-n1c4cc5c(cc4c4cccc(c41)B3c1ccccc1N2c1ccccc1)c1cccc2c3ccccc3n5c21]

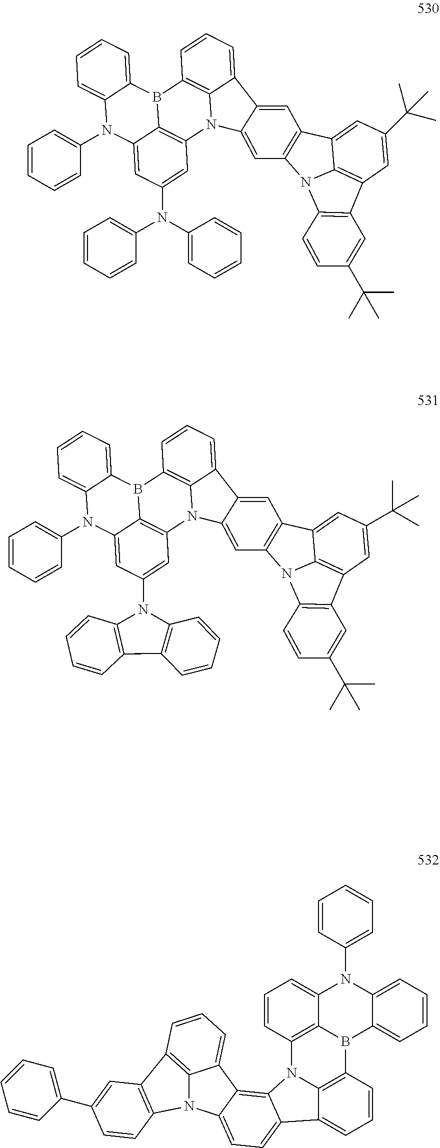 [SMILES: CC(C)(C)c1ccc2c(c1)c1cc(C(C)(C)C)cc3c4cc5c6cccc7c6n(c5cc4n2c13)-c1cc(N(c2ccccc2)c2ccccc2)cc2c1B7c1ccccc1N2c1ccccc1 ; CC(C)(C)c1ccc2c(c1)c1cc(C(C)(C)C)cc3c4cc5c6cccc7c6n(c5cc4n2c13)-c1cc(-n2c3ccccc3c3ccccc32)cc2c1B7c1ccccc1N2c1ccccc1 ; c1ccc(-c2ccc3c(c2)c2cccc4c5c6c(ccc5n3c24)c2cccc3c2n6-c2cccc4c2B3c2ccccc2N4c2ccccc2)cc1]

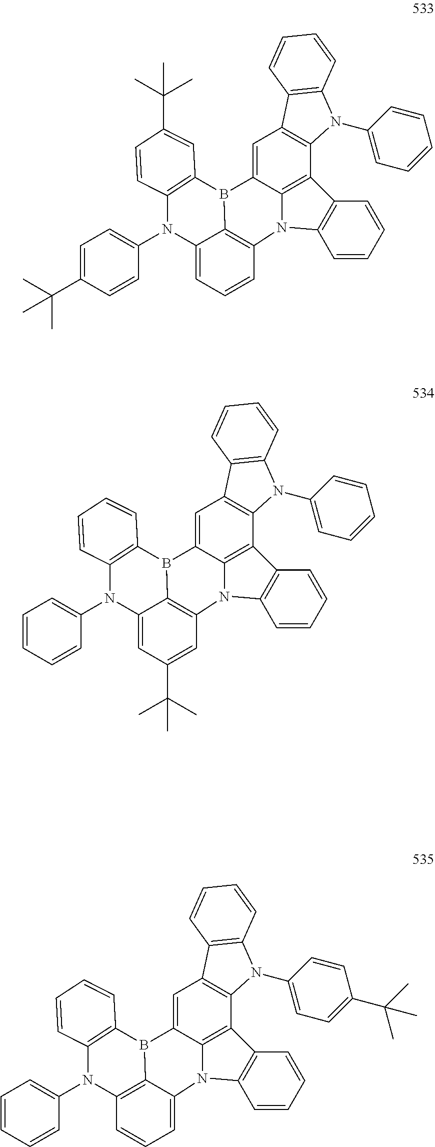 [SMILES: CC(C)(C)c1ccc(N2c3ccc(C(C)(C)C)cc3B3c4c2cccc4-n2c4ccccc4c4c2c3cc2c3ccccc3n(-c3ccccc3)c24)cc1 ; CC(C)(C)c1cc2c3c(c1)-n1c4ccccc4c4c1c(cc1c5ccccc5n(-c5ccccc5)c14)B3c1ccccc1N2c1ccccc1 ; CC(C)(C)c1ccc(-n2c3ccccc3c3cc4c5c(c6ccccc6n5-c5cccc6c5B4c4ccccc4N6c4ccccc4)c32)cc1]

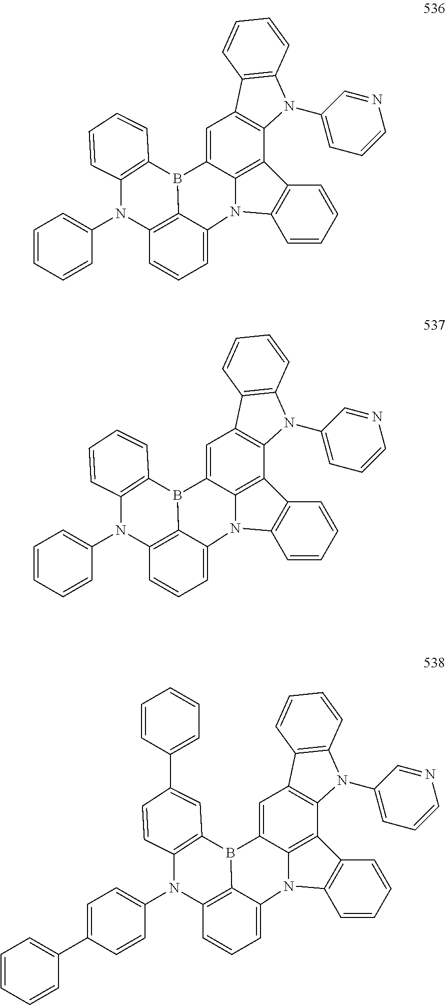 [SMILES: c1ccc(N2c3ccccc3B3c4c2cccc4-n2c4ccccc4c4c2c3cc2c3ccccc3n(-c3cccnc3)c24)cc1 ; c1ccc(N2c3ccccc3B3c4c2cccc4-n2c4ccccc4c4c2c3cc2c3ccccc3n(-c3cccnc3)c24)cc1 ; c1ccc(-c2ccc(N3c4ccc(-c5ccccc5)cc4B4c5c3cccc5-n3c5ccccc5c5c3c4cc3c4ccccc4n(-c4cccnc4)c35)cc2)cc1]

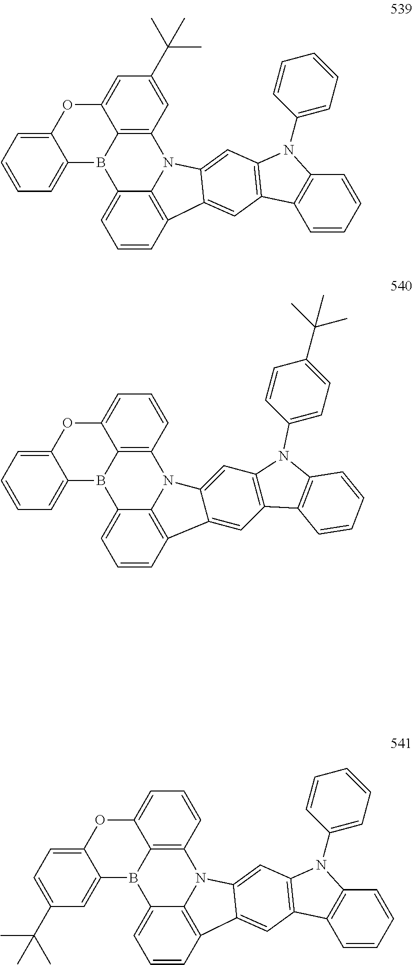 [SMILES: CC(C)(C)c1cc2c3c(c1)-n1c4cc5c(cc4c4cccc(c41)B3c1ccccc1O2)c1ccccc1n5-c1ccccc1 ; CC(C)(C)c1ccc(-n2c3ccccc3c3cc4c5cccc6c5n(c4cc32)-c2cccc3c2B6c2ccccc2O3)cc1 ; CC(C)(C)c1ccc2c(c1)B1c3c(cccc3-n3c4cc5c(cc4c4cccc1c43)c1ccccc1n5-c1ccccc1)O2]

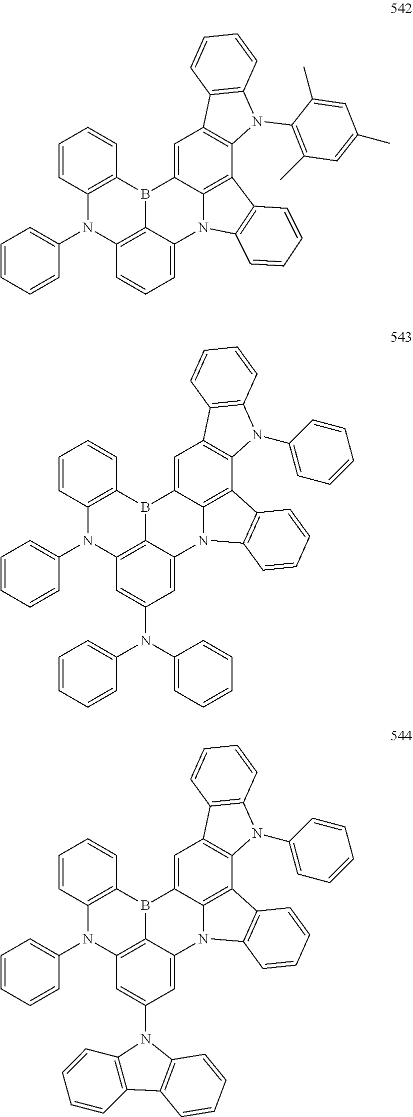

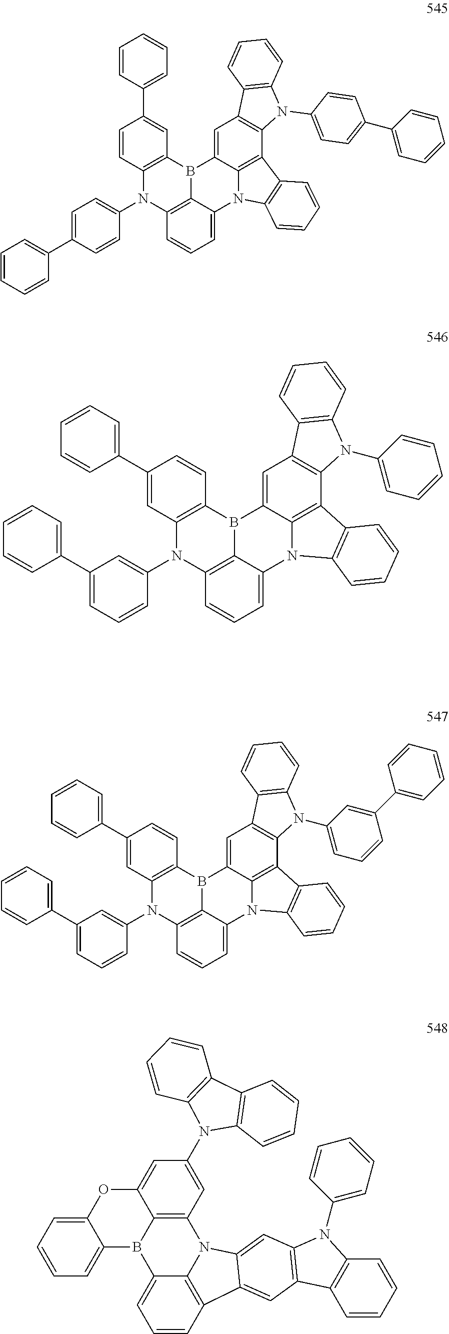 [SMILES: c1ccc(-c2ccc(N3c4ccc(-c5ccccc5)cc4B4c5c3cccc5-n3c5ccccc5c5c3c4cc3c4ccccc4n(-c4ccc(-c6ccccc6)cc4)c35)cc2)cc1 ; c1ccc(-c2cccc(N3c4cc(-c5ccccc5)ccc4B4c5c3cccc5-n3c5ccccc5c5c3c4cc3c4ccccc4n(-c4ccccc4)c35)c2)cc1 ; c1ccc(-c2cccc(N3c4cc(-c5ccccc5)ccc4B4c5c3cccc5-n3c5ccccc5c5c3c4cc3c4ccccc4n(-c4cccc(-c6ccccc6)c4)c35)c2)cc1 ; c1ccc(-n2c3ccccc3c3cc4c5cccc6c5n(c4cc32)-c2cc(-n3c4ccccc4c4ccccc43)cc3c2B6c2ccccc2O3)cc1]

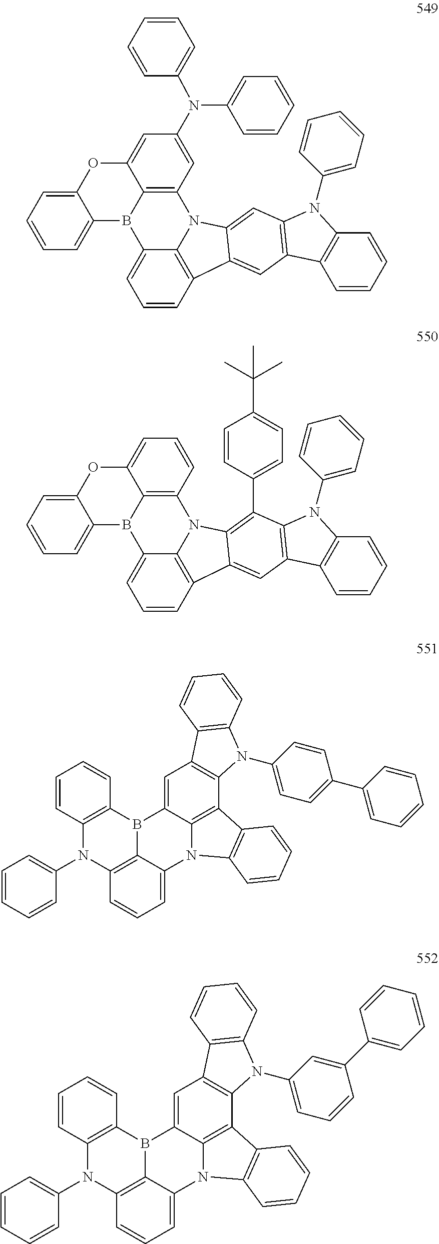 [SMILES: c1ccc(N(c2ccccc2)c2cc3c4c(c2)-n2c5cc6c(cc5c5cccc(c52)B4c2ccccc2O3)c2ccccc2n6-c2ccccc2)cc1 ; CC(C)(C)c1ccc(-c2c3c(cc4c5cccc6c5n(c24)-c2cccc4c2B6c2ccccc2O4)c2ccccc2n3-c2ccccc2)cc1 ; c1ccc(-c2ccc(-n3c4ccccc4c4cc5c6c(c7ccccc7n6-c6cccc7c6B5c5ccccc5N7c5ccccc5)c43)cc2)cc1 ; c1ccc(-c2cccc(-n3c4ccccc4c4cc5c6c(c7ccccc7n6-c6cccc7c6B5c5ccccc5N7c5ccccc5)c43)c2)cc1]

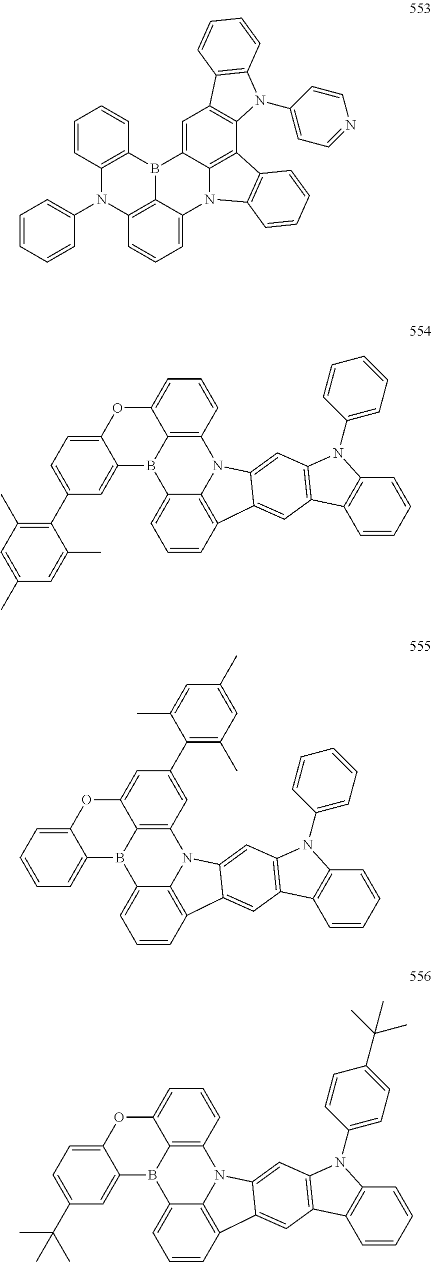 [SMILES: c1ccc(N2c3ccccc3B3c4c2cccc4-n2c4ccccc4c4c2c3cc2c3ccccc3n(-c3ccncc3)c24)cc1 ; Cc1cc(C)c(-c2ccc3c(c2)B2c4c(cccc4-n4c5cc6c(cc5c5cccc2c54)c2ccccc2n6-c2ccccc2)O3)c(C)c1 ; Cc1cc(C)c(-c2cc3c4c(c2)-n2c5cc6c(cc5c5cccc(c52)B4c2ccccc2O3)c2ccccc2n6-c2ccccc2)c(C)c1 ; CC(C)(C)c1ccc(-n2c3ccccc3c3cc4c5cccc6c5n(c4cc32)-c2cccc3c2B6c2cc(C(C)(C)C)ccc2O3)cc1]

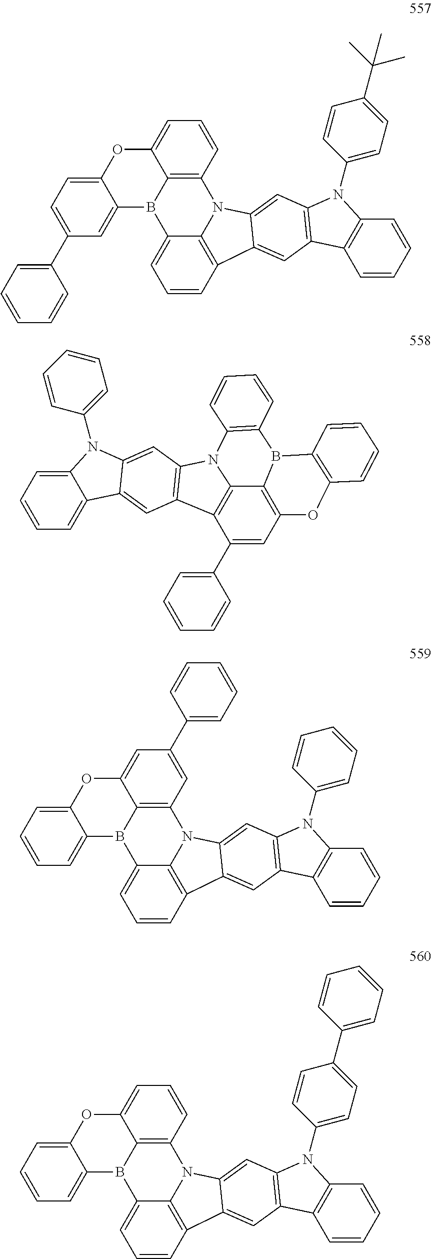

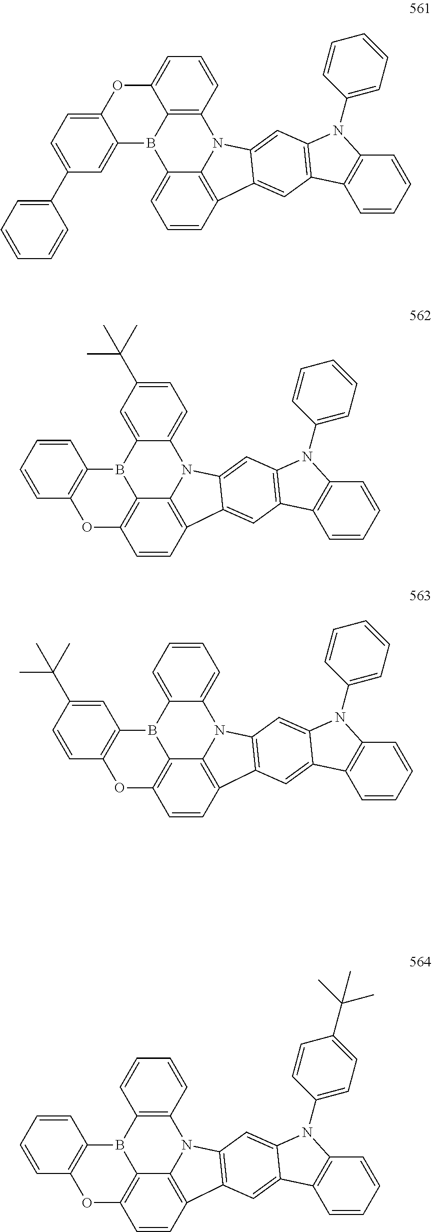 [SMILES: c1ccc(-c2ccc3c(c2)B2c4c(cccc4-n4c5cc6c(cc5c5cccc2c54)c2ccccc2n6-c2ccccc2)O3)cc1 ; CC(C)(C)c1ccc2c(c1)B1c3ccccc3Oc3ccc4c5cc6c7ccccc7n(-c7ccccc7)c6cc5n-2c4c31 ; CC(C)(C)c1ccc2c(c1)B1c3ccccc3-n3c4cc5c(cc4c4ccc(c1c43)O2)c1ccccc1n5-c1ccccc1 ; CC(C)(C)c1ccc(-n2c3ccccc3c3cc4c5ccc6c7c5n(c4cc32)-c2ccccc2B7c2ccccc2O6)cc1]

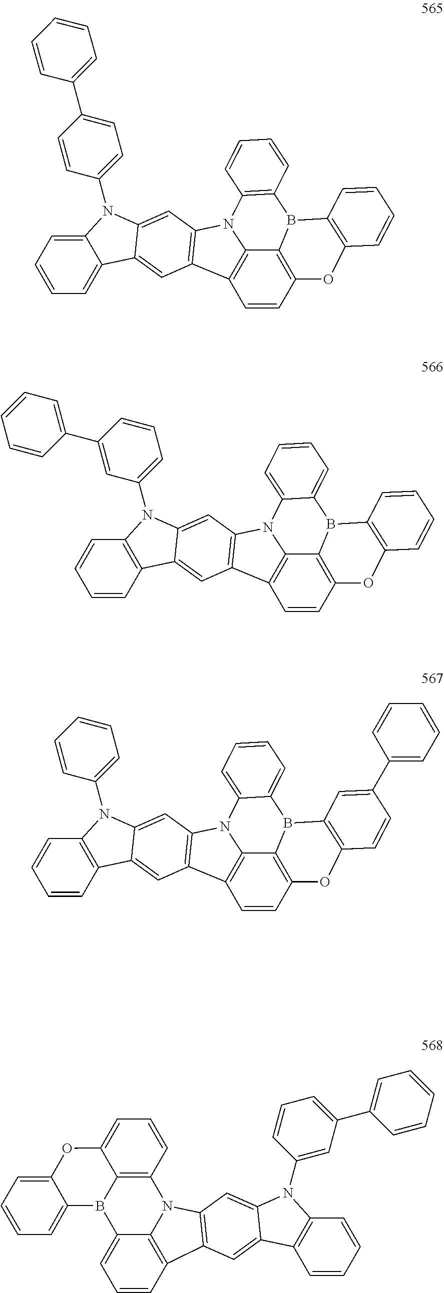 [SMILES: c1ccc(-c2ccc(-n3c4ccccc4c4cc5c6ccc7c8c6n(c5cc43)-c3ccccc3B8c3ccccc3O7)cc2)cc1 ; c1ccc(-c2cccc(-n3c4ccccc4c4cc5c6ccc7c8c6n(c5cc43)-c3ccccc3B8c3ccccc3O7)c2)cc1 ; c1ccc(-c2ccc3c(c2)B2c4ccccc4-n4c5cc6c(cc5c5ccc(c2c54)O3)c2ccccc2n6-c2ccccc2)cc1 ; c1ccc(-c2cccc(-n3c4ccccc4c4cc5c6cccc7c6n(c5cc43)-c3cccc4c3B7c3ccccc3O4)c2)cc1]

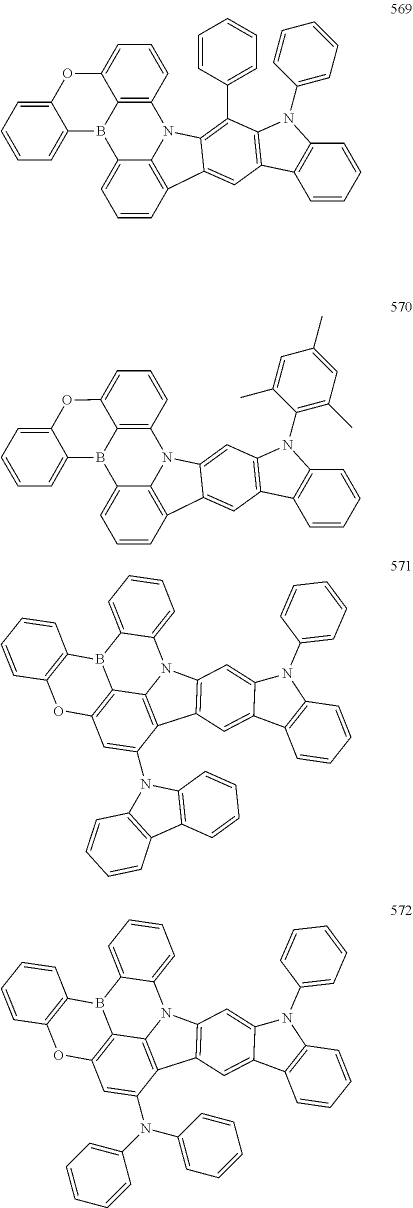

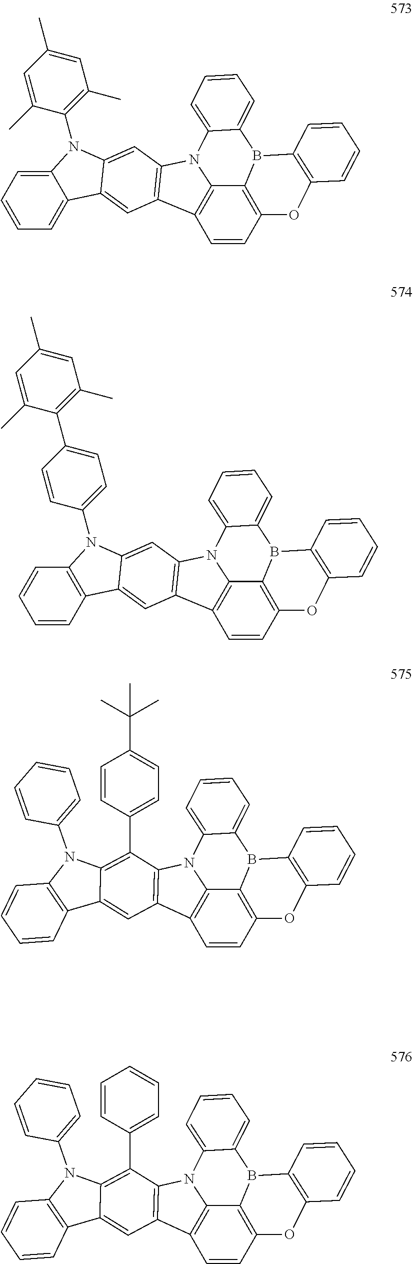 [SMILES: Cc1cc(C)c(-n2c3ccccc3c3cc4c5ccc6c7c5n(c4cc32)-c2ccccc2B7c2ccccc2O6)c(C)c1 ; Cc1cc(C)c(-c2ccc(-n3c4ccccc4c4cc5c6ccc7c8c6n(c5cc43)-c3ccccc3B8c3ccccc3O7)cc2)c(C)c1 ; CC(C)(C)c1ccc(-c2c3c(cc4c5ccc6c7c5n(c24)-c2ccccc2B7c2ccccc2O6)c2ccccc2n3-c2ccccc2)cc1 ; c1ccc(-c2c3c(cc4c5ccc6c7c5n(c24)-c2ccccc2B7c2ccccc2O6)c2ccccc2n3-c2ccccc2)cc1]

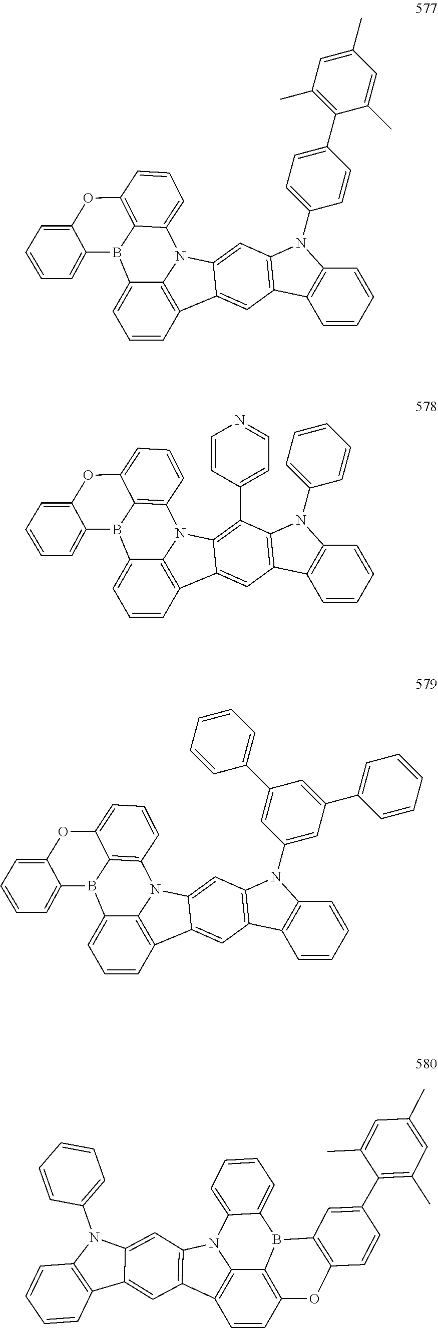 [SMILES: Cc1cc(C)c(-c2ccc(-n3c4ccccc4c4cc5c6cccc7c6n(c5cc43)-c3cccc4c3B7c3ccccc3O4)cc2)c(C)c1 ; c1ccc(-n2c3ccccc3c3cc4c5cccc6c5n(c4c(-c4ccncc4)c32)-c2cccc3c2B6c2ccccc2O3)cc1 ; c1ccc(-c2cc(-c3ccccc3)cc(-n3c4ccccc4c4cc5c6cccc7c6n(c5cc43)-c3cccc4c3B7c3ccccc3O4)c2)cc1 ; Cc1cc(C)c(-c2ccc3c(c2)B2c4ccccc4-n4c5cc6c(cc5c5ccc(c2c54)O3)c2ccccc2n6-c2ccccc2)c(C)c1]

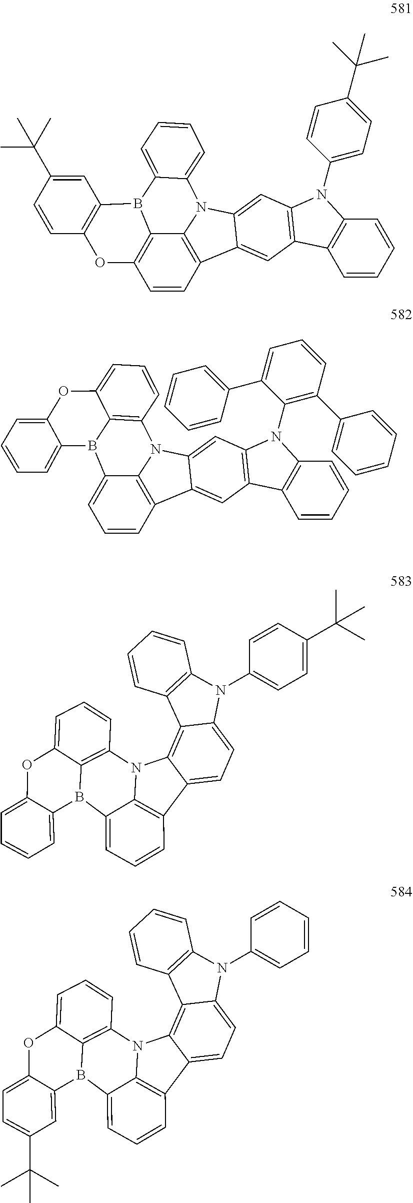

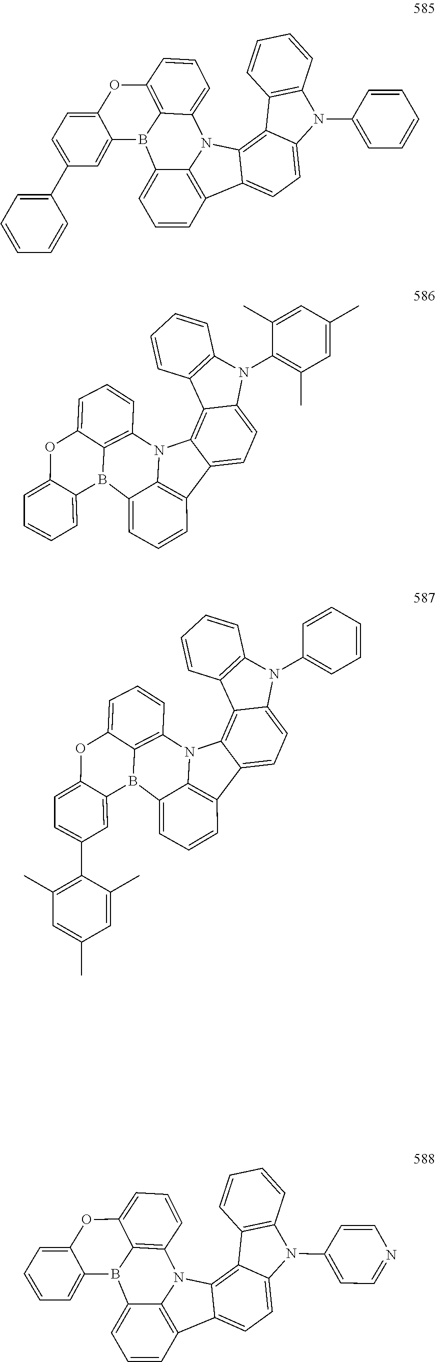

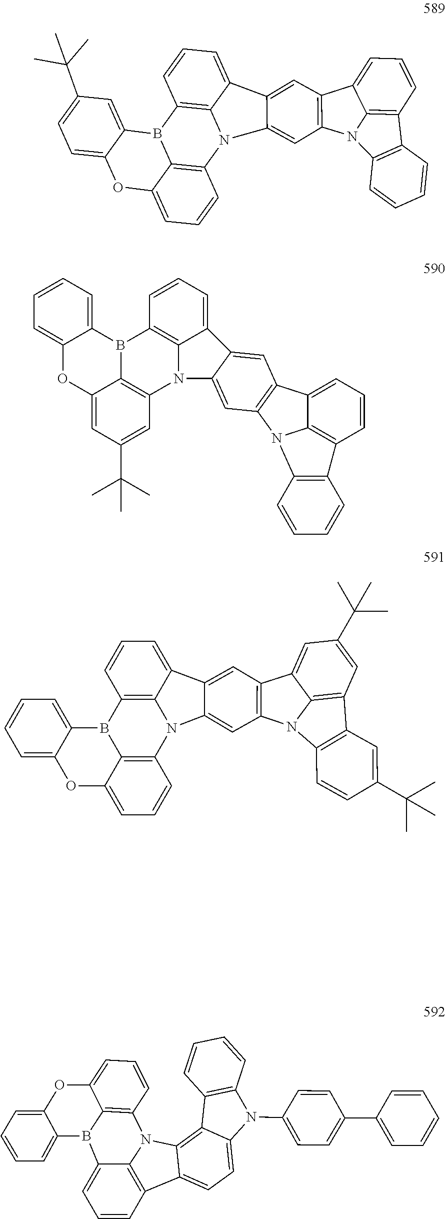 [SMILES: CC(C)(C)c1ccc2c(c1)B1c3c(cccc3-n3c4cc5c(cc4c4cccc1c43)c1cccc3c4ccccc4n5c31)O2 ; CC(C)(C)c1cc2c3c(c1)-n1c4cc5c(cc4c4cccc(c41)B3c1ccccc1O2)c1cccc2c3ccccc3n5c21 ; CC(C)(C)c1ccc2c(c1)c1cc(C(C)(C)C)cc3c4cc5c6cccc7c6n(c5cc4n2c13)-c1cccc2c1B7c1ccccc1O2 ; c1ccc(-c2ccc(-n3c4ccccc4c4c3ccc3c5cccc6c5n(c34)-c3cccc4c3B6c3ccccc3O4)cc2)cc1]

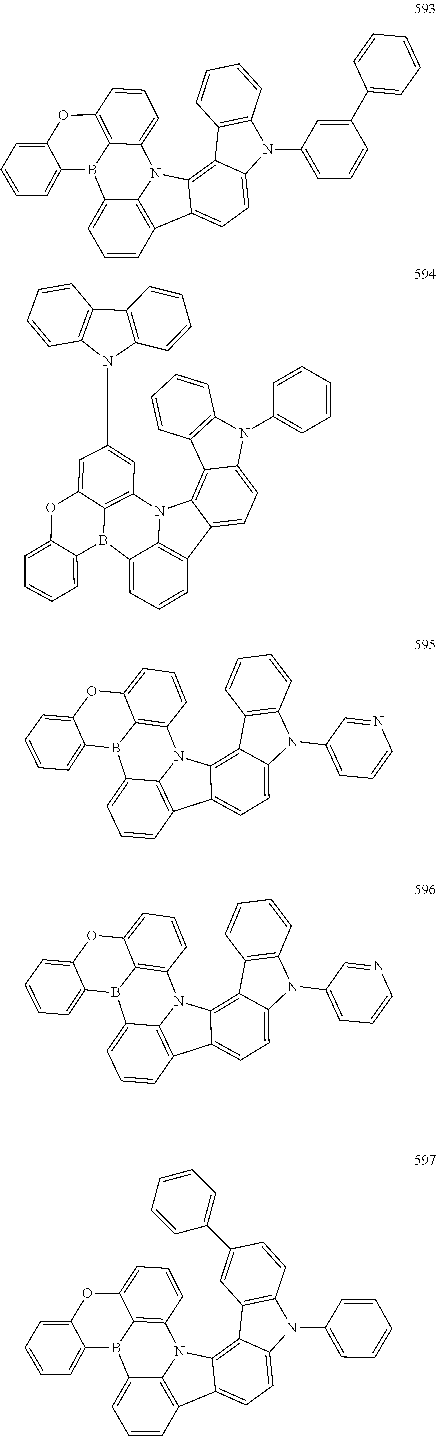

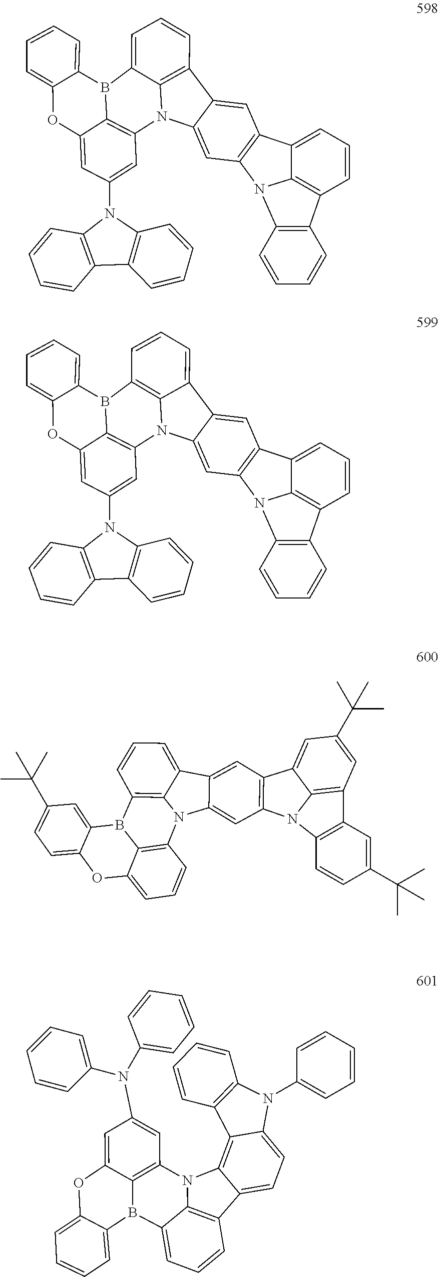

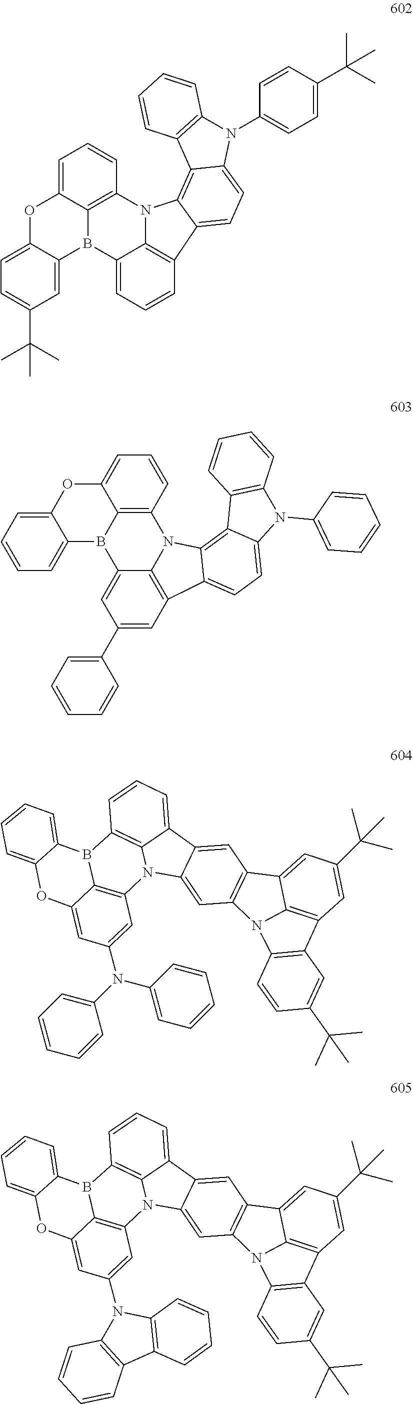 [SMILES: CC(C)(C)c1ccc(-n2c3ccccc3c3c2ccc2c4cccc5c4n(c23)-c2cccc3c2B5c2cc(C(C)(C)C)ccc2O3)cc1 ; c1ccc(-c2cc3c4c(c2)c2ccc5c(c6ccccc6n5-c5ccccc5)c2n4-c2cccc4c2B3c2ccccc2O4)cc1 ; CC(C)(C)c1ccc2c(c1)c1cc(C(C)(C)C)cc3c4cc5c6cccc7c6n(c5cc4n2c13)-c1cc(N(c2ccccc2)c2ccccc2)cc2c1B7c1ccccc1O2 ; CC(C)(C)c1ccc2c(c1)c1cc(C(C)(C)C)cc3c4cc5c6cccc7c6n(c5cc4n2c13)-c1cc(-n2c3ccccc3c3ccccc32)cc2c1B7c1ccccc1O2]

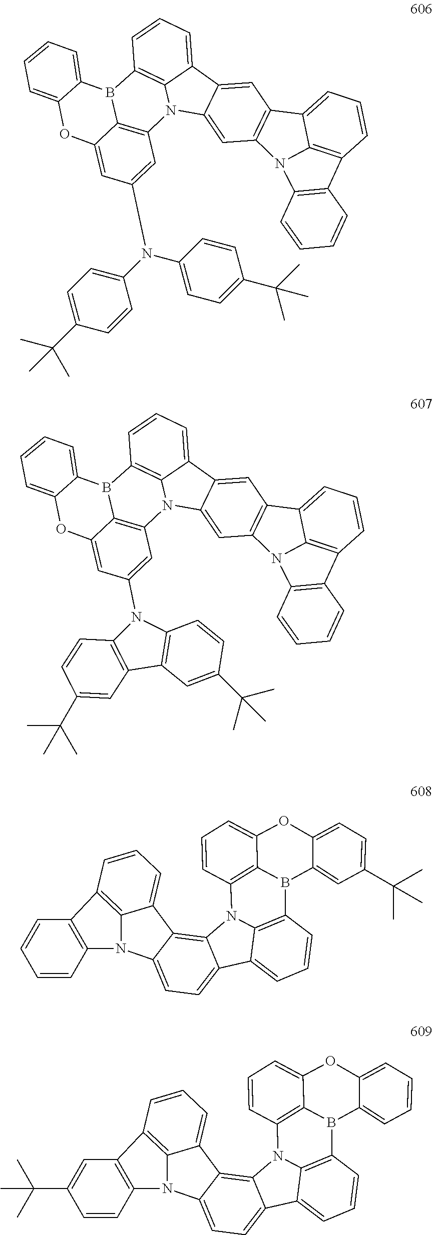

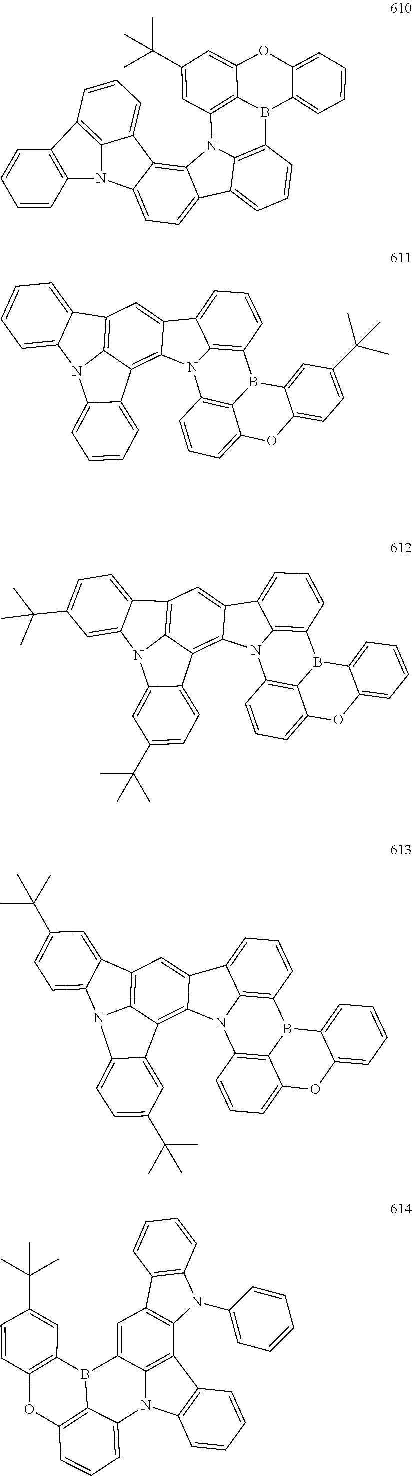

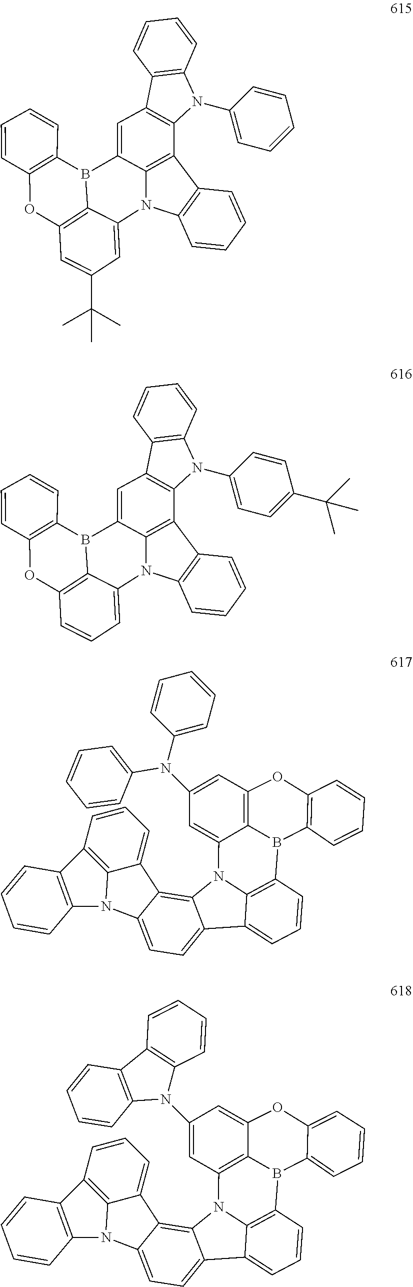

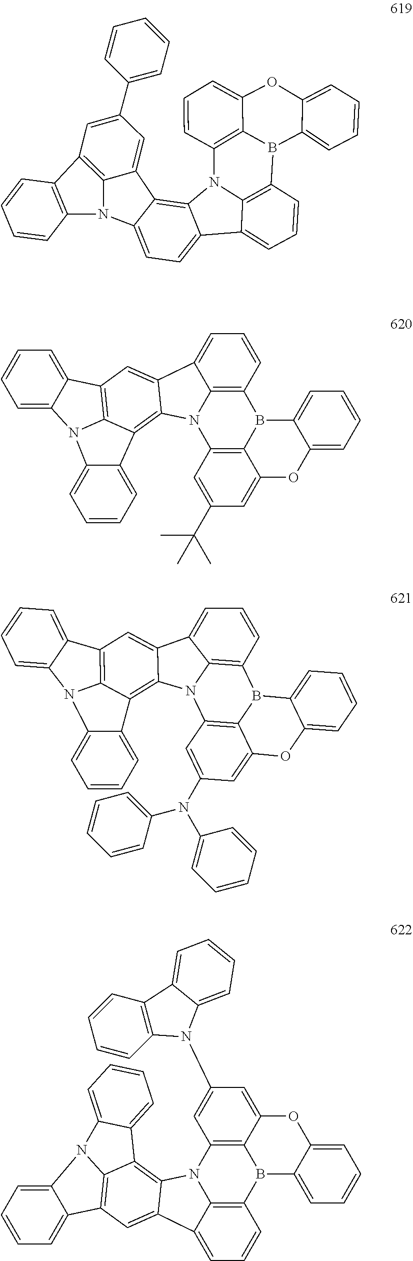

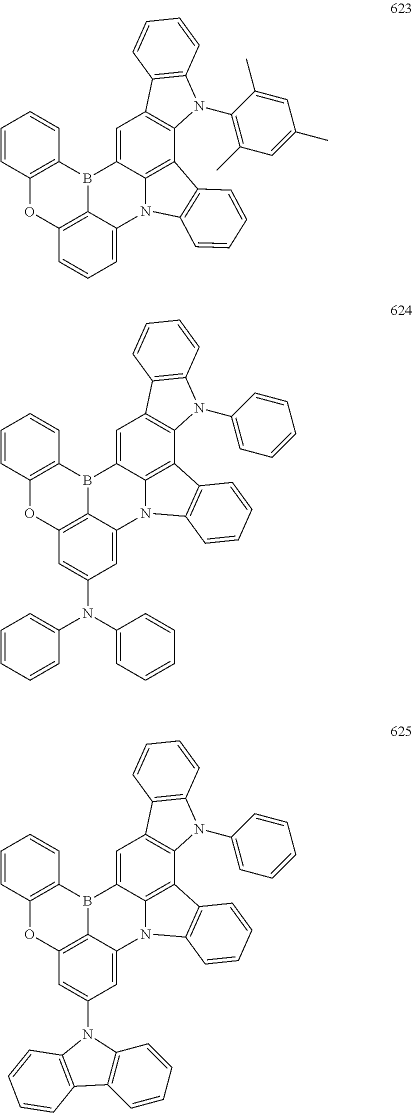 [SMILES: Cc1cc(C)c(-n2c3ccccc3c3cc4c5c(c6ccccc6n5-c5cccc6c5B4c4ccccc4O6)c32)c(C)c1 ; c1ccc(N(c2ccccc2)c2cc3c4c(c2)-n2c5ccccc5c5c2c(cc2c6ccccc6n(-c6ccccc6)c25)B4c2ccccc2O3)cc1 ; c1ccc(-n2c3ccccc3c3cc4c5c(c6ccccc6n5-c5cc(-n6c7ccccc7c7ccccc76)cc6c5B4c4ccccc4O6)c32)cc1]

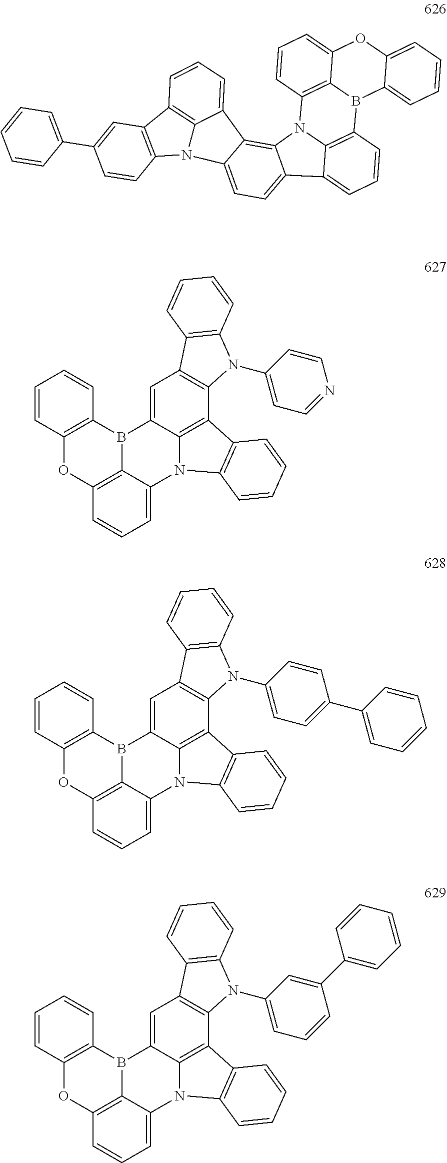 [SMILES: c1ccc(-c2ccc3c(c2)c2cccc4c5c6c(ccc5n3c24)c2cccc3c2n6-c2cccc4c2B3c2ccccc2O4)cc1 ; c1ccc2c(c1)Oc1cccc3c1B2c1cc2c4ccccc4n(-c4ccncc4)c2c2c4ccccc4n-3c12 ; c1ccc(-c2ccc(-n3c4ccccc4c4cc5c6c(c7ccccc7n6-c6cccc7c6B5c5ccccc5O7)c43)cc2)cc1 ; c1ccc(-c2cccc(-n3c4ccccc4c4cc5c6c(c7ccccc7n6-c6cccc7c6B5c5ccccc5O7)c43)c2)cc1]

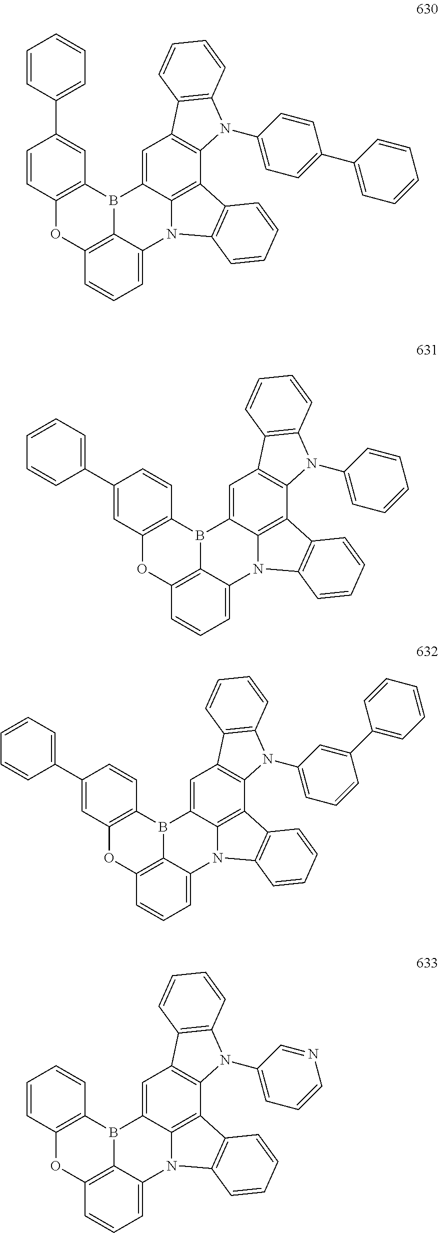 [SMILES: c1ccc(-c2ccc(-n3c4ccccc4c4cc5c6c(c7ccccc7n6-c6cccc7c6B5c5cc(-c6ccccc6)ccc5O7)c43)cc2)cc1 ; c1ccc(-c2ccc3c(c2)Oc2cccc4c2B3c2cc3c5ccccc5n(-c5ccccc5)c3c3c5ccccc5n-4c23)cc1 ; c1ccc(-c2cccc(-n3c4ccccc4c4cc5c6c(c7ccccc7n6-c6cccc7c6B5c5ccc(-c6ccccc6)cc5O7)c43)c2)cc1 ; c1cncc(-n2c3ccccc3c3cc4c5c(c6ccccc6n5-c5cccc6c5B4c4ccccc4O6)c32)c1]

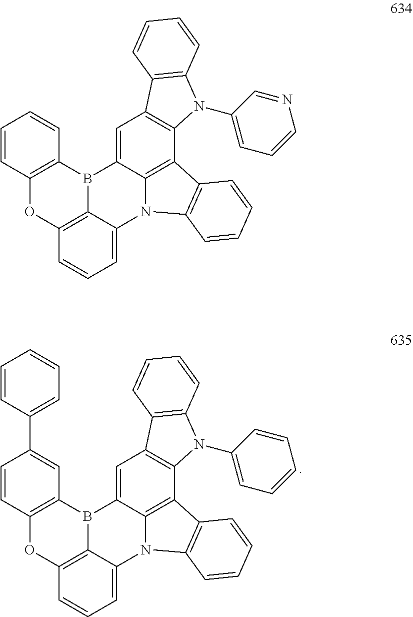 [SMILES: c1cncc(-n2c3ccccc3c3cc4c5c(c6ccccc6n5-c5cccc6c5B4c4ccccc4O6)c32)c1 ; c1ccc(-c2ccc3c(c2)B2c4c(cccc4-n4c5ccccc5c5c4c2cc2c4ccccc4n(-c4ccccc4)c25)O3)cc1]

In an embodiment, the heterocyclic compound may be Compound 101, Compound 102, Compound 103 Compound 104, Compound 105, Compound 106, Compound 116, Compound 119, Compound 124 Compound 130, Compound 140, Compound 141, Compound 144, Compound 150, Compound 155, Compound 157, Compound 158, Compound 160, Compound 169, Compound 190, Compound 210, Compound 233, Compound 244, Compound 315, Compound 316, Compound 318, Compound 349, Compound 369, Compound 370, Compound 371, Compound 375, Compound 376, Compound 382, Compound 384, Compound 410, Compound 462, Compound 465, Compound 480, Compound 483, Compound 486, Compound 487, Compound 493, Compound 500, Compound 507, Compound 510, Compound 511, Compound 512, Compound 519, Compound 520, Compound 521, Compound 523, Compound 526, Compound 527, Compound 529, Compound 530, Compound 531, Compound 533, Compound 535, Compound 538, Compound 544, or Compound 551.

The heterocyclic compound according to an embodiment may have a structure in which a nitrogen atom (N) having electron donating properties and a boron atom (B) having electron withdrawing properties are bonded in a specific structure at an appropriate position in a conjugated system. Such an arrangement of the heterocyclic compound may alternately provide the highest occupied molecular orbital (HOMO) and the lowest unoccupied molecular orbital (LUMO) on adjacent carbon atoms. Thus, a change in the molecular structure between a ground state (S0) and a first excited singlet state (S1) may be suppressed to maintain a rigid structure, thereby providing blue light emission with improved color purity.

In addition, a thermally activated delayed fluorescence (TADF) compound of the related art has a structure in which a donor portion and an acceptor portion are combined. Accordingly, the donor portion in which HOMO of the compound is located and the acceptor portion in which LUMO of the compound is located are spatially separated from each other. As a result, a HOMO-LUMO overlap may be very small, oscillator strength f of a stable structure in the first excited singlet state (S1) (hereinafter, also referred to as “oscillator strength f”) may be small, and luminescence efficiency may not be sufficient.

On the contrary, in the heterocyclic compound according to an embodiment, the HOMO and LUMO may be positioned alternately on adjacent atoms of a ring to reduce the HOMO-LUMO overlap. Accordingly, the heterocyclic compound according to an embodiment may have improved oscillator strength f compared to a TADF compound of the related art, and the luminescence efficiency of an organic light-emitting device including the heterocyclic compound may be improved.

A HOMO level of the heterocyclic compound according to an embodiment may be, but is not particularly limited to, about −5.8 eV or more, or for example, about −5.6 eV or more or about −5.4 eV or more. In addition, the HOMO level of the heterocyclic compound according to an embodiment may be about −4.6 eV or less, about −4.8 eV or less, or about −5.0 eV or less, from the viewpoint of consistency with an energy diagram of other general materials forming the emission layer and the stability in the atmosphere. When the HOMO level is within these ranges, the organic light-emitting device may have a low driving voltage.

A LUMO level of the heterocyclic compound according to an embodiment may be, but is not particularly limited to, about −2.4 eV or more. In addition, the LUMO level may be about −2.2 eV or more, about −2.1 eV or more, or about −2.0 eV or more. In addition, the LUMO level of the heterocyclic compound according to an embodiment may be about −0.8 eV or less from the viewpoint of consistency with an energy diagram of other general materials forming the emission layer. In an embodiment, the LUMO level of the heterocyclic compound according to an embodiment may be about −1.0 eV or less, about −1.1 eV or less, or about −1.2 eV or less. When the HOMO level is within the above range, the organic light-emitting device may have a low driving voltage.

A fluorescence peak wavelength obtained by converting the energy (eV) of the adiabatic first excited singlet state (S1) (hereinafter, also referred to as “adiabatic S1 excitation energy”) of the heterocyclic compound into a wavelength of light (nm) may be, but is not particularly limited to, 360 nm or more to 515 nm or less. In an embodiment, the fluorescence peak wavelength of the heterocyclic compound may be about 380 nm or more and about 505 nm or less, about 400 nm or more and about 500 nm or less, about 420 nm or more and about 490 nm or less, about 430 nm or more and about 480 nm or less, or about 440 nm or more and about 470 nm or less. When the above range is satisfied, the heterocyclic compound may be more suitable for blue light emission.

In addition, a range of the fluorescence peak wavelength of photoluminescence (PL) is the same as a range of the fluorescence peak wavelength obtained by converting the adiabatic S1 excitation energy into a light wavelength (nm).

In this regard, a spectrum width of fluorescence in PL (a full width at half maximum (FWHM) of the fluorescence spectrum peak) may be used as an index of color purity. The narrower the FWHM of the heterocyclic compound, the higher the color purity. In an embodiment, the FWHM of the heterocyclic compound may be about 30 nm or less, about 25 nm or less, or about 20 nm or less, and may be greater than 0 nm. When the above range is satisfied, light emission with improved color purity may be obtained.

In an embodiment, ΔE_{ST} of the heterocyclic compound may be about 0.4 eV or less. In an embodiment, ΔE_{ST} of the heterocyclic compound may be about 0.30 eV or less, or about 0.25 eV or less. When the above range is satisfied, the width of the emission spectrum of the heterocyclic compound may be large, and light emission with high efficiency may be obtained.

The oscillator strength f of the stable structure in the adiabatic first excited singlet state (S1) of the heterocyclic compound may be, but not particularly limited to, about 0.22 or more. In addition, the oscillator strength f may be about 0.3 or more, about 0.4 or more, or about 0.5 or more. When the above range is satisfied, improved fluorescence intensity may be provided. In addition, the theoretical maximum value of the oscillator strength f is the number of electrons included in the molecule. The upper limit of the oscillator strength f may be, for example, 2 or 3, but is not limited thereto.

The rearrangement energy of the heterocyclic compound may be about 0.1 eV or less. In an embodiment, the rearrangement energy of the heterocyclic compound may be about 0.08 eV or less, about 0.07 eV or less, about 0.065 eV or less, or about 0.06 eV or less, and may be 0 eV or more. When the above range is satisfied, the width of the emission spectrum of the heterocyclic compound may be large, and improved color purity may be provided.

The HOMO, LUMO, peak oscillator strength f of the fluorescence wavelength obtained by converting the adiabatic S1 excitation energy into a light wavelength, and rearrangement energy may be calculated by a density functional theory (DFT) using the calculation software Gaussian 16 (Gaussian Inc.). The calculation method is as described in Examples.

In addition, ΔE_{ST} may be calculated by the DFT, and the calculation method is as described in Examples.

In addition, the singlet energy S1, triplet energy T1, ΔE_{ST}, fluorescence peak wavelength of PL, and FWHM of fluorescence spectrum may each be measured using a spectrofluorophotometer F7000 manufactured by Hitachi High-Tech Co., Ltd. In addition, the measurement method is as described in the Examples.

The synthesis method of the heterocyclic compound according to one or more embodiments is not particularly limited, and the heterocyclic compound may be synthesized according to a known synthesis method. In particular, the heterocyclic compound may be synthesized according to or in view of the method described in the Examples. For example, in the method described in the Examples, the heterocyclic compound according to one or more embodiments may be synthesized through modifications such as changing raw materials and reaction conditions, adding or excluding some processes, or appropriately combining with other known synthesis methods.

The method of identifying a structure of the heterocyclic compound according to one or more embodiments is not particularly limited. The heterocyclic compound containing nitrogen according to one or more embodiments may be identified by a known method, for example, NMR or LC-MS.

### Material for Organic Light-Emitting Device

Another embodiment of the present disclosure relates to a material for an organic light-emitting device including the heterocyclic compound. The material for the organic light-emitting device may include the heterocyclic compound and other materials used in an organic light-emitting device.

The other materials used in an organic light-emitting device may be, but are not limited to, materials known in the art. For example, as the other materials used in an organic light-emitting device, materials constituting each layer described in the below description of the organic light-emitting device may be used. Among the materials constituting each layer, a dopant material or a host material described in the below description of an emission layer of the organic light-emitting device may be used. In addition, a TADF material, a phosphorescent material, or a host material described in the below description of the emission layer of the organic light-emitting device may be used. In this regard, the phosphorescent material may be a platinum complex to be described below.

Accordingly, an embodiment of the present disclosure may provide, in addition to the heterocyclic compound, a material for an organic light-emitting device that further includes a TADF material or a phosphorescent material to be described below. In particular, a material for an emission layer may include a TADF material or a phosphorescent material in addition to the heterocyclic compound, thereby significantly improving the luminescence efficiency and/or device lifespan of the organic light-emitting device.

The material for an organic light-emitting device may be a liquid material further including a solvent. The solvent may be, but is not particularly limited to, a solvent having a boiling point of about 100° C. or more and about 350° C. or less at atmospheric pressure (101.3 kPa, 1 atm). In an embodiment, the boiling point of the solvent at atmospheric pressure may be about 150° C. or more and about 320° C. or less, or about 180° C. or more and about 300° C. or less. When the above range is satisfied, the processability or film-forming capability of a wet film forming method may be improved, especially in an inkjet method.

The solvent having a boiling point of about 100° C. or more and about 350° C. or less at atmospheric pressure is not particularly limited, and a known solvent may be appropriately used. Hereinafter, the solvent having a boiling point of about 100° C. or more and about 350° C. or less at atmospheric pressure will be described in detail, but embodiments of the present disclosure are not limited thereto.

Examples of a hydrocarbon-based solvent may include octane, nonane, decane, undecane, dodecane, and the like. Examples of an aromatic hydrocarbon-based solvent may include toluene, xylene, ethylbenzene, n-propyl benzene, iso-propyl benzene, mesitylene, n-butyl benzene, sec-butyl benzene, 1-phenyl pentane, 2-phenyl pentane, 3-phenyl pentane, phenyl cyclopentane, phenyl cyclohexane, 2-ethyl biphenyl, 3-ethyl biphenyl, and the like. Examples of an ether-based solvent may include 1,4-dioxane, 1,2-diethoxyethane, diethylene glycol dimethyl ether, diethylene glycol diethyl ether, anisole, ethoxybenzene, 3-methylanisole, m-dimethoxy benzene, and the like. Examples of a ketone-based solvent may include 2-hexanone, 3-hexanone, cyclohexanone, 2-heptanone, 3-heptanone, 4-heptanone, cycloheptanone, and the like. Examples of an ester-based solvent may include butyl acetate, butyl propionate, heptyl butyrate, propylene carbonate, methyl benzoate, ethyl benzoate, 1-propyl benzoate, 1-butyl benzoate, and the like. Examples of a nitrile-based solvent may include benzonitrile, 3-methyl benzonitrile, and the like. Examples of an amide-based solvent may include dimethyl formamide, dimethyl acetamide, N-methyl pyrrolidone, and the like. Such solvent may be used alone or in combination of two or more.

The material for an organic light-emitting device according to an embodiment may be a material for an emission layer.

The material for an organic light-emitting device according to an embodiment may not be a liquid composition. That is, the material for an organic light-emitting device may be substantially free of a solvent. In this regard, the term “material substantially free of a solvent” indicates that the amount of the solvent is less than 1 wt % based on the total weight of the composition. When the material for an organic light-emitting device is not a liquid composition, the organic light-emitting device may be substantially free of a solvent, and may not include a solvent (wherein the amount of the solvent is 0 wt % based on the total weight of the composition).

An amount of the heterocyclic compound based on the total weight (in the case of a liquid composition, the total weight excluding the solvent) of the material for an organic light-emitting device (in particular, the material for an emission layer) is the same as an amount of the heterocyclic compound based on the total weight of the emission layer of the organic light-emitting device to be described below.

In addition, an amount of the TADF material or the phosphorescent material (specifically, the phosphorescent material) based on the total weight (in the case of a liquid composition, the total weight excluding the solvent) of the material for an organic light-emitting device (in particular, the material for an emission layer) is the same as an amount of the TADF material or the phosphorescent material (specifically, the phosphorescent material) based on the total weight of the emission layer of the organic light-emitting device to be described below.

In addition, the amount of the TADF material or the phosphorescent material based on the total weight of the material for an organic light-emitting device is the same as an amount (parts by weight) of the TADF material or the phosphorescent material (specifically, the phosphorescent material) based on 100 parts by weight of the heterocyclic compound in the material for an organic light-emitting device (in particular, the material for an emission layer).

In addition, an amount of the host material based on the total weight (in the case of a liquid composition, the total weight excluding the solvent) of the material for an organic light-emitting device (in particular, the material for an emission layer) is the same as an amount of the host material based on the total weight of the emission layer of the organic light-emitting device to be described below.

In addition, an amount (parts by weight) of the host material based on 100 parts by weight of the heterocyclic compound in the material for an organic light-emitting device (in particular, the material for an emission layer) is the same as an amount (parts by weight) of the host material based on 100 parts by weight of the heterocyclic compound in the emission layer of the organic light-emitting device to be described below.

When the amounts of the heterocyclic compound, the TADF material or the phosphorescent material, and the host material in the material for an organic light-emitting device are within the above ranges, respectively, an organic light-emitting device having improved luminescence efficiency and/or lifespan may be obtained according to the emission color purity.

### Organic Light-Emitting Device

Another embodiment of the present disclosure relates to an organic light-emitting device having an organic layer including the heterocyclic compound. The organic light emitting device may have a narrow emission spectrum, and may realize luminescence with high color purity. In addition, the organic light-emitting device may realize improved luminescence efficiency.

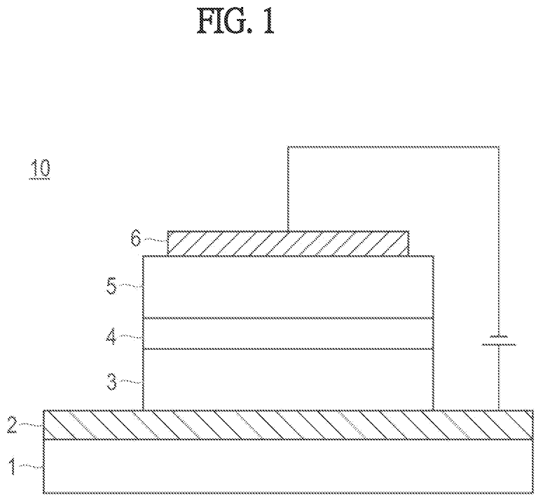

### Description of FIGS. 1 to 3

Hereinafter, an organic light-emitting device 10 according to an embodiment will be described in detail with reference to FIGS. 1 to 3.

FIG. 1 is a schematic cross-sectional view of the organic light-emitting device 10 according to an exemplary embodiment. The organic light-emitting device 10 according to an embodiment may include a substrate 1, a first electrode 2, a hole transport region 3, an emission layer 4, an electron transport region 5, and a second electrode 6, which are sequentially stacked in this stated order.

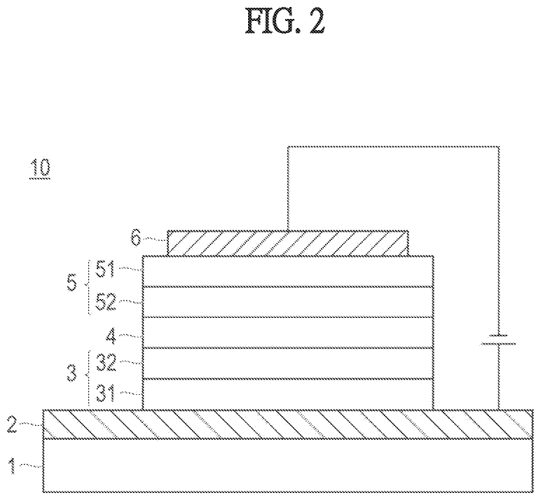

FIG. 2 is a schematic cross-sectional view of the organic light-emitting device 10 according to another exemplary embodiment. The organic light-emitting device 10 according to an embodiment may include the substrate 1, the first electrode 2, the hole transport region 3, the emission layer 4, the electron transport region 5, and the second electrode 6. As shown in FIG. 2, the hole transport region 3 may include a hole injection layer 31 and a hole transport layer 32, which are sequentially stacked in this stated order. In addition, as shown in FIG. 2, the electron transport region 5 may include an electron transport layer 52 and an electron injection layer 51, which are sequentially stacked in this stated order.

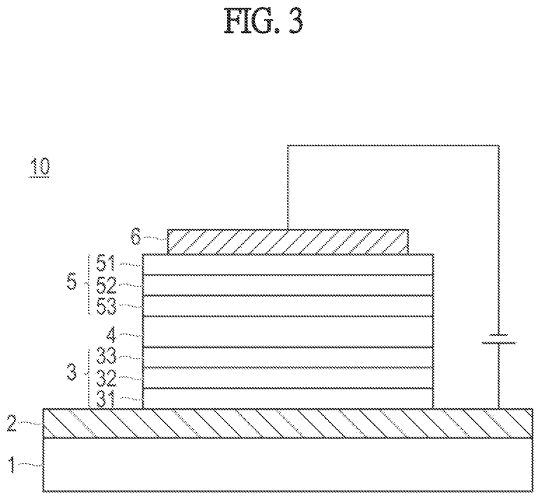

FIG. 3 is a schematic cross-sectional view of the organic light-emitting device 10 according to another exemplary embodiment. The organic light-emitting device 10 according to an embodiment may include the substrate 1, the first electrode 2, the hole transport region 3, the emission layer 4, the electron transport region 5, and the second electrode 6. As shown in FIG. 3, the hole transport region 3 may include the hole injection layer 31, the hole transport layer 32, and an electron blocking layer 33, which are sequentially layered in the stated order. In addition, as shown in FIG. 2, the electron transport region 5 may include a hole blocking layer 53, the electron transport layer 52, and the electron injection layer 51, which are sequentially layered in the stated order.

An embodiment may include, for example, an organic electroluminescence device including a first electrode, a second electrode, and a single or a plurality of emission layers. The second electrode may be arranged on the first electrode.

In the present specification, “on” may not apply only to a case of “just on” another part and may also include a case where another part may be present therebetween. Similarly, when a part such as a layer, a membrane, a regions, a plate, or the like is described as being “below” or “under” another part, a case of “just under” another part and also a case where another part present therebetween may be included.

In the present specification, “arrangement” may include a case where a portion is arranged not only on an upper part but also on a lower part.

The organic light-emitting device 10 may include the heterocyclic compound according to an embodiment. For example, the heterocyclic compound according to an embodiment may be included in an organic layer arranged between the first electrode 2 and the second electrode 6. In an embodiment, the heterocyclic compound may be included in the emission layer 4.

Hereinafter, an embodiment in which the emission layer includes the heterocyclic compound according to an embodiment will be described.

### Emission Layer 4

The emission layer 4 may emit light by fluorescence or phosphorescence.

The emission layer 4 may be a single layer consisting of a single material or a single layer consisting of a plurality of different materials. In addition, the emission layer 4 may have a multi-layered structure having multiple layers including a plurality of different materials.

In the emission layer 4, the heterocyclic compound may be used alone or two or more thereof may be combined.

The amount of the heterocyclic compound may be, but is not particularly limited to about 0.05 wt % or more based on the total weight of the emission layer. In an embodiment, the amount of the heterocyclic compound may be about 0.1 wt % or more, about 0.2 wt % or more, about 50 wt % or less, about 30 wt % or less, or about 25 wt % or less, based on the total weight of the emission layer. Within these ranges, an organic light-emitting device having improved color purity, luminescence efficiency and/or lifespan may be obtained.

In an embodiment, the emission layer 4 may further include a host, the host and the heterocyclic compound may be different from each other, and the emission layer 4 may consist of the host and the heterocyclic compound. In this regard, the host may not emit light, and the heterocyclic compound may emit light. That is, the heterocyclic compound may be a dopant.

In some embodiments, the emission layer 4 may further include a host and a dopant, the host, the dopant, and the heterocyclic compound may be different from one another, and the emission layer 4 may consist of the host, the dopant, and the heterocyclic compound. In this embodiment, the host and the heterocyclic compound may not each emit light, and the dopant may emit light.

In the Examples, the host and the dopant will be described in more detail.

The emission layer 4 may include a known host material and a known dopant material.

For example, the emission layer may include, in addition to the heterocyclic compound, an anthracene derivative, a pyrene derivative, a fluoranthene derivative, a chrysene derivative, a dihydrobenzoanthracene derivative, or a triphenylene derivative.

For example, the emission layer may include, as the host material, at least one of bis[2-(diphenylphosphino)phenyl]etheroxide (DPEPO), 4,4′-bis(carbazol-9-yl)biphenyl (CBP), 3,3′-bis(carbazol-9-yl)biphenyl (mCBP), 1,3-bis(carbazol-9-yl)benzene (mCP), 2,8-bis(diphenylphosphoryl)dibenzo[b,d]furan (PPF), 4,4′,4″-tris(carbazol yl)triphenylamine (TcTa), and 1,3,5-tris(N-phenylbenzimidazole-2-yl)benzene (TPBi). However, the host material is not limited thereto, and the emission layer may include, for example, tris(8-hydroxyquinolino)aluminum (Alq3), 4,4′-bis(N-carbazolyl)-1,1′-biphenyl (CBP), poly(n-vinylcarbazole) (PVK), 9,10-di(naphthalene-2-yl)anthracene (ADN), 4,4′,4″-tris(carbazol-9-yl)-triphenylamine (TCTA), 1,3,5-tris(N-phenylbenzimidazol-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalene-2-yl)anthracene (MADN), bis[2-(diphenylphosphino)phenyl]etheroxide (DPEPO), hexaphenylcyclotriphosphazene (CP1), 1,4-bis(triphenylsilyl)benzene (IGH2), hexaphenylcyclotrisiloxane (DPSiO₃), octaphenylcyclotetrasiloxane (DPSiO4), or 2,8-bis(diphenylphosphoryl)dibenzofuran (PPF).

In addition, the emission layer may include, as the host material, a material having a HOMO of about −5.2 eV or less. In addition, the emission layer may include, as the host material, a material having a LUMO of about −1.4 eV or less. By using a host material having low HOMO and LUMO and high electron transport properties, the driving durability in an organic light-emitting device, particularly in a blue organic light-emitting device, may be improved. Such a material is not particularly limited, and an example thereof may include Compound A represented by the formula below, which is disclosed in “An Alternative Host Material for Long-Lifespan Blue Organic Light-Emitting Diodes Using Thermally Activated Delayed Fluorescence”, Soo-Ghang Ihn, Namheon Lee, Soon Ok Jeon, Myungsun Sim, Hosuk Kang, Yongsik Jung, Dal Ho Huh, Young Mok Son, Sae Youn Lee, Masaki Numata, Hiroshi Miyazaki, Rafael Gomez-Bombarelli, Jorge Aguilera-Iparraguirre, Timothy Hirzel, Alan Aspuru-Guzik, Sunghan Kim, and Sangyoon Lee, Advanced Science News 2017, 4, 1600502. Not wishing to be bound by theory, when the emission layer is formed in combination with such a host material, a blue luminescent material in the related art may become a deep hole trap, thereby causing undesirable effects such as an increase in driving voltage. The heterocyclic compound has weak hole trapping properties, and thus is expected to suppress the increase in the driving voltage.

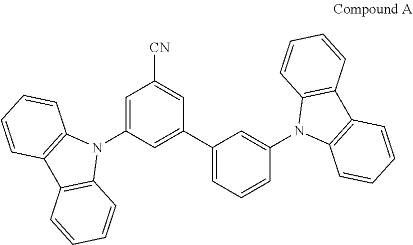 [SMILES: N#Cc1cc(-c2cccc(-n3c4ccccc4c4ccccc43)c2)cc(-n2c3ccccc3c3ccccc32)c1]

In addition, the emission layer may include the compounds below as the host material.

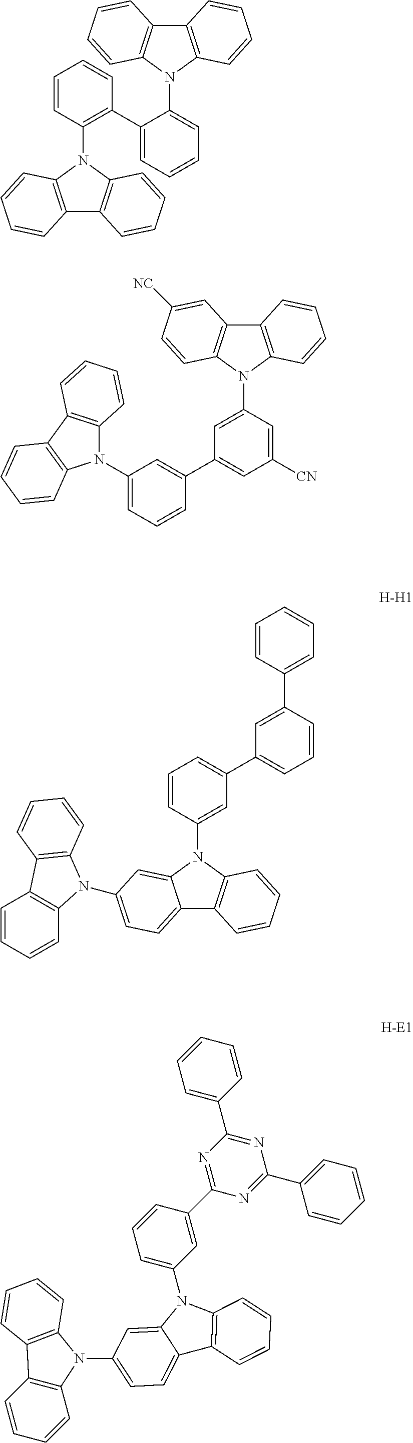 [SMILES: c1ccc(-n2c3ccccc3c3ccccc32)c(-c2ccccc2-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; c1ccc(-c2cccc(-c3cccc(-n4c5ccccc5c5ccc(-n6c7ccccc7c7ccccc76)cc54)c3)c2)cc1 ; c1ccc(-c2nc(-c3ccccc3)nc(-c3cccc(-n4c5ccccc5c5ccc(-n6c7ccccc7c7ccccc76)cc54)c3)n2)cc1]

Among them compounds, the emission layer may include, as the host material, Compound H-H1 and/or Compound H-E1, and in particular, may include Compound H-H1 and Compound H-E1.

The amount of the host material based on the total weight of the emission layer may be, but is not particularly limited to, about 5 wt % or more. In an embodiment, the amount may be about 10 wt % or more, or about 20 wt % or more. In addition, the amount of the host material based on the total weight of the emission layer may be about 99 wt % or less. In an embodiment, the amount may be about 95 wt % or less, or about 90 wt % or less. Within these ranges, an organic light-emitting device having improved luminescence efficiency and/or lifespan may be obtained.

When the emission layer includes a host material, the amount thereof may be, but is not particularly limited to, about 1,000 parts by weight or more, or about 200,000 parts by weight or less, based on 100 parts by weight of the heterocyclic compound. In an embodiment, the amount may be about 2,000 parts by weight or more, about 3,000 parts by weight or more, about 150,000 parts by weight or less, or about 100,000 parts by weight or less, based on 100 parts by weight of the heterocyclic compound. Within these ranges, an organic light-emitting device having improved luminescence efficiency and/or lifespan may be obtained.

The emission layer is not particularly limited, and may include, for example, a known dopant material. For example, the emission layer may include a styryl derivative (for example, 1,4-bis[2-(3-N-ethylcarbazolyl)vinyl]benzene (BCzVB), 4-(di-p-tolylamino)-4′-[(di-p)-tolylamino)styryl]stilbene (DPAVB), or N-(4-((E)-2-(6-((E)-4-(diphenylamino)styryl)naphthalene-2-yl)vinyl)phenyl)-N-phenylbenzeneamine (N-BDAVBi)), perylene or a derivative thereof (for example, 2,5,8,11-tetra-tert-butylperylene (TBP)), or pyrene or a derivative thereof (for example, 1,1-dipyrene, 1,4-dipyrenylbenzene, or 1,4-bis(N,N-diphenylamino)pyrene).

In addition, the emission layer may further include a known TADF compound or phosphorescent material in addition to the heterocyclic compound. The term “thermally activated delayed fluorescence” refers to a phenomenon in which reverse intersystem crossing occurs between triplet excitons and singlet excitons in a compound with a small energy difference (ΔE_{ST}) between the singlet level and the triplet level, and the term “TADF material” refers to a material in which such a phenomenon occurs.

As is known in the related art, in the emission layer of an organic light-emitting device, singlet excitons and triplet excitons are generated at a ratio of 1:3 by recombination of holes and electrons. In a device including only a fluorescent material as a luminescent material, only singlet excitons are involved in light emission, whereas in a device including a TADF material or a phosphorescent material as a luminescent material, both singlet excitons and triplet excitons may be used for light emission. Accordingly, the luminescence efficiency of the device including the TADF material or the phosphorescent material as a luminescent material may be significantly improved. Excitons generated on the TADF material or the phosphorescent material generally have a long lifespan of 1 μs or more. The excitons are in an unstable state with high energy, and thus, material degradation may occur while the excitons are present, leading to a reduction in device lifespan. When the TADF material or the phosphorescent material is present in the emission layer, in addition to the heterocyclic compound, excitons are generated with high efficiency on the TADF material or the phosphorescent material, and energy is transferred to the heterocyclic compound through a Förster resonance energy transfer (FRET) mechanism. As a result, highly efficient fluorescence may be obtained from the heterocyclic compound, and the time for which excitons are present on the TADF material or the phosphorescent material may be shortened. Thus, the possibility of material deterioration may be significantly reduced, and the device lifespan may be significantly improved.

The amount of the TADF material or the phosphorescent material (in particular, the phosphorescent material) based on the total weight of the emission layer may be, but is not particularly limited to, about 0.1 wt % or more. In an embodiment, the amount may be about 0.5 wt % or more, about 1 wt % or more, about 3 wt % or more, or about 5 wt % or more. In addition, the amount of the TADF material or the phosphorescent material (in particular, the phosphorescent material) based on the total weight of the emission layer may be about 50 wt % or less. In an embodiment, the amount may be about 40 wt % or less, or about 30 wt % or less. In addition, when the emission layer includes both the TADF material and the phosphorescent material, the total amount thereof may be within the above ranges. Within these ranges, an organic light-emitting device having improved luminescence efficiency and/or lifespan may be obtained.

When the emission layer includes the TADF material or the phosphorescent material (in particular, the phosphorescent material), the amount thereof may be, but is not particularly limited to, 100 parts by mass or more based on 100 parts by mass of the heterocyclic compound. In an embodiment, the amount may be about 150 parts by mass or more, or about 200 parts by mass or more, based on 100 parts by mass of the heterocyclic compound. In addition, the amount of the TADF material or the phosphorescent material (in particular, the phosphorescent material) may be about 10,000 parts by mass or less based on 100 parts by mass of the heterocyclic compound. In an embodiment, the amount may be about 7,500 parts by mass or less, or about 5,000 parts by mass or less, based on 100 parts by mass of the heterocyclic compound. In addition, when the emission layer includes both the TADF material and the phosphorescent material, the total amount thereof may be within the above ranges. Within these ranges, an organic light-emitting device having improved luminescence efficiency and/or lifespan may be obtained.

Examples of the TADF material may include the following compounds.

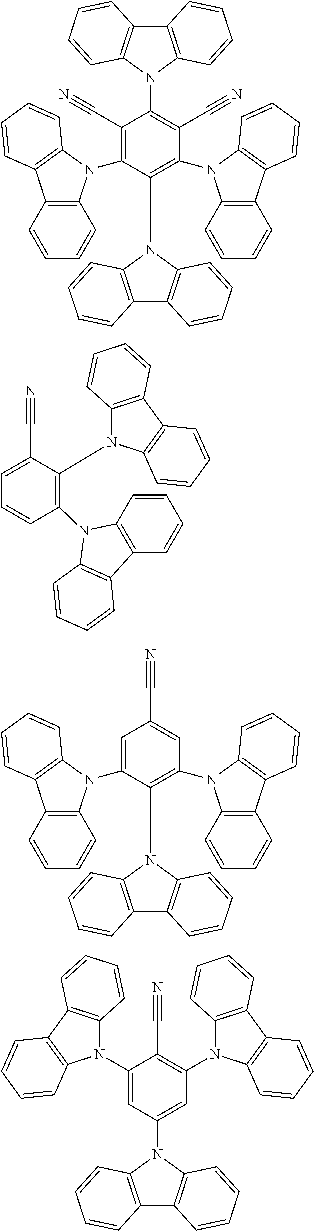

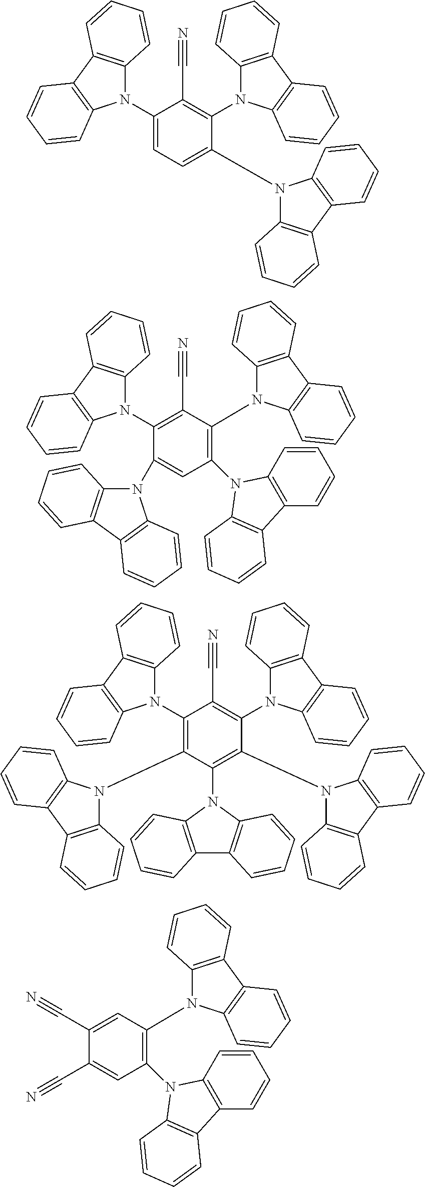

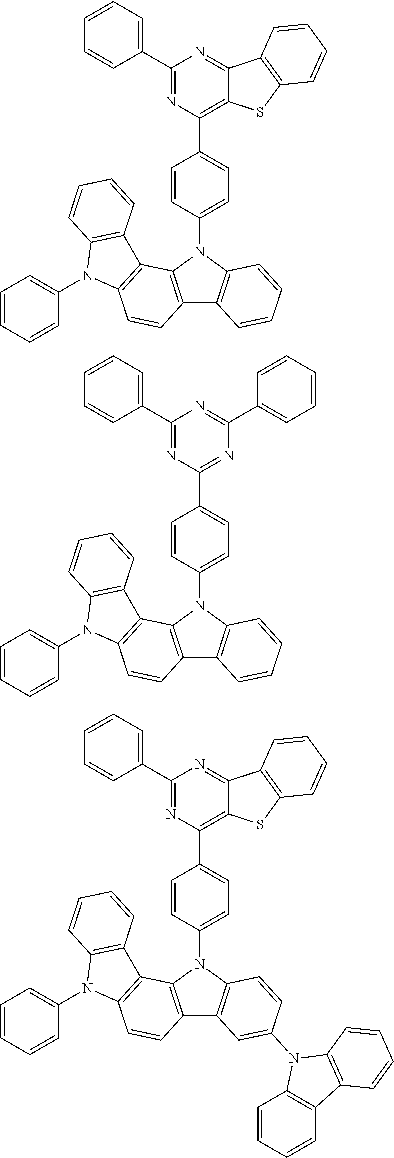

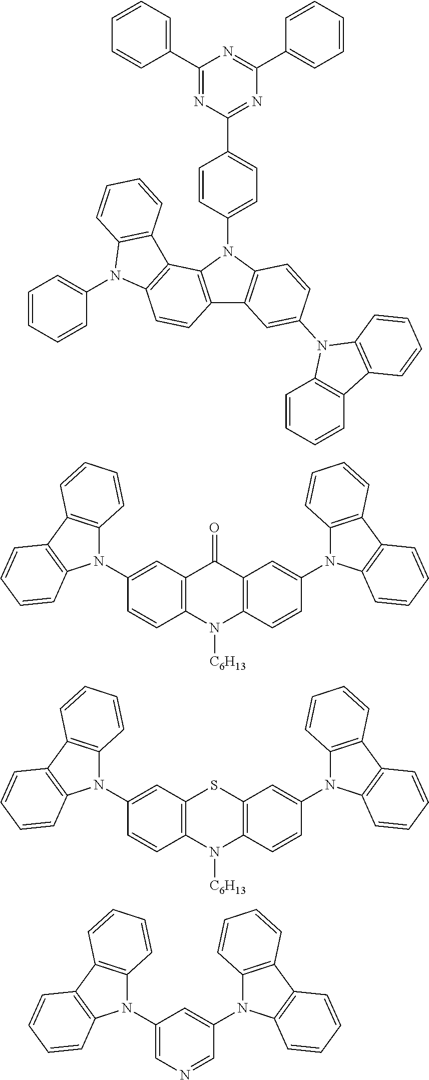

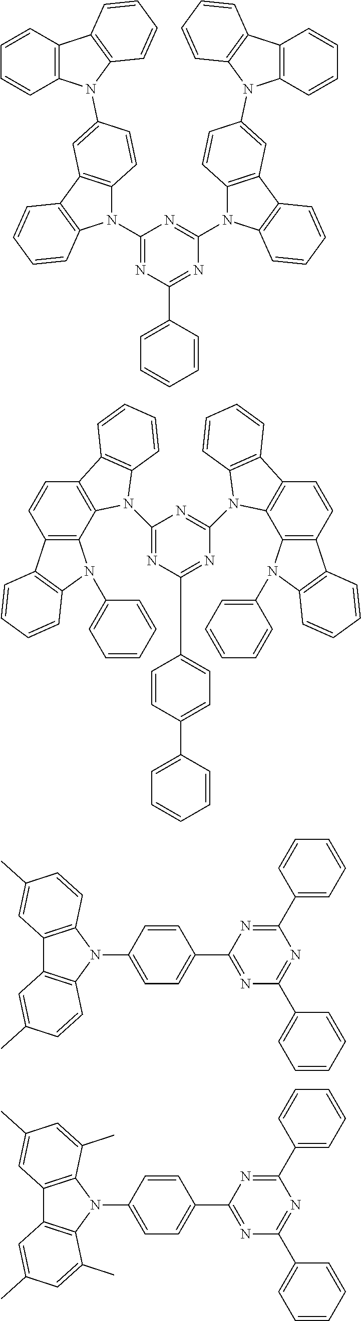

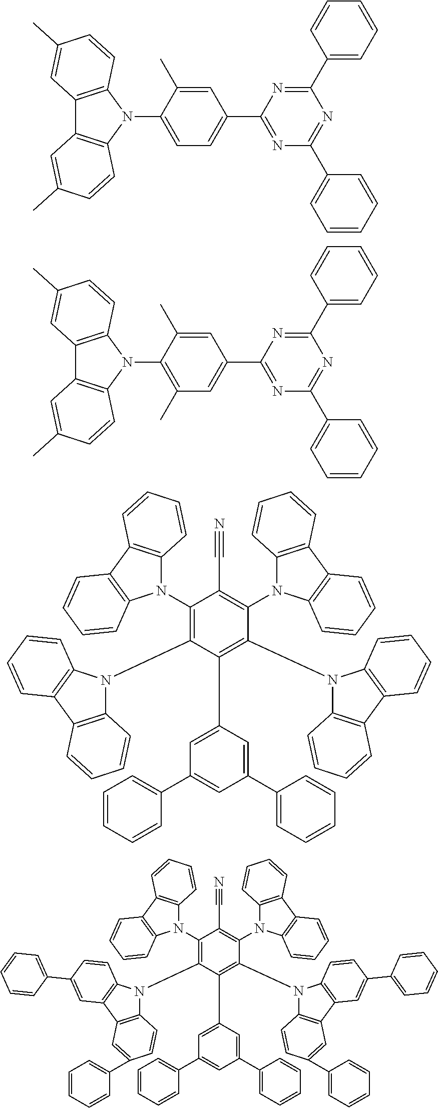

The TADF material may be used alone or in combination of two or more TADF materials.

In addition, the emission layer may include a phosphorescent material (phosphorescent compound) in addition to the heterocyclic compound. The phosphorescent material (phosphorescent compound) is not particularly limited, and a known phosphorescent compound may be used. Among known phosphorescent compounds, a phosphorescent complex may be used, and in particular, a platinum complex may be used.

Examples of the phosphorescent material (phosphorescent compound) may include the following compounds.

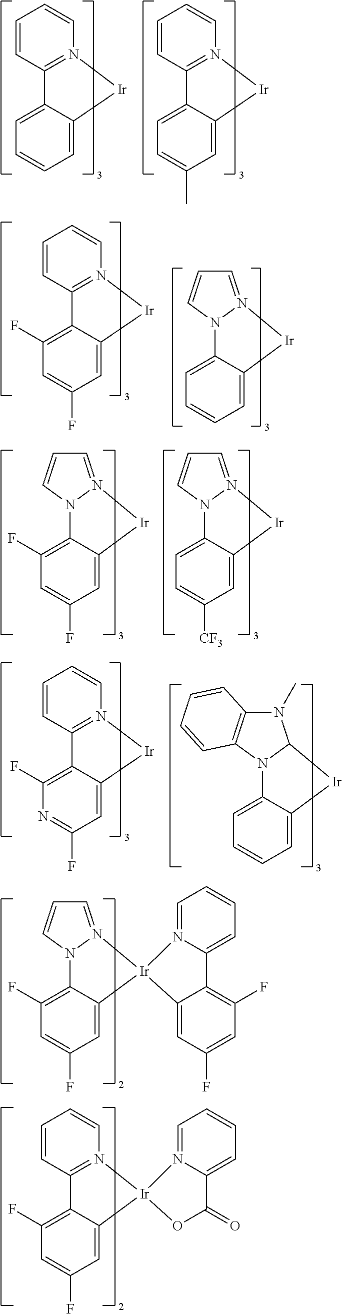

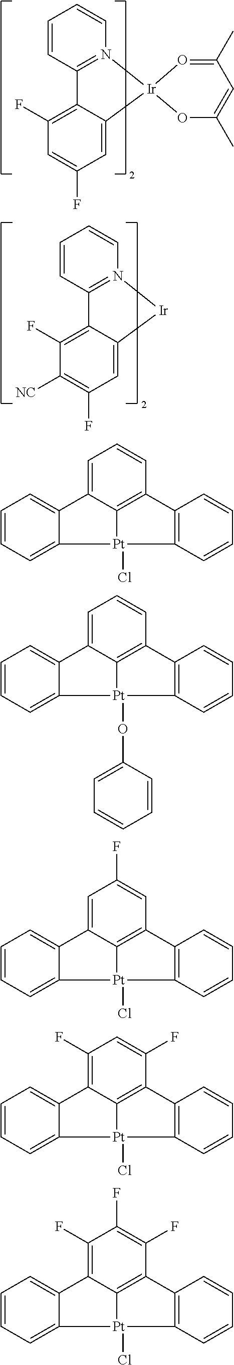

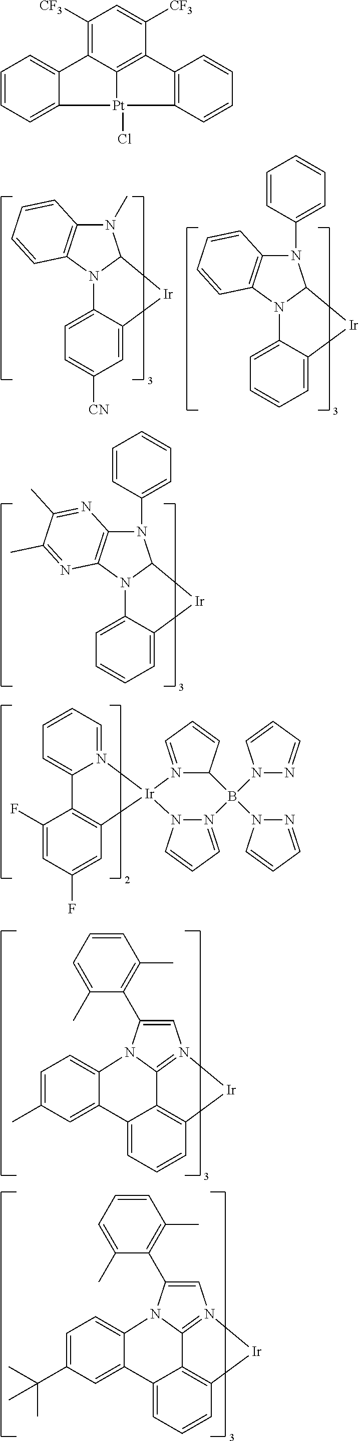

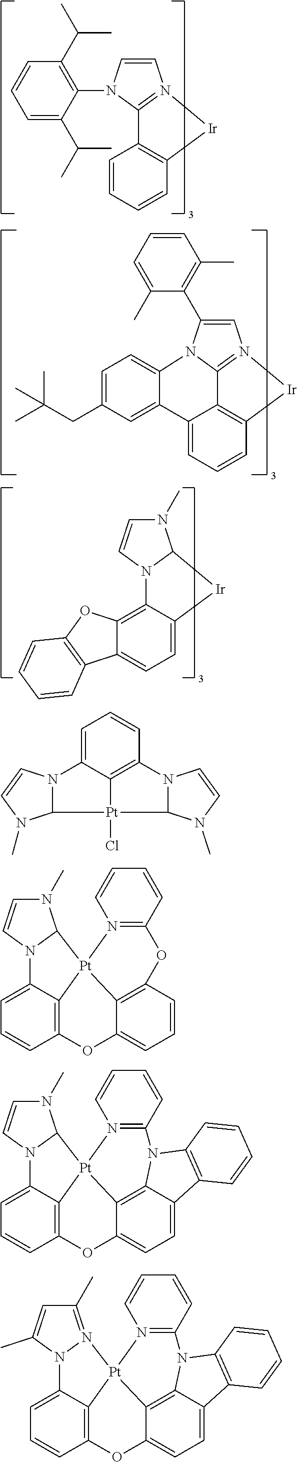

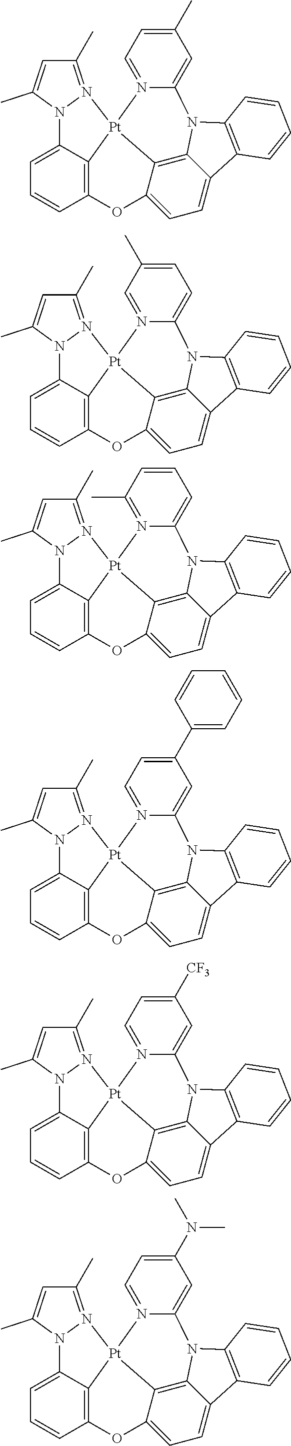

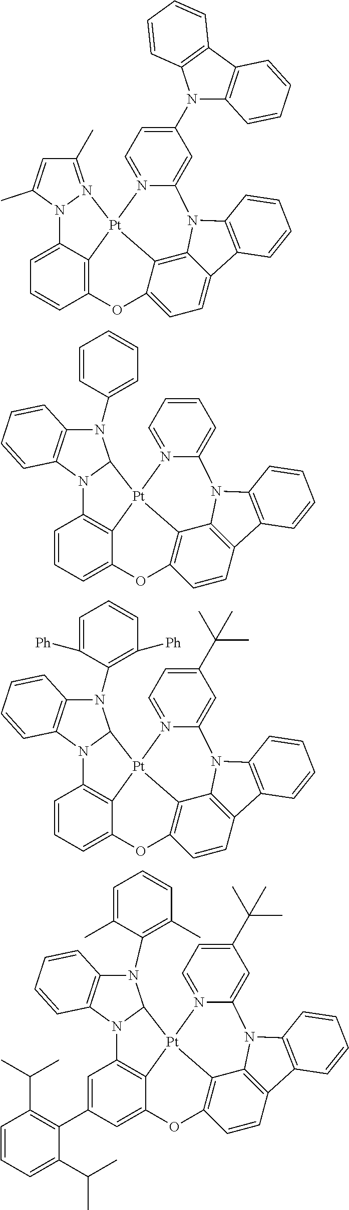

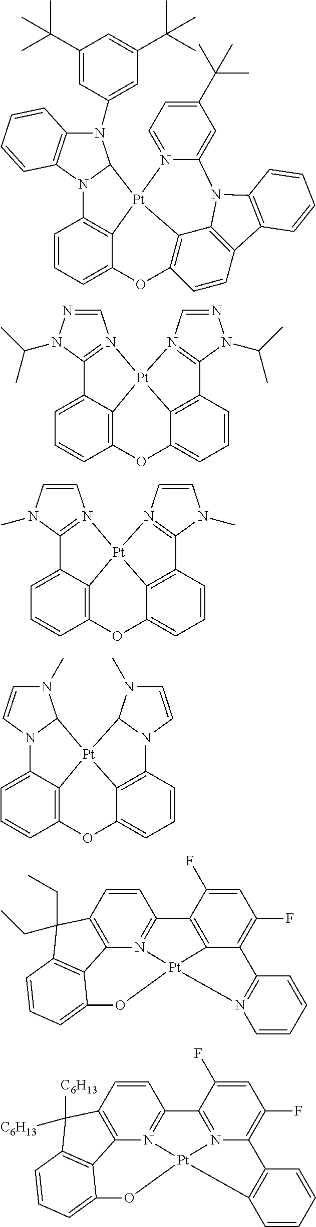

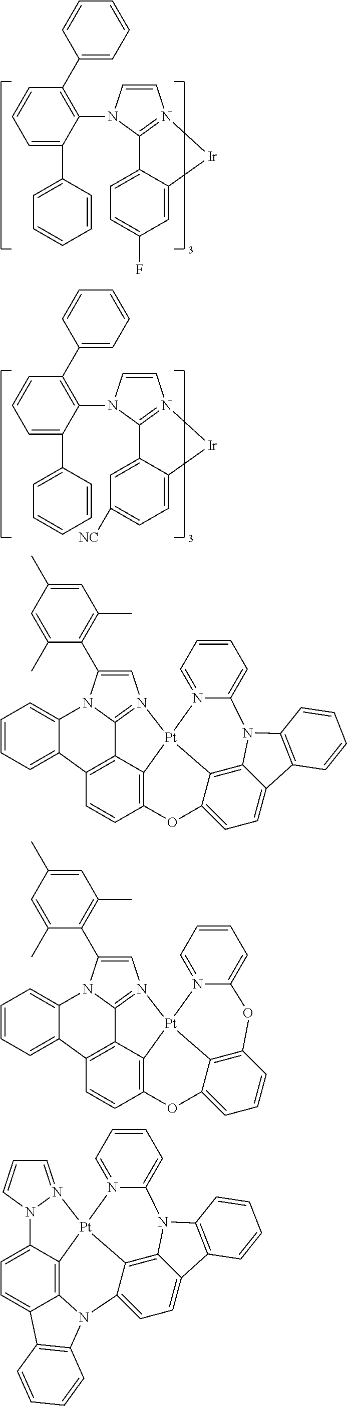

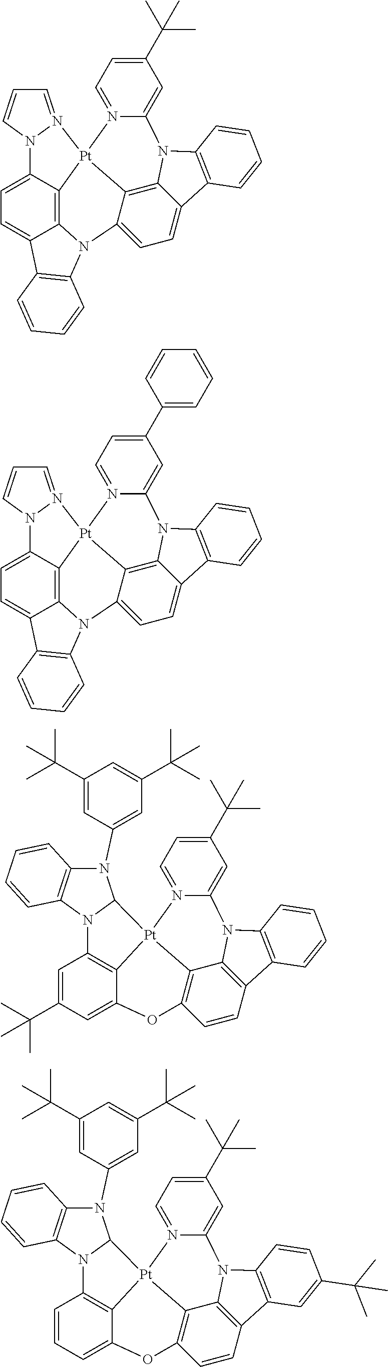

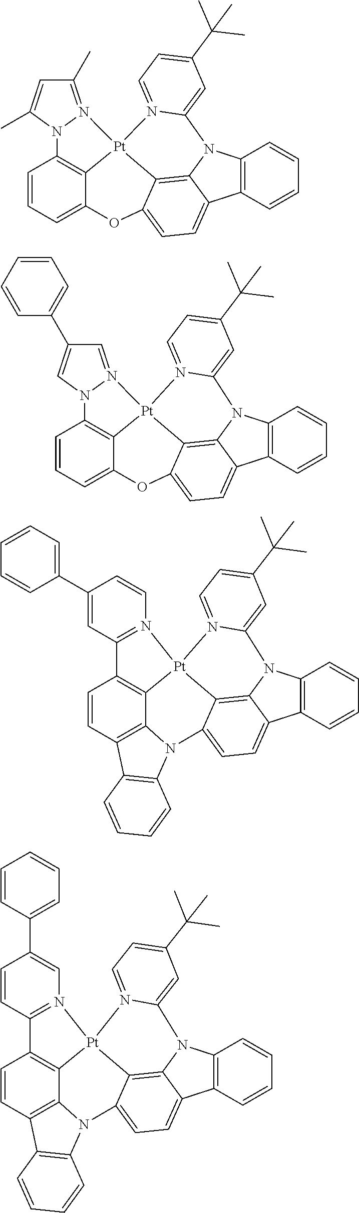

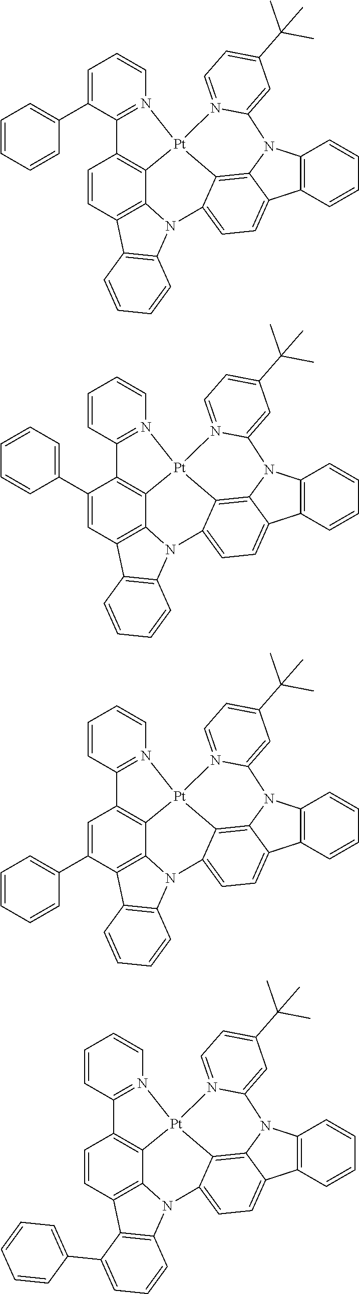

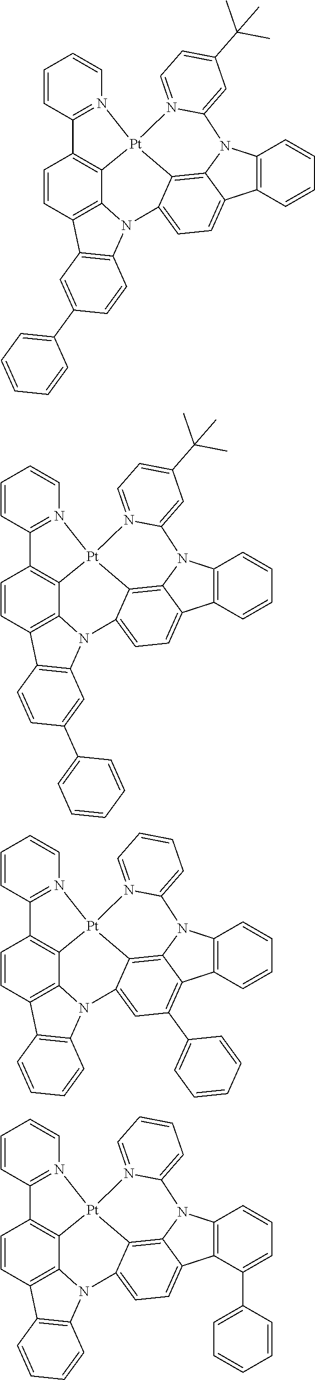

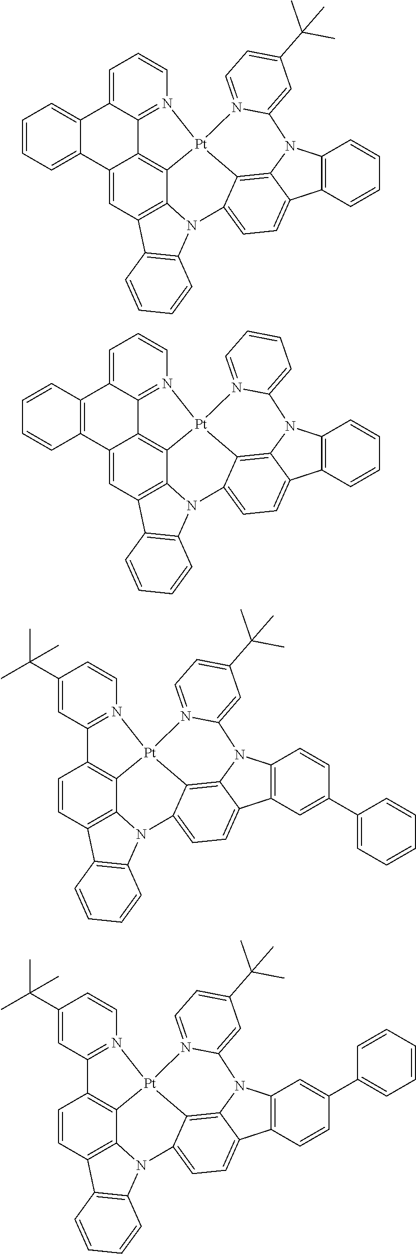

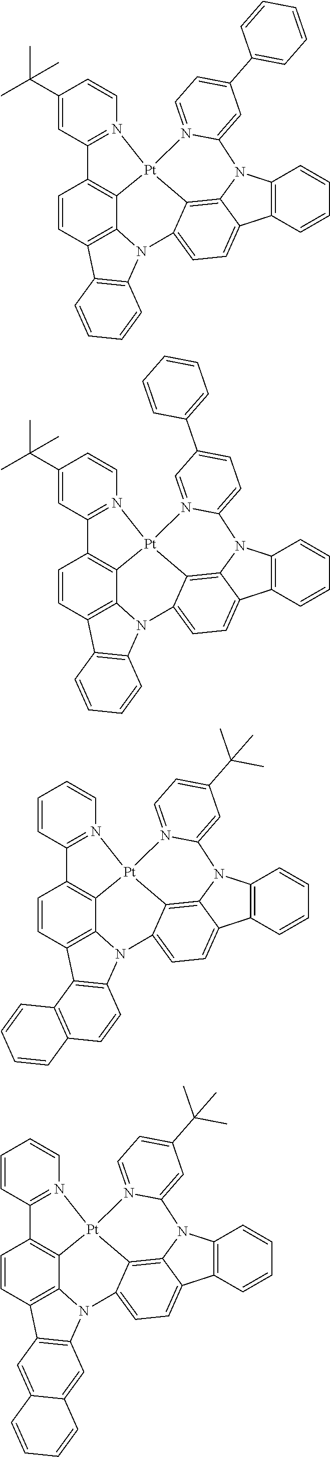

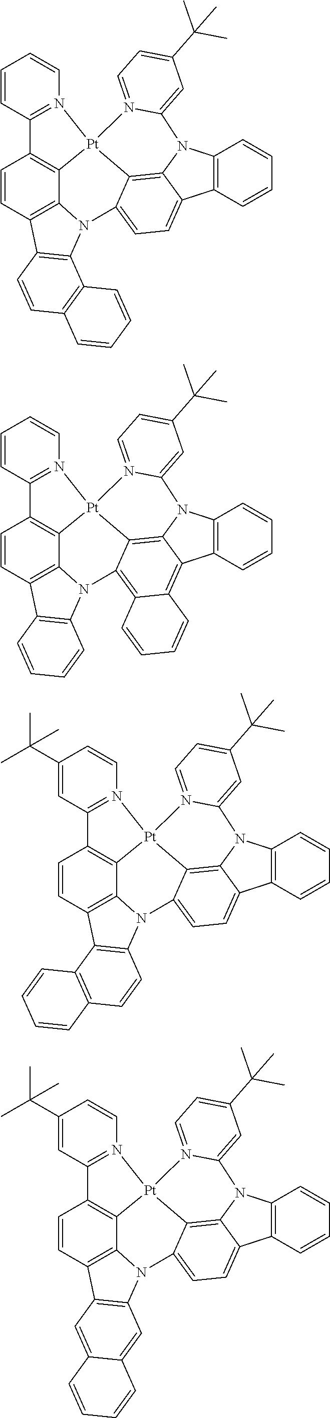

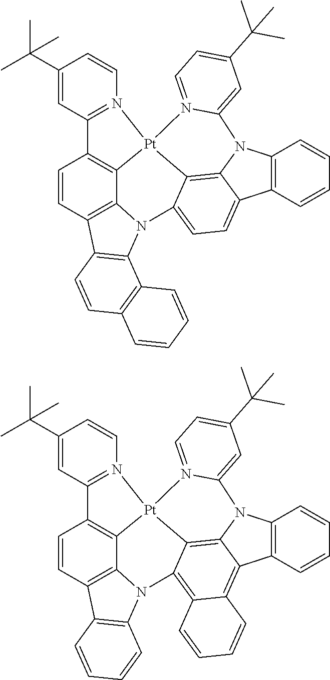

The phosphorescent material (phosphorescent compound) may be used alone or in combination of two or more phosphorescent materials.

The thickness of the emission layer is not particularly limited and may be in a range about 1 nm to about 100 nm, or for example, about 10 nm to about 30 nm.

The emission wavelength of the organic light-emitting device is not particularly limited. However, the organic light-emitting device may emit light having a peak in a wavelength range of about 360 nm or more to about 515 nm or less, about 380 nm or more to about 505 nm or less, about 400 nm or more to about 500 nm or less, about 420 nm or more to about 490 nm or less, or about 430 nm or more to about 480 nm or less.

In addition, the FWHM of an emission spectrum of the organic light-emitting device may be about 30 nm or less, about 25 nm or less, about 20 nm or less, or about 0 nm or more.

Hereinafter, each region and each layer other than the emission layer 4 will be described in detail.

### Substrate 1

The organic light-emitting device 10 may include the substrate 1. The substrate 1 may be any suitable substrate generally used in organic light-emitting devices. For example, the substrate 1 may be a glass substrate, a silicon substrate, or a transparent plastic substrate having excellent mechanical strength, thermal stability, transparency, surface smoothness, ease of handling, and water repellency, but embodiments are not limited thereto.

### First Electrode 2

The first electrode 2 may be formed on the substrate 1. The first electrode 2 may be an anode and be formed from a material with a relatively high work function including a metal, an alloy, a conductive compound, or a combination thereof, for facilitating hole injection. The first electrode 2 may be a pixel electrode. The first electrode 2 may be a reflective electrode, a semi-transmissive electrode, or a transmissive electrode.

The materials for forming the first electrode 2 are not particularly limited and may be, for example, indium tin oxide (ITO), indium zinc oxide (IZO), tin oxide (SnO₂), zinc oxide (ZnO), indium tin zinc oxide (ITZO), or the like, having excellent transparency and conductivity, when the first electrode 2 is a transparent electrode. When the first electrode 2 is a semi-transmissive or reflective electrode, Ag, Mg, Cu, Al, Pt, Pd, Au, Ni, Nd, Ir, Cr, Li, Ca, In, LiF/Ca, LiF/Al, Mo, Ti, or a mixture thereof (for example, a mixture of Ag and Mg or a mixture of Mg and In) may be included.

The first electrode 2 may be a single layer consisting of a single material or a single layer consisting of a plurality of different materials. In one or more embodiments, the first electrode 2 may have a multi-layer structure including a plurality of layers including various different materials.

A thickness of the first electrode 2 may be, but is not particularly limited to, about 10 nm or more and about 1,000 nm or less, or about 100 nm or more and about 300 nm or less.

### Hole Transport Region 3

The hole transport region 3 may be arranged on the first electrode 2.

The hole transport region 3 may include at least one of a hole injection layer 31, a hole transport layer 32, an electron blocking layer (33), a hole buffer layer (not shown), or a combination thereof.

The hole transport region 3 may be a single layer consisting of a single material or a single layer consisting of a plurality of different materials. In one or more embodiments, the hole transport region 3 may have a multi-layer structure including a plurality of layers including various different materials.

The hole transport region 3 may include the hole injection layer 31 only or the hole transport layer 32 only. In one or more embodiments, the hole transport region 3 may be a single layer including a hole injection material and a hole transport material. The hole transport region 3 may have a hole injection layer/hole transport layer structure, a hole injection layer/hole buffer layer structure, a hole injection layer/hole transport layer/hole buffer layer structure, or a hole injection layer/hole transport layer/electron blocking layer structure, wherein layers of each structure are sequentially stacked on the first electrode 2 in each stated order.

Layers forming the hole injection layer 31 and other layers included in the hole transport region 3 are not particularly limited, and a known hole injection material and/or a hole transport material may be included.

Examples of the hole injection material may include a phthalocyanin compound such as copper phthalocyanin, N,N′-diphenyl-N,N′-bis-[4-phenyl-m-tril-amino)-phenyl]-biphenyl-4,4′-diamine (DNTPD), (4,4′,4″-tris(3-methylphenylphenylamino)triphenylamine) (m-MTDATA), 4,4′,4″-tris(N,N-diphenylamino)triphenylamine (TDATA), 4,4′,4″-tris{N,-(2-naphthyl)-N-phenyl amino}-triphenylamine (2-TNATA), poly(3,4-ethylenedioxythiophene)/poly(4-styrenesulfonate) (PEDOT/PSS), polyaniline/dodecylbenzenesulfonic acid (PAN I/DBSA), polyaniline/camphor sulfonic acid (PANI/CSA), polyaniline/poly(4-styrenesulfonate) (PAN I/PSS), N,N′-di(naphthalene-1-yl)-N,N′-diphenyl-benzidine (NPB), polyether ketone including triphenylamine (TPAPEK), 4-isopropyl-4′-methyldiphenyliodonium tetrakis(pentafluorophenyl)borate, dipyrazino[2,3-f:2′,3′-h]quinoxaline-2,3,6,7,10,11-hexacarbonitrile (HAT-CN), 1,3,4,5,7,8-hexafluorotetracyano-2,6-naphthoquinodimethane (F6-TCNNQ), and the like.

Examples of the hole transport material may include N-phenylcarbazole, a carbazole-based derivative such as polyvinyl carbazole, a fluorene-based derivative, N,N′-bis(3-methylphenyl)-N,N′-diphenyl-[1,1-biphenyl]-4,4′-diamine (TPD), a triphenylamine-based derivative such as 4,4′,4″-tris(N-carbazolyl)triphenylamine (TCTA), N,N′-di(naphthalene-1-yl)-N,N′-diphenylbenzidine (NPB), 4,4′-cyclohexylidenbis[N,N-bis(4-methylphenyl)benzenamine] (TAPC), 4,4′-bis[N,N′-(3-tril)amino]-3,3′-dimethylbiphenyl (HMTPD), 1,3-bis(N-carbazolyl)benzene (mCP), Compound H1, Compound H2, Compound HT01, and the like.

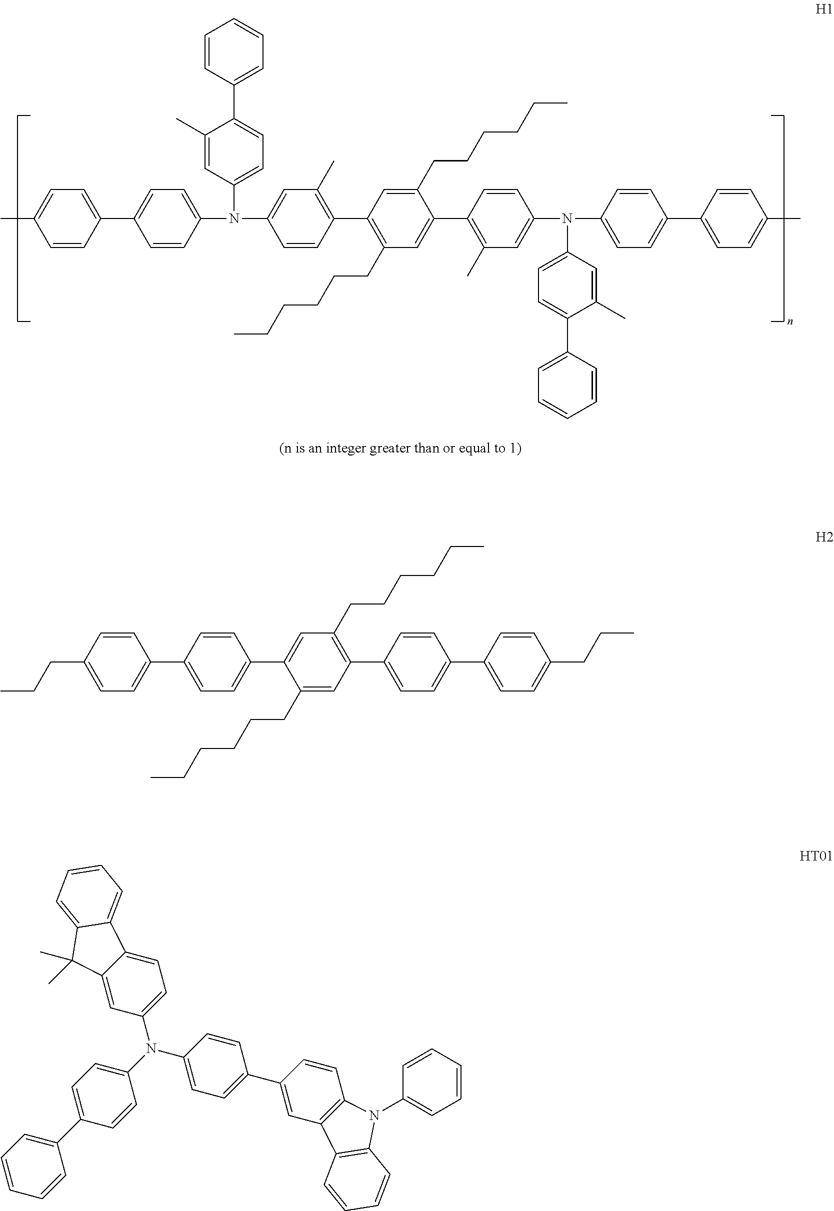

The hole transport region 3 may include, in addition to the materials described above, a charge generating material to improve conductive properties of the hole transport region. The charge generating material may be homogeneously or non-homogeneously dispersed in the hole transport region 3.

The charge generating material is not particularly limited and may be, for example, a p-dopant. Examples of the p-dopant may include: a quinone derivative, such as tetracyanoquinodimethane (TCNQ) or 2,3,5,6-tetrafluoro-tetracyano-1,4-benzoquinonedimethane (F4-TCNQ); a metal oxide, such as a tungsten oxide or a molybdenum oxide; and a compound containing a cyano group, but are not limited thereto.

The hole buffer layer (not shown) may increase luminescence efficiency by compensating for an optical resonance distance according to the wavelength of light emitted by the emission layer 4. Materials included in the hole buffer layer (not shown) are not particularly limited, and a known hole buffer layer material may be used. For example, the compounds that may be included in the hole transport region 3.

The electron blocking layer 33 may prevent electron injection from the electron transport region 5 to the hole transport region 3. Materials included in the electron blocking layer 33 are not particularly limited, and a known electron blocking layer material may be used. For example, the host materials that may be included in the emission layer and Compound H-H1 as a host material may be included.

A thickness of the hole transport region 3 may be, but is not particularly limited to, about 1 nm or more and about 1,000 nm or less, or for example, about 10 nm or more and about 500 nm or less. In addition, a thickness of the hole injection layer 31 may be, but is not particularly limited to, about 3 nm or more and about 100 nm or less. A thickness of the hole transport layer 32 may be, but is not particularly limited to, about 3 nm or more and about 100 nm or less. A thickness of the electron blocking layer 33 may be, but is not particularly limited to, about 1 nm or more and about 100 nm or less. In addition, a thickness of the hole buffer layer (not shown) is not particularly limited, as long as the hole buffer layer may not adversely effect on functions of an organic light-emitting device. When the thickness of the hole transport region 3, the hole injection layer 31, the hole transport layer 32, or the electron blocking layer 33 is within the above ranges, excellent hole transport characteristics may be obtained without a substantial increase in driving voltage.

### Emission Layer 4

The emission layer 4 may be arranged on the hole transport region 3. The emission layer 4 may be understood by referring to the description of the emission layer 4 described above.

### Electron Transport Region 5

The electron transport region 5 may be arranged on the emission layer 4. The electron transport region 5 may include at least one of a hole blocking layer 53, the electron transport layer 52, the electron injection layer 51, or a combination thereof.

The electron transport region 5 may be a single layer consisting of a single material or a single layer consisting of a plurality of different materials. In one or more embodiments, the electron transport region 5 may have a multi-layered structure including a plurality of layers including various different materials.

The electron transport region 5 may include the electron transport layer 52 only or the electron injection layer 51 only. In one or more embodiments, the electron transport region 5 may be a single layer including an electron injection material and an electron transport material. In one or more embodiments, the electron transport region 5 may include an electron transport layer/electron injection layer structure or a hole blocking layer/electron transport layer/electron injection layer structure, which are sequentially stacked on the emission layer 4.

The electron injection layer 51 is not particularly limited and may include, for example, a known electron injection material. Examples of the electron injection layer material may include Yb, a lithium compound such as (8-hydroxyquinolinato)lithium (Liq) and lithium fluoride (LiF), sodium chloride (NaCl), cesium fluoride (CsF), rubidium fluoride (RbCl), lithium oxide (Li₂O), or barium oxide (BaO).

In one or more embodiments, the electron injection layer 51 may include an electron transporting material and an insulating organic metal salt to be described below. The metal salt is not particularly limited and may be, for example, a material having an energy band gap of 4 eV or more. The organic metal salt may include, for example, an acetate metal salt, a benzoate metal salt, an acetate metal salt, an acetyl acetonate metal salt, or a stearate metal salt.

The electron transport layer 52 is not particularly limited and may include, for example, a known electron transport material. Examples of the electron transport material may include an anthracene-based compound, tris(8-hydroxyquinolinolate)aluminum) (Alq3), 1,3,5-tri[(3-pyridyl)-pen-3-yl]benzene, 2,4,6-tris(3′-pyridine-3-yl)biphenyl-3-yl)-1,3,5-triazine, 2-(4-(N-phenylbenzimidazolyl-1-ylphenyl)-9,10-dinaphthylanthracene, 1,3,5-tri(1-phenyl-1H-benzo[d]imidazole-2-yl)phenyl (TPBi), 2,9-dimethyl-4,7-diphenyl-1,10-phenanthroline (BCP), 4,7-diphenyl-1,10-phenanthroline (Bphen), 3-(4-biphenyl)-4-phenyl-5-tert-butylphenyl-1,2,4-triazole (TAZ), 4-(naphthalene-1-yl)-3,5-diphenyl-4H-1,2,4-triazole (NTAZ), 2-(4-biphenyl)-5-(4-tert-butylphenyl)-1,3,4-oxadiazole (tBu-PBD), bis(2-methyl-8-quinolinolate-N1,O8)-(1,1′-biphenyl-4-orato)aluminum (BAlq), beryllium bis(benzoquinoline-10-orato) (Bebq2), 9,10-di(naphthalene-2-yl)anthracene (ADN), lithum quinolate (LiQ), Compound ET1, and the like.

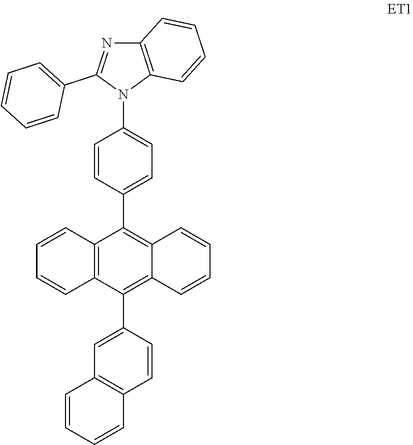 [SMILES: c1ccc(-c2nc3ccccc3n2-c2ccc(-c3c4ccccc4c(-c4ccc5ccccc5c4)c4ccccc34)cc2)cc1]

The hole blocking layer 53 may prevent hole injection from the hole transport region 3 to the electron transport region 5. Materials included in the hole blocking layer 53 are not particularly limited, and a known hole blocking material may be used. The hole blocking layer 53 may include, for example, 2,9-dimethyl-4,7-diphenyl-1,10-phenanthroline (BCP), 4,7-diphenyl-1,10-phenanthroline (Bphen), and the like. In addition, examples of the hole blocking material may include the host materials that may be included in the emission layer, and Compound H-E1 as a host material.

A thickness of the electron transport region 5 may be, but is not particularly limited to, about 0.1 nm or more and about 210 nm or less, or for example, about 100 nm or more and about 150 nm or less. A thickness of the electron transport layer 52 may be, but is not particularly limited to, about 10 nm or more and about 100 nm or less, or for example, about 15 nm or more and about 50 nm or less. A thickness of the hole blocking layer 53 may be, but is not particularly limited to, about 10 nm or more and about 100 nm or less, or for example, about 15 nm or more and about 50 nm or less. A thickness of the electron injection layer 51 may be, but is not particularly limited to, about 0.1 nm or more and about 10 nm or less, or for example, about 0.3 nm or more and about 9 nm or less. When the thickness of the electron injection layer 51 is within the above ranges, excellent electron injection characteristics may be obtained without a substantial increase in driving voltage.

In addition, when the thickness of the electron transport region 5, the electron injection layer 51, the electron transport layer 52, or the hole blocking layer 53 is within the above ranges, excellent hole transport characteristics may be obtained without a substantial increase in driving voltage.

### Second Electrode 6

The second electrode 6 may be arranged on the electron injection layer 51. The second electrode 6 may be a cathode and be formed of a material with a relatively low work function including a metal, an alloy, or a conductive compound, for facilitating electron injection. The second electrode 6 may be a common electrode. The second electrode 6 may be a reflective electrode, a semi-transmissive electrode, or a transmissive electrode. The second electrode 6 may have a single-layered structure or a multi-layered structure including a plurality of layers. Materials for forming the second electrode 6 are not particularly limited. For example, when the second electrode 6 is a transparent electrode, the second electrode 6 may include a transparent metal oxide, for example, ITO, IZO, ZnO, or ITZO. When the second electrode 6 is a semi-transmissive or reflective electrode, Ag, Mg, Cu, Al, Pt, Pd, Au, Ni, Nd, Ir, Cr, Li, Ca, In, LiF/Ca, LiF/, Mo, Ti, or a mixture thereof (for example, a mixture of Ag and Mg or a mixture of Mg and In) may be included.

The second electrode 6 may be a single layer consisting of a single material or a single layer consisting of a plurality of different materials. In one or more embodiments, the second electrode 6 may have a multi-layered structure including a plurality of layers including various different materials.

A thickness of the second electrode 6 may be, but is not particularly limited to, about 10 nm or more and about 1,000 nm or less.

The second electrode 6 may be further connected to an auxiliary electrode (not shown). When the second electrode 6 is connected to the auxiliary electrode, the resistance of the second electrode 6 may be further reduced.

An encapsulation layer (not shown) may be further arranged on the second electrode 6. The encapsulation layer (not shown) is not particularly limited and may include, for example, a-NPD, NPB, TPD, m-MTDATA, Alq3, CuPc, N4,N4,N4′,N4′-tetra(phenyl-4-yl)biphenyl-4,4′-diamine (TPD15), TCTA, N,N′-bis(naphthalene-1-yl), and the like.

In addition, a stacking structure of the organic light-emitting device 10 according to an embodiment is not limited to the above descriptions. The organic light-emitting device 10 according to an embodiment may have a different stacking structure known in the art. For example, the organic light-emitting device 10 may not include at least one selected from the hole injection layer 31, the hole transport layer 32, the electron transport layer 52, and the electron injection layer 51, or may further include another layer. In one or more embodiments, each layer of the organic light-emitting device 10 may be formed as a single layer or as multiple layers.

Methods of forming each layer of the organic light-emitting device 10 according to one or more embodiments are not particularly limited. For example, vacuum-deposition, solution coating, a laser printing method, Langmuir-Blodgett (LB) method, or laser induced thermal imaging (LITI), may be used in forming each layer thereof.

The solution coating may include spin coating, casting, micro-gravure coating, gravure coating, bar coating, roll coating, wire bar coating, dip coating, spray coating, screen printing, flexographic printing, offset printing, or ink-jet printing.

The vacuum deposition may be performed at a deposition temperature in a range of about 100° C. to about 500° C., at a vacuum pressure in a range of about 10⁻⁸ torr to about 10⁻³ torr, and at a deposition rate in a range of about 0.01 nm per second (nm/sec) to about 10 nm/sec, though the conditions may vary depending on a compound that is used and a structure and thermal properties of a desired layer.

In an embodiment, the first electrode 2 may be an anode, and the second electrode 6 may be a cathode.

For example, the first electrode 2 may be an anode, the second electrode 6 may be a cathode, and an organic layer may include the emission layer 4 between the first electrode 2 and the second electrode 6 and may further include a hole transport region between the first electrode 2 and the emission layer 4 and an electron transport region between the emission layer 4 and the second electrode 6, wherein the hole transport region 3 may include at least one including the hole injection layer 31, the hole transport layer 32, a hole buffer layer, an electron blocking layer, or a combination thereof, and the electron transport region 5 may include at least one including a hole blocking layer, the electron transport layer 52, the electron injection layer 51, or a combination thereof.

In one or more embodiments, the first electrode 2 may be a cathode, and the second electrode 6 may be an anode.

In the organic light-emitting device 10 of FIGS. 1 to 3, since a voltage is applied to each of the first electrode 2 and the second electrode 6, holes provided from the first electrode 2 may move toward the emission layer 4 through the hole transport region 3, and electrons provided from the second electrode 6 may move toward the emission layer 4 through the electron transport region 5. The holes and the electrons may recombine in the emission layer 4 to produce excitons, and these excitons may transition from an excited state to a ground state to thereby generate light.

Hereinbefore, the organic light-emitting device 10 has been described with reference to FIGS. 1 to 3, but embodiments are not limited thereto.

### Electronic Apparatus

The organic light-emitting device may be included in various electronic apparatuses.

The electronic apparatus may further include a thin-film transistor in addition to the organic light-emitting device as described above. The thin-film transistor may include a source electrode, a drain electrode, and an activation layer, wherein any one of the source electrode and the drain electrode may be electrically connected to any one of the first electrode and the second electrode of the organic light-emitting device.

Hereinafter, a compound and an organic light-emitting device according to embodiments are described in detail with reference to Synthesis Examples and Examples. However, the organic light-emitting device is not limited thereto. The wording “‘B’ was used instead of ‘A’” used in describing Synthesis Examples means that an amount of ‘A’ used was identical to an amount of ‘B’ used, in terms of a molar equivalent.

### EXAMPLES

### Synthesis Example 1: Synthesis of Compound 101

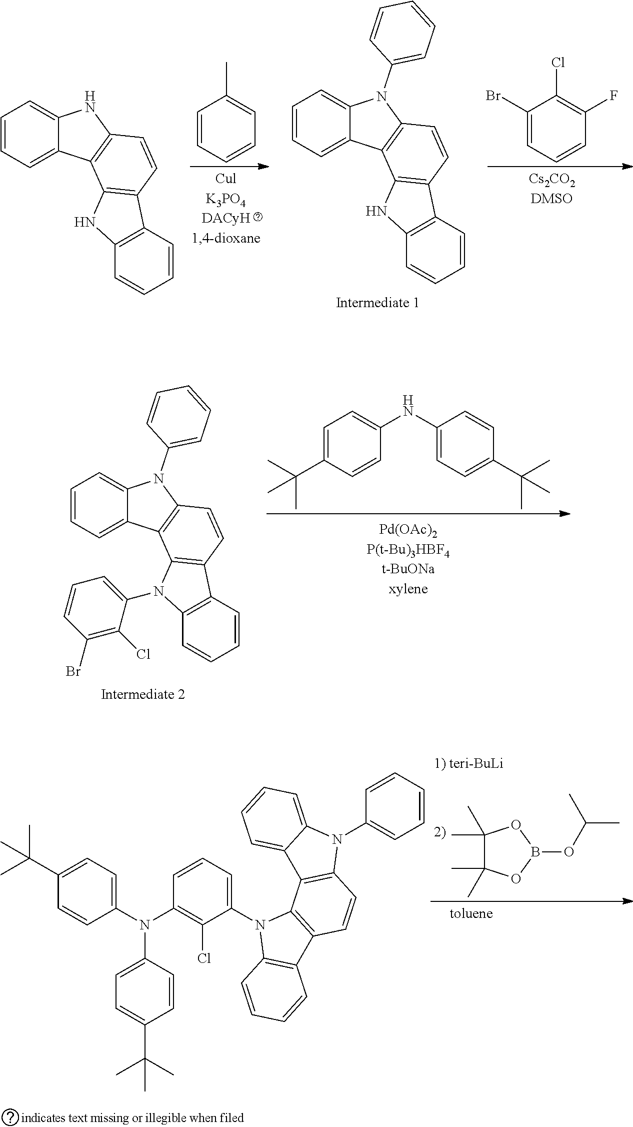

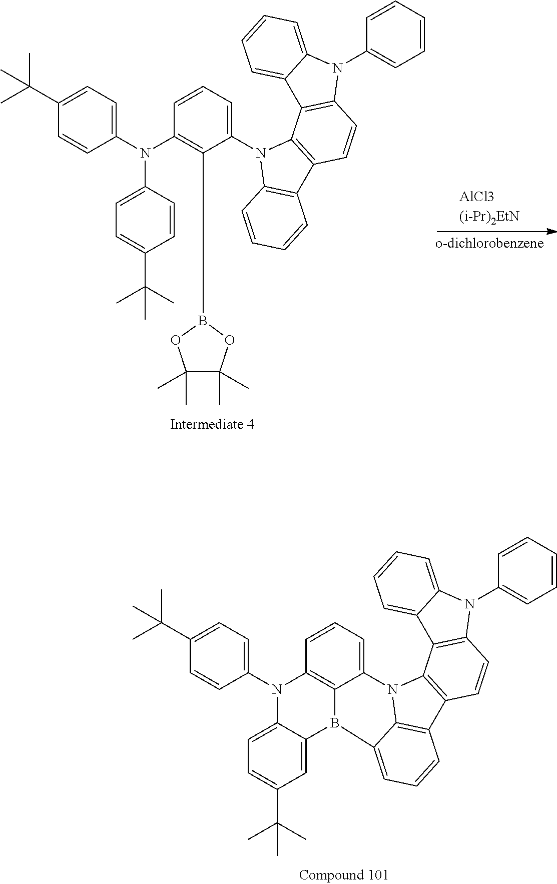 [SMILES: CC(C)(C)c1ccc(N(c2ccc(C(C)(C)C)cc2)c2cccc(-n3c4ccccc4c4ccc5c(c6ccccc6n5-c5ccccc5)c43)c2B2OC(C)(C)C(C)(C)O2)cc1 ; CC(C)(C)c1ccc(N2c3ccc(C(C)(C)C)cc3B3c4c2cccc4-n2c4c3cccc4c3ccc4c(c5ccccc5n4-c4ccccc4)c32)cc1]

### Synthesis of Intermediate 1

10.0 g (39.0 mmol, 1.0 eq) of 5,12-dihydroindolo[3,2-a]carbazole, 8.76 g (42.9 mmol, 1.1 eq) of iodobenzene, 33.1 g (156.1 mmol, 4.0 eq) of potassium phosphate, 0.22 g (1.17 mmol, 0.03 eq) of copper iodide (I), and 195 ml of 1,4-dioxane were added to a reaction vessel, followed by stirring under reflux for 8 hours in a nitrogen atmosphere. After completion of the reaction, the reaction solution was diluted with toluene and filtered using Celite. The filtrate was concentrated and washed with hexane to obtain Intermediate 1 (yield: 15.3 g, 65%).

### Synthesis of Intermediate 2

5.0 g (15.0 mmol, 1.0 eq) of Intermediate 1, 6.3 g (30.1 mmol, 2.0 eq) of 1-bromo-2-chloro-3-fluorobenzene, 7.35 g (22.6 mmol, 1.5 eq) of cesium carbonate, and 15 ml of dimethylsulfoxide were added to a reaction vessel, followed by stirring while heating at 160° C. for 30 hours in a nitrogen atmosphere. After completion of the reaction, the reaction solution was diluted with toluene and filtered using Celite. Water was added to the filtrate to extract an organic layer therefrom, and the organic layer was dried using magnesium sulfate and then concentrated. Then, purification was performed thereon using silica gel column chromatography to obtain Intermediate 2 (yield: 2.5 g, 32%).

### Synthesis of Intermediate 3

2.3 g (4.4 mmol, 1.0 eq) of Intermediate 2, 1.2 g (4.4 mmol, 1.0 eq) of bis(4-tert-butylphenyl)amine, 0.64 g (6.61 mmol, 1.5 eq) of sodium tert-butoxide, 0.01 g (0.04 mmol, 0.01 eq) of palladium (II) acetate, 0.05 g (0.18 mmol, 0.04 eq) of tri-tert-butylphosphonium tetrafluoroborate, and 22 ml of xylene were added to a reaction vessel, followed by stirring under reflux for 3 hours in a nitrogen atmosphere. After completion of the reaction, the reaction solution was diluted with toluene and filtered using Celite. The obtained filtrate was concentrated, and then, purification was performed thereon using silica gel column chromatography to obtain Intermediate 3 (yield: 2.2 g, 69%).

### Synthesis of Intermediate 4

1.0 g (1.4 mmol, 1.0 eq) of Intermediate 3 and 7 ml of toluene were added to a reaction vessel and stirred. The mixture was cooled to 0° C. in a nitrogen atmosphere, and 1.7 ml (2.8 mmol, 2.0 eq) of a 1.6M tert-butyllithium pentane solution was added dropwise thereto, followed by stirring at room temperature (25° C.) for 1 hour. Then, the reaction solution was cooled to 0° C., and 0.77 g (4.2 mmol, 3.0 eq) of 2-isopropoxy-4,4,5,5-tetramethyl-1,3,2-dioxaborane was added dropwise thereto. The reaction solution was stirred at room temperature (25° C.) for 1 hour. Then, the reaction solution was diluted with toluene, and water was added thereto to extract an organic layer therefrom. The organic layer was dried using magnesium sulfate and concentrated to obtain Intermediate 4 (yield: 1.0 g, 90%).

### Synthesis of Compound 101

1.0 g (1.2 mmol, 1.0 eq) of Intermediate 4, 1.6 g (12.3 mmol, 10 eq) of aluminum chloride, 0.8 g (6.1 mmol, 5.0 eq) of N,N-diisopropylethylamine, and 4 ml of o-dichloro benzene were added to a reaction vessel, followed by heating and stirring at 180° C. for 15 minutes using a microwave synthesizing device Initiator+(BIOTAGE). Then, an organic layer was extracted therefrom using water and dichloromethane. The organic layer was dried using magnesium sulfate, concentrated, and purified by silica gel column chromatography to obtain Compound 101 (yield: 0.02 g, 1.8%).

### Structural Identification of Compound 101

Structural identification of Compound 101 was performed using liquid chromatography mass spectrometry (LC/MS). In detail, the sample (obtained Compound 101) was dissolved in tetrahydrofuran at a concentration of 0.1 wt %, and then, mass spectrometry was performed thereon using an LC/MS measuring device 1260 Infinity-quadruple electrode 6100MS (manufactured by Agilent Technology Co., Ltd.). The obtained results are shown below:

LC-MS: 696 ([M+H]+).

### Synthesis Example 2: Synthesis of Compound 102

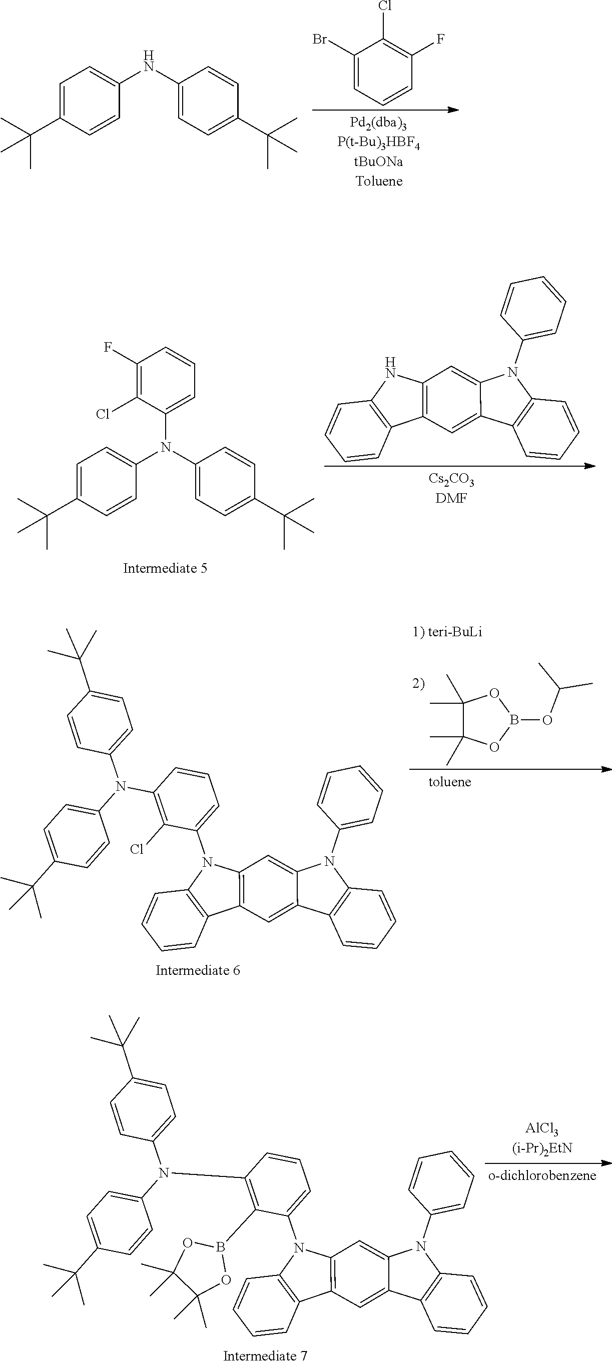

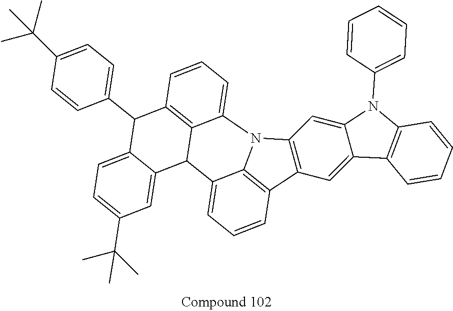 [SMILES: CC(C)(C)c1ccc(C2c3ccc(C(C)(C)C)cc3C3c4c2cccc4-n2c4cc5c(cc4c4cccc3c42)c2ccccc2n5-c2ccccc2)cc1]

### Synthesis of Intermediate 5

6.719 g (23.87 mmol, 1.0 eq) of bis(4-tert-butylphenyl)amine, 5.0 g (23.87 mmol, 1.0 eq) of 1-bromo-2-chloro-3-fluorobenzene, 6.883 g (71.62 mmol, 3.0 eq) of sodium tert-butoxide, 0.874 g (0.95 mmol, 0.04 eq) of tris(dibenzylideneacetone)dipalladium (0), 0.554 g (1.91 mmol, 0.08 eq) of tri-tert-butylphosphonium tetrafluoroborate, and 50 ml of toluene were added to a reaction vessel, followed by heating and stirring at 75° C. for 2 hours in a nitrogen atmosphere. After completion of the reaction, the reaction solution was diluted with toluene and filtered using Celite. The filtrate was concentrated and purified by silica gel column chromatography to obtain Intermediate 5 (yield: 6.475 g, 66%).

### Synthesis of Intermediate 6

6.475 g (15.79 mmol, 1.05 eq) of Intermediate 5, 5.0 g (15.04 mmol, 1.0 eq) of 5,7-dihydro-5-phenyl-indolo[2,3-b]carbazole, 9.802 g (30.08 mmol, 2.0 eq) of cesium carbonate, and 96 ml of dimethylformamide were added to a reaction vessel, followed by heating and stirring at 155° C. for 30 hours in a nitrogen atmosphere. After completion of the reaction, the reaction solution was cooled to room temperature, diluted with toluene, filtered through Celite, and then filtered through a pad of silica gel. The obtained filtrate was concentrated and washed with methanol to obtain Intermediate 6 (yield: 7.4 g, 68%). Synthesis of Intermediate 7

Intermediate 7 was synthesized in the same manner as in <Synthesis of Intermediate 4> except that Intermediate 3 was changed to Intermediate 6 (amount: 5.3 g, yield: 64%).

### Synthesis of Compound 102

0.4 g (0.49 mmol, 1.0 eq) of Intermediate 7, 0.66 g (4.91 mmol, 10 eq) of aluminum chloride, and 1.7 ml of o-dichlorobenzene were added to a reaction vessel, followed by stirring at room temperature (25° C.) in a nitrogen atmosphere. Then, 0.32 g (2.46 mmol, 5.0 eq) of N,N-diisopropylethylamine was added thereto, followed by heating and stirring at 160° C. for 3 hours. After completion of the reaction, the reaction solution was cooled to room temperature, and an organic layer was extracted therefrom using water and dichloromethane. The organic layer was dried using magnesium sulfate, concentrated, and purified by silica gel column chromatography. Then, the organic layer was washed with methanol to obtain Compound 102 (yield: 0.14 g, 40%).

Structural identification of Compound 102 was performed in the same manner as that of Compound 101:

LC-MS: 696 ([M+H]+).

### Synthesis Example 3: Synthesis of Compound 103

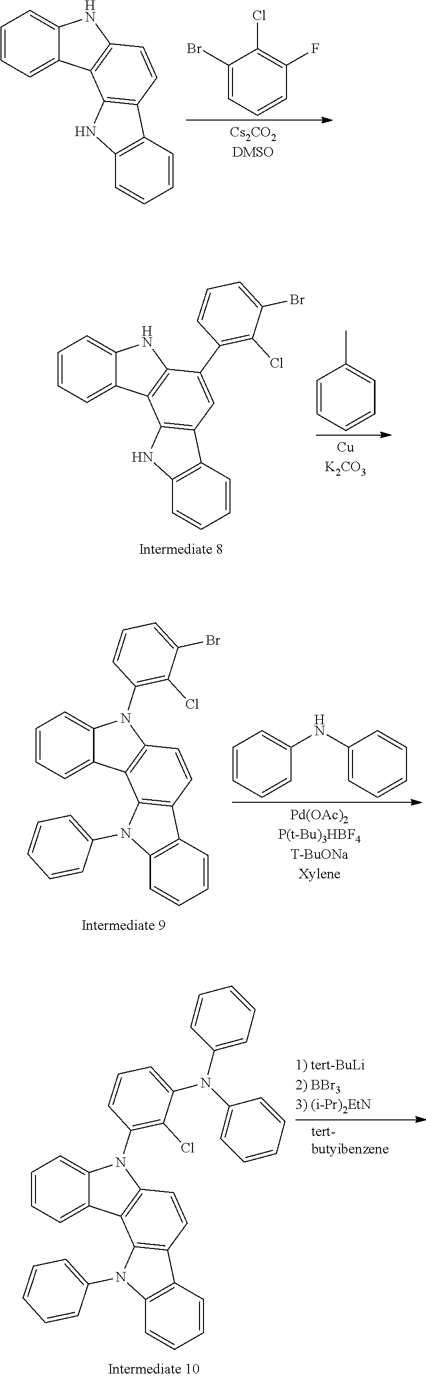

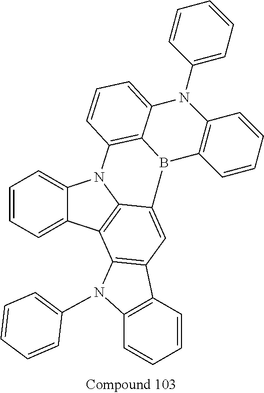 [SMILES: c1ccc(N2c3ccccc3B3c4c2cccc4-n2c4ccccc4c4c2c3cc2c3ccccc3n(-c3ccccc3)c24)cc1]

### Synthesis of Intermediate 8

10.0 g (39.0 mmol, 1.0 eq) of 5,12-dihydroindolo[3,2-a]carbazole, 8.58 g (41.0 mmol, 1.05 eq) of 1-bromo-2-chloro-3-fluorobenzene, 19.1 g (58.5 mmol, 1.5 eq) of cesium carbonate, and 40 ml of dimethylsulfoxide were added to a reaction vessel, followed by heating and stirring at 160° C. for 8 hours in a nitrogen atmosphere. After completion of the reaction, the reaction solution was diluted with toluene and filtered using Celite. Water was added to the filtrate to extract an organic layer therefrom, and the organic layer was dried using magnesium sulfate and then concentrated. The obtained solid was washed with hexane to obtain Intermediate 8 (yield: 15.3 g, 88%).

### Synthesis of Intermediate 9

15.0 g (39.0 mmol, 1.0 eq) of Intermediate 8, 82.4 g (403.8 mmol, 12 eq) of iodobenzene, 1.07 g (16.8 mmol, 0.5 eq) of copper powder, 14.0 g (101.0 mmol, 3.0 eq) of potassium carbonate, and 195 ml of 1,4-dioxane were added to a reaction vessel, followed by heating and stirring at 180° C. for 16 hours in a nitrogen atmosphere. After completion of the reaction, the reaction solution was cooled to room temperature, diluted with toluene, and filtered using Celite. The filtrate was concentrated, and the solid obtained by adding hexane thereto was separated by filtration to obtain Intermediate 9 (yield: 11.3 g, 70%).

### Synthesis of Intermediate 10

Intermediate 10 was synthesized in the same manner as in <Synthesis of Intermediate 3> except that Intermediate 2 of <Synthesis of Intermediate 3> was changed to Intermediate 9 (amount: 7.15 g, yield: 72%).

### Synthesis of Compound 103

Intermediate 10 (1.0 eq, 2.0 g, 3.28 mmol) and 16 ml of tert-butyl benzene were added to a reaction vessel and stirred. In a nitrogen atmosphere, the reaction solution was cooled to 0° C., and a 1.6 M tert-butyllithium pentane solution (2.0 eq, 4.1 ml, 6.56 mmol) was added dropwise thereto. The mixture was stirred at 60° C. for 2 hours, and then, the low-boiling components were removed therefrom by distillation. Then, the reaction solution was cooled to −30° C., and boron tribromide (2.0 eq, 1.6 g, 6.56 mmol) was added thereto, followed by stirring at room temperature (25° C.) for 1 hour. Then, the reaction solution was cooled to 0° C., and N,N-diisopropylethylamine (2.0 eq, 0.85 g, 6.56 mmol) was added thereto, followed by heating and stirring at 120° C. for 3 hours. After completion of the reaction, the reaction solution was cooled to room temperature, and an organic layer was extracted therefrom using water and dichloromethane. The organic layer was dried using magnesium sulfate, concentrated, and purified by silica gel column chromatography to obtain Compound 103 (yield: 0.68 g, 30%).

Structural identification of Compound 103 was performed in the same manner as that of Compound 101:

LC-MS: 584 ([M+H]+).

### Simulation of Heterocyclic Compound

According to “High-Performance Dibenzoheteraborin-Based Thermally Activated Delayed Fluorescence Emitters: Molecular Architectonics for Concurrently Achieving Narrowband Emission and Efficient Triplet-Singlet Spin Conversion”, In Seob Park, Kyohei Matsuo, Naoya Aizawa, and Takuma Yasuda, Advanced Functional Materials 2018 28 1802031, the spectrum width of fluorescence (the FWHM of the fluorescence spectrum) has a close relationship with the reorganization energy [E(S0@S1)−E(S0@S0)] that is expressed by the difference between the ground state (S0) energy of the stable structure in the first excited singlet state (S1) [E(S0@S1)] and the ground state (S0) energy of the stable structure in the ground state (S0) [E(S0@S0)].

### Identification of Relationship Between Reorganization Energy and Spectrum Width of Fluorescence

First, the relationship between the reorganization energy [E(S0@S1)−E(S0@S0)] and the spectrum width (FWHM) of fluorescence was identified as follows.

### Calculation by DFT

For Compounds R1 to R3 known in the related art, the following calculations were performed by the DFT.

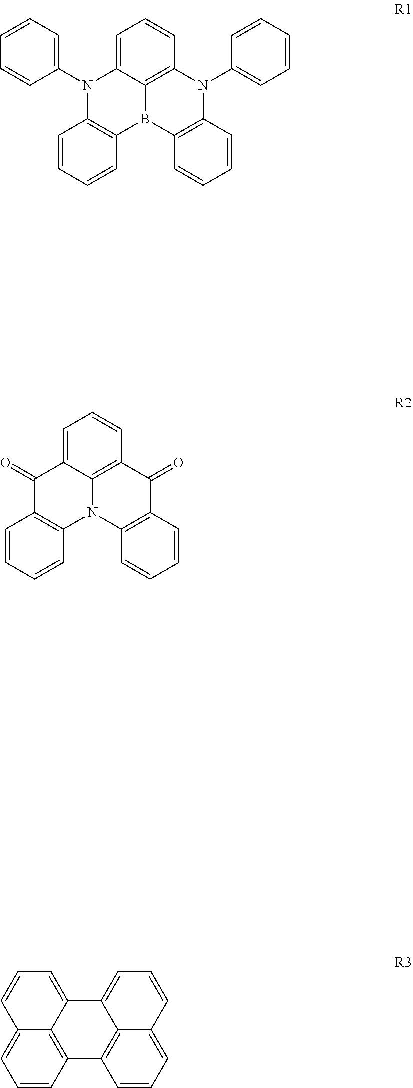

The ground state (S0) energy of the stable structure in the first excited singlet state (S1) [E(S0@S1)] and the ground state (S0) energy of the stable structure in the ground state (S0) [E(S0@S0)] were calculated, and from the difference therebetween, the reorganization energy [E(S0@S1)]−[E(S0@S0)] (eV) was calculated.

In addition, the first excited singlet state (S1) energy of the stable structure in the first excited singlet state (S1) [E(S1@S1)] was calculated, and from the difference between this value and the ground state (S0) energy of the stable structure in the ground state (S0) [E(S0@S0)], the adiabatic first excited singlet state (S1) energy [E(S1@S1)]-[E(S0@S0)] (eV) was calculated.

Then, the fluorescent wavelength (nm) obtained by converting the adiabatic first excited singlet state (S1) energy into a light wavelength (nm) was calculated.

In addition, the oscillator strength f of the stable structure in the first excited singlet state (S1) was calculated.

In addition, the HOMO energy and the LUMO energy were calculated.

In this regard, calculation by the DFT was performed by using Gaussian 16 (Gaussian Inc.) as calculation software, according to the following calculation methods (I), (II), and (III):

(I) S0 calculation method: structural optimization calculation by DFT including functional B3LYP, basis function 6-31G(d, p), and toluene solvent effect (PCM);

(II) S1 calculation method: structural optimization calculation by time-dependent DFT (TDDFT) including functional B3LYP, basis function 6-31G(d, p), and toluene solvent effect (PCM); and

(III) S0 calculation method: calculation on input structure by DFT including functional B3LYP, basis function 6-31G(d, p), and toluene solvent effect (PCM).

In detail, the calculation of each item was performed using the following calculation methods.

Ground state (S0) energy of stable structure in ground state (S0) [E(S0@S0)]: Calculation method (I);

First excited singlet state (S1) energy of stable structure in first excited singlet state (S1) [E(S1@S1)]: Calculation method (II);

Ground state (S0) energy of stable structure in first excited singlet state (S1) [E(S0@S1)]: Calculation methods (II) and (III);

Reorganization energy [E(S0@S1)]−[E(S0@S0)]: Calculation methods (I), (II), and (III);

Adiabatic first excited singlet state (S1) energy [E(S1@S1)]−[E(S0@S0)]: Calculation methods (I) and (II);

Fluorescent wavelength (nm): Calculation methods (I) and (II);

Oscillator strength f of stable structure in first excited singlet state (S1): Calculation method (II); and

HOMO and LUMO: Calculation method (I).

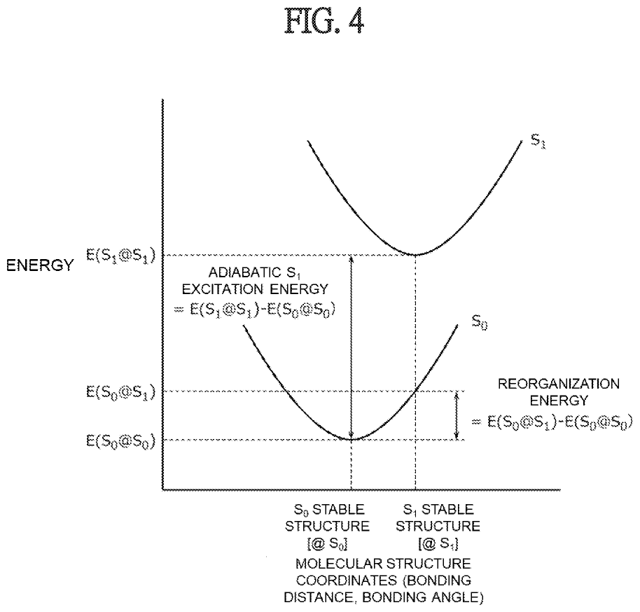

FIG. 4 is an explanatory diagram qualitatively illustrating each energy relationship.

### Measurement of Spectrum Width (FWHM) of Fluorescence

For each of toluene solutions respectively including Compounds R1 to R3 at a concentration of 1×10⁻⁵M (=mol/dm³, mol/L), the PL peak wavelength (nm) of fluorescence and the spectrum width of fluorescence (the FWHM of the fluorescence spectrum peak) were evaluated by measuring at room temperature with an excitation wavelength of 320 nm using a spectrofluorophotometer F-7000 manufactured by Hitachi High-Tech Co., Ltd. The results are shown in Table 1.

TABLE 1

| | Calculated Result by the DFT | | | | | | Found value | |
|---|---|---|---|---|---|---|---|---|
| | | | Adiabatic | | | Fluores- | PL | |
| | | | first excited | Oscilla- | Reorgan- | cent | Peak | |
| | | | singlet state | tor | ization | wave- | wave- | PL |
| | HOMO | LUMO | (S₁) energy | strength | energy | length | length | FWHM |
| Compound | (eV) | (eV) | (eV) | f | (eV) | (nm) | (nm) | (nm) |
| R1 | −4.88 | −1.23 | 2.99 | 0.214 | 0.109 | 415 | 453 | 22 |
| R2 | −5.94 | −2.36 | 2.96 | 0.161 | 0.132 | 419 | 451 | 26 |
| R3 | −5.02 | −1.96 | 2.62 | 0.491 | 0.164 | 474 | 445 | 42 |

From the results of Table 1, it was confirmed that the color of the fluorescence wavelength (nm) calculated by the DFT and the measured peak wavelength showed values close to each other to a certain extent. From these results, it was confirmed that the color estimated by the calculation by the DFT and the color measured were colors of the same kind.

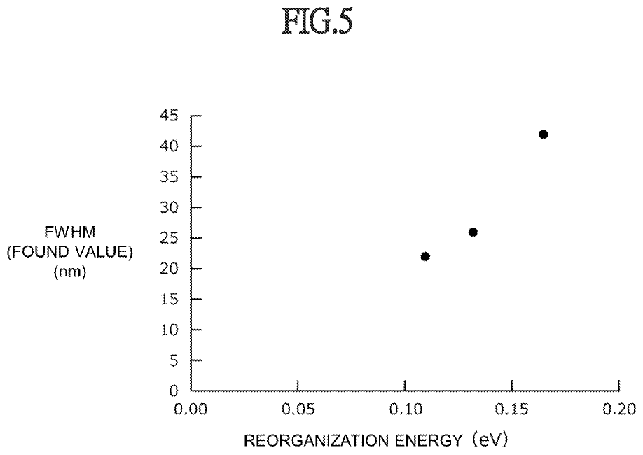

In this regard, a graph of the FWHM of fluorescence in PL measured in Compounds R1 to R3 versus the reorganization energy (eV) calculated by the DFT is shown in FIG. 5. From the results of FIG. 5, it was confirmed that there was a correlation between the reorganization energy (eV) calculated by the DFT and the FWHM of fluorescence, and that the smaller the reorganization energy (eV), the smaller the FWHM of fluorescence. That is, it was confirmed that the spectrum width of fluorescence became narrow.

### Calculation of E(S1), E(T1), and ΔE_{ST} in Ground State

The evaluation was performed on the TADF properties of the compounds of the present disclosure. In detail, for each of the compounds shown in Table 2 (here, the numbers of the compounds are the same as the numbers of the compounds described above), the singlet energy (E(S1)), the triplet energy (E(T1)), and the difference (ΔE_{ST}) therebetween were calculated by the DFT. The results are shown in Table 3.

### Calculation Method

E(S1), E(T1): calculation was performed by the functional B3LYP in the ground-state optimization structure that is obtained by DFT using the functional B3LYP and the basis function 6-31G(d,p), and the TDDFT according to the basis function 6-31G(d,p).

ΔE_{ST}=E(S1)−E(T1)

Calculation software used: Gaussian 16 (Gaussian Inc.).

Calculation of oscillator strength f, reorganization energy, and fluorescence wavelength

For each of the compounds shown in Table 2, the oscillator strength f, reorganization energy, and fluorescence wavelength were calculated using the same method as described in the above “Identification of relationship between reorganization energy and spectrum width of fluorescence” section. The calculation results are shown in Table 2.

TABLE 2

| | Calculated Result by the DFT | | | | | |
|---|---|---|---|---|---|---|
| | | | | | | Fluores- |
| | | | | Oscilla- | Reorgan- | cent |
| | | | | tor | ization | wave- |
| | E(S₁) | E(T₁) | Δ Est | strength | energy | length |
| Compound | (eV) | (eV) | (eV) | f | (eV) | (nm) |
| Compound 101 | 2.98 | 2.50 | 0.479 | 0.342 | 0.089 | 436 |
| Compound 102 | 2.95 | 2.52 | 0.427 | 0.460 | 0.077 | 439 |
| Compound 103 | 2.96 | 2.51 | 0.448 | 0.533 | 0.055 | 435 |
| Compound 104 | 2.86 | 2.50 | 0.361 | 0.656 | 0.043 | 444 |
| Compound 105 | 2.91 | 2.59 | 0.320 | 0.591 | 0.049 | 438 |
| Compound 106 | 2.96 | 2.54 | 0.417 | 0.437 | 0.081 | 437 |
| Compound 116 | 2.99 | 2.54 | 0.452 | 0.416 | 0.086 | 434 |
| Compound 119 | 2.92 | 2.49 | 0.425 | 0.324 | 0.089 | 444 |
| Compound 124 | 2.95 | 2.48 | 0.473 | 0.288 | 0.095 | 439 |
| Compound 130 | 2.97 | 2.52 | 0.448 | 0.456 | 0.066 | 435 |
| Compound 140 | 2.94 | 2.50 | 0.442 | 0.419 | 0.070 | 440 |
| Compound 141 | 2.99 | 2.52 | 0.474 | 0.309 | 0.094 | 434 |
| Compound 144 | 2.91 | 2.47 | 0.441 | 0.539 | 0.078 | 445 |
| Compound 150 | 2.95 | 2.52 | 0.428 | 0.500 | 0.074 | 439 |
| Compound 155 | 2.94 | 2.48 | 0.457 | 0.497 | 0.082 | 442 |
| Compound 157 | 2.99 | 2.53 | 0.465 | 0.338 | 0.086 | 433 |
| Compound 158 | 2.90 | 2.46 | 0.439 | 0.408 | 0.091 | 448 |
| Compound 160 | 2.97 | 2.51 | 0.461 | 0.449 | 0.081 | 437 |
| Compound 169 | 2.94 | 2.48 | 0.461 | 0.486 | 0.084 | 441 |
| Compound 190 | 3.04 | 2.59 | 0.447 | 0.351 | 0.078 | 424 |
| Compound 210 | 3.02 | 2.59 | 0.432 | 0.326 | 0.064 | 425 |
| Compound 233 | 3.02 | 2.57 | 0.455 | 0.404 | 0.109 | 430 |
| Compound 244 | 2.88 | 2.50 | 0.377 | 0.350 | 0.103 | 451 |
| Compound 315 | 2.84 | 2.39 | 0.449 | 0.651 | 0.081 | 452 |
| Compound 316 | 2.79 | 2.43 | 0.358 | 0.564 | 0.098 | 463 |
| Compound 318 | 2.80 | 2.44 | 0.362 | 0.714 | 0.051 | 457 |
| Compound 349 | 2.81 | 2.41 | 0.399 | 0.245 | 0.075 | 459 |
| Compound 369 | 2.91 | 2.58 | 0.322 | 0.617 | 0.052 | 438 |
| Compound 370 | 2.89 | 2.57 | 0.323 | 0.599 | 0.046 | 440 |
| Compound 371 | 2.87 | 2.56 | 0.315 | 0.602 | 0.045 | 444 |
| Compound 375 | 2.88 | 2.57 | 0.312 | 0.720 | 0.047 | 442 |
| Compound 376 | 2.86 | 2.55 | 0.313 | 0.605 | 0.044 | 445 |
| Compound 382 | 2.89 | 2.56 | 0.322 | 0.636 | 0.048 | 441 |
| Compound 384 | 2.84 | 2.53 | 0.306 | 0.729 | 0.043 | 449 |
| Compound 410 | 2.77 | 2.42 | 0.352 | 0.647 | 0.044 | 461 |
| Compound 462 | 2.96 | 2.54 | 0.413 | 0.436 | 0.079 | 438 |
| Compound 465 | 2.91 | 2.51 | 0.406 | 0.501 | 0.074 | 444 |
| Compound 480 | 2.94 | 2.52 | 0.423 | 0.456 | 0.078 | 439 |
| Compound 483 | 2.96 | 2.54 | 0.414 | 0.427 | 0.080 | 437 |
| Compound 486 | 2.90 | 2.50 | 0.401 | 0.499 | 0.073 | 446 |
| Compound 487 | 2.96 | 2.54 | 0.415 | 0.431 | 0.083 | 437 |
| Compound 493 | 2.93 | 2.48 | 0.452 | 0.368 | 0.084 | 442 |
| Compound 500 | 2.99 | 2.52 | 0.474 | 0.309 | 0.094 | 434 |
| Compound 507 | 3.02 | 2.57 | 0.451 | 0.263 | 0.101 | 430 |
| Compound 510 | 2.93 | 2.49 | 0.434 | 0.519 | 0.073 | 442 |
| Compound 511 | 2.94 | 2.53 | 0.414 | 0.461 | 0.079 | 440 |
| Compound 512 | 2.94 | 2.52 | 0.419 | 0.531 | 0.071 | 440 |
| Compound 519 | 2.96 | 2.55 | 0.407 | 0.493 | 0.067 | 435 |
| Compound 520 | 2.97 | 2.55 | 0.419 | 0.537 | 0.062 | 433 |
| Compound 521 | 2.92 | 2.50 | 0.427 | 0.550 | 0.072 | 442 |
| Compound 523 | 3.01 | 2.55 | 0.464 | 0.368 | 0.071 | 427 |
| Compound 526 | 2.98 | 2.55 | 0.439 | 0.413 | 0.087 | 433 |
| Compound 527 | 2.98 | 2.52 | 0.454 | 0.465 | 0.075 | 433 |
| Compound 529 | 2.97 | 2.55 | 0.415 | 0.518 | 0.062 | 433 |
| Compound 530 | 2.96 | 2.57 | 0.393 | 0.500 | 0.072 | 435 |
| Compound 531 | 2.95 | 2.55 | 0.401 | 0.562 | 0.061 | 435 |
| Compound 533 | 2.93 | 2.49 | 0.441 | 0.526 | 0.058 | 440 |
| Compound 535 | 2.96 | 2.52 | 0.449 | 0.549 | 0.054 | 434 |
| Compound 538 | 2.90 | 2.48 | 0.424 | 0.544 | 0.056 | 444 |
| Compound 544 | 2.98 | 2.53 | 0.445 | 0.602 | 0.046 | 432 |
| Compound 551 | 2.95 | 2.51 | 0.443 | 0.563 | 0.056 | 436 |
| Comparative | 3.13 | 2.64 | 0.492 | 0.214 | 0.109 | 415 |
| Compound R1 | | | | | | |

As shown in Table 2, the heterocyclic compound of the present disclosure has a smaller ΔE_{ST} than Comparative Compound R1. Accordingly, the heterocyclic compound as a TADF material is understood to have TADF properties equivalent or superior to those of Comparative Compound R1 known in the related art, and thus, high luminescence efficiency is expected.

In addition, the heterocyclic compound of the present disclosure has a reorganization energy of 0.100 eV or less, which is smaller than that of Comparative Compound R1. From these results, referring to FIG. 5, the FWHM of the heterocyclic compound of the present disclosure is assumed to be smaller than that of Comparative Compound R1 known in the related art, and the color purity thereof is also assumed to be higher than that of Comparative Compound R1 known in the related art.

In addition, the heterocyclic compound of the present disclosure has a sufficient magnitude of oscillator strength f, and thus is expected to have excellent fluorescence efficiency.

From the above results, it was confirmed that the heterocyclic compound of the present disclosure had a narrow ΔE_{ST}, a small reorganization energy, a large oscillator strength f, and a suitable blue fluorescence wavelength, as compared with Comparative Compound R1. Thus, the heterocyclic compound of the present disclosure may have a narrow emission spectrum, may realize high color purity, and may improve the luminescence efficiency of an organic light-emitting device.

### Evaluation of Heterocyclic Compound by Experiment

Characteristics of the heterocyclic compound of the present disclosure were identified in an experiment. In the experiment below, Compound 101, Compound 102, and Compound 103 were used to represent the heterocyclic compound of the present disclosure.

### Measurement of Spectrum Width (FWHM) of Fluorescence

For each of toluene solutions respectively including Compound 100, Compound 102, and Compound 103 at a concentration of 1×10⁻⁵M (=mol/dm³, mol/L), the PL peak wavelength (nm) of fluorescence and the spectrum width of fluorescence (the FWHM of the fluorescence spectrum peak) were evaluated by measuring at room temperature with an excitation wavelength of 320 nm using a spectrofluorophotometer F-7000 manufactured by Hitachi High-Tech Co., Ltd.

In this evaluation, the peak wavelength of fluorescence is not particularly limited, but may be within the blue emission region, and may be 440 nm or more and 470 nm or less.

In this evaluation, the spectrum width (FWHM) of fluorescence may be smaller, and it is considered than the smaller the spectrum width is, the better the color purity is.

The results are shown in Table 3. In addition, Table 3 shows the results of Comparative Compounds R1 to R3 measured in the same manner as described above.

TABLE 3

| | PL Peak | |
|---|---|---|
| | wavelength | PL FWHM |
| Compound | (nm) | (nm) |
| Compound101 | 468 | 24 |
| Compound102 | 469 | 24 |
| Compound103 | 465 | 19 |
| Comparative Compound R1 | 453 | 22 |
| Comparative Compound R2 | 451 | 26 |
| Comparative Compound R3 | 445 | 42 |

### Measurement of HOMO Level and LUMO Level

Compounds 101 to 103 and Comparative Compounds R1 to R3 obtained above were each prepared as sample solids. Next, the HOMO and LUMO levels were measured as follows.

1. Preparation of Measurement Sample

(1) A sample solution was prepared such that a sample solid was 4 parts by weight based on 100 parts by weight of methyl benzoate as a solvent.

(2) The sample solution prepared in Section (1) was coated on each of an ITO substrate and a quartz substrate by a spin-coating method to form a coating film having a dry film thickness of 50 nm. The resulting coating film was heated under vacuum of 10⁻¹ Pa or lower at 120° C. for 1 hour. Then, under vacuum of 10⁻¹ Pa or lower, the coating film was cooled to room temperature to form a thin film layer (thin film sample).

2. Measurement of HOMO Level

The HOMO level of each compound was measured using the thin film sample on the ITO substrate prepared in Section 1.(2) by a photoelectron spectrometer AC-3 (available from Rikoki Co., Ltd.).

3. Measurement of LUMO Level

An energy gap value (Eg) at an absorption end of ultraviolet visible absorption spectrum was measured using the thin film sample on the quartz substrate prepared in Section 1.(2) by a spectrophotometer U-3900 (product of Hitachi High-Tech), and the LUMO level was calculated by Equation A. The calculation results are shown in Table 4.

LUMO=HOMO+Eg Equation A

Measurement of PL of Solution

Compounds and the Comparative Compound obtained above were each dissolved in toluene to prepare a 1×10⁻⁵ M solution. This solution was filled in a 1 cm square four-sided transmission cell, and PL measurement was performed at room temperature using a spectrofluorophotometer F7000 (manufactured by Hitachi High-Technologies Corporation). A peak wavelength, a FWHM, and a Stokes shift were computed from the obtained emission spectrum. The evaluation results are shown in Table 4.

Measurement of S1 Value, T1 Value, and ΔE_{ST} Value

1. Preparation of Measurement Samples

(1) The resulting Compounds and the Comparative Compound (sample solids) and polymethyl methacrylate (PMMA) were dissolved in toluene, followed by mixing PMMA and sample solids at a weight ratio of 99.5:0.5, to prepare 5 wt % of a toluene solution.

(2) The sample solutions prepared in Section (1) was spin-coated by using a spin coater MS-B100 (Mikasa Corporation) on an ITO substrate and a quartz substrate to form a spin-coating film having a dried film thickness of 500 nm. Subsequently, by 1 hour of heating at a temperature of 120° C., a thin film sample was prepared.

2. Measurement of S1 Value, T1 Value, and ΔE_{ST} Value

A fluorescence spectrum and a phosphorescence spectrum were measured at 77K with a spectrofluorophotometer F7000 (manufactured by Hitachi High-Tech Co., Ltd.) using the thin film sample on the quartz substrate prepared in Section 1.(2). The singlet energy S1 was calculated from the obtained fluorescence spectrum, and the triplet energy T1 was calculated from the phosphorescence spectrum. In addition, ΔE_{ST} was obtained according to Equation B. The results are shown in Table 4.

ΔEₛₜ=S1−T1 Equation B

Measurement of PLQY

The compounds shown in Table 4 were vacuum-deposited on a quartz substrate at a weight ratio of 1 wt % with respect to the host compound mCP at a vacuum pressure of 10⁻⁵ Pa to prepare a thin film having a thickness of 50 nm. The emission spectrum of each of the prepared thin film was measured using Quantaurus-QY absolute PL quantum yield (PLQY) measurement system C11347-01 (Hamamatsu Photonics Co., Ltd.) to measure PLQY. In the measurement, the excitation wavelength was scanned at intervals of 10 nm from 300 nm to 400 nm, and the excitation wavelength region in which the compound absorption value showed 10% or more of the excitation light intensity ratio was adopted. The value of PLQY was taken as the highest value in the adopted excitation wavelength region. The results are shown in Table 4.

TABLE 4

| | HOMO | LUMO | S1 | T1 | Δ Est | PLQY |
|---|---|---|---|---|---|---|
| Compound | (eV) | (eV) | (eV) | (eV) | (eV) | (%) |
| Compound 101 | 5.80 | 3.17 | 2.73 | 2.51 | 0.221 | >99 |
| Compound 102 | 5.65 | 3.04 | 2.72 | 2.54 | 0.178 | 98 |
| Compound 103 | 5.90 | 3.26 | 2.72 | 2.54 | 0.184 | >99 |
| Comparative | 6.05 | 3.33 | 2.81 | 2.62 | 0.184 | >99 |
| Compound R1 | | | | | | |

From the results of Table 4, it was confirmed that Compounds 101, 102, and 103 have a narrow emission spectrum having a peak wavelength of a blue wavelength region and emit blue light with high color purity. In addition, it was confirmed that Compounds 101, 102, and 103 each have small ΔE_{ST}, and thus may realize light emission with high efficiency.

As apparent from the foregoing description, an organic light-emitting device including the heterocyclic compound may have improved efficiency and/or color purity.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A heterocyclic compound comprising:
a group represented by Formula 1;
a group represented by Formula 2; and
one to four groups each independently represented by Formula 3 or 4: 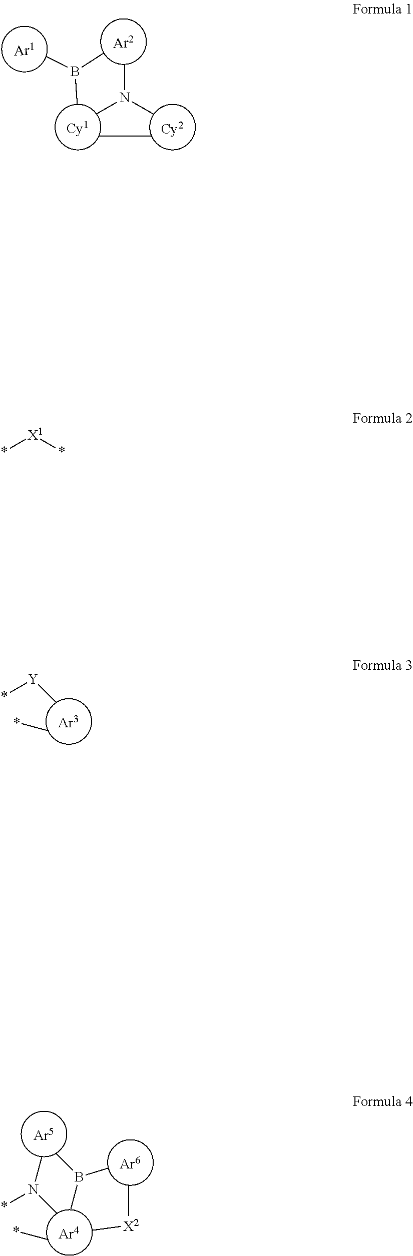
wherein, in Formulae 1 to 4,
at least one of: Ar¹ and Ar²; Ar¹ and Cy¹, or a combination thereof are linked to each other via the group represented by Formula 2,
Cy¹, Cy², and Ar¹ to Ar⁶ are each independently a substituted or unsubstituted aromatic hydrocarbon ring having 6 to 30 ring-forming atoms or a substituted or unsubstituted aromatic hetero ring having 5 to 30 ring-forming atoms,
X¹ and X² are each independently O, S, NR, CR′R″, or a single bond, wherein R, R′, and R″ are each independently a substituted or unsubstituted alkyl group, a substituted or unsubstituted aryl group, or a substituted or unsubstituted heteroaryl group,
Y is O, S, NZ, or CZ′Z″, wherein Z, Z′, and Z″ are each independently a substituted or unsubstituted alkyl group, a substituted or unsubstituted aryl group, or a substituted or unsubstituted heteroaryl group,
Z in NZ is optionally bonded to Cy¹, Cy², or Ara via O, S, NZ, CZ′Z″, or a single bond,
* in Formula 2 indicates a binding site to Ar¹, Ar², or Cy¹, and
two *(s) in Formulae 3 and 4 each indicate a binding site to Cy¹ or Cy² in Formula 1.

2. The heterocyclic compound of claim 1, wherein Cy¹, Cy², and Ar¹ to Ar⁶ are each independently an aromatic hydrocarbon ring having 6 to 10 ring-forming atoms or an aromatic hetero ring having 5 to 20 ring-forming atoms.

3. The heterocyclic compound of claim 1, wherein a substituent of the substituted aromatic hydrocarbon ring and the substituted aromatic hetero ring is independently a deuterium atom, a halogen atom, a substituted or unsubstituted alkyl group, a substituted or unsubstituted aryl group, a substituted or unsubstituted heteroaryl group, a substituted or unsubstituted alkoxy group, a substituted or unsubstituted aryloxy group, a substituted or unsubstituted heteroaryloxy group, a substituted or unsubstituted diarylamino group, a substituted or unsubstituted diheteroaryl amino group, or a substituted or unsubstituted arylheteroaryl amino group.

4. The heterocyclic compound of claim 1, wherein a substituent of the substituted aromatic hydrocarbon ring and the substituted aromatic hetero ring is a tert-butyl group, a phenyl group, a 4-tert-butyl phenyl group, a 2,4,6-trimethyl phenyl group, a 4-(2,4,6-trimethylphenyl)phenyl group, a 2,5-diphenylphenyl group, a 3,5-diphenylphenyl group, a biphenyl group, a 2-pyridyl group, a 3-pyridyl group, a 4-pyridyl group, a carbazolyl group, a 3,6-di-tert-butylcarbazolyl group, a diphenylamino group, or a bis(4-tert-butylphenyl)amino group.

5. The heterocyclic compound of claim 1, wherein, in the heterocyclic compound, a moiety represented by Formulae 1 and 2 is represented by one of Formulae 5-1 to 5-3: 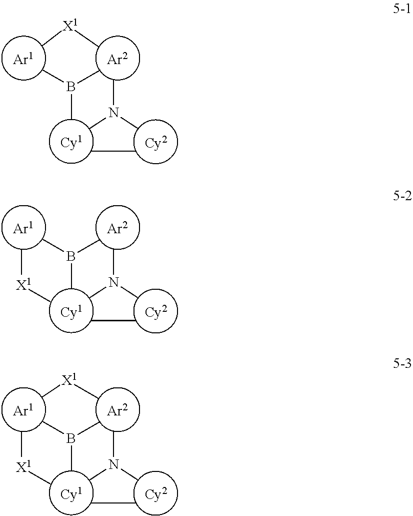
wherein, in Formulae 5-1 to 5-3,
one to four groups represented by at least one of Formulae 3, 4, or a combination thereof are bonded to at least one of Cy¹, Cy², or a combination thereof.
two *(s) in Formulae 3 and 4 each indicate a binding site to Cy¹ or Cy² in Formulae 5-1 to 5-3, and
Cy¹, Cy², Ar¹, Ar², X¹, X², and Y are the same as those described in claim 1, respectively.

6. The heterocyclic compound of claim 1, wherein the heterocyclic compound is represented by one of Formulae 6-1 to 6-4: 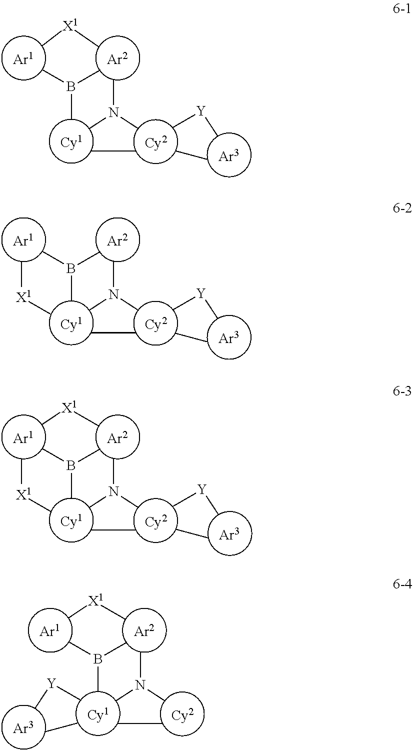
wherein, in Formulae 6-1 to 6-4,
Cy¹, Cy², Ar¹, Ar², X¹, X², and Y are the same as those as described in claim 1, respectively.

7. The heterocyclic compound of claim 1, wherein the heterocyclic compound is represented by one of Formulae 1 to 43: 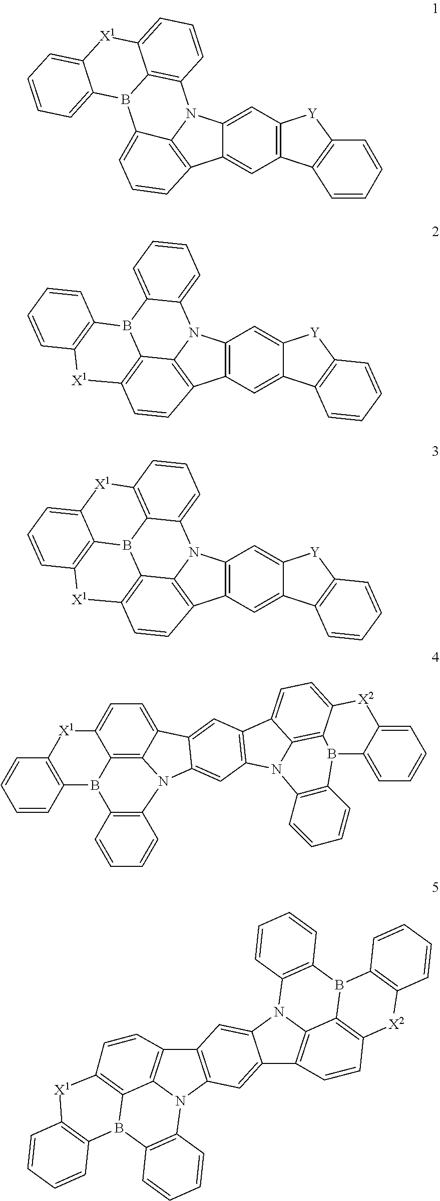 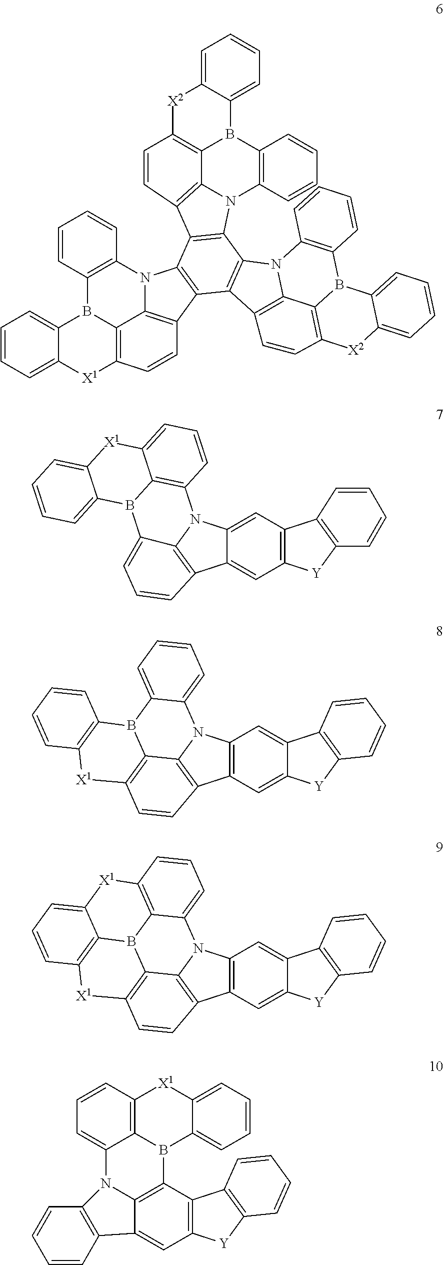 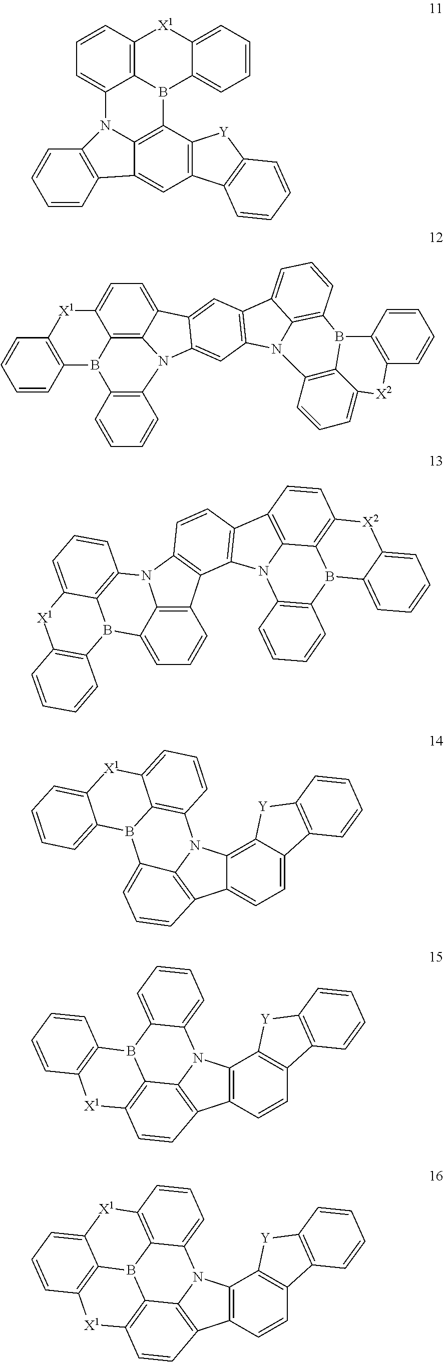 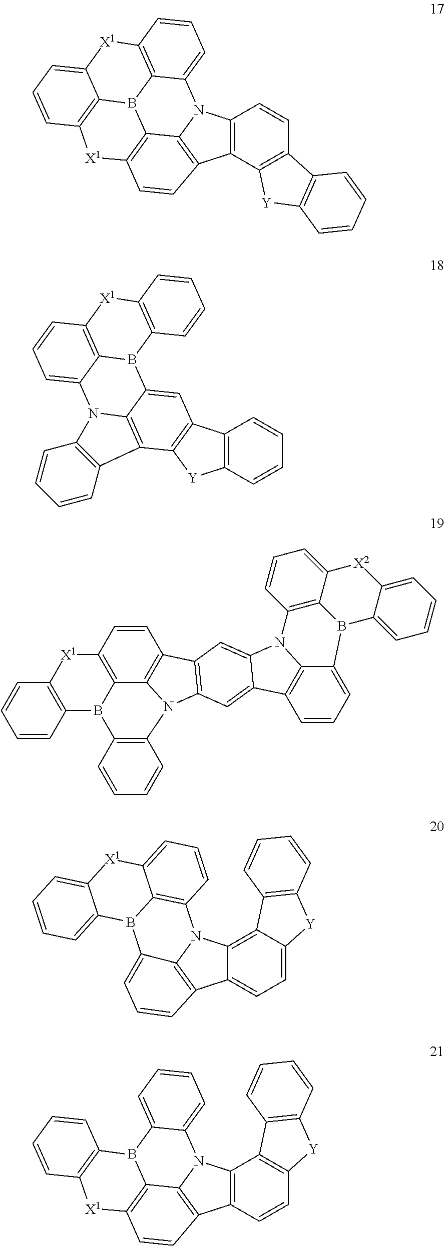 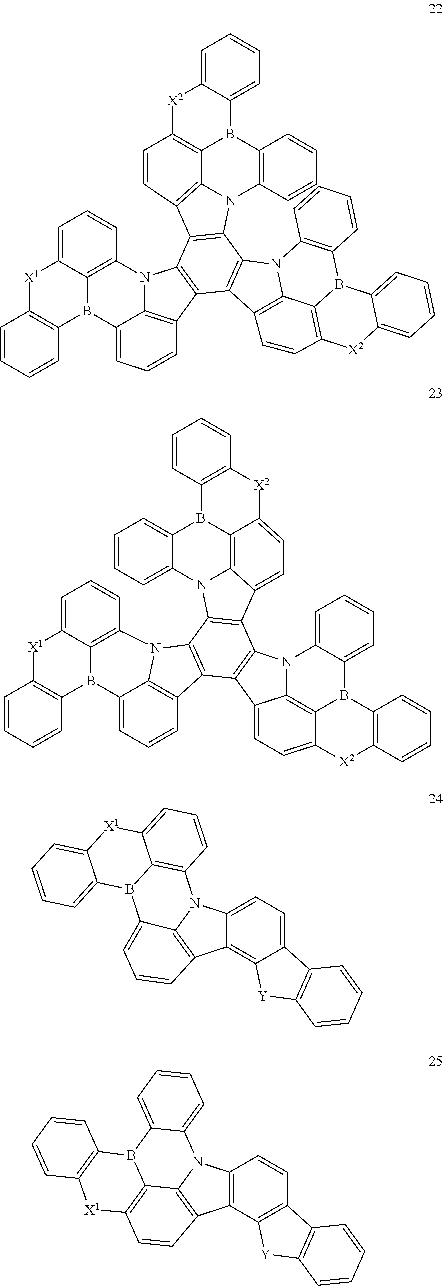 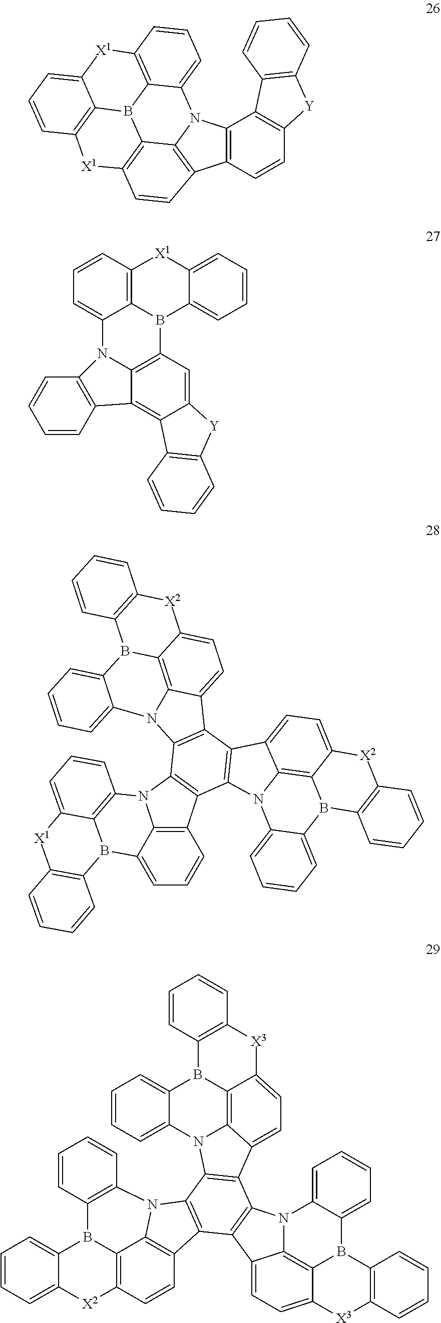 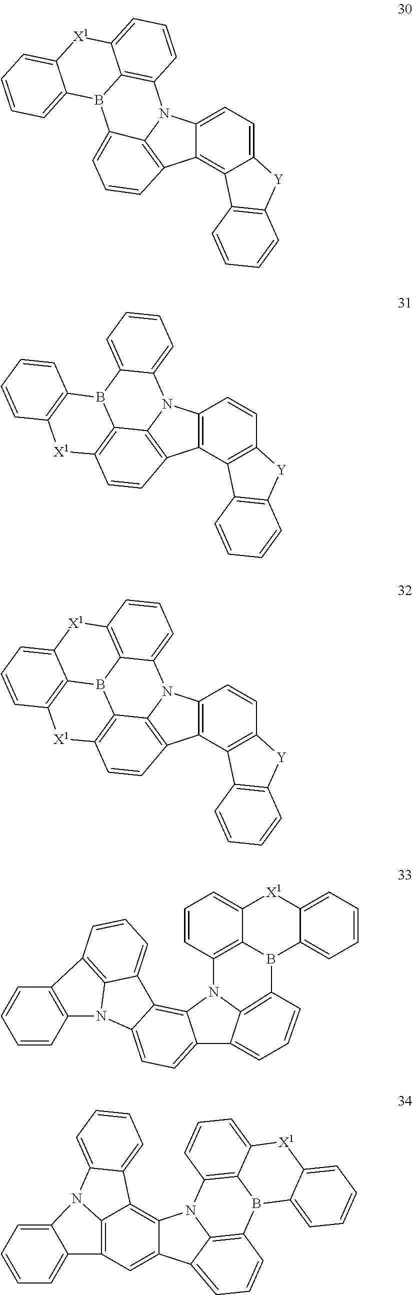 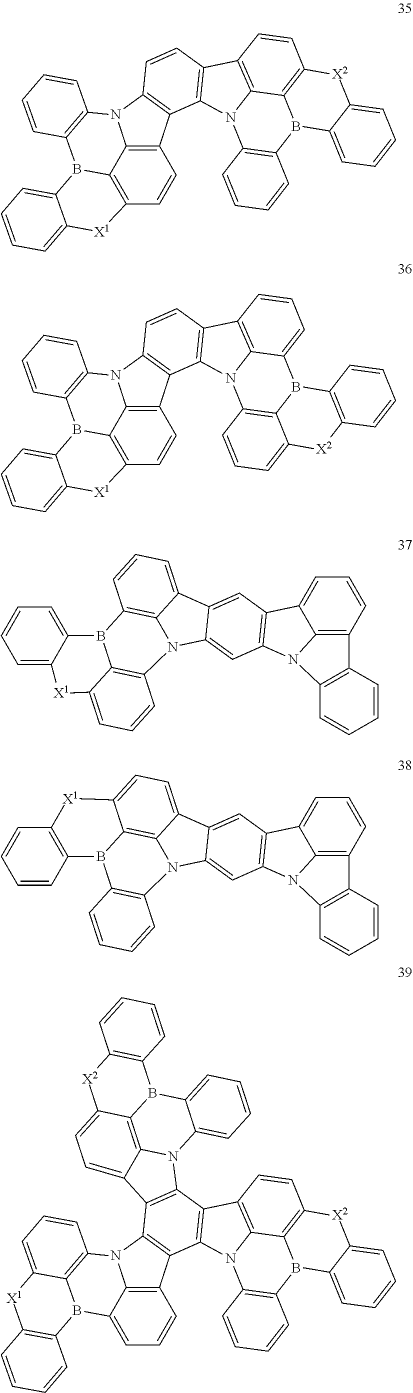 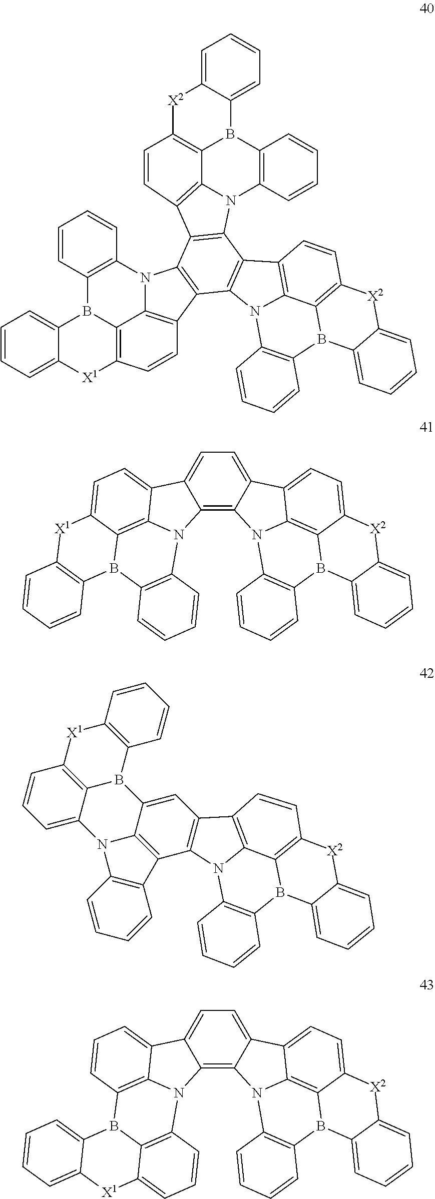
wherein, in Formulae 1 to 43,
X¹ and X² are each independently O, S, NR, CR′R″, or a single bond, wherein R, R′, and R″ are each independently a substituted or unsubstituted alkyl group, a substituted or unsubstituted aryl group, or a substituted or unsubstituted heteroaryl group,
Y is O, S, NZ, or CZ′Z″, wherein Z, Z′, and Z″ are each independently a substituted or unsubstituted alkyl group, a substituted or unsubstituted aryl group, or a substituted or unsubstituted heteroaryl group,
Z in NZ is optionally bonded to Cy¹, Cy², or Ar³ via O, S, NZ, CZ′Z″, or a single bond, and
at least one hydrogen atom of Formulae 1 to 43 is optionally substituted with a deuterium atom, a halogen atom, a substituted or unsubstituted alkyl group, a substituted or unsubstituted aryl group, a substituted or unsubstituted heteroaryl group, or a substituted or unsubstituted diarylamino group.

8. The light-emitting device of claim 1, wherein the heterocyclic compound is a compound of Group I:
Group I

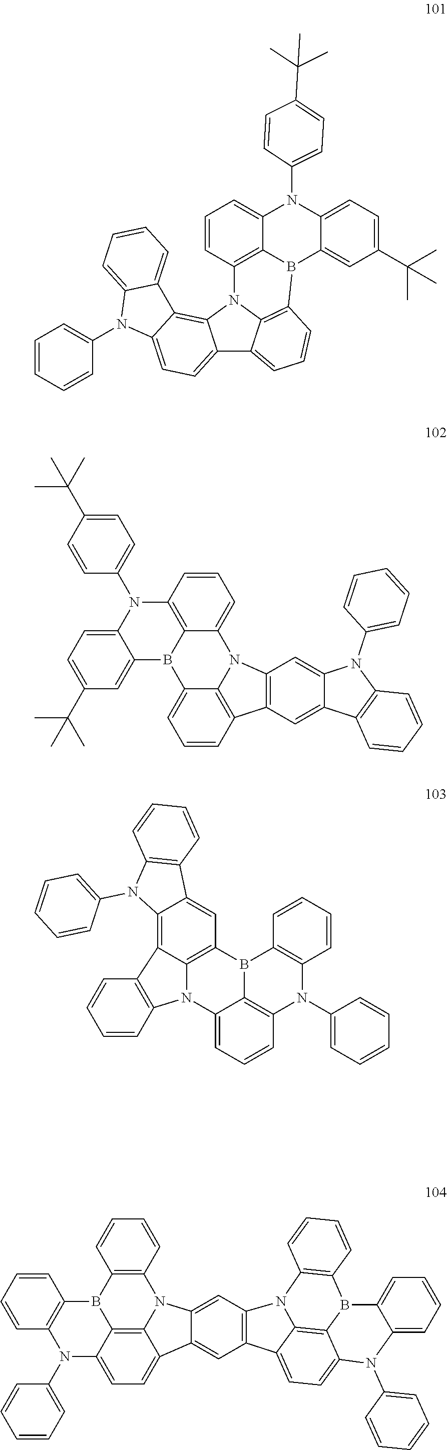

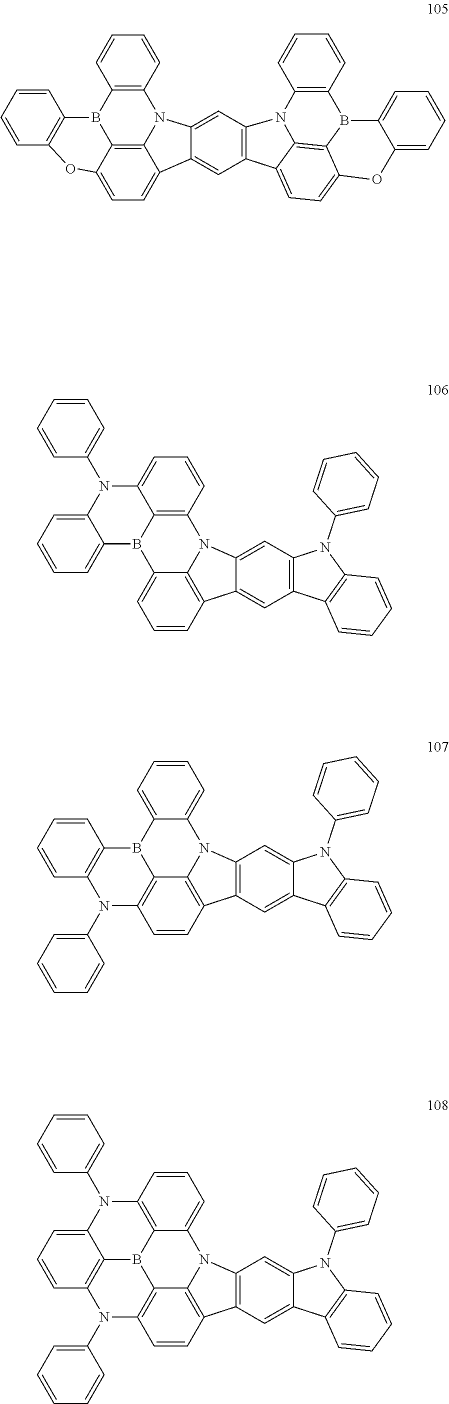 [SMILES: c1ccc2c(c1)Oc1ccc3c4cc5c6ccc7c8c6n(c5cc4n4c3c1B2c1ccccc1-4)-c1ccccc1B8c1ccccc1O7 ; c1ccc(N2c3ccccc3B3c4c2cccc4-n2c4cc5c(cc4c4cccc3c42)c2ccccc2n5-c2ccccc2)cc1 ; c1ccc(N2c3ccccc3B3c4ccccc4-n4c5cc6c(cc5c5ccc2c3c54)c2ccccc2n6-c2ccccc2)cc1 ; c1ccc(N2c3cccc4c3B3c5c2cccc5-n2c5cc6c(cc5c5ccc(c3c52)N4c2ccccc2)c2ccccc2n6-c2ccccc2)cc1]

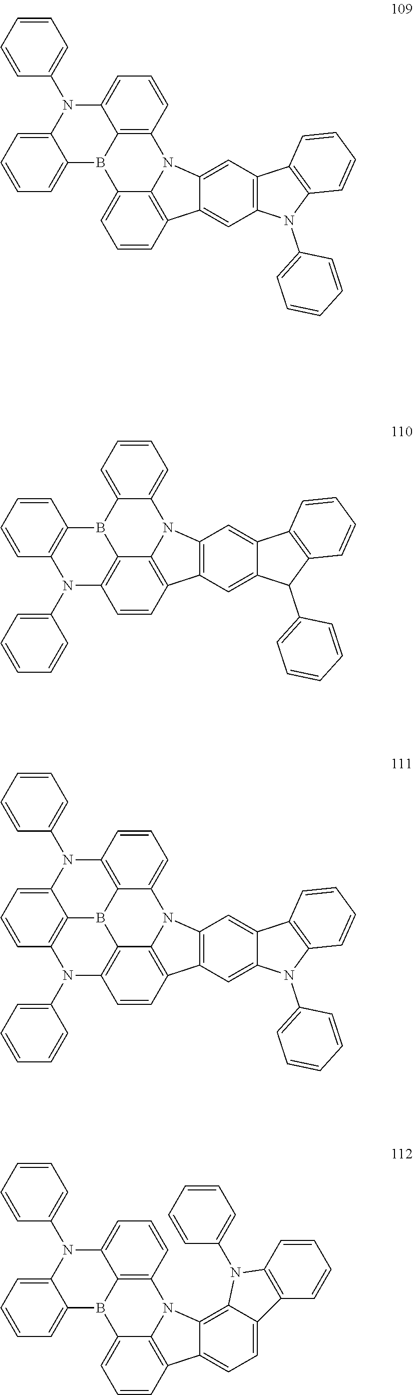 [SMILES: c1ccc(N2c3ccccc3B3c4c2cccc4-n2c4cc5c6ccccc6n(-c6ccccc6)c5cc4c4cccc3c42)cc1 ; c1ccc(C2c3ccccc3-c3cc4c(cc32)c2ccc3c5c2n4-c2ccccc2B5c2ccccc2N3c2ccccc2)cc1 ; c1ccc(N2c3cccc4c3B3c5c2cccc5-n2c5cc6c7ccccc7n(-c7ccccc7)c6cc5c5ccc(c3c52)N4c2ccccc2)cc1 ; c1ccc(N2c3ccccc3B3c4c2cccc4-n2c4c3cccc4c3ccc4c5ccccc5n(-c5ccccc5)c4c32)cc1]

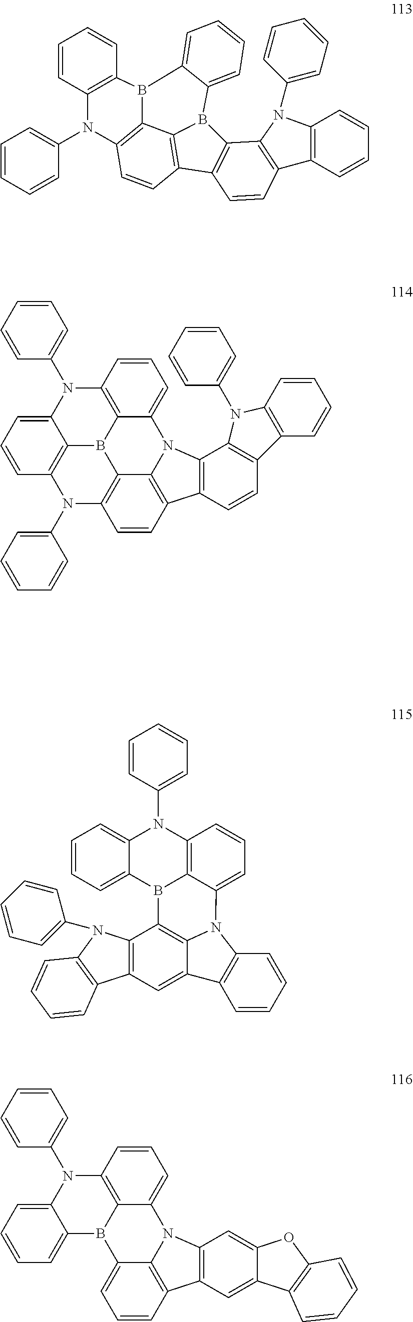 [SMILES: c1ccc(N2c3ccccc3B3c4ccccc4B4c5c(ccc2c53)-c2ccc3c5ccccc5n(-c5ccccc5)c3c24)cc1 ; c1ccc(N2c3cccc4c3B3c5c2cccc5-n2c5c3c(ccc5c3ccc5c6ccccc6n(-c6ccccc6)c5c32)N4c2ccccc2)cc1 ; c1ccc(N2c3ccccc3B3c4c2cccc4-n2c4ccccc4c4cc5c6ccccc6n(-c6ccccc6)c5c3c42)cc1 ; c1ccc(N2c3ccccc3B3c4c2cccc4-n2c4cc5oc6ccccc6c5cc4c4cccc3c42)cc1]

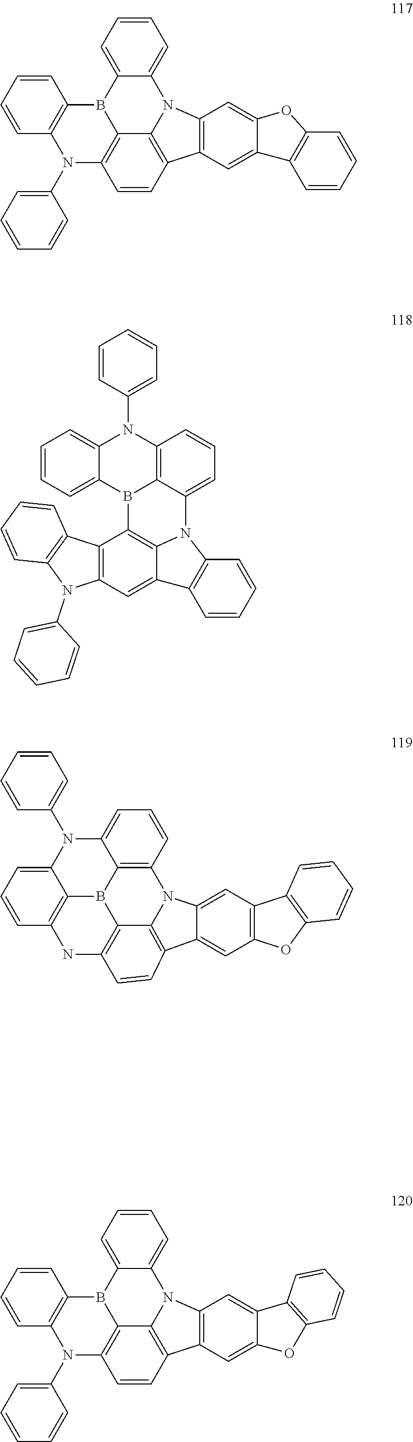 [SMILES: c1ccc(N2c3ccccc3B3c4ccccc4-n4c5cc6oc7ccccc7c6cc5c5ccc2c3c54)cc1 ; c1ccc(N2c3ccccc3B3c4c2cccc4-n2c4ccccc4c4cc5c(c3c42)c2ccccc2n5-c2ccccc2)cc1 ; c1ccc(N2c3cccc4c3B3c5c2cccc5-n2c5cc6c(cc5c5ccc(c3c52)N4)oc2ccccc26)cc1 ; c1ccc(N2c3ccccc3B3c4ccccc4-n4c5cc6c(cc5c5ccc2c3c54)oc2ccccc26)cc1]

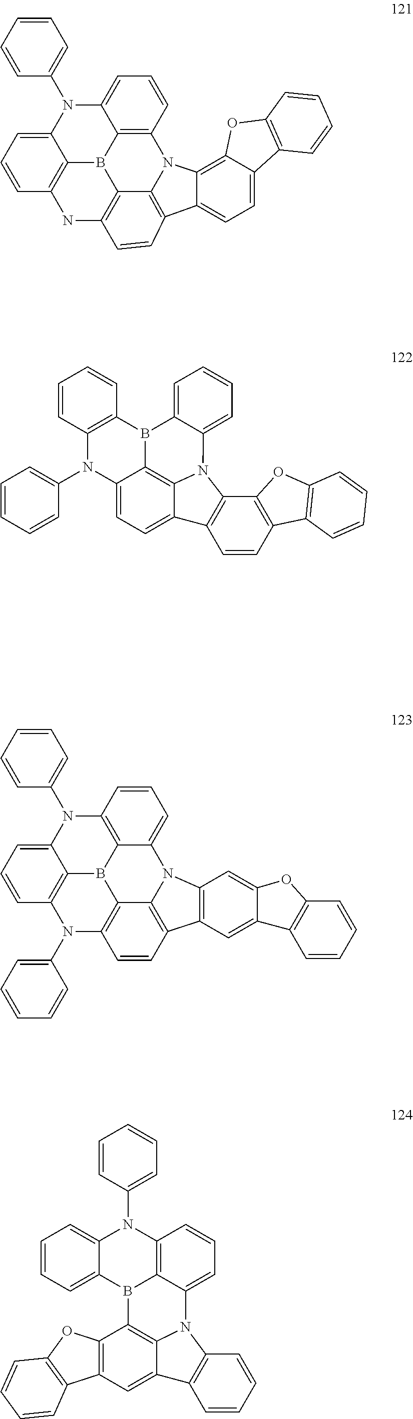 [SMILES: c1ccc(N2c3cccc4c3B3c5c2cccc5-n2c5c3c(ccc5c3ccc5c6ccccc6oc5c32)N4)cc1 ; c1ccc(N2c3ccccc3B3c4ccccc4-n4c5c3c2ccc5c2ccc3c5ccccc5oc3c24)cc1 ; c1ccc(N2c3cccc4c3B3c5c2cccc5-n2c5cc6oc7ccccc7c6cc5c5ccc(c3c52)N4c2ccccc2)cc1 ; c1ccc(N2c3ccccc3B3c4c2cccc4-n2c4ccccc4c4cc5c(oc6ccccc65)c3c42)cc1]

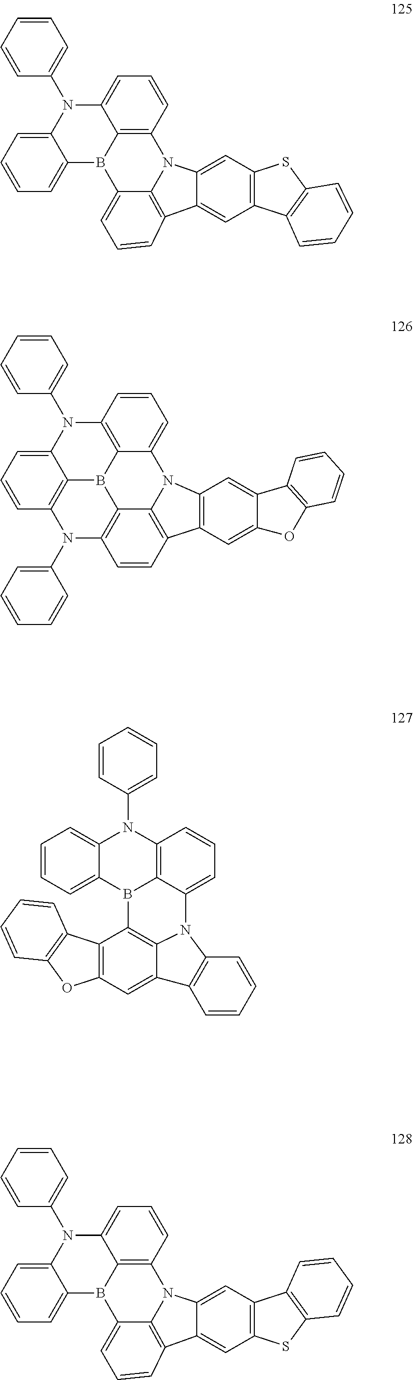 [SMILES: c1ccc(N2c3ccccc3B3c4c2cccc4-n2c4cc5sc6ccccc6c5cc4c4cccc3c42)cc1 ; c1ccc(N2c3cccc4c3B3c5c2cccc5-n2c5cc6c(cc5c5ccc(c3c52)N4c2ccccc2)oc2ccccc26)cc1 ; c1ccc(N2c3ccccc3B3c4c2cccc4-n2c4ccccc4c4cc5oc6ccccc6c5c3c42)cc1 ; c1ccc(N2c3ccccc3B3c4c2cccc4-n2c4cc5c(cc4c4cccc3c42)sc2ccccc25)cc1]

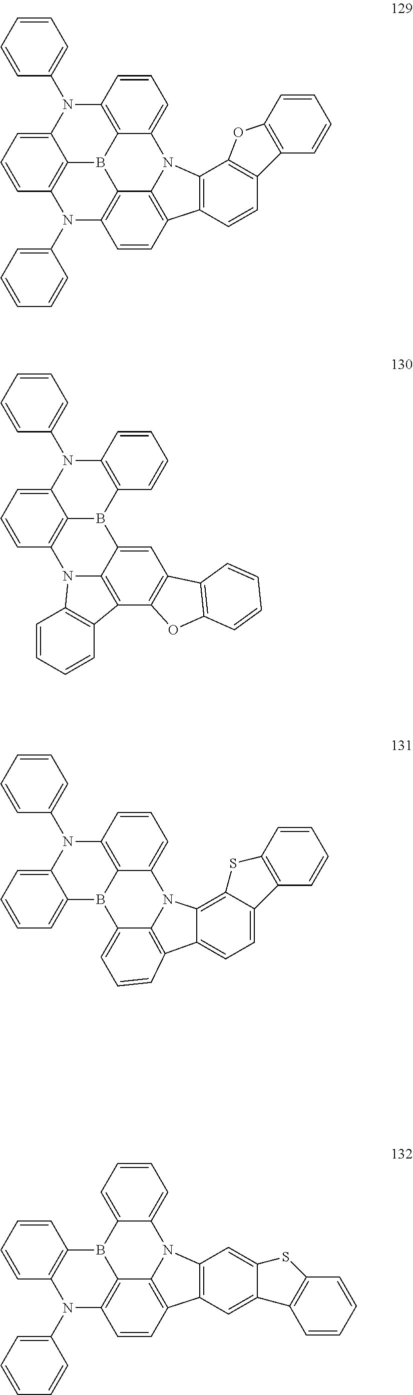 [SMILES: c1ccc(N2c3cccc4c3B3c5c2cccc5-n2c5c3c(ccc5c3ccc5c6ccccc6oc5c32)N4c2ccccc2)cc1 ; c1ccc(N2c3ccccc3B3c4c2cccc4-n2c4ccccc4c4c5oc6ccccc6c5cc3c42)cc1 ; c1ccc(N2c3ccccc3B3c4c2cccc4-n2c4c3cccc4c3ccc4c5ccccc5sc4c32)cc1 ; c1ccc(N2c3ccccc3B3c4ccccc4-n4c5cc6sc7ccccc7c6cc5c5ccc2c3c54)cc1]

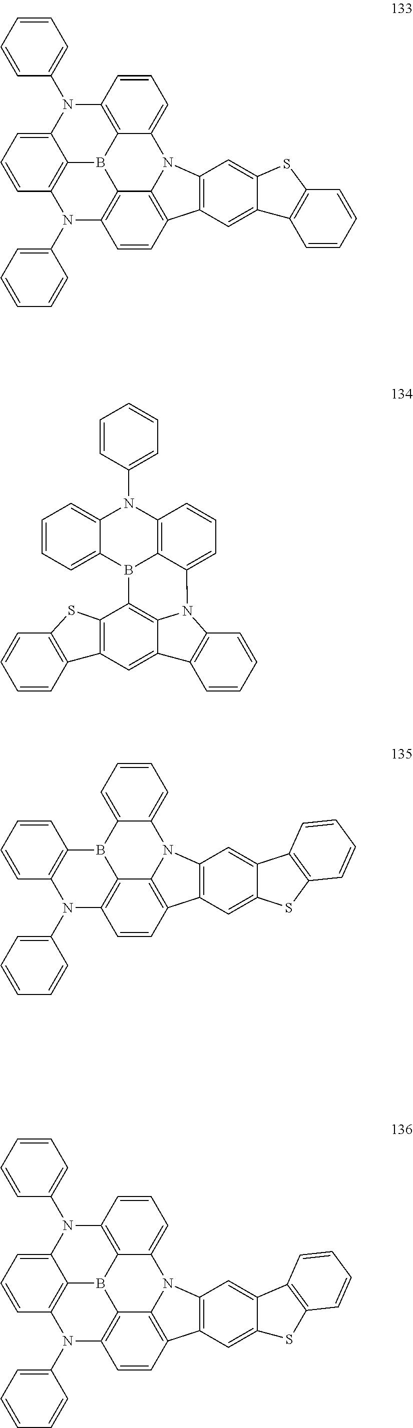 [SMILES: c1ccc(N2c3cccc4c3B3c5c2cccc5-n2c5cc6sc7ccccc7c6cc5c5ccc(c3c52)N4c2ccccc2)cc1 ; c1ccc(N2c3ccccc3B3c4c2cccc4-n2c4ccccc4c4cc5c(sc6ccccc65)c3c42)cc1 ; c1ccc(N2c3ccccc3B3c4ccccc4-n4c5cc6c(cc5c5ccc2c3c54)sc2ccccc26)cc1 ; c1ccc(N2c3cccc4c3B3c5c2cccc5-n2c5cc6c(cc5c5ccc(c3c52)N4c2ccccc2)sc2ccccc26)cc1]

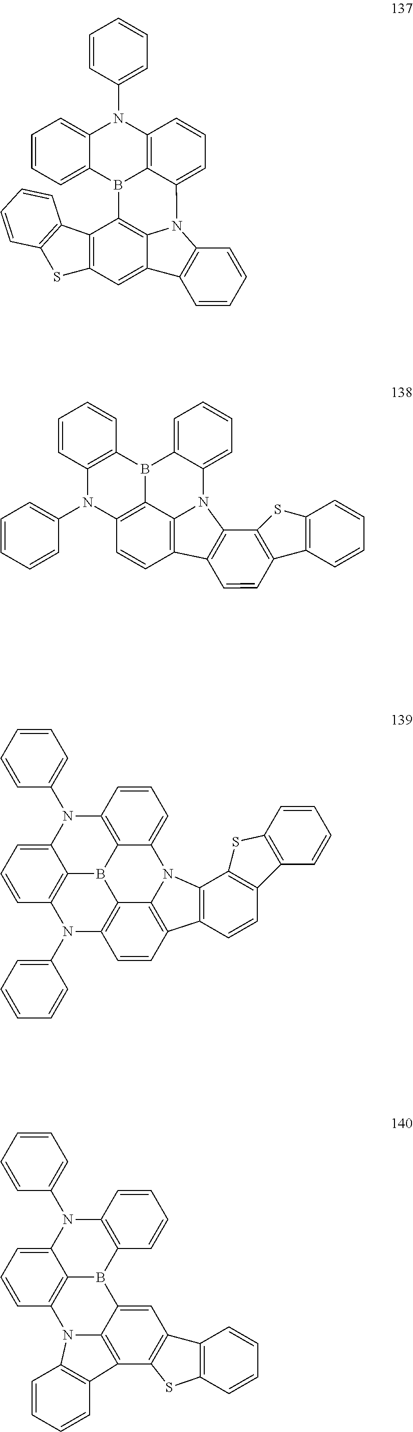 [SMILES: c1ccc(N2c3ccccc3B3c4c2cccc4-n2c4ccccc4c4cc5sc6ccccc6c5c3c42)cc1 ; c1ccc(N2c3ccccc3B3c4ccccc4-n4c5c3c2ccc5c2ccc3c5ccccc5sc3c24)cc1 ; c1ccc(N2c3cccc4c3B3c5c2cccc5-n2c5c3c(ccc5c3ccc5c6ccccc6sc5c32)N4c2ccccc2)cc1 ; c1ccc(N2c3ccccc3B3c4c2cccc4-n2c4ccccc4c4c5sc6ccccc6c5cc3c42)cc1]

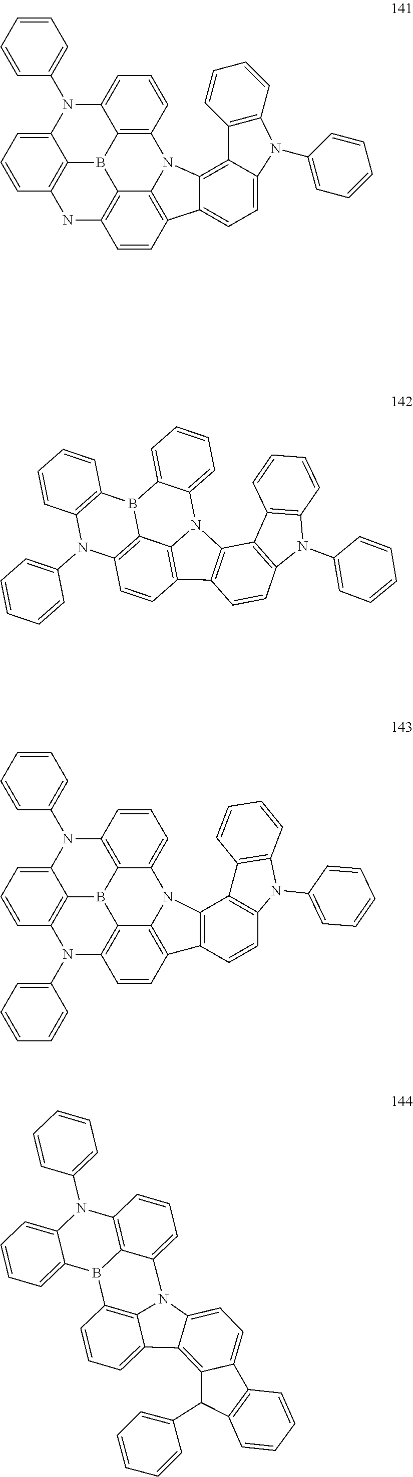 [SMILES: c1ccc(N2c3cccc4c3B3c5c2cccc5-n2c5c3c(ccc5c3ccc5c(c6ccccc6n5-c5ccccc5)c32)N4)cc1 ; c1ccc(N2c3ccccc3B3c4ccccc4-n4c5c3c2ccc5c2ccc3c(c5ccccc5n3-c3ccccc3)c24)cc1 ; c1ccc(N2c3cccc4c3B3c5c2cccc5-n2c5c3c(ccc5c3ccc5c(c6ccccc6n5-c5ccccc5)c32)N4c2ccccc2)cc1 ; c1ccc(C2c3ccccc3-c3ccc4c(c32)c2cccc3c2n4-c2cccc4c2B3c2ccccc2N4c2ccccc2)cc1]

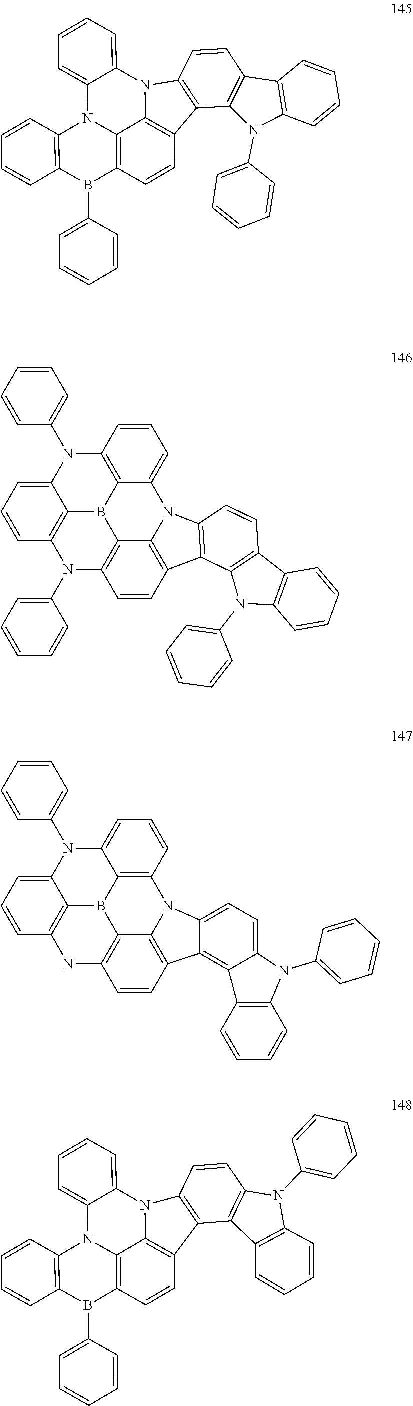 [SMILES: c1ccc(B2c3ccccc3N3c4ccccc4-n4c5ccc6c7ccccc7n(-c7ccccc7)c6c5c5ccc2c3c54)cc1 ; c1ccc(N2c3cccc4c3B3c5c2cccc5-n2c5ccc6c7ccccc7n(-c7ccccc7)c6c5c5ccc(c3c52)N4c2ccccc2)cc1 ; c1ccc(N2c3cccc4c3B3c5c2cccc5-n2c5ccc6c(c7ccccc7n6-c6ccccc6)c5c5ccc(c3c52)N4)cc1 ; c1ccc(B2c3ccccc3N3c4ccccc4-n4c5ccc6c(c7ccccc7n6-c6ccccc6)c5c5ccc2c3c54)cc1]

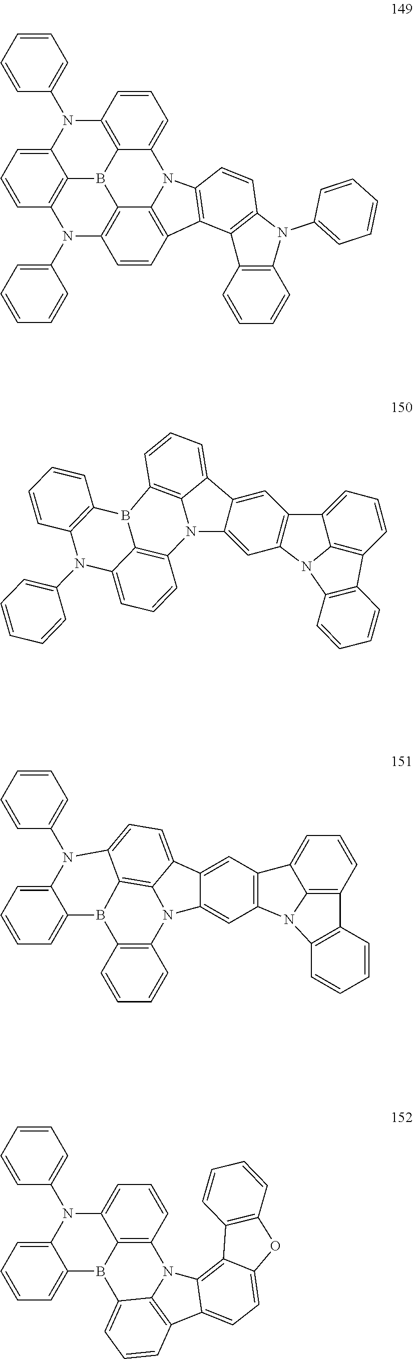 [SMILES: c1ccc(N2c3cccc4c3B3c5c2cccc5-n2c5ccc6c(c7ccccc7n6-c6ccccc6)c5c5ccc(c3c52)N4c2ccccc2)cc1 ; c1ccc(N2c3ccccc3B3c4c2cccc4-n2c4cc5c(cc4c4cccc3c42)c2cccc3c4ccccc4n5c32)cc1 ; c1ccc(N2c3ccccc3B3c4ccccc4-n4c5cc6c(cc5c5ccc2c3c54)c2cccc3c4ccccc4n6c32)cc1 ; c1ccc(N2c3ccccc3B3c4c2cccc4-n2c4c3cccc4c3ccc4oc5ccccc5c4c32)cc1]

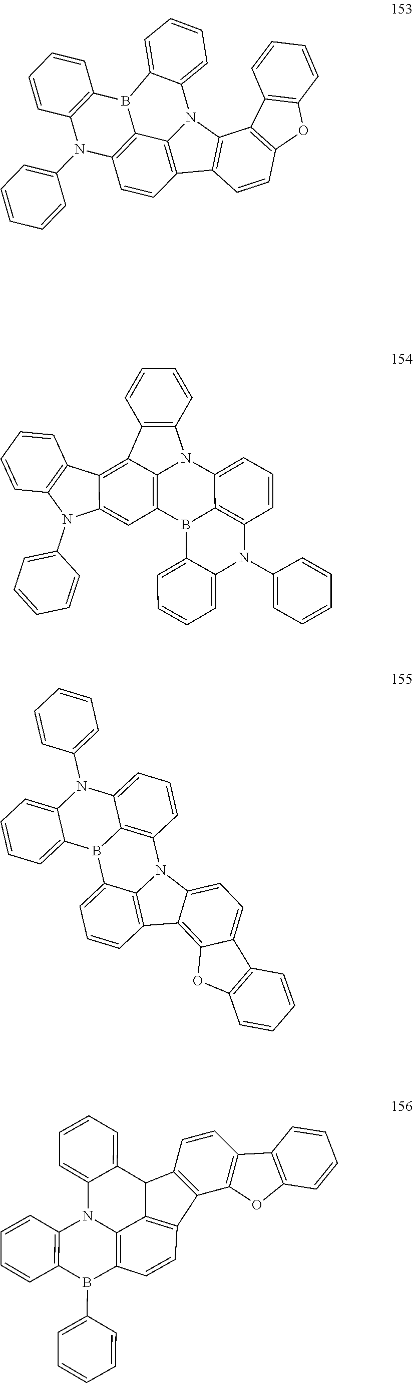 [SMILES: c1ccc(N2c3ccccc3B3c4ccccc4-n4c5c3c2ccc5c2ccc3oc5ccccc5c3c24)cc1 ; c1ccc(N2c3ccccc3B3c4c2cccc4-n2c4ccccc4c4c5c6ccccc6n(-c6ccccc6)c5cc3c42)cc1 ; c1ccc(N2c3ccccc3B3c4c2cccc4-n2c4ccc5c6ccccc6oc5c4c4cccc3c42)cc1 ; c1ccc(B2c3ccccc3N3c4ccccc4C4c5ccc6c(oc7ccccc76)c5-c5ccc2c3c54)cc1]

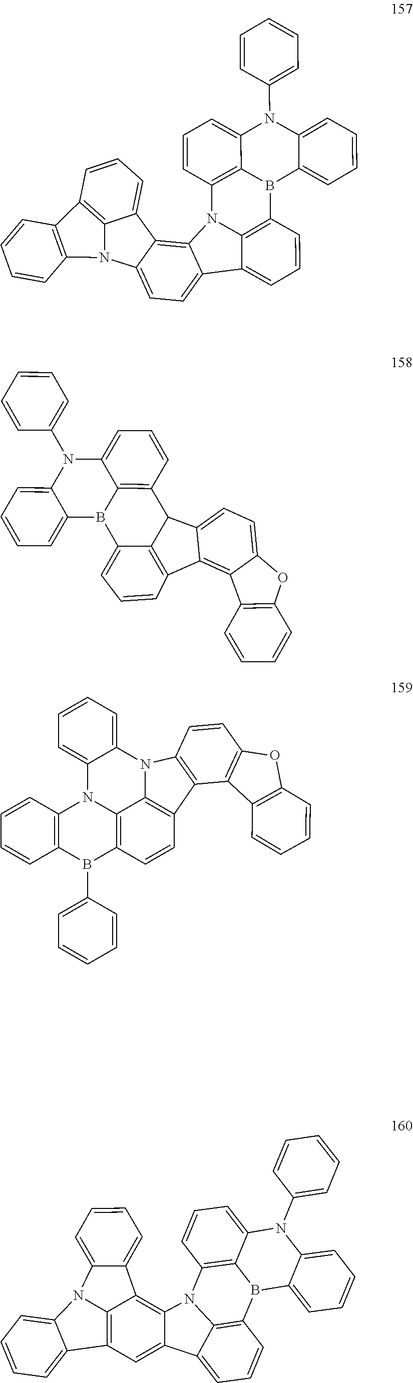 [SMILES: c1ccc(N2c3ccccc3B3c4c2cccc4-n2c4c3cccc4c3ccc4c(c5cccc6c7ccccc7n4c65)c32)cc1 ; c1ccc(N2c3ccccc3B3c4cccc5c4C(c4cccc2c43)c2ccc3oc4ccccc4c3c2-5)cc1 ; c1ccc(B2c3ccccc3N3c4ccccc4-n4c5ccc6oc7ccccc7c6c5c5ccc2c3c54)cc1 ; c1ccc(N2c3ccccc3B3c4c2cccc4-n2c4c3cccc4c3cc4c5ccccc5n5c6ccccc6c(c32)c45)cc1]

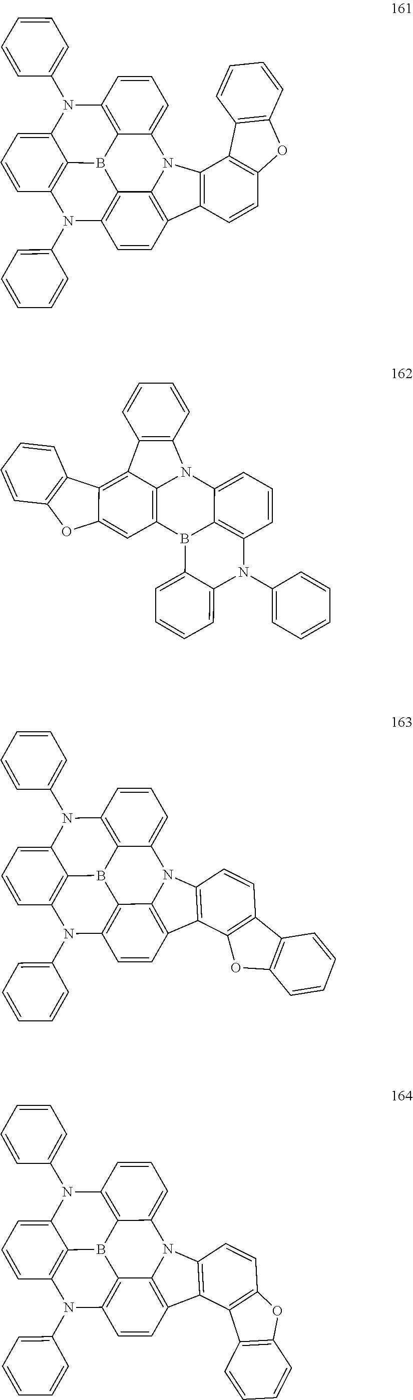 [SMILES: c1ccc(N2c3cccc4c3B3c5c2cccc5-n2c5c3c(ccc5c3ccc5oc6ccccc6c5c32)N4c2ccccc2)cc1 ; c1ccc(N2c3ccccc3B3c4c2cccc4-n2c4ccccc4c4c5c(cc3c42)oc2ccccc25)cc1 ; c1ccc(N2c3cccc4c3B3c5c2cccc5-n2c5ccc6c7ccccc7oc6c5c5ccc(c3c52)N4c2ccccc2)cc1 ; c1ccc(N2c3cccc4c3B3c5c2cccc5-n2c5ccc6oc7ccccc7c6c5c5ccc(c3c52)N4c2ccccc2)cc1]

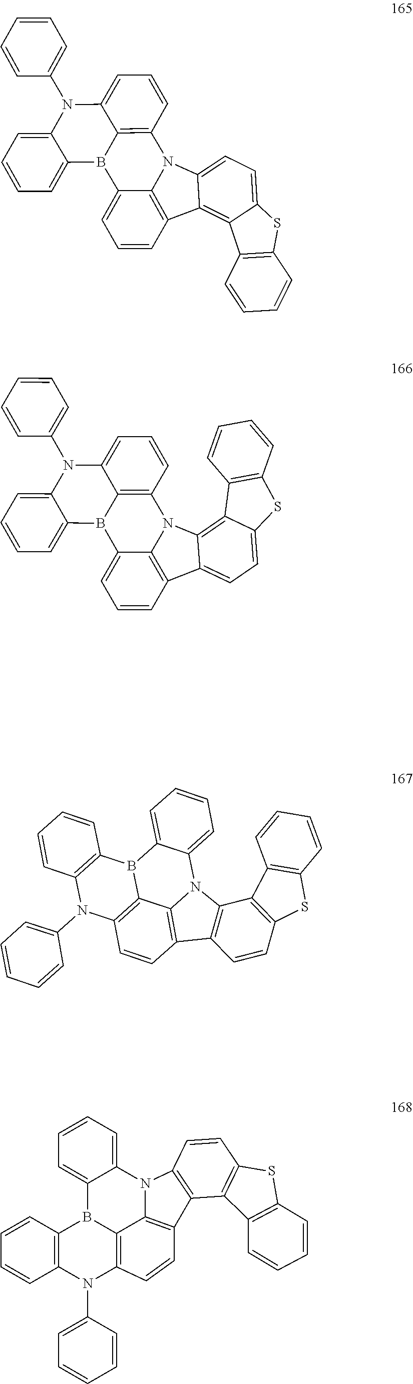 [SMILES: c1ccc(N2c3ccccc3B3c4c2cccc4-n2c4ccc5sc6ccccc6c5c4c4cccc3c42)cc1 ; c1ccc(N2c3ccccc3B3c4c2cccc4-n2c4c3cccc4c3ccc4sc5ccccc5c4c32)cc1 ; c1ccc(N2c3ccccc3B3c4ccccc4-n4c5c3c2ccc5c2ccc3sc5ccccc5c3c24)cc1 ; c1ccc(N2c3ccccc3B3c4ccccc4-n4c5ccc6sc7ccccc7c6c5c5ccc2c3c54)cc1]

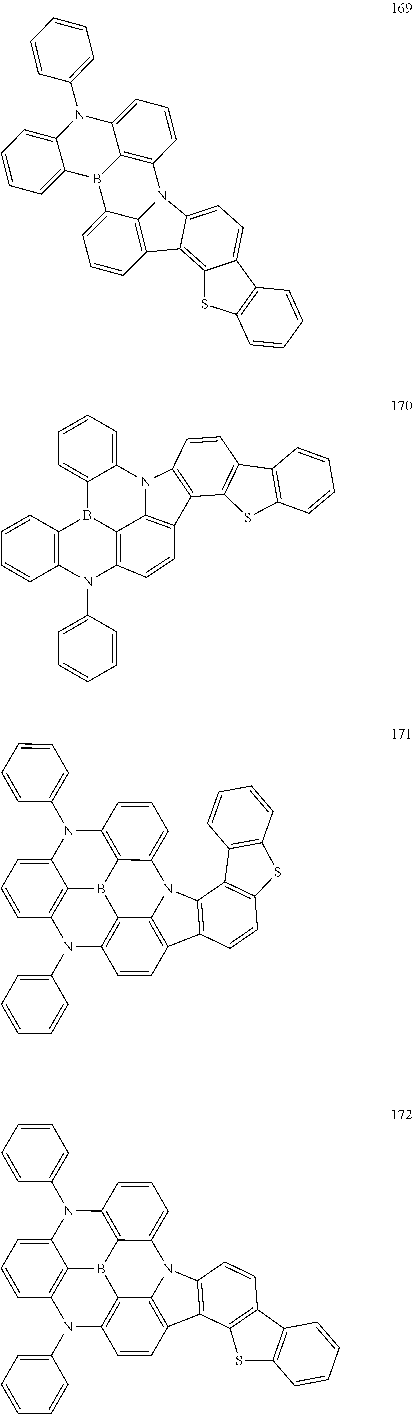 [SMILES: c1ccc(N2c3ccccc3B3c4c2cccc4-n2c4ccc5c6ccccc6sc5c4c4cccc3c42)cc1 ; c1ccc(N2c3ccccc3B3c4ccccc4-n4c5ccc6c7ccccc7sc6c5c5ccc2c3c54)cc1 ; c1ccc(N2c3cccc4c3B3c5c2cccc5-n2c5c3c(ccc5c3ccc5sc6ccccc6c5c32)N4c2ccccc2)cc1 ; c1ccc(N2c3cccc4c3B3c5c2cccc5-n2c5ccc6c7ccccc7sc6c5c5ccc(c3c52)N4c2ccccc2)cc1]

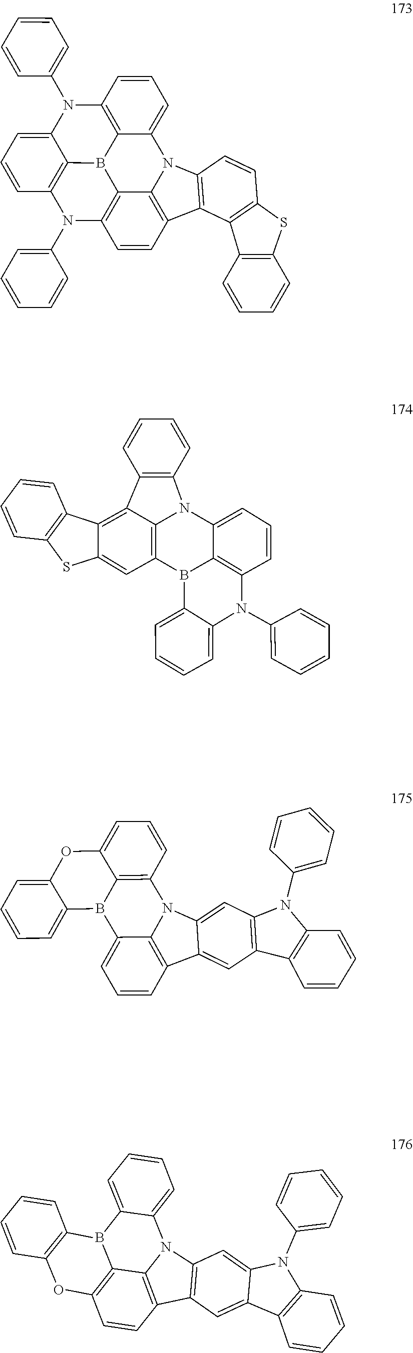 [SMILES: c1ccc(N2c3cccc4c3B3c5c2cccc5-n2c5ccc6sc7ccccc7c6c5c5ccc(c3c52)N4c2ccccc2)cc1 ; c1ccc(N2c3ccccc3B3c4c2cccc4-n2c4ccccc4c4c5c(cc3c42)sc2ccccc25)cc1 ; c1ccc(-n2c3ccccc3c3cc4c5cccc6c5n(c4cc32)-c2cccc3c2B6c2ccccc2O3)cc1 ; c1ccc(-n2c3ccccc3c3cc4c5ccc6c7c5n(c4cc32)-c2ccccc2B7c2ccccc2O6)cc1]

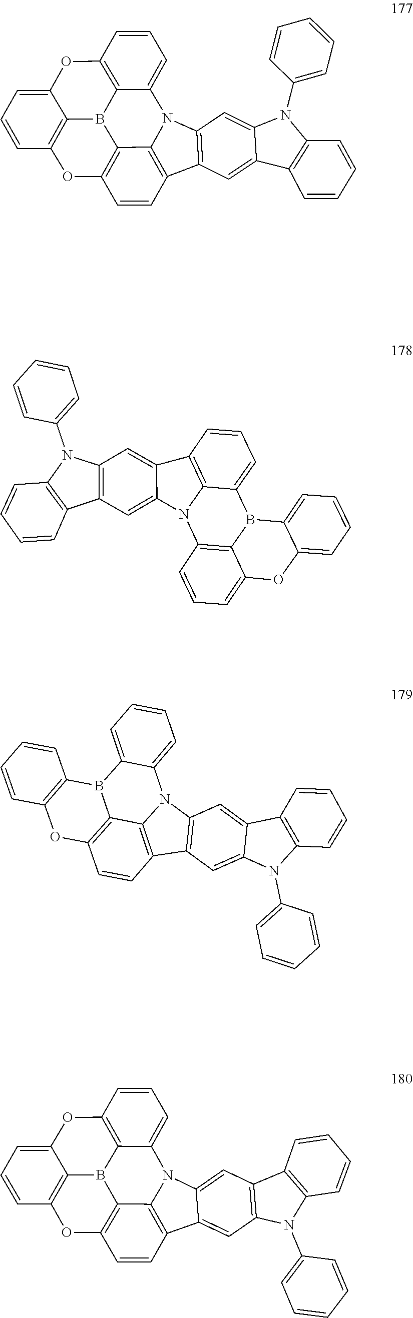 [SMILES: c1ccc(-n2c3ccccc3c3cc4c5ccc6c7c5n(c4cc32)-c2cccc3c2B7c2c(cccc2O6)O3)cc1 ; c1ccc(-n2c3ccccc3c3cc4c(cc32)c2cccc3c2n4-c2cccc4c2B3c2ccccc2O4)cc1 ; c1ccc(-n2c3ccccc3c3cc4c(cc32)c2ccc3c5c2n4-c2ccccc2B5c2ccccc2O3)cc1 ; c1ccc(-n2c3ccccc3c3cc4c(cc32)c2ccc3c5c2n4-c2cccc4c2B5c2c(cccc2O3)O4)cc1]

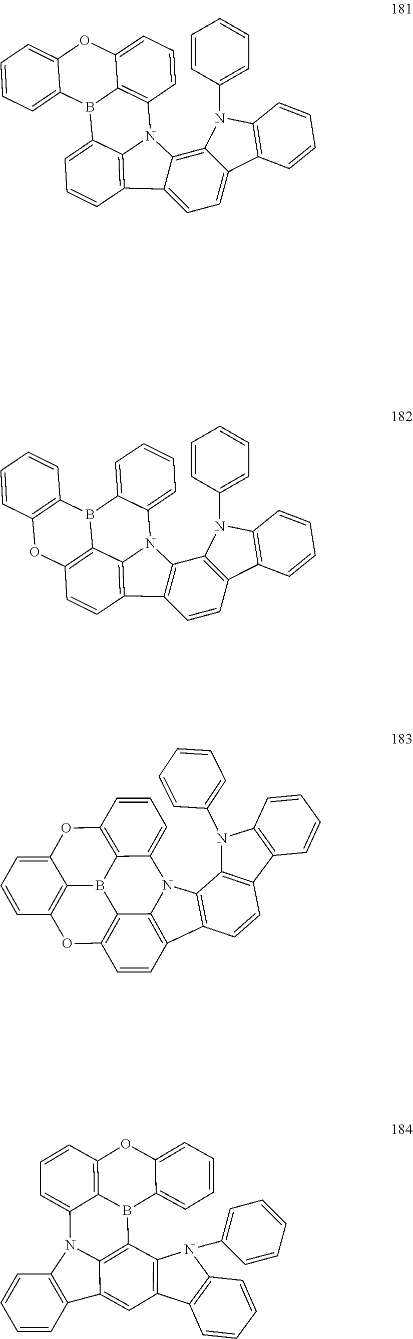 [SMILES: c1ccc(-n2c3ccccc3c3ccc4c5cccc6c5n(c4c32)-c2cccc3c2B6c2ccccc2O3)cc1 ; c1ccc(-n2c3ccccc3c3ccc4c5ccc6c7c5n(c4c32)-c2ccccc2B7c2ccccc2O6)cc1 ; c1ccc(-n2c3ccccc3c3ccc4c5ccc6c7c5n(c4c32)-c2cccc3c2B7c2c(cccc2O6)O3)cc1 ; c1ccc(-n2c3ccccc3c3cc4c5ccccc5n5c4c(c32)B2c3ccccc3Oc3cccc-5c32)cc1]

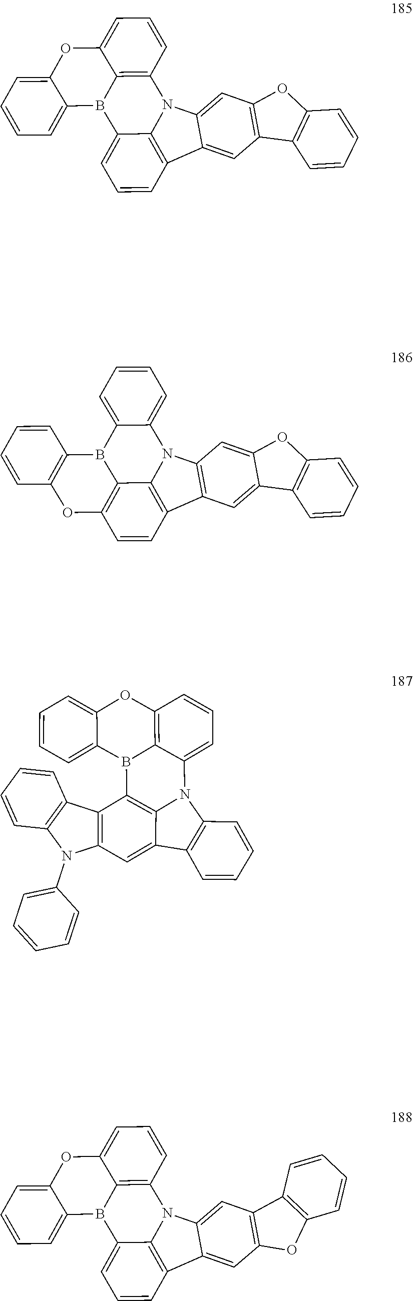 [SMILES: c1ccc2c(c1)Oc1cccc3c1B2c1cccc2c4cc5c(cc4n-3c12)oc1ccccc15 ; c1ccc2c(c1)Oc1ccc3c4cc5c(cc4n4c3c1B2c1ccccc1-4)oc1ccccc15 ; c1ccc(-n2c3ccccc3c3c4c5c(cc32)c2ccccc2n5-c2cccc3c2B4c2ccccc2O3)cc1 ; c1ccc2c(c1)Oc1cccc3c1B2c1cccc2c4cc5oc6ccccc6c5cc4n-3c12]

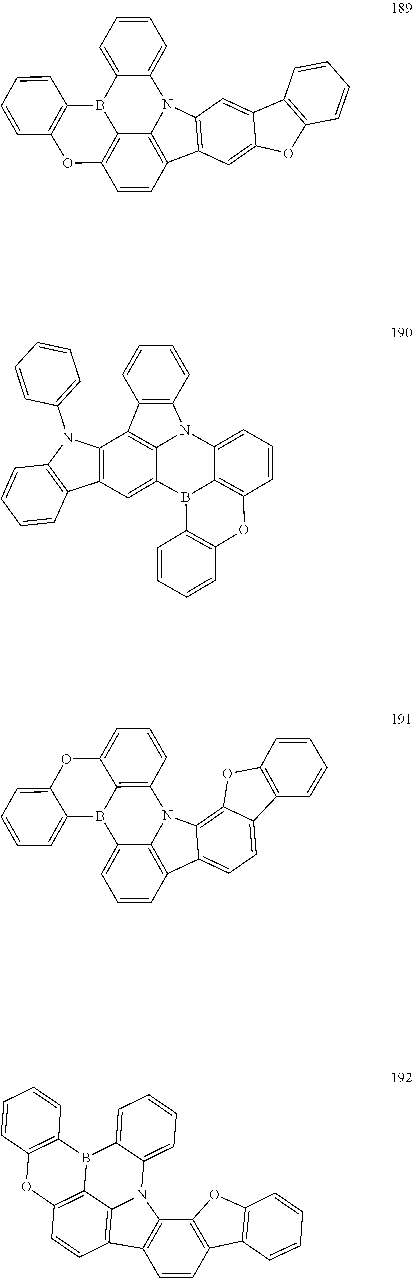 [SMILES: c1ccc2c(c1)Oc1ccc3c4cc5oc6ccccc6c5cc4n4c3c1B2c1ccccc1-4 ; c1ccc(-n2c3ccccc3c3cc4c5c(c6ccccc6n5-c5cccc6c5B4c4ccccc4O6)c32)cc1 ; c1ccc2c(c1)Oc1cccc3c1B2c1cccc2c4ccc5c6ccccc6oc5c4n-3c12 ; c1ccc2c(c1)Oc1ccc3c4ccc5c6ccccc6oc5c4n4c3c1B2c1ccccc1-4]

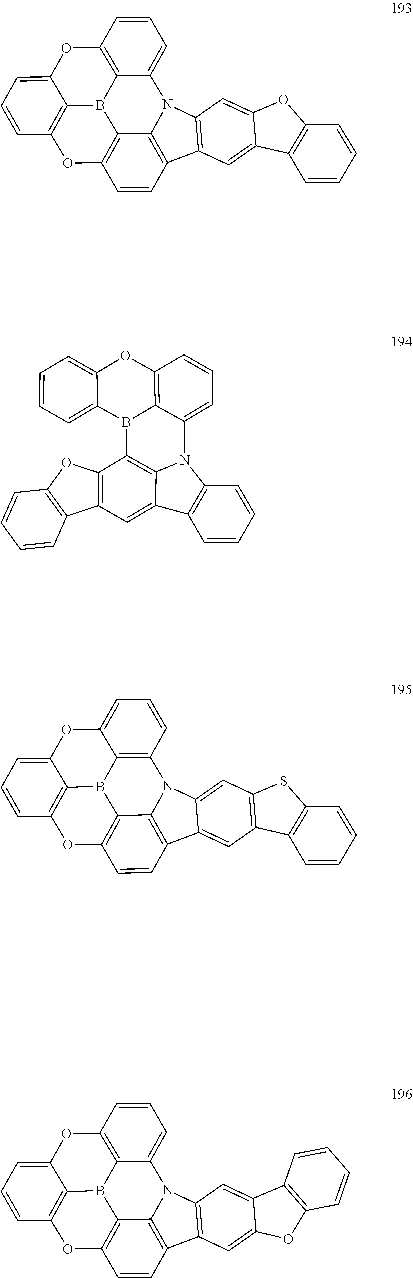 [SMILES: c1cc2c3c(c1)Oc1ccc4c5cc6c(cc5n5c4c1B3c1c(cccc1-5)O2)oc1ccccc16 ; c1ccc2c(c1)Oc1cccc3c1B2c1c2oc4ccccc4c2cc2c4ccccc4n-3c12 ; c1cc2c3c(c1)Oc1ccc4c5cc6c(cc5n5c4c1B3c1c(cccc1-5)O2)sc1ccccc16 ; c1cc2c3c(c1)Oc1ccc4c5cc6oc7ccccc7c6cc5n5c4c1B3c1c(cccc1-5)O2]

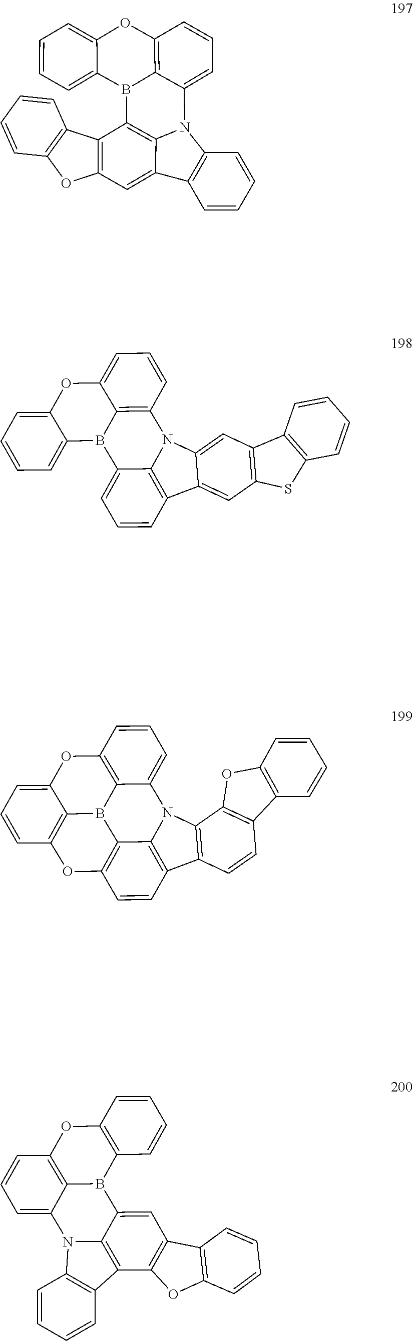 [SMILES: c1ccc2c(c1)Oc1cccc3c1B2c1c2c(cc4c5ccccc5n-3c14)oc1ccccc12 ; c1ccc2c(c1)Oc1cccc3c1B2c1cccc2c4cc5sc6ccccc6c5cc4n-3c12 ; c1cc2c3c(c1)Oc1ccc4c5ccc6c7ccccc7oc6c5n5c4c1B3c1c(cccc1-5)O2 ; c1ccc2c(c1)Oc1cccc3c1B2c1cc2c4ccccc4oc2c2c4ccccc4n-3c12]

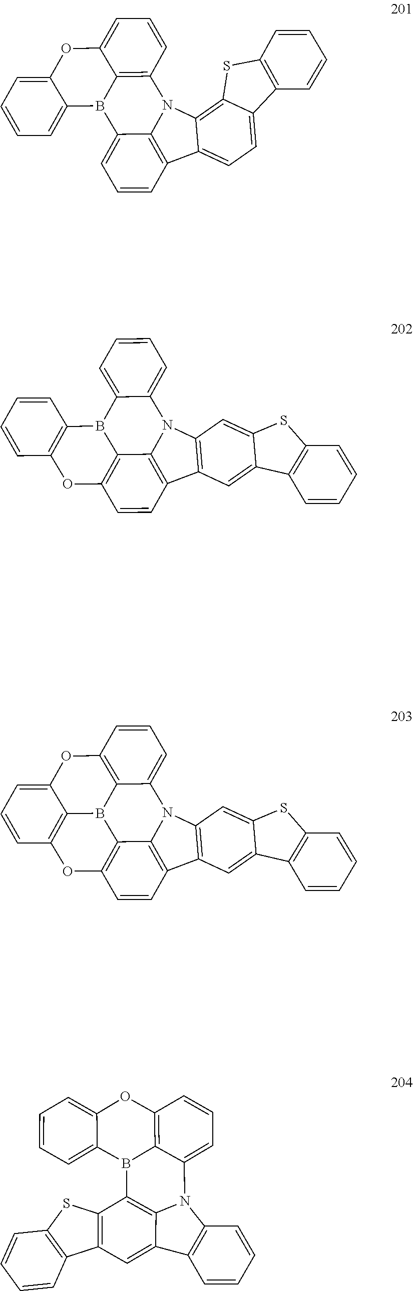 [SMILES: c1ccc2c(c1)Oc1cccc3c1B2c1cccc2c4ccc5c6ccccc6sc5c4n-3c12 ; c1ccc2c(c1)Oc1ccc3c4cc5c(cc4n4c3c1B2c1ccccc1-4)sc1ccccc15 ; c1cc2c3c(c1)Oc1ccc4c5cc6c(cc5n5c4c1B3c1c(cccc1-5)O2)sc1ccccc16 ; c1ccc2c(c1)Oc1cccc3c1B2c1c2sc4ccccc4c2cc2c4ccccc4n-3c12]

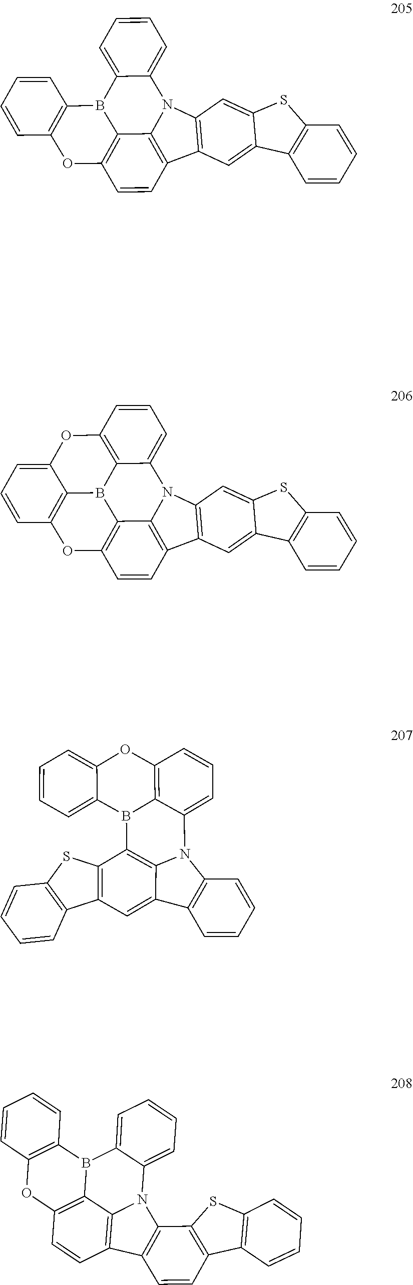 [SMILES: c1ccc2c(c1)Oc1ccc3c4cc5c(cc4n4c3c1B2c1ccccc1-4)sc1ccccc15 ; c1cc2c3c(c1)Oc1ccc4c5cc6c(cc5n5c4c1B3c1c(cccc1-5)O2)sc1ccccc16 ; c1ccc2c(c1)Oc1cccc3c1B2c1c2sc4ccccc4c2cc2c4ccccc4n-3c12 ; c1ccc2c(c1)Oc1ccc3c4ccc5c6ccccc6sc5c4n4c3c1B2c1ccccc1-4]

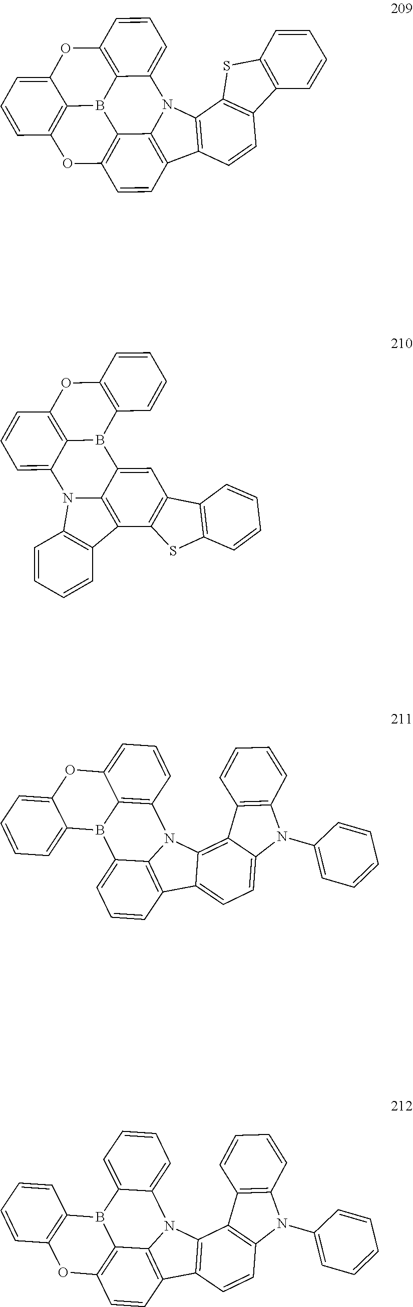 [SMILES: c1cc2c3c(c1)Oc1ccc4c5ccc6c7ccccc7sc6c5n5c4c1B3c1c(cccc1-5)O2 ; c1ccc2c(c1)Oc1cccc3c1B2c1cc2c4ccccc4sc2c2c4ccccc4n-3c12 ; c1ccc(-n2c3ccccc3c3c2ccc2c4cccc5c4n(c23)-c2cccc3c2B5c2ccccc2O3)cc1 ; c1ccc(-n2c3ccccc3c3c2ccc2c4ccc5c6c4n(c23)-c2ccccc2B6c2ccccc2O5)cc1]

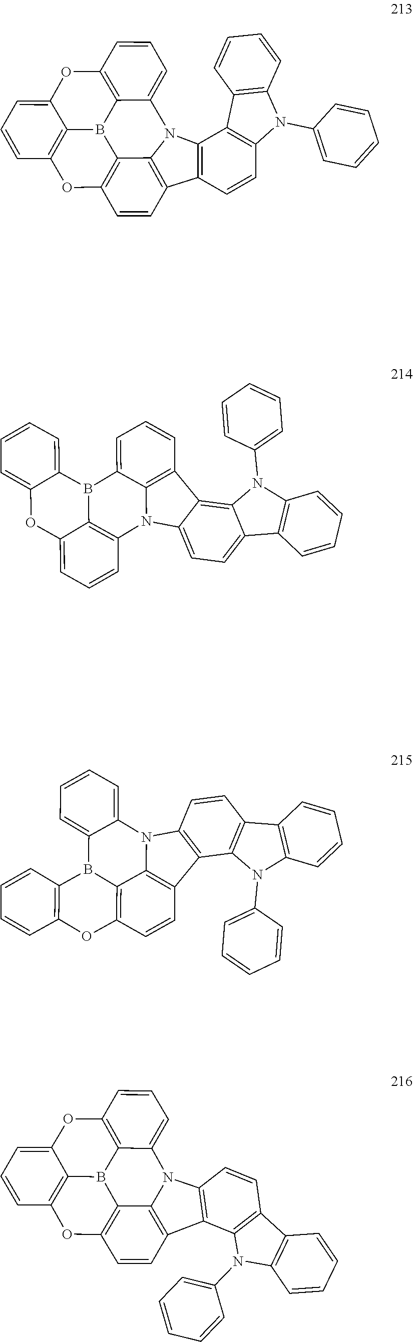 [SMILES: c1ccc(-n2c3ccccc3c3c2ccc2c4ccc5c6c4n(c23)-c2cccc3c2B6c2c(cccc2O5)O3)cc1 ; c1ccc(-n2c3ccccc3c3ccc4c(c5cccc6c5n4-c4cccc5c4B6c4ccccc4O5)c32)cc1 ; c1ccc(-n2c3ccccc3c3ccc4c(c5ccc6c7c5n4-c4ccccc4B7c4ccccc4O6)c32)cc1 ; c1ccc(-n2c3ccccc3c3ccc4c(c5ccc6c7c5n4-c4cccc5c4B7c4c(cccc4O6)O5)c32)cc1]

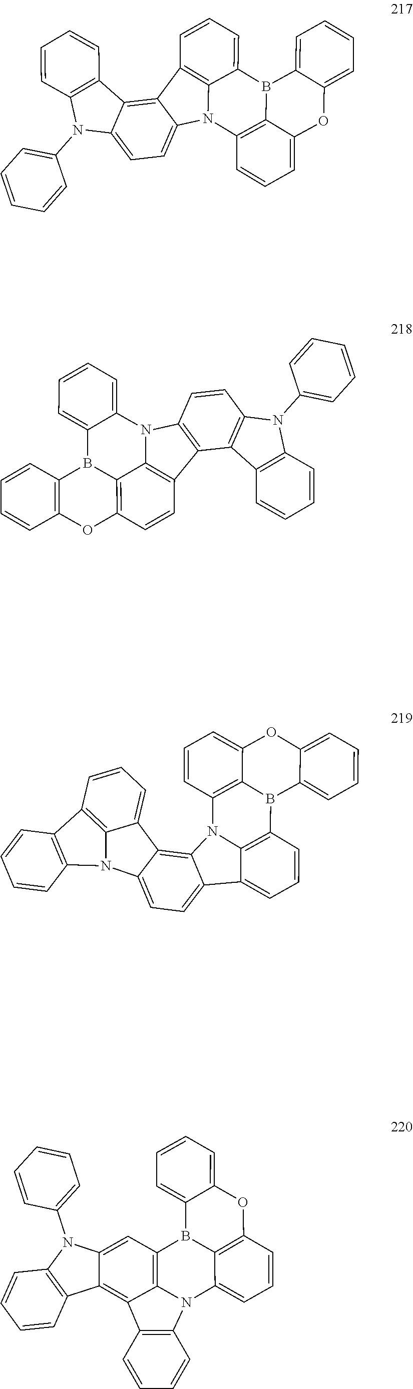 [SMILES: c1ccc(-n2c3ccccc3c3c4c5cccc6c5n(c4ccc32)-c2cccc3c2B6c2ccccc2O3)cc1 ; c1ccc(-n2c3ccccc3c3c4c5ccc6c7c5n(c4ccc32)-c2ccccc2B7c2ccccc2O6)cc1 ; c1ccc2c(c1)Oc1cccc3c1B2c1cccc2c4ccc5c(c6cccc7c8ccccc8n5c76)c4n-3c12 ; c1ccc(-n2c3ccccc3c3c4c5ccccc5n5c4c(cc32)B2c3ccccc3Oc3cccc-5c32)cc1]

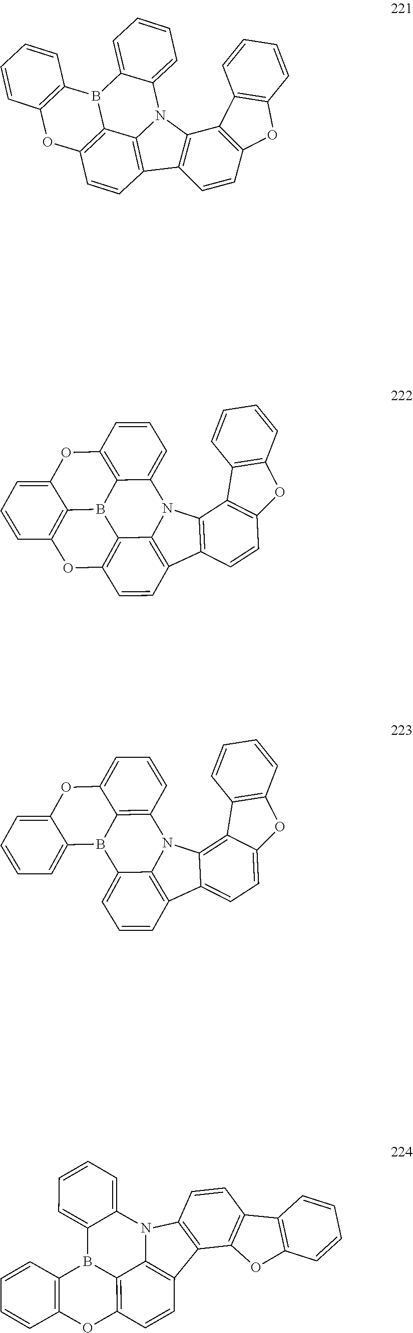 [SMILES: c1ccc2c(c1)Oc1ccc3c4ccc5oc6ccccc6c5c4n4c3c1B2c1ccccc1-4 ; c1cc2c3c(c1)Oc1ccc4c5ccc6oc7ccccc7c6c5n5c4c1B3c1c(cccc1-5)O2 ; c1ccc2c(c1)Oc1cccc3c1B2c1cccc2c4ccc5oc6ccccc6c5c4n-3c12 ; c1ccc2c(c1)Oc1ccc3c4c5oc6ccccc6c5ccc4n4c3c1B2c1ccccc1-4]

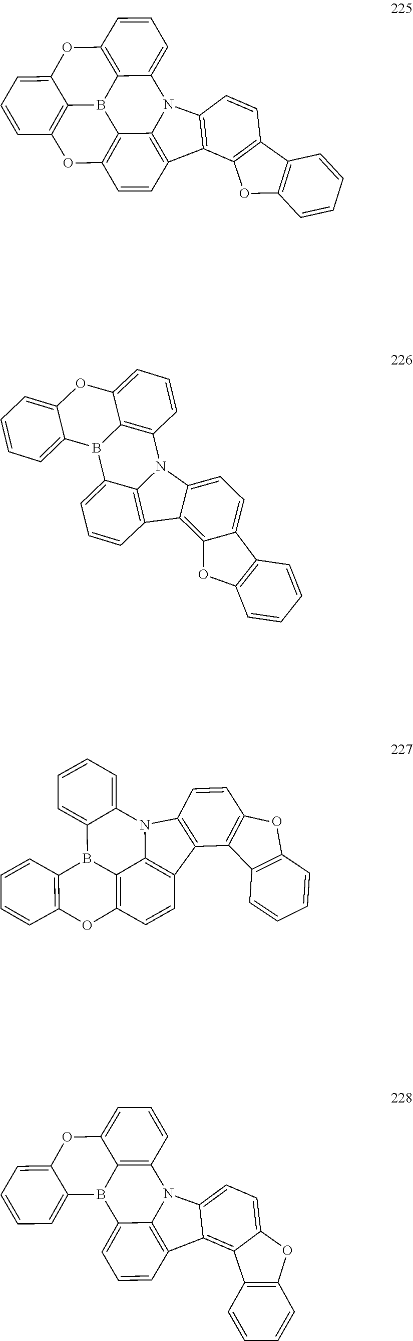 [SMILES: c1cc2c3c(c1)Oc1ccc4c5c6oc7ccccc7c6ccc5n5c4c1B3c1c(cccc1-5)O2 ; c1ccc2c(c1)Oc1cccc3c1B2c1cccc2c4c5oc6ccccc6c5ccc4n-3c12 ; c1ccc2c(c1)Oc1ccc3c4c5c(ccc4n4c3c1B2c1ccccc1-4)oc1ccccc15 ; c1ccc2c(c1)Oc1cccc3c1B2c1cccc2c4c5c(ccc4n-3c12)oc1ccccc15]

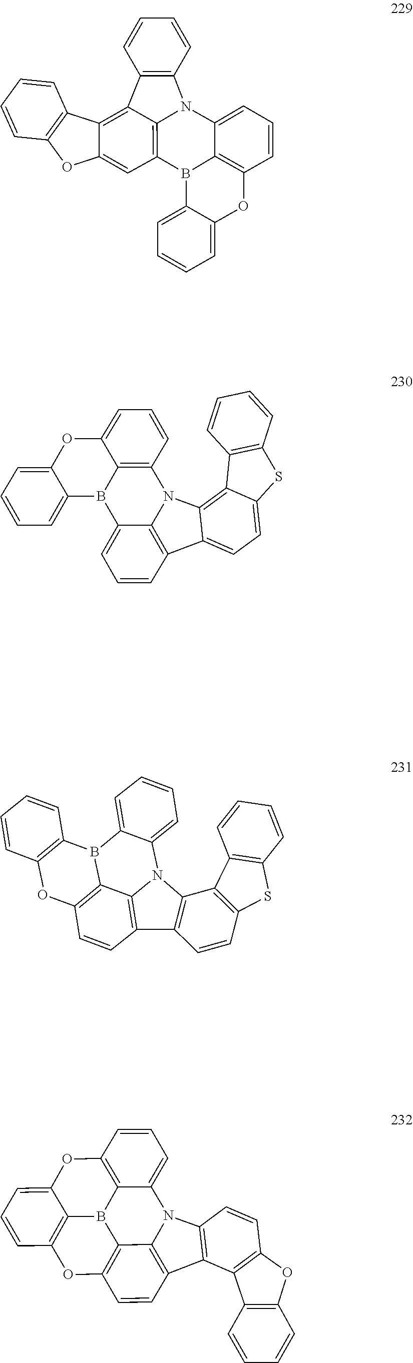 [SMILES: c1ccc2c(c1)Oc1cccc3c1B2c1cc2oc4ccccc4c2c2c4ccccc4n-3c12 ; c1ccc2c(c1)Oc1cccc3c1B2c1cccc2c4ccc5sc6ccccc6c5c4n-3c12 ; c1ccc2c(c1)Oc1ccc3c4ccc5sc6ccccc6c5c4n4c3c1B2c1ccccc1-4 ; c1cc2c3c(c1)Oc1ccc4c5c6c(ccc5n5c4c1B3c1c(cccc1-5)O2)oc1ccccc16]

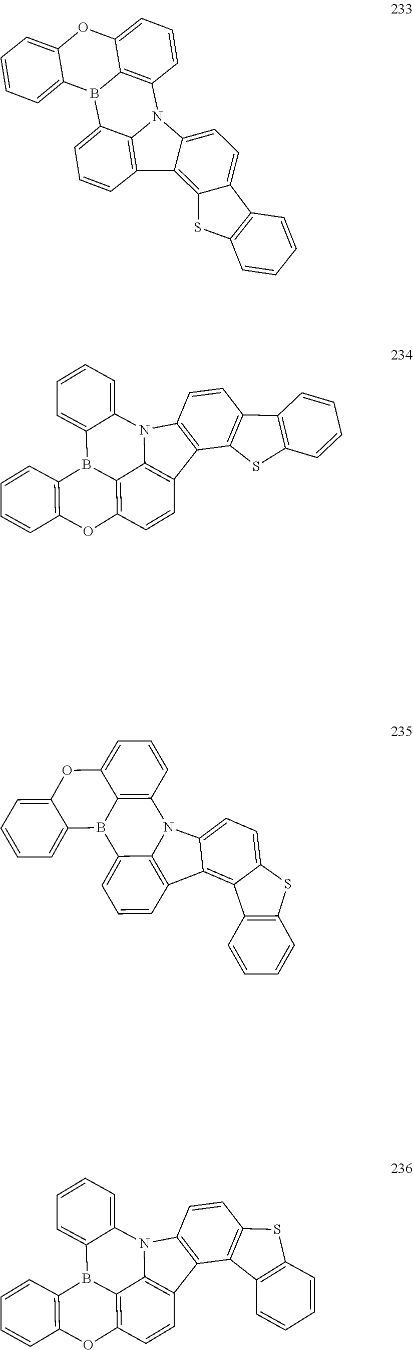 [SMILES: c1ccc2c(c1)Oc1cccc3c1B2c1cccc2c4c5sc6ccccc6c5ccc4n-3c12 ; c1ccc2c(c1)Oc1ccc3c4c5sc6ccccc6c5ccc4n4c3c1B2c1ccccc1-4 ; c1ccc2c(c1)Oc1cccc3c1B2c1cccc2c4c5c(ccc4n-3c12)sc1ccccc15 ; c1ccc2c(c1)Oc1ccc3c4c5c(ccc4n4c3c1B2c1ccccc1-4)sc1ccccc15]

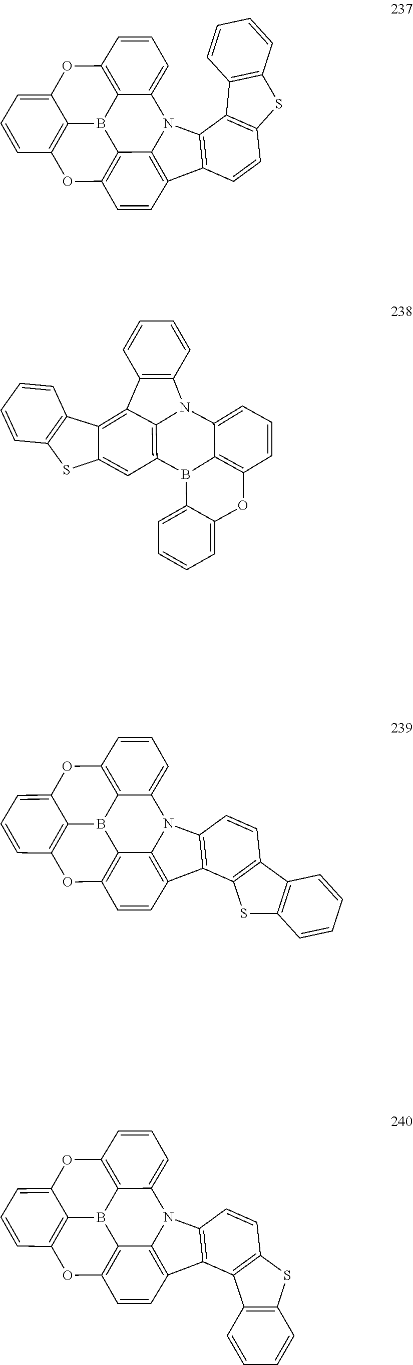 [SMILES: c1cc2c3c(c1)Oc1ccc4c5ccc6sc7ccccc7c6c5n5c4c1B3c1c(cccc1-5)O2 ; c1ccc2c(c1)Oc1cccc3c1B2c1cc2sc4ccccc4c2c2c4ccccc4n-3c12 ; c1cc2c3c(c1)Oc1ccc4c5c6sc7ccccc7c6ccc5n5c4c1B3c1c(cccc1-5)O2 ; c1cc2c3c(c1)Oc1ccc4c5c6c(ccc5n5c4c1B3c1c(cccc1-5)O2)sc1ccccc16]

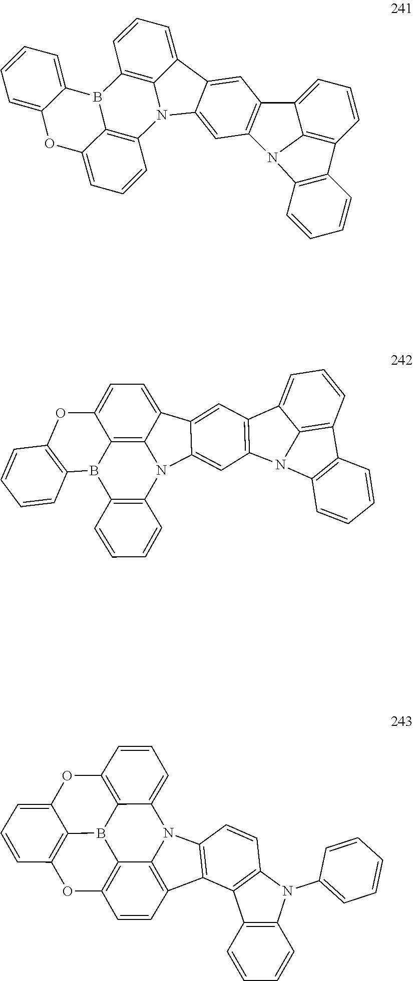 [SMILES: c1ccc2c(c1)Oc1cccc3c1B2c1cccc2c4cc5c6cccc7c8ccccc8n(c5cc4n-3c12)c76 ; c1ccc2c(c1)Oc1ccc3c4cc5c6cccc7c8ccccc8n(c5cc4n4c3c1B2c1ccccc1-4)c76 ; c1ccc(-n2c3ccccc3c3c4c5ccc6c7c5n(c4ccc32)-c2cccc3c2B7c2c(cccc2O6)O3)cc1]

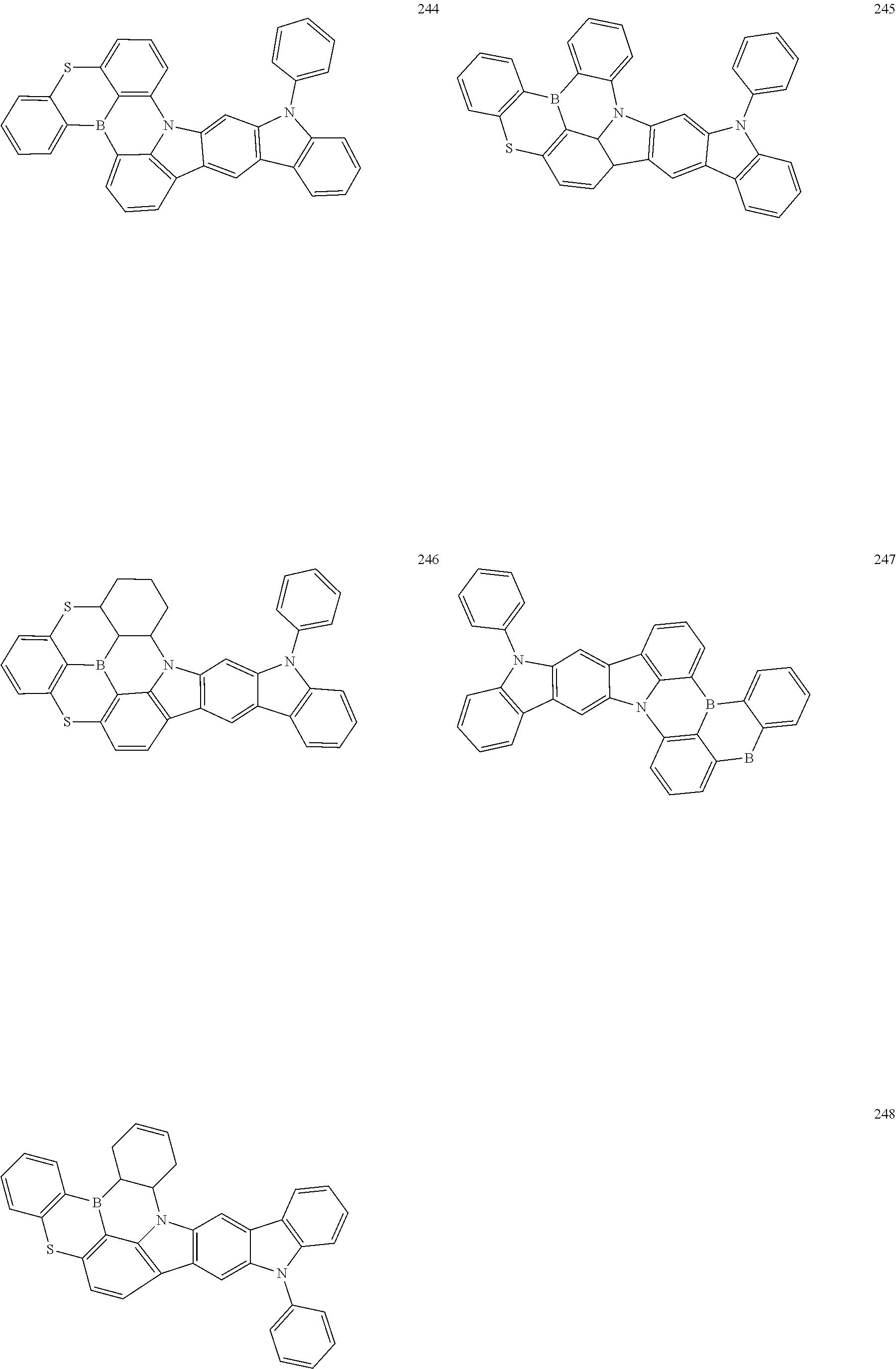

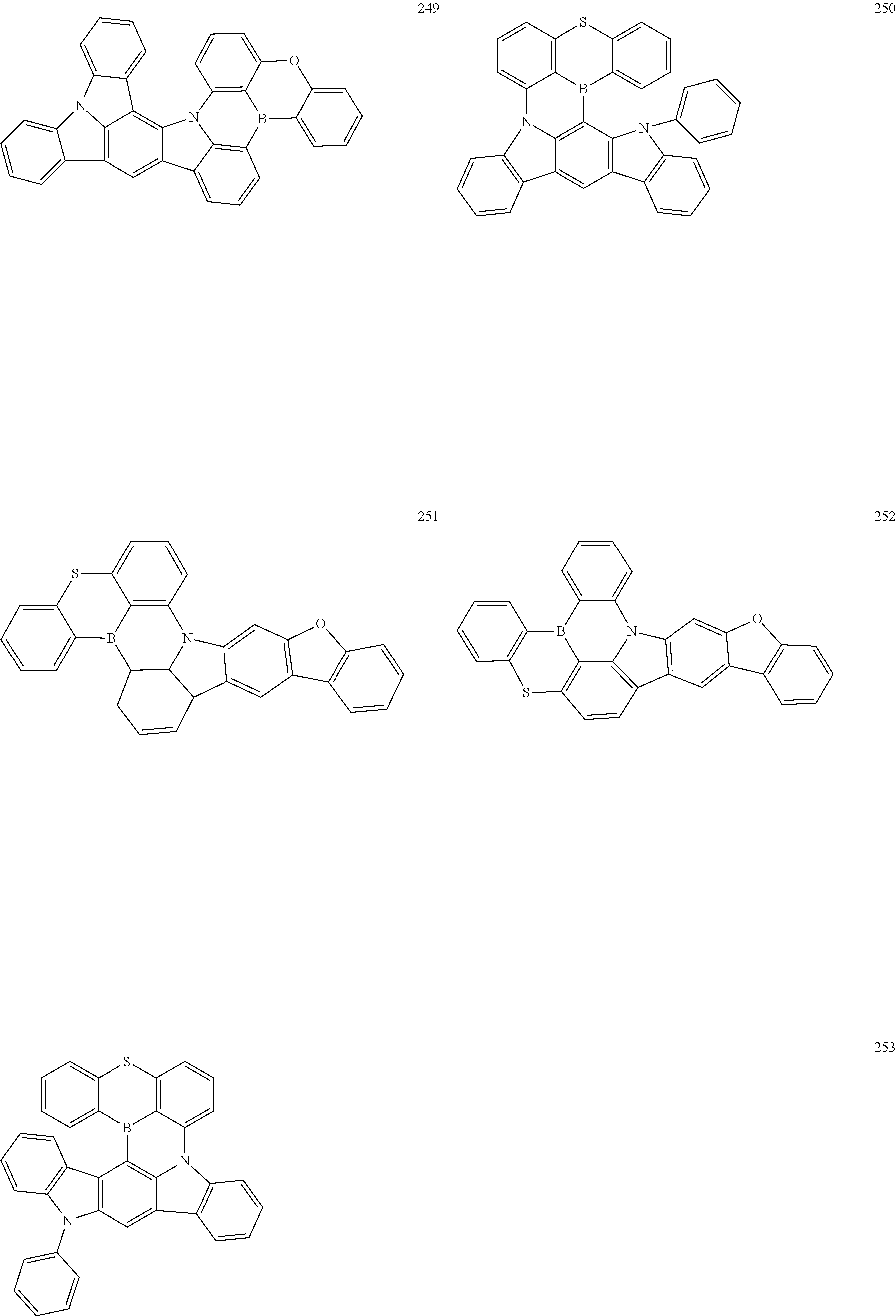 [SMILES: c1ccc2c(c1)Oc1cccc3c1B2c1cccc2c4cc5c6ccccc6n6c7ccccc7c(c4n-3c12)c56 ; c1ccc(-n2c3ccccc3c3cc4c5ccccc5n5c4c(c32)B2c3ccccc3Sc3cccc-5c32)cc1 ; C1=CC2c3cc4c(cc3N3c5cccc6c5B(c5ccccc5S6)C(C1)C23)oc1ccccc14 ; c1ccc2c(c1)Sc1ccc3c4cc5c(cc4n4c3c1B2c1ccccc1-4)oc1ccccc15 ; c1ccc(-n2c3ccccc3c3c4c5c(cc32)c2ccccc2n5-c2cccc3c2B4c2ccccc2S3)cc1]

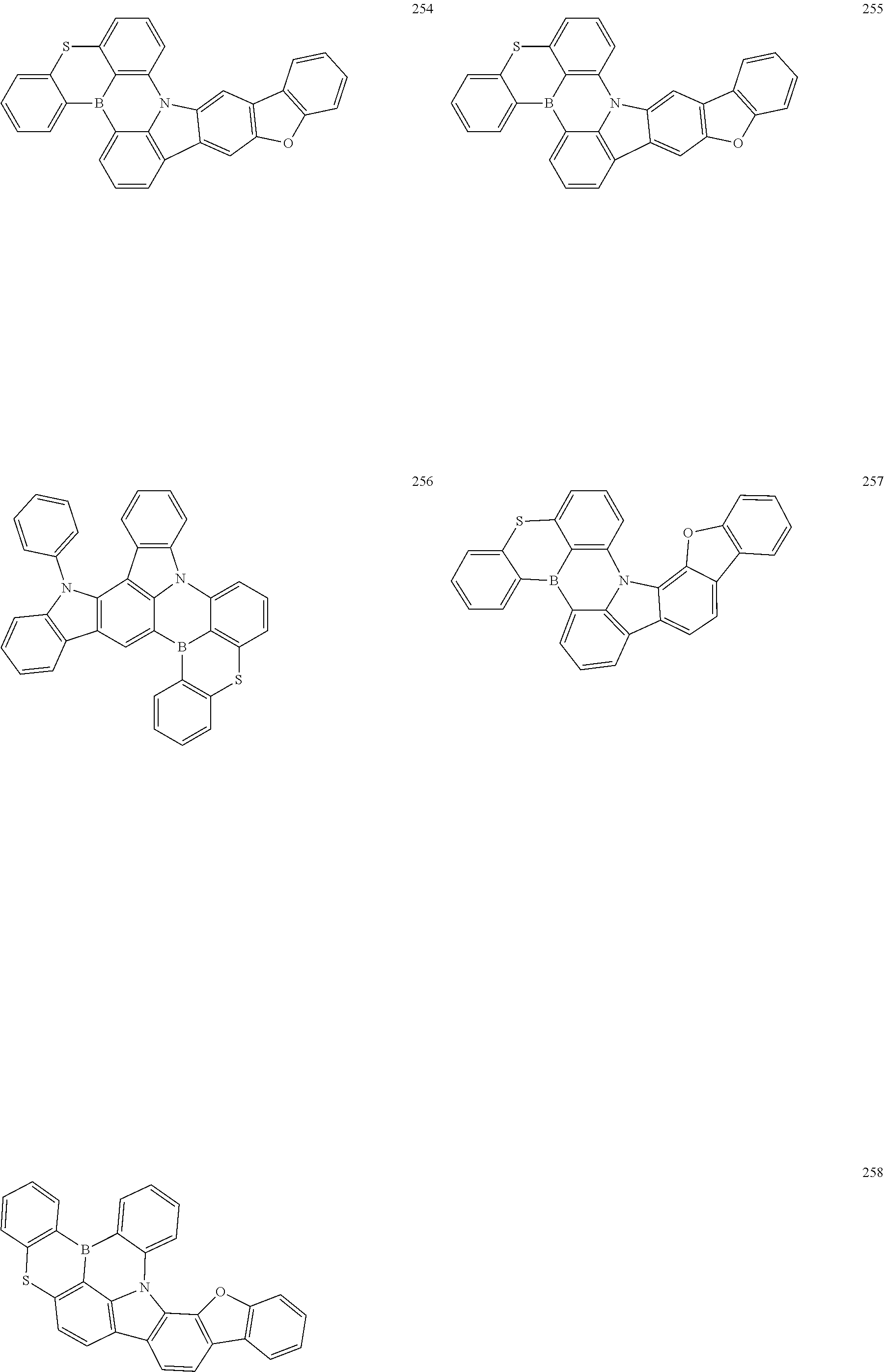

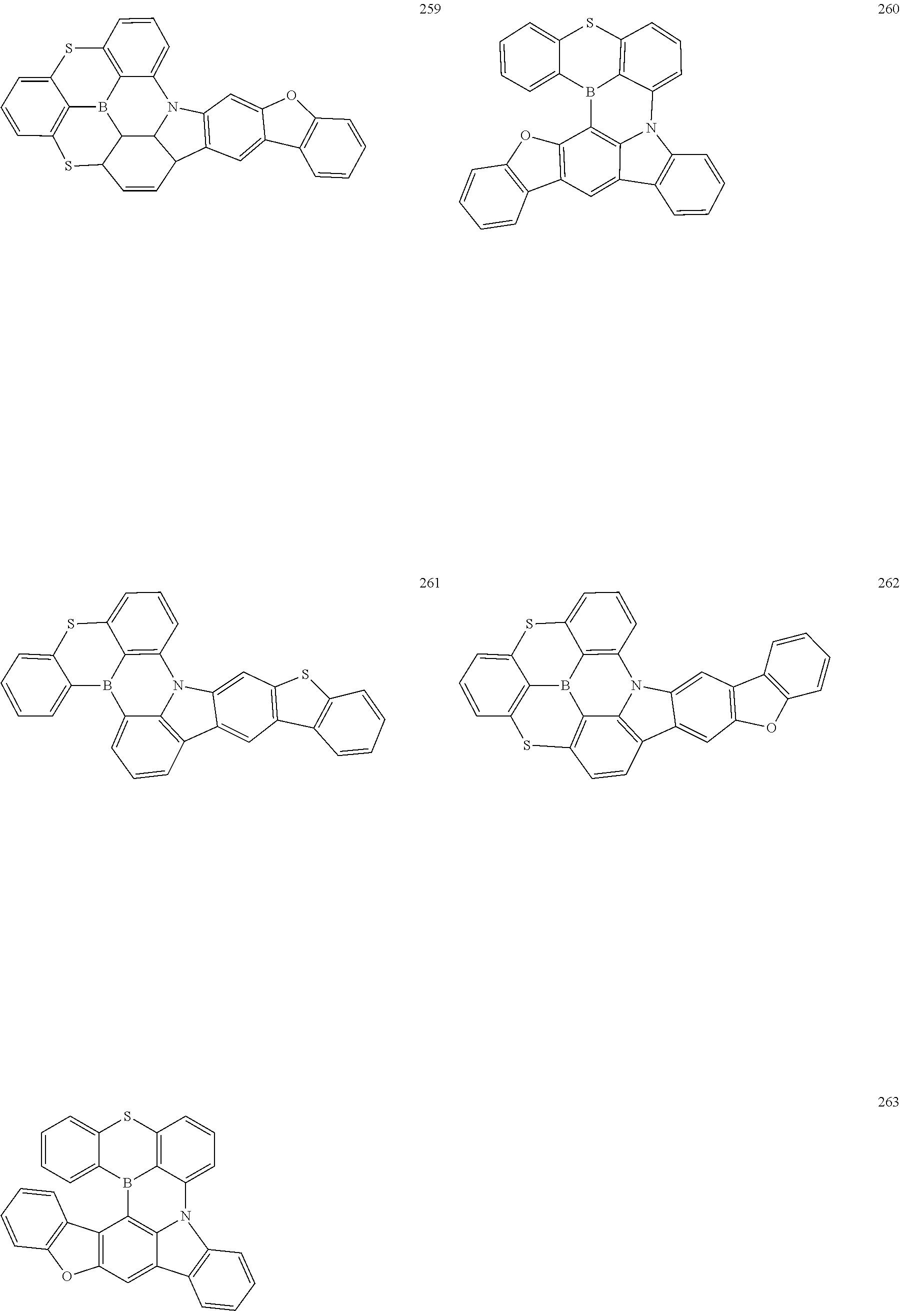 [SMILES: C1=CC2c3cc4c(cc3N3c5cccc6c5B5c7c(cccc7SC1C5C23)S6)oc1ccccc14 ; c1ccc2c(c1)Sc1cccc3c1B2c1c2oc4ccccc4c2cc2c4ccccc4n-3c12 ; c1ccc2c(c1)Sc1cccc3c1B2c1cccc2c4cc5c(cc4n-3c12)sc1ccccc15 ; c1cc2c3c(c1)Sc1ccc4c5cc6oc7ccccc7c6cc5n5c4c1B3c1c(cccc1-5)S2 ; Cc1ccccc1-c1cc2oc3ccccc3c2c2c1Nc1cccc3c1B2c1ccccc1S3]

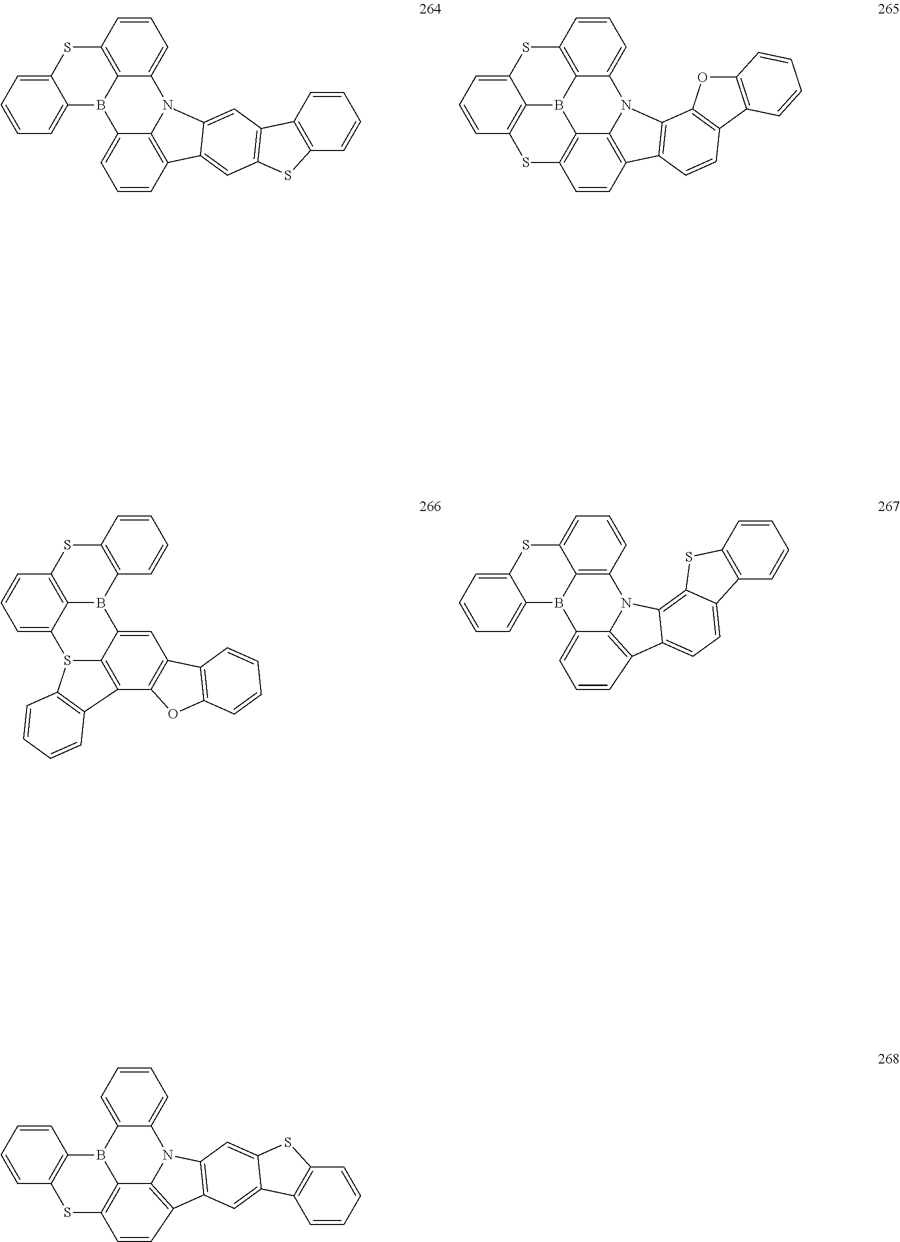

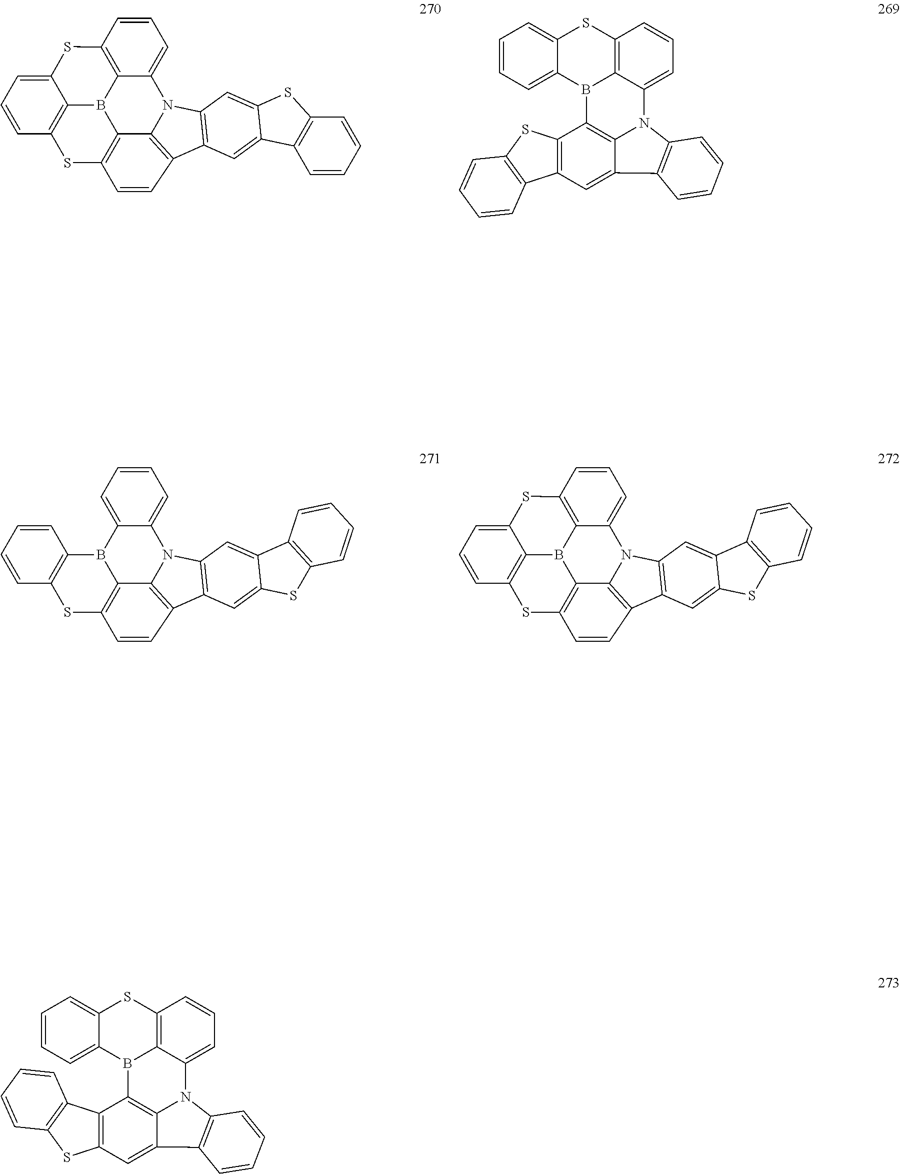 [SMILES: c1cc2c3c(c1)Sc1ccc4c5cc6c(cc5n5c4c1B3c1c(cccc1-5)S2)sc1ccccc16 ; c1ccc2c(c1)Sc1cccc3c1B2c1c2sc4ccccc4c2cc2c4ccccc4n-3c12 ; c1ccc2c(c1)Sc1ccc3c4cc5sc6ccccc6c5cc4n4c3c1B2c1ccccc1-4 ; c1cc2c3c(c1)Sc1ccc4c5cc6sc7ccccc7c6cc5n5c4c1B3c1c(cccc1-5)S2 ; c1ccc2c(c1)Sc1cccc3c1B2c1c2c(cc4c5ccccc5n-3c14)sc1ccccc12]

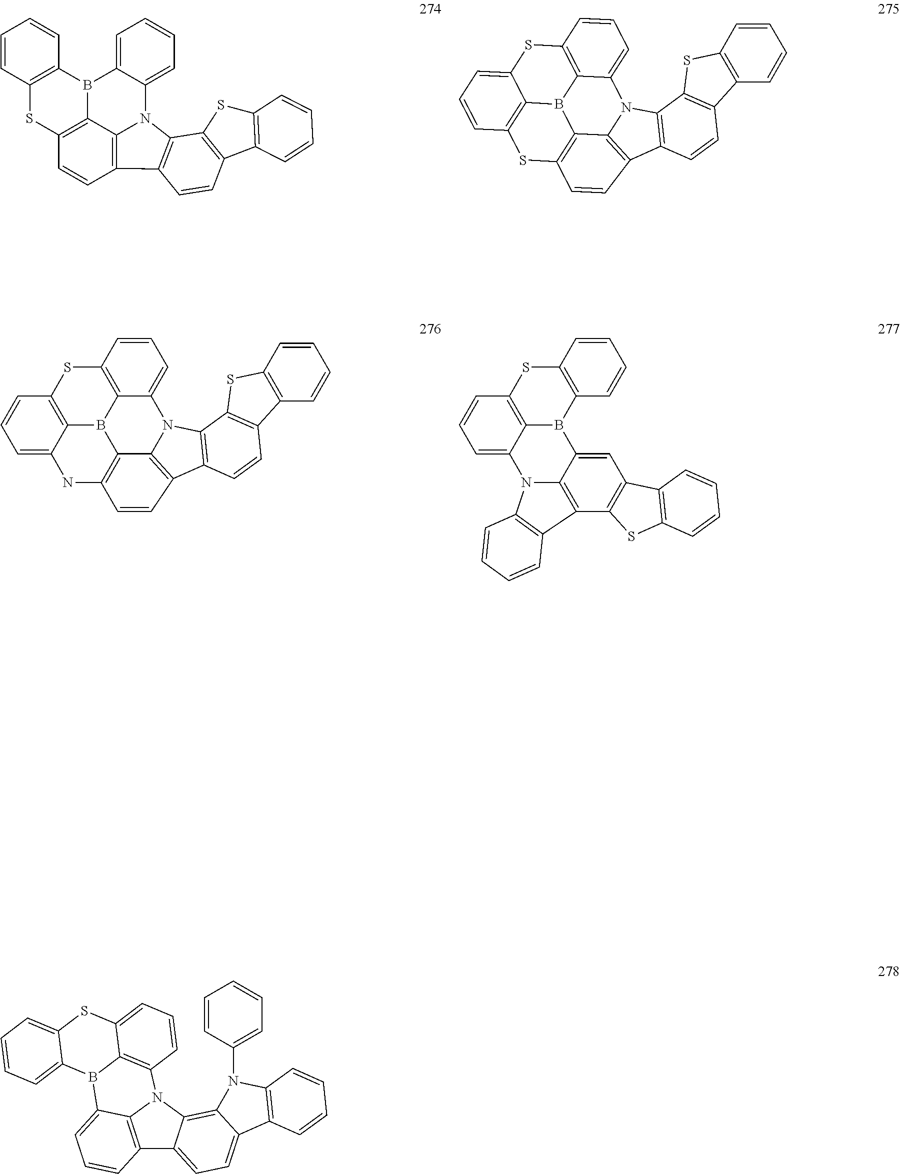 [SMILES: c1ccc2c(c1)Sc1ccc3c4ccc5c6ccccc6sc5c4n4c3c1B2c1ccccc1-4 ; c1cc2c3c(c1)Sc1ccc4c5ccc6c7ccccc7sc6c5n5c4c1B3c1c(cccc1-5)S2 ; c1cc2c3c(c1)Sc1cccc4c1B3c1c(ccc3c5ccc6c7ccccc7sc6c5n-4c13)N2 ; c1ccc2c(c1)Sc1cccc3c1B2c1cc2c4ccccc4sc2c2c4ccccc4n-3c12 ; c1ccc(-n2c3ccccc3c3ccc4c5cccc6c5n(c4c32)-c2cccc3c2B6c2ccccc2S3)cc1]

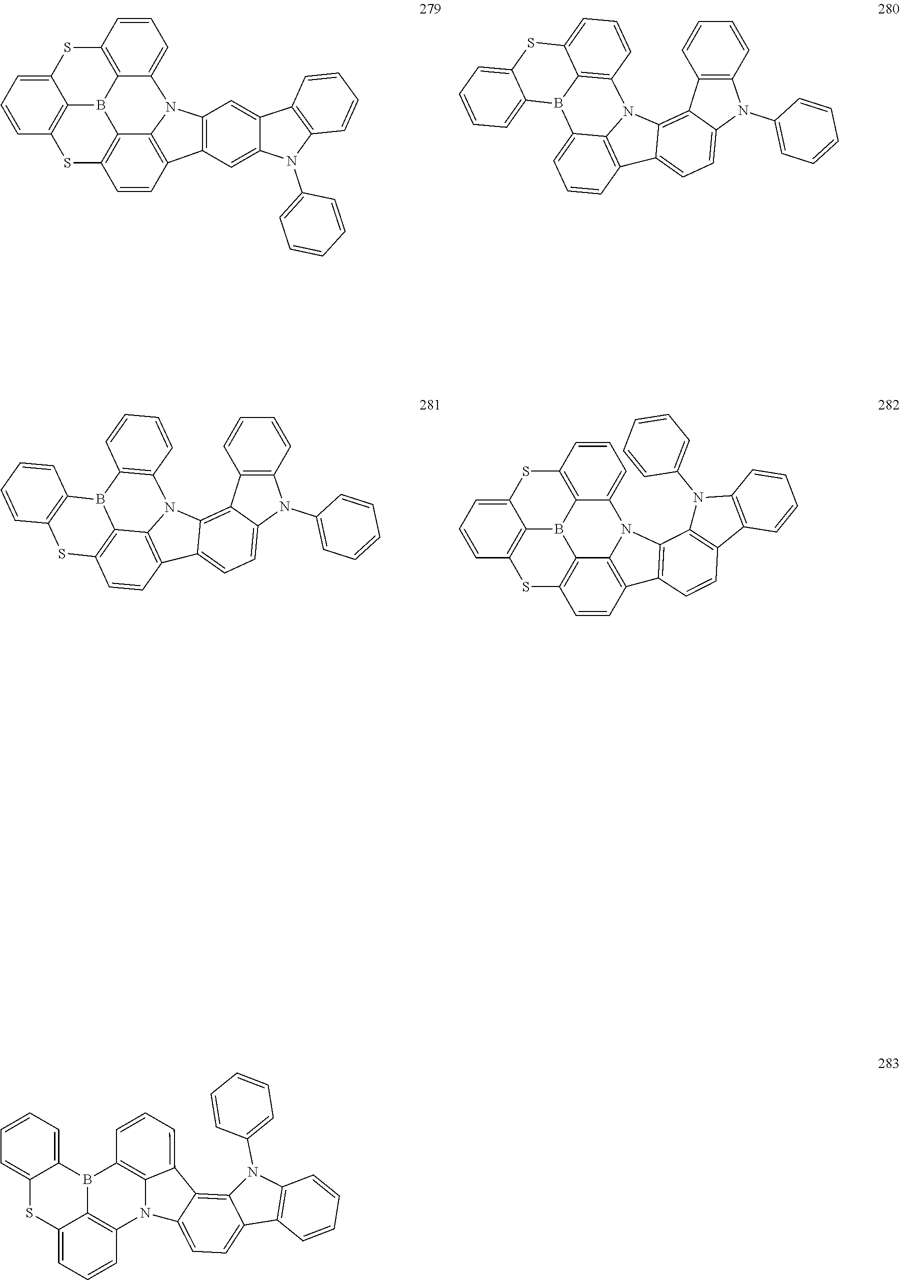 [SMILES: c1ccc(-n2c3ccccc3c3cc4c(cc32)c2ccc3c5c2n4-c2cccc4c2B5c2c(cccc2S3)S4)cc1 ; c1ccc(-n2c3ccccc3c3c2ccc2c4cccc5c4n(c23)-c2cccc3c2B5c2ccccc2S3)cc1 ; c1ccc(-n2c3ccccc3c3c2ccc2c4ccc5c6c4n(c23)-c2ccccc2B6c2ccccc2S5)cc1 ; c1ccc(-n2c3ccccc3c3ccc4c5ccc6c7c5n(c4c32)-c2cccc3c2B7c2c(cccc2S6)S3)cc1 ; c1ccc(-n2c3ccccc3c3ccc4c(c5cccc6c5n4-c4cccc5c4B6c4ccccc4S5)c32)cc1]

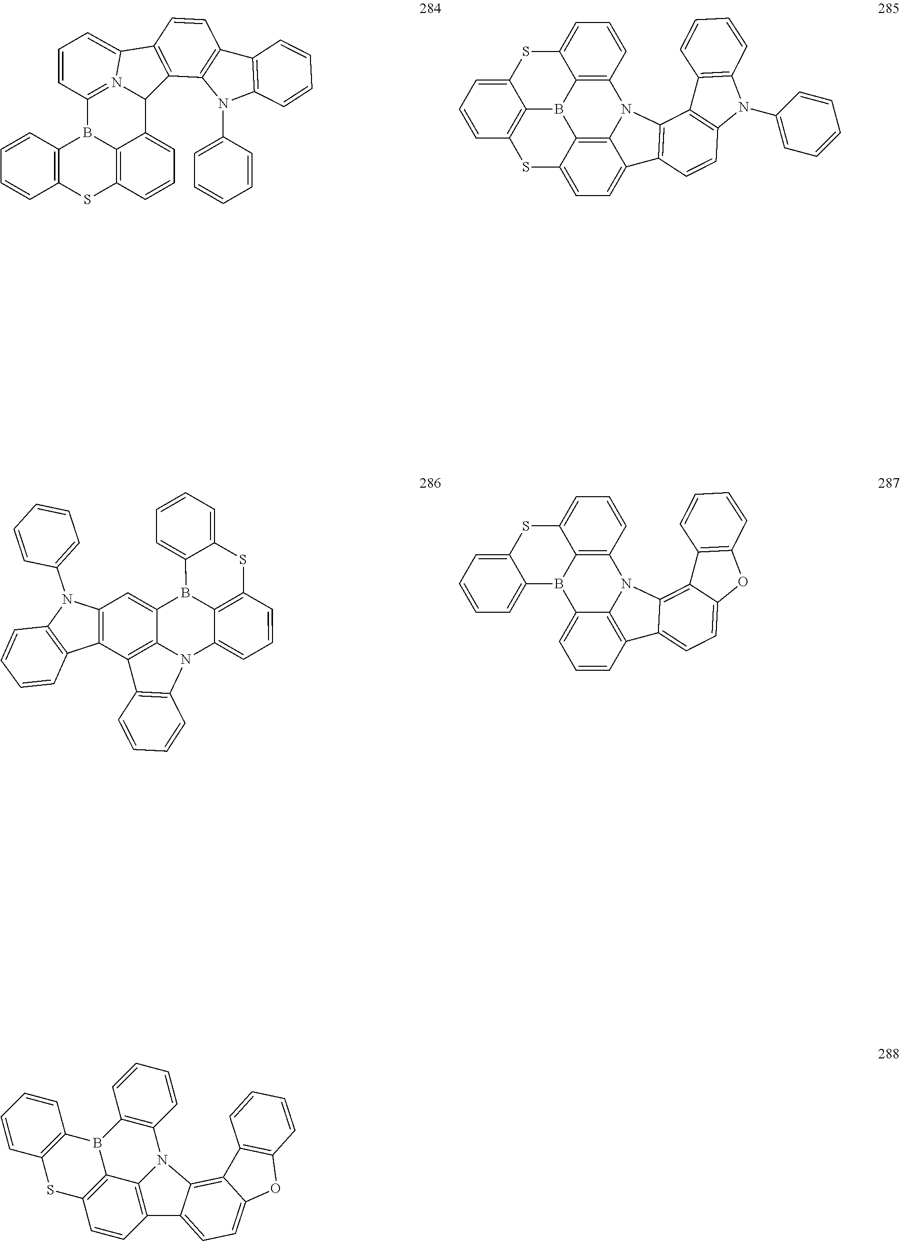

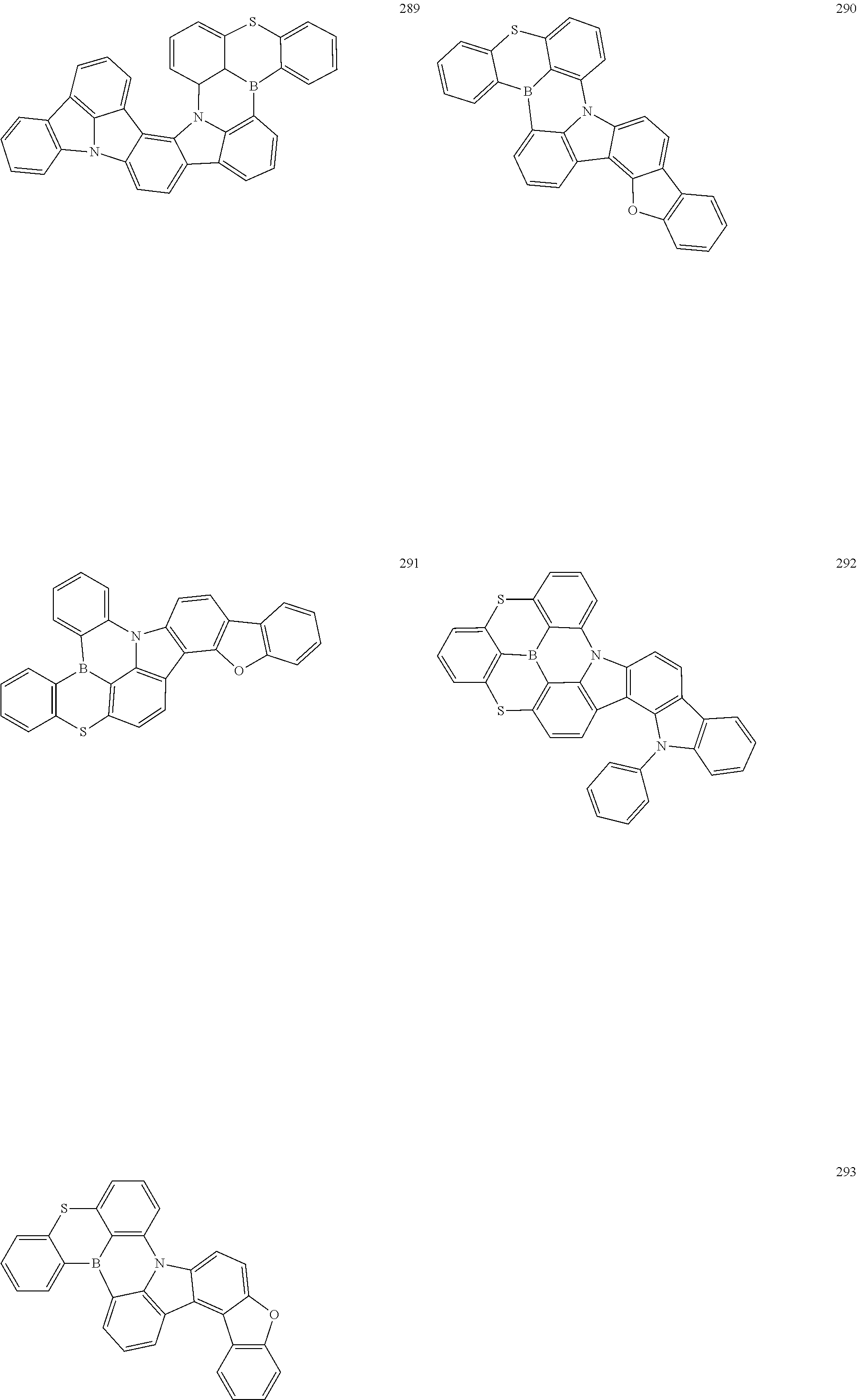 [SMILES: C1=CC2C3B(c4ccccc4SC3=C1)c1cccc3c4ccc5c(c6cccc7c8ccccc8n5c76)c4n2c13 ; c1ccc2c(c1)Sc1cccc3c1B2c1cccc2c4c5oc6ccccc6c5ccc4n-3c12 ; c1ccc2c(c1)Sc1ccc3c4c5oc6ccccc6c5ccc4n4c3c1B2c1ccccc1-4 ; c1ccc(-n2c3ccccc3c3ccc4c(c5ccc6c7c5n4-c4cccc5c4B7c4c(cccc4S6)S5)c32)cc1 ; c1ccc2c(c1)Sc1cccc3c1B2c1cccc2c4c5c(ccc4n-3c12)oc1ccccc15]

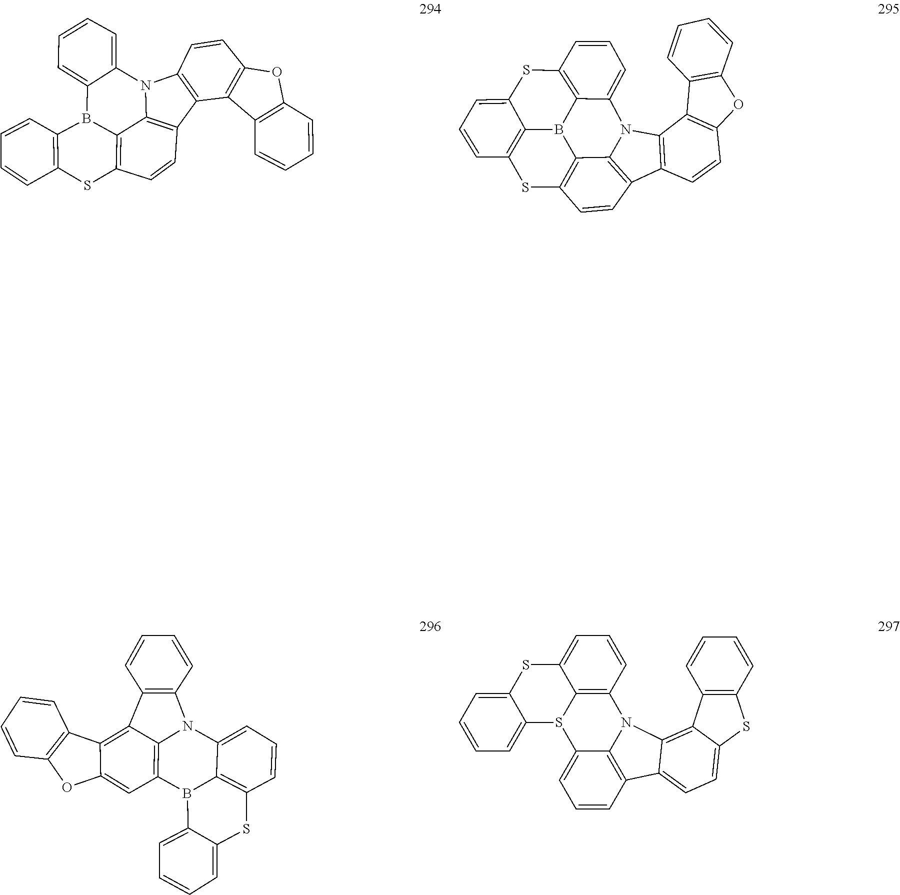

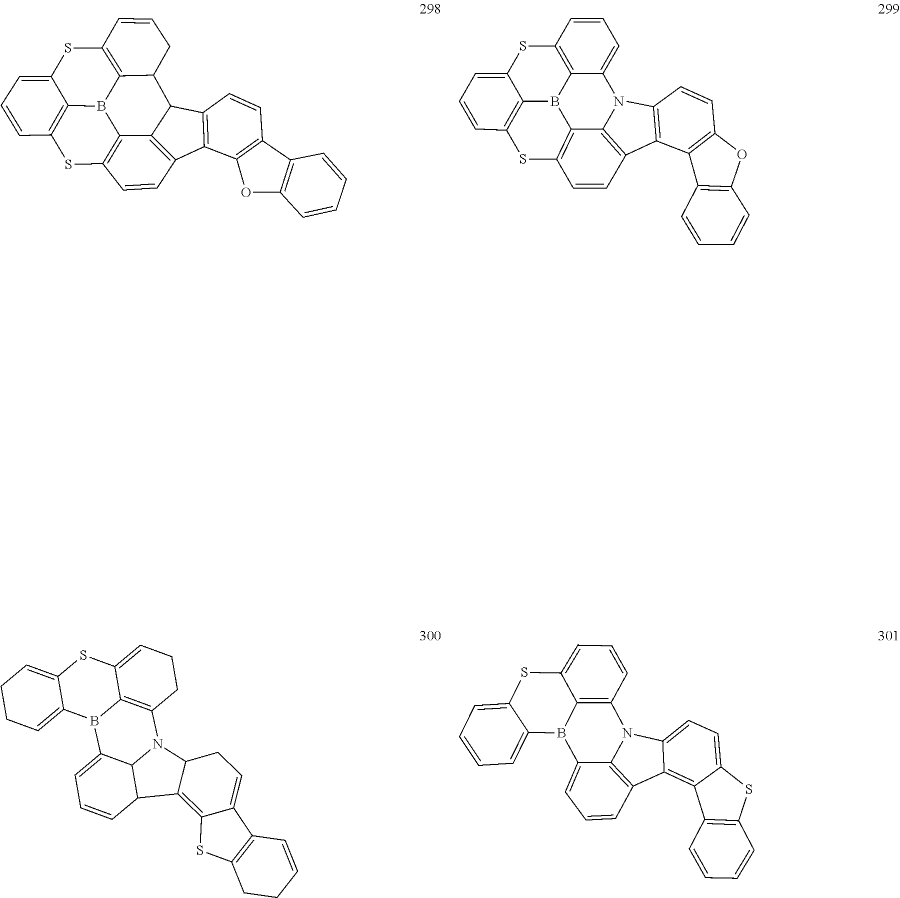

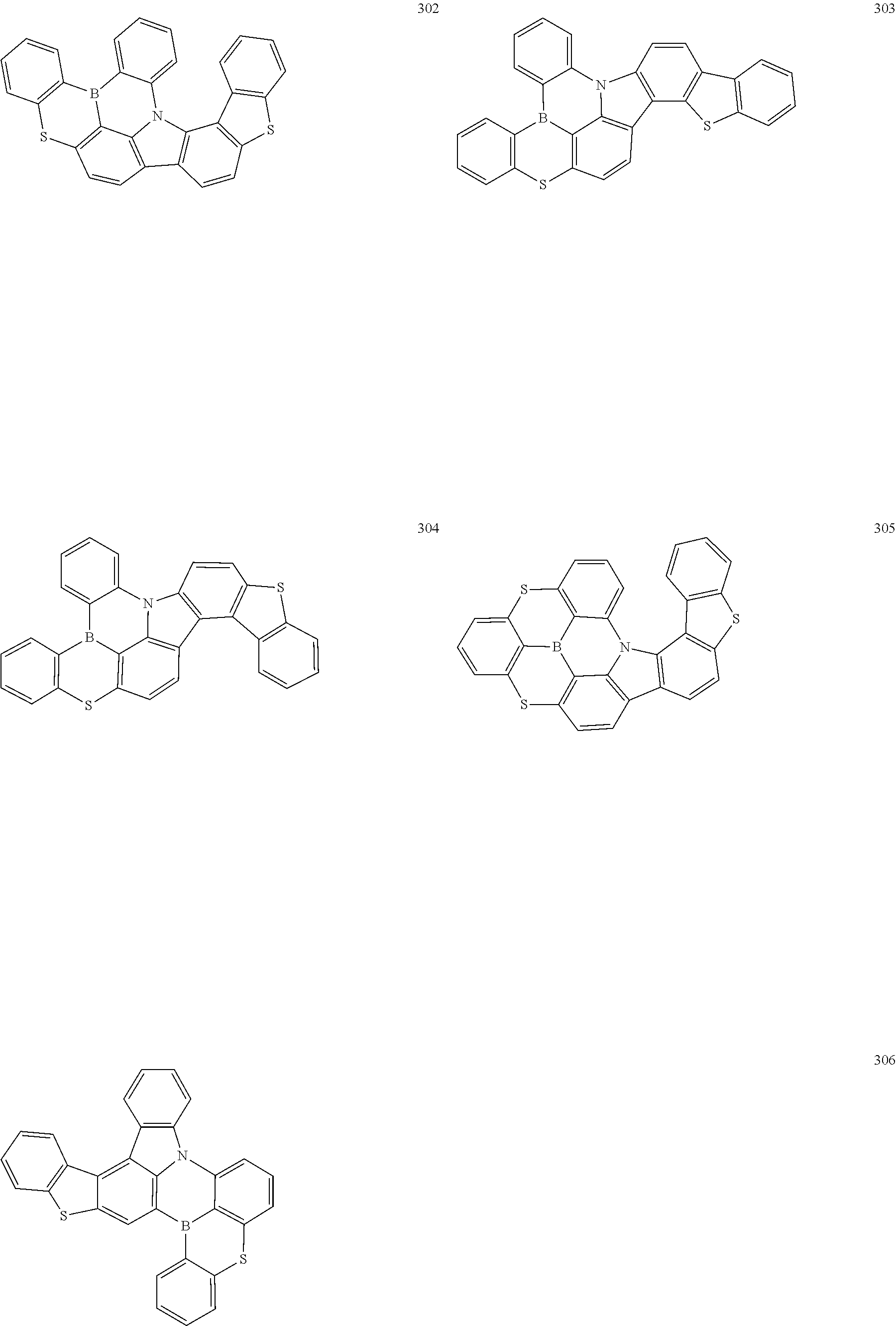

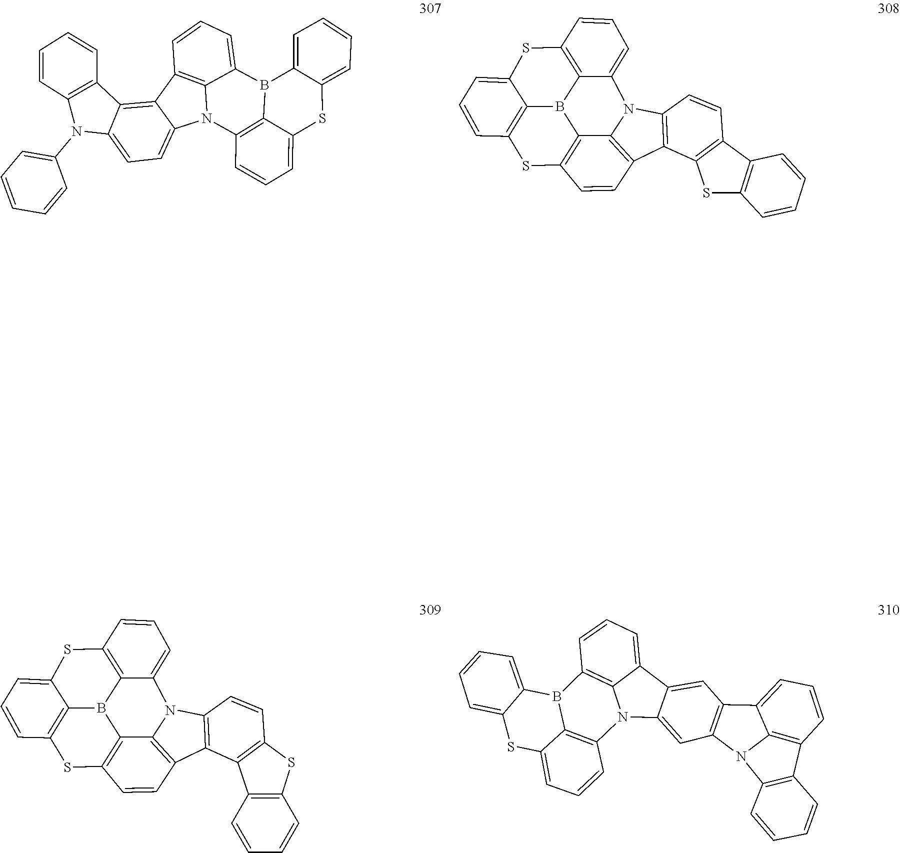 [SMILES: c1ccc(-n2c3ccccc3c3c4c5cccc6c5n(c4ccc32)-c2cccc3c2B6c2ccccc2S3)cc1 ; c1cc2c3c(c1)Sc1ccc4c5c6sc7ccccc7c6ccc5n5c4c1B3c1c(cccc1-5)S2 ; c1cc2c3c(c1)Sc1ccc4c5c6c(ccc5n5c4c1B3c1c(cccc1-5)S2)sc1ccccc16 ; c1ccc2c(c1)Sc1cccc3c1B2c1cccc2c4cc5c6cccc7c8ccccc8n(c5cc4n-3c12)c76]

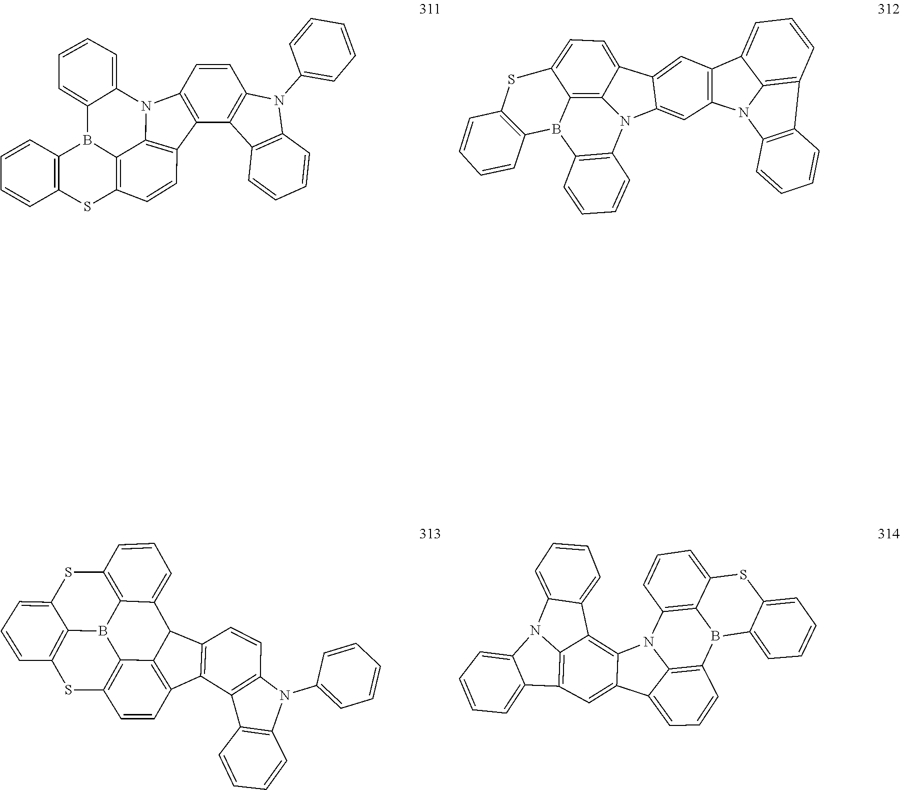

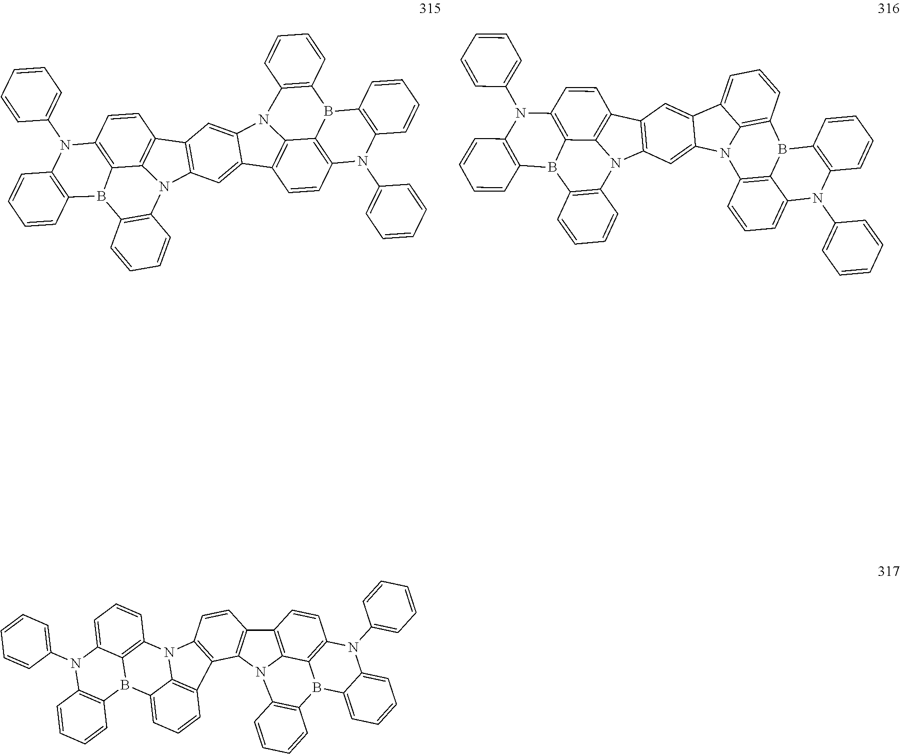 [SMILES: c1ccc(N2c3ccccc3B3c4ccccc4-n4c5cc6c7ccc8c9c7n(c6cc5c5ccc2c3c54)-c2ccccc2B9c2ccccc2N8c2ccccc2)cc1 ; c1ccc(N2c3ccccc3B3c4c2cccc4-n2c4cc5c(cc4c4cccc3c42)c2ccc3c4c2n5-c2ccccc2B4c2ccccc2N3c2ccccc2)cc1 ; c1ccc(N2c3ccccc3B3c4c2cccc4-n2c4ccc5c6ccc7c8c6n(c5c4c4cccc3c42)-c2ccccc2B8c2ccccc2N7c2ccccc2)cc1]

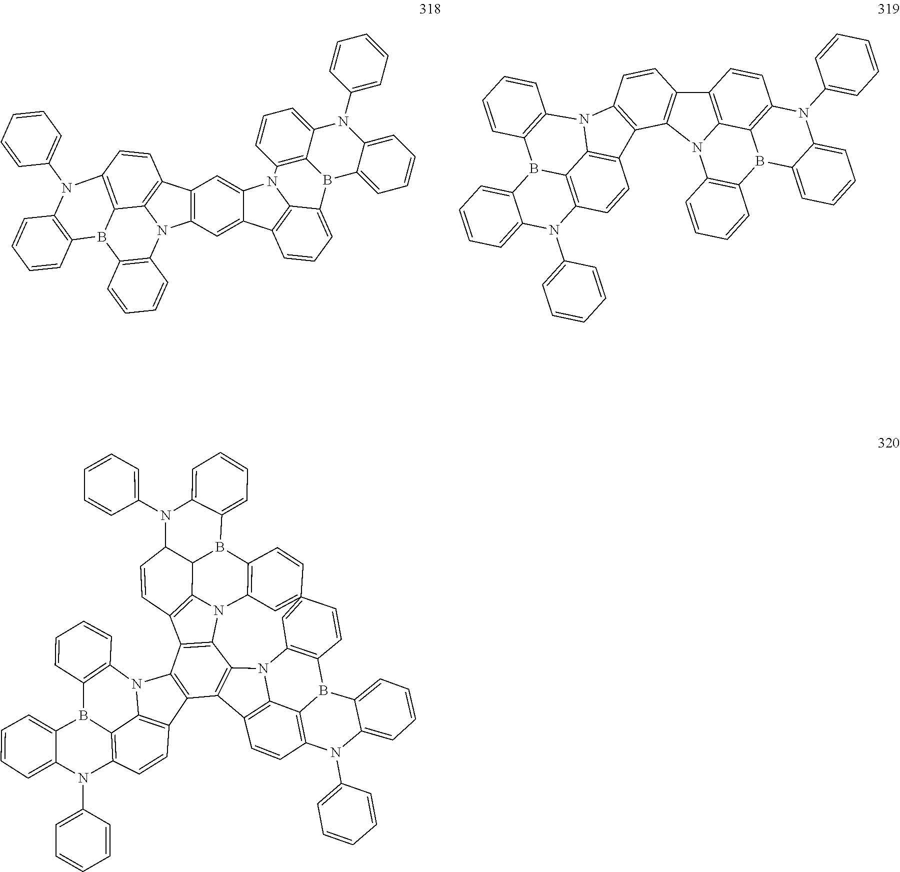

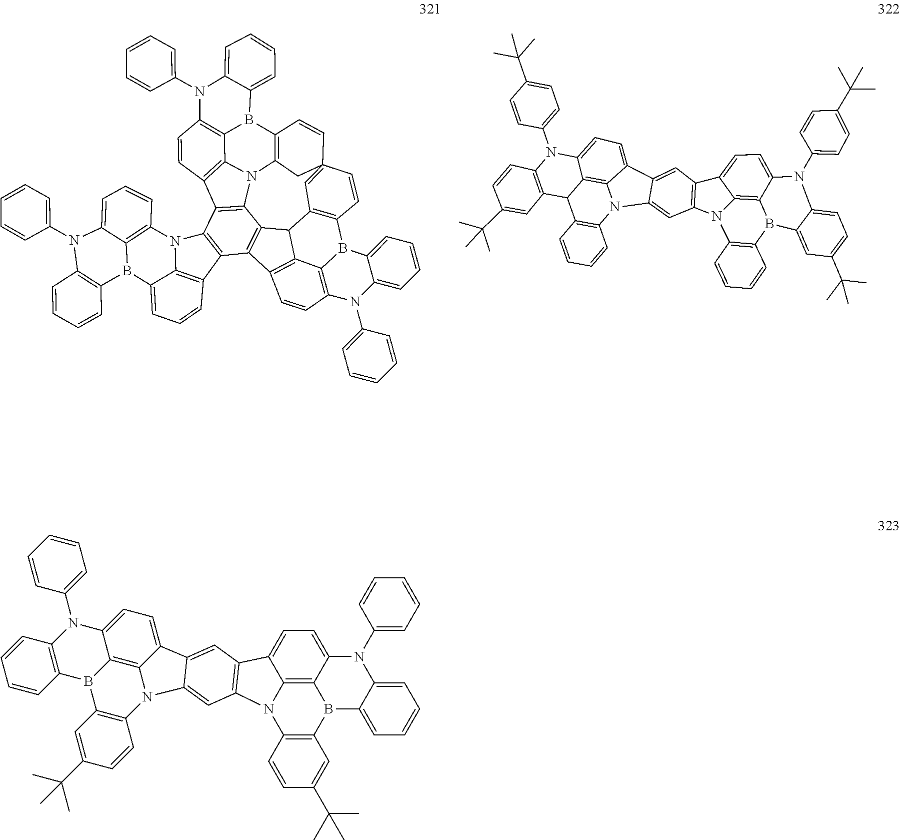

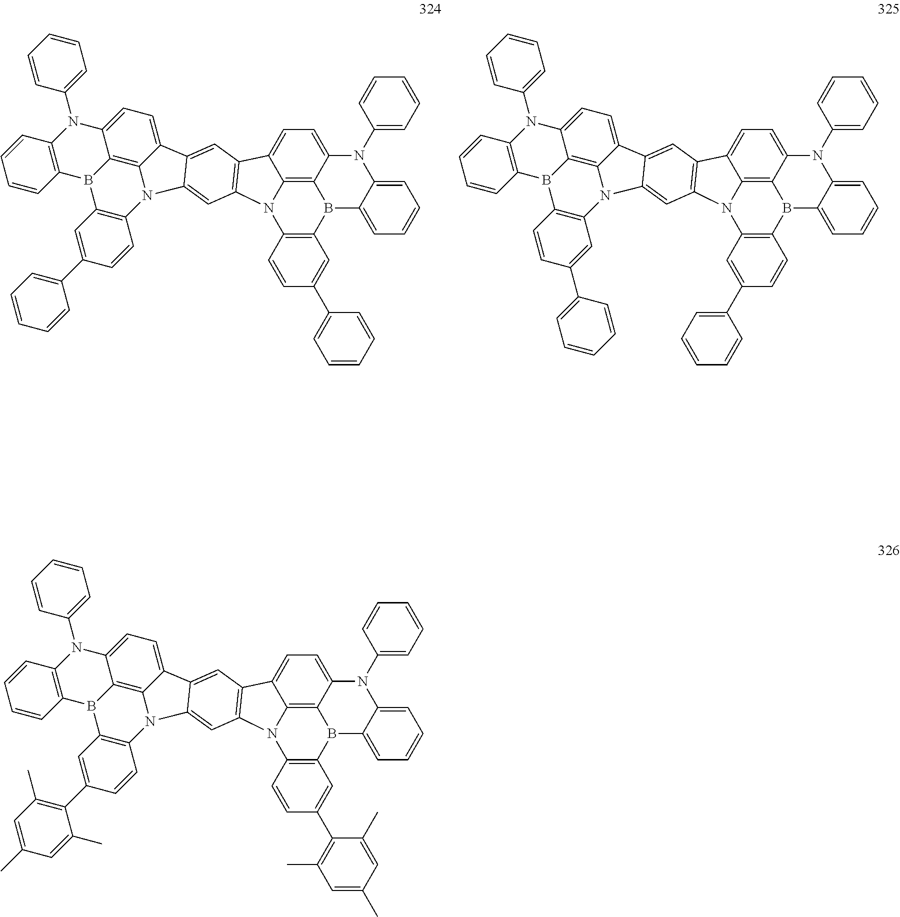 [SMILES: c1ccc(-c2ccc3c(c2)B2c4ccccc4N(c4ccccc4)c4ccc5c6cc7c8ccc9c%10c8n(c7cc6n-3c5c42)-c2ccc(-c3ccccc3)cc2B%10c2ccccc2N9c2ccccc2)cc1 ; c1ccc(-c2ccc3c(c2)-n2c4cc5c(cc4c4ccc6c(c42)B3c2ccccc2N6c2ccccc2)c2ccc3c4c2n5-c2cc(-c5ccccc5)ccc2B4c2ccccc2N3c2ccccc2)cc1 ; Cc1cc(C)c(-c2ccc3c(c2)B2c4ccccc4N(c4ccccc4)c4ccc5c6cc7c8ccc9c%10c8n(c7cc6n-3c5c42)-c2ccc(-c3c(C)cc(C)cc3C)cc2B%10c2ccccc2N9c2ccccc2)c(C)c1]

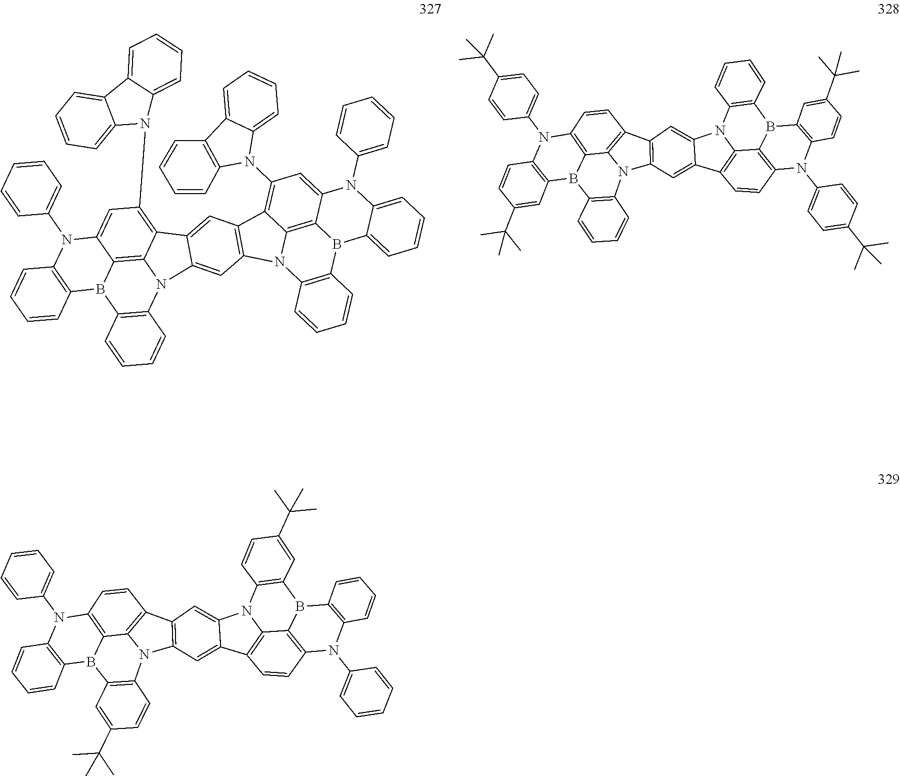 [SMILES: c1ccc(N2c3ccccc3B3c4ccccc4-n4c5cc6c(cc5c5c(-n7c8ccccc8c8ccccc87)cc2c3c54)c2c(-n3c4ccccc4c4ccccc43)cc3c4c2n6-c2ccccc2B4c2ccccc2N3c2ccccc2)cc1 ; CC(C)(C)c1ccc(N2c3ccc(C(C)(C)C)cc3B3c4ccccc4-n4c5cc6c7ccc8c9c7n(c6cc5c5ccc2c3c54)-c2ccccc2B9c2cc(C(C)(C)C)ccc2N8c2ccc(C(C)(C)C)cc2)cc1 ; CC(C)(C)c1ccc2c(c1)B1c3ccccc3N(c3ccccc3)c3ccc4c5cc6c(cc5n-2c4c31)c1ccc2c3c1n6-c1ccc(C(C)(C)C)cc1B3c1ccccc1N2c1ccccc1]

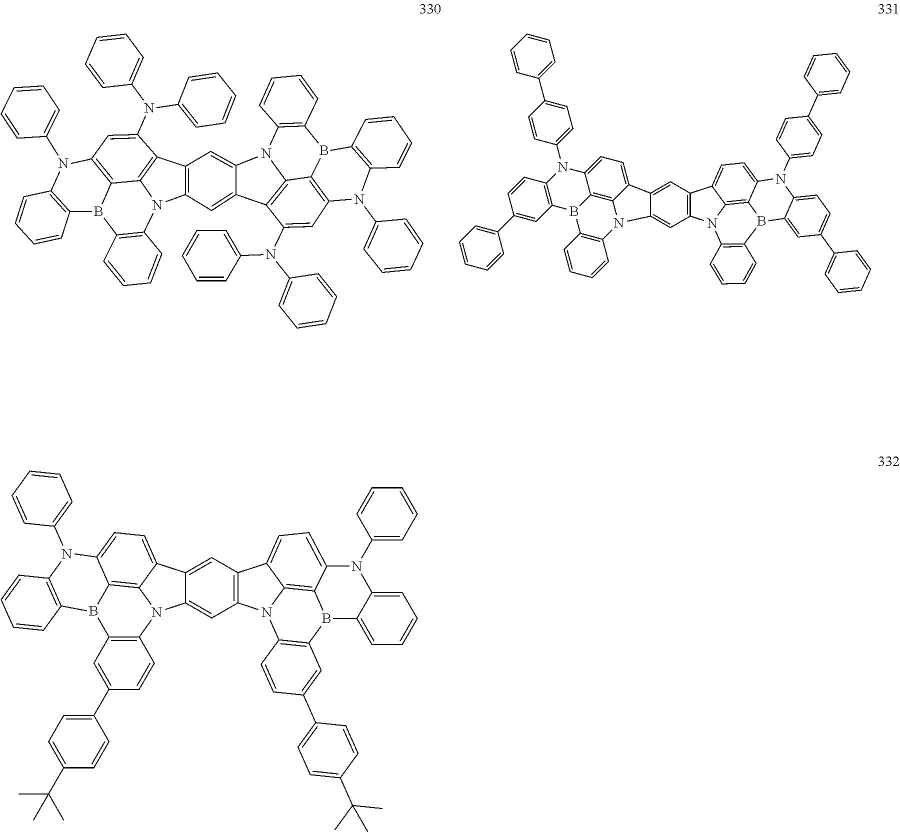

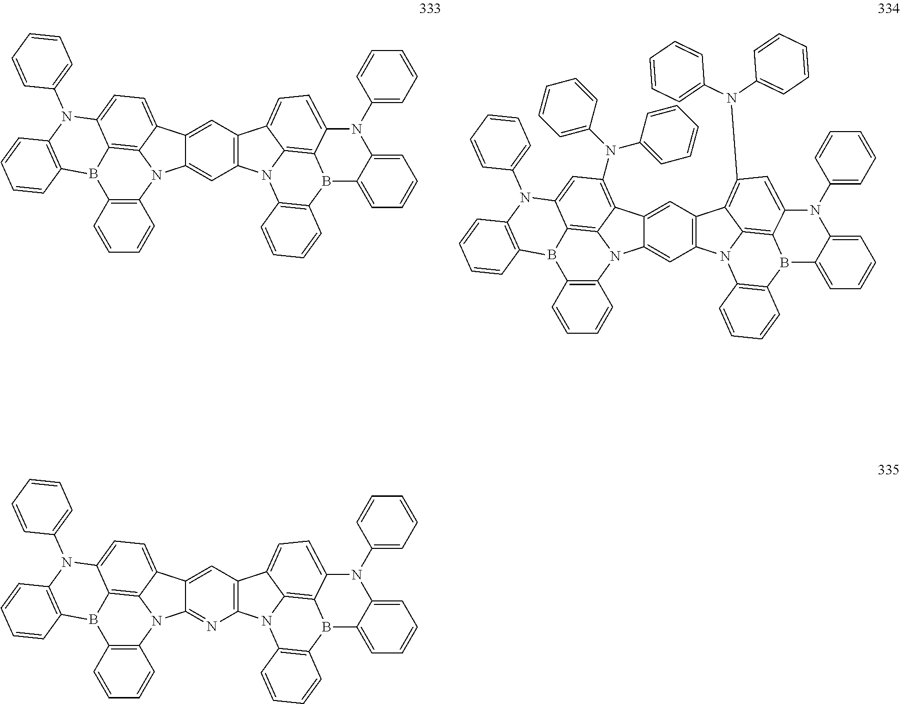 [SMILES: c1ccc(N2c3ccccc3B3c4ccccc4-n4c5cc6c(cc5c5ccc2c3c54)c2ccc3c4c2n6-c2ccccc2B4c2ccccc2N3c2ccccc2)cc1 ; c1ccc(N2c3ccccc3B3c4ccccc4-n4c5cc6c(cc5c5c(N(c7ccccc7)c7ccccc7)cc2c3c54)c2c(N(c3ccccc3)c3ccccc3)cc3c4c2n6-c2ccccc2B4c2ccccc2N3c2ccccc2)cc1 ; c1ccc(N2c3ccccc3B3c4ccccc4-n4c5nc6c(cc5c5ccc2c3c54)c2ccc3c4c2n6-c2ccccc2B4c2ccccc2N3c2ccccc2)cc1]

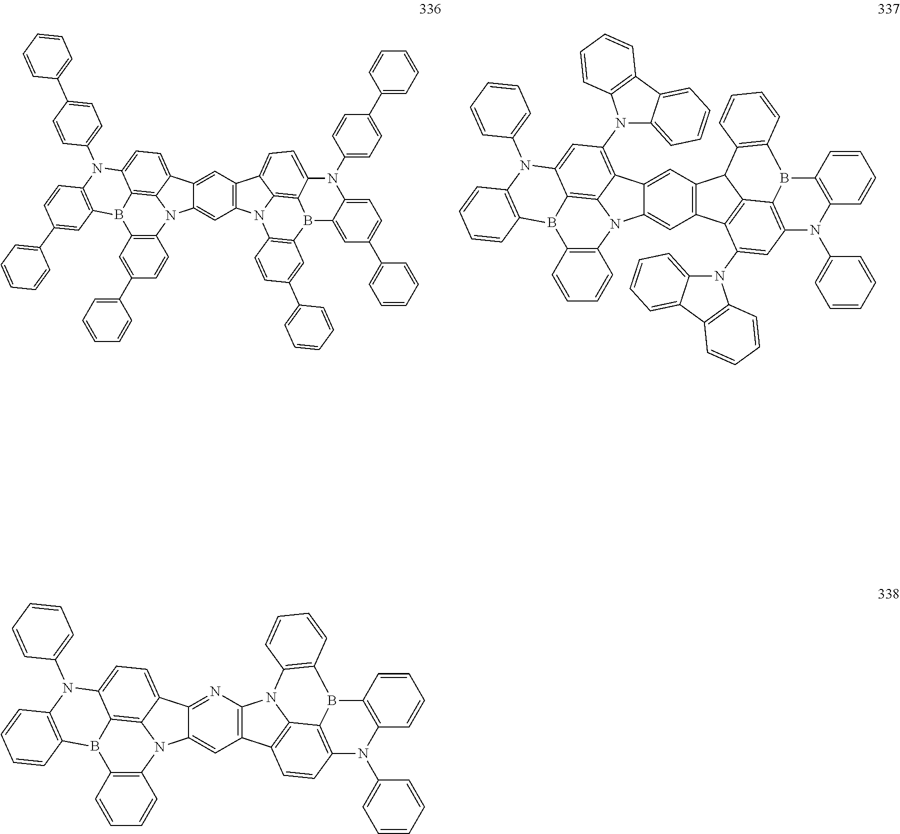 [SMILES: c1ccc(-c2ccc(N3c4ccc(-c5ccccc5)cc4B4c5cc(-c6ccccc6)ccc5-n5c6cc7c(cc6c6ccc3c4c65)c3ccc4c5c3n7-c3ccc(-c6ccccc6)cc3B5c3cc(-c5ccccc5)ccc3N4c3ccc(-c4ccccc4)cc3)cc2)cc1 ; c1ccc(N2c3ccccc3B3c4ccccc4C4c5cc6c7c(-n8c9ccccc9c9ccccc98)cc8c9c7n(c6cc5-c5c(-n6c7ccccc7c7ccccc76)cc2c3c54)-c2ccccc2B9c2ccccc2N8c2ccccc2)cc1 ; c1ccc(N2c3ccccc3B3c4ccccc4-n4c5cc6c7ccc8c9c7n(c6nc5c5ccc2c3c54)-c2ccccc2B9c2ccccc2N8c2ccccc2)cc1]

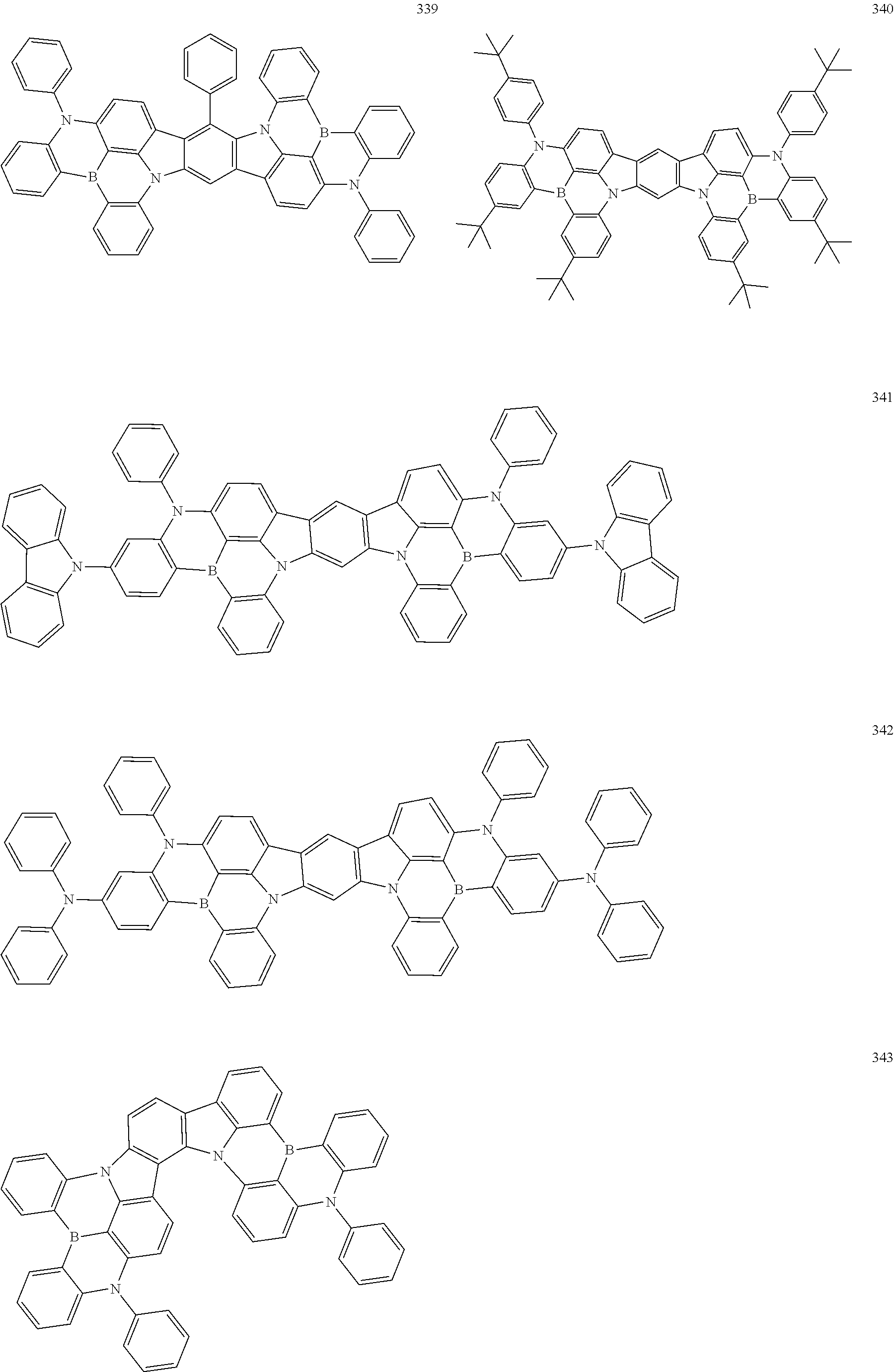

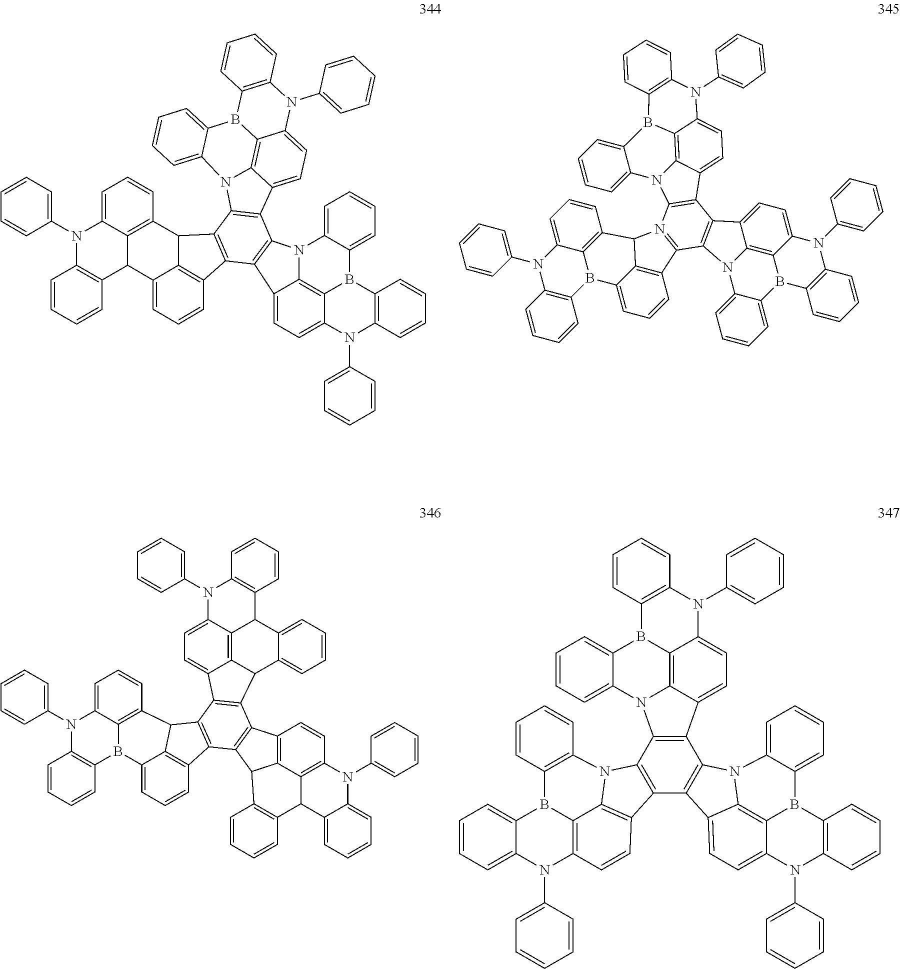

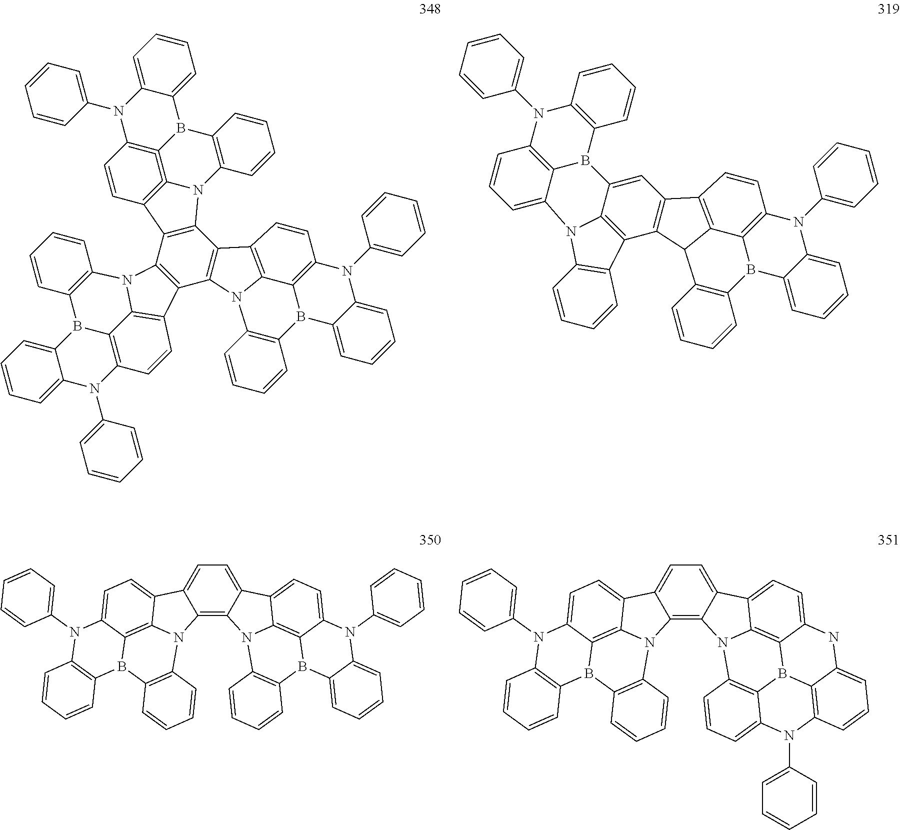

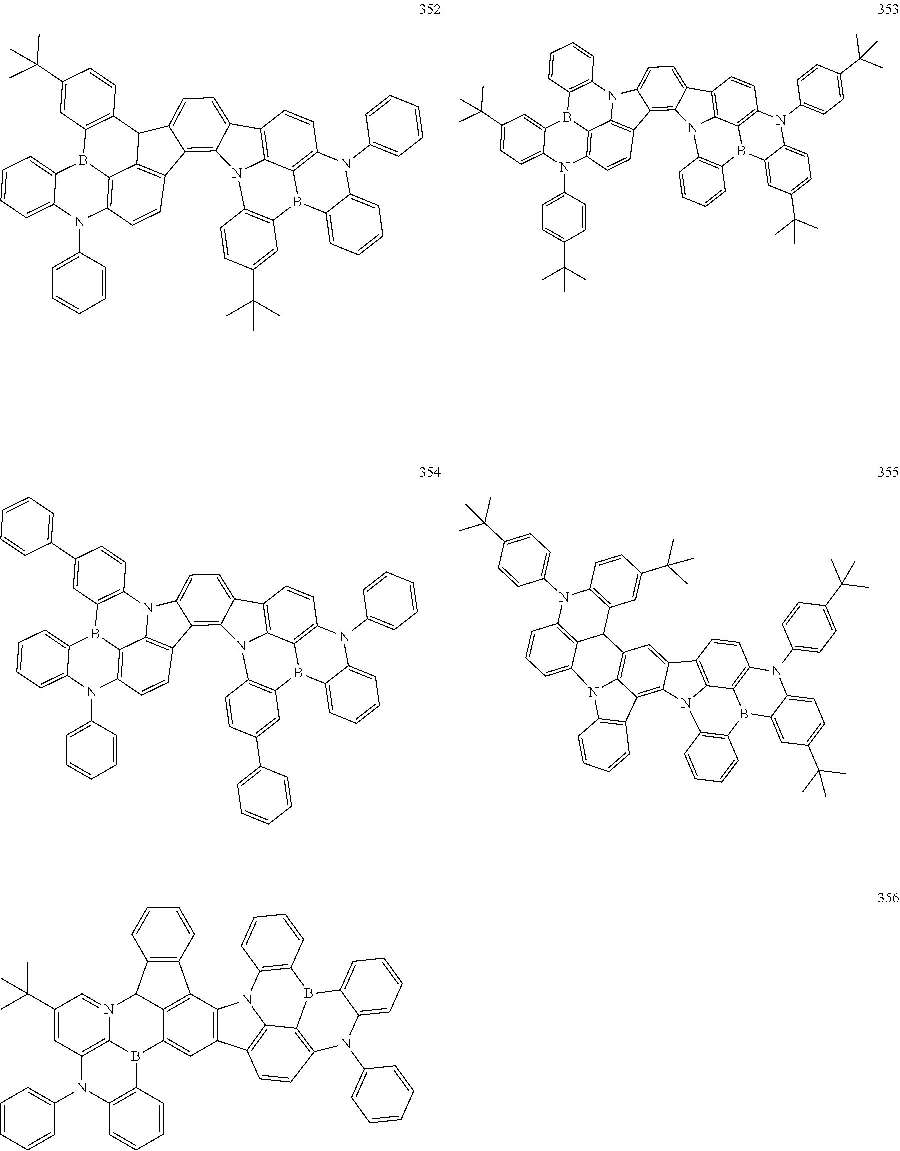

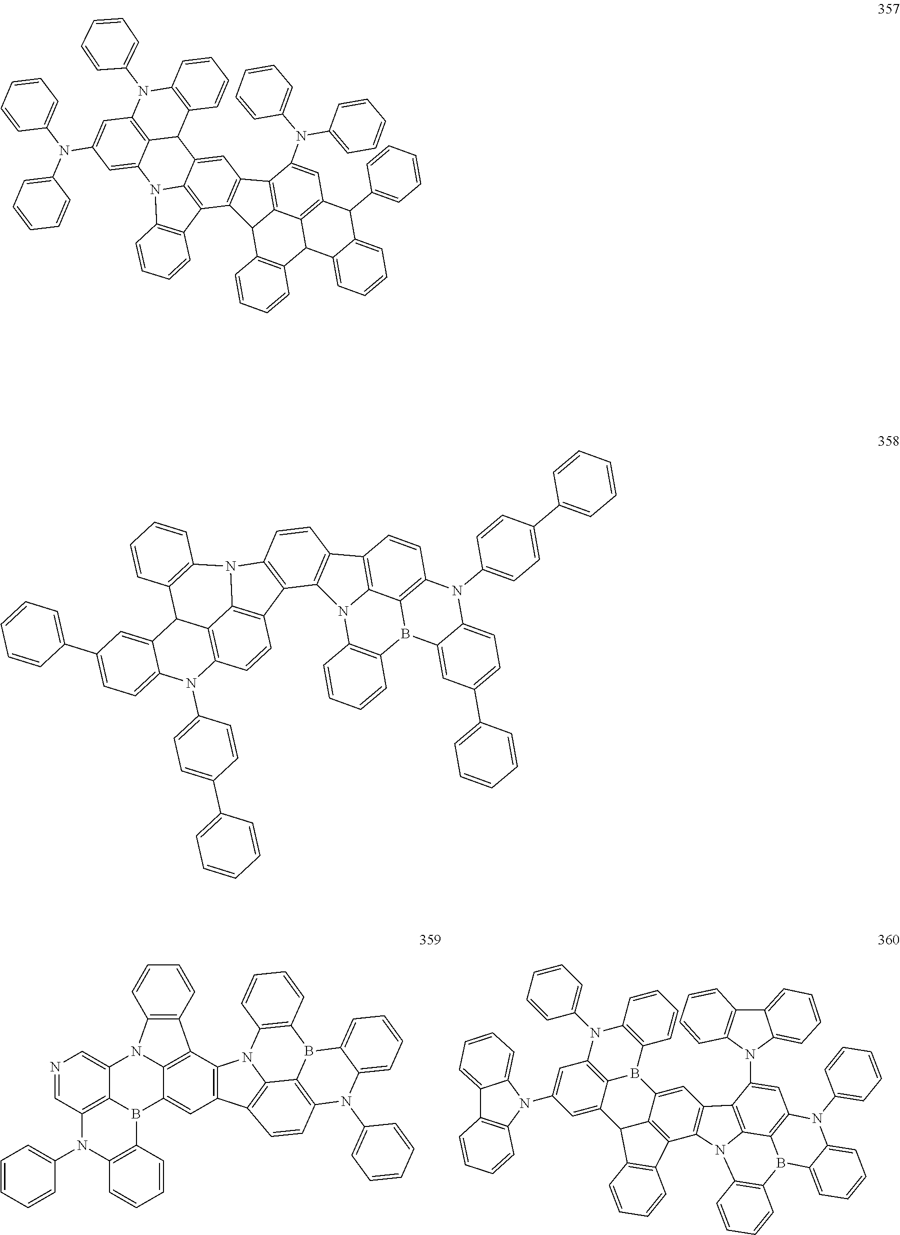

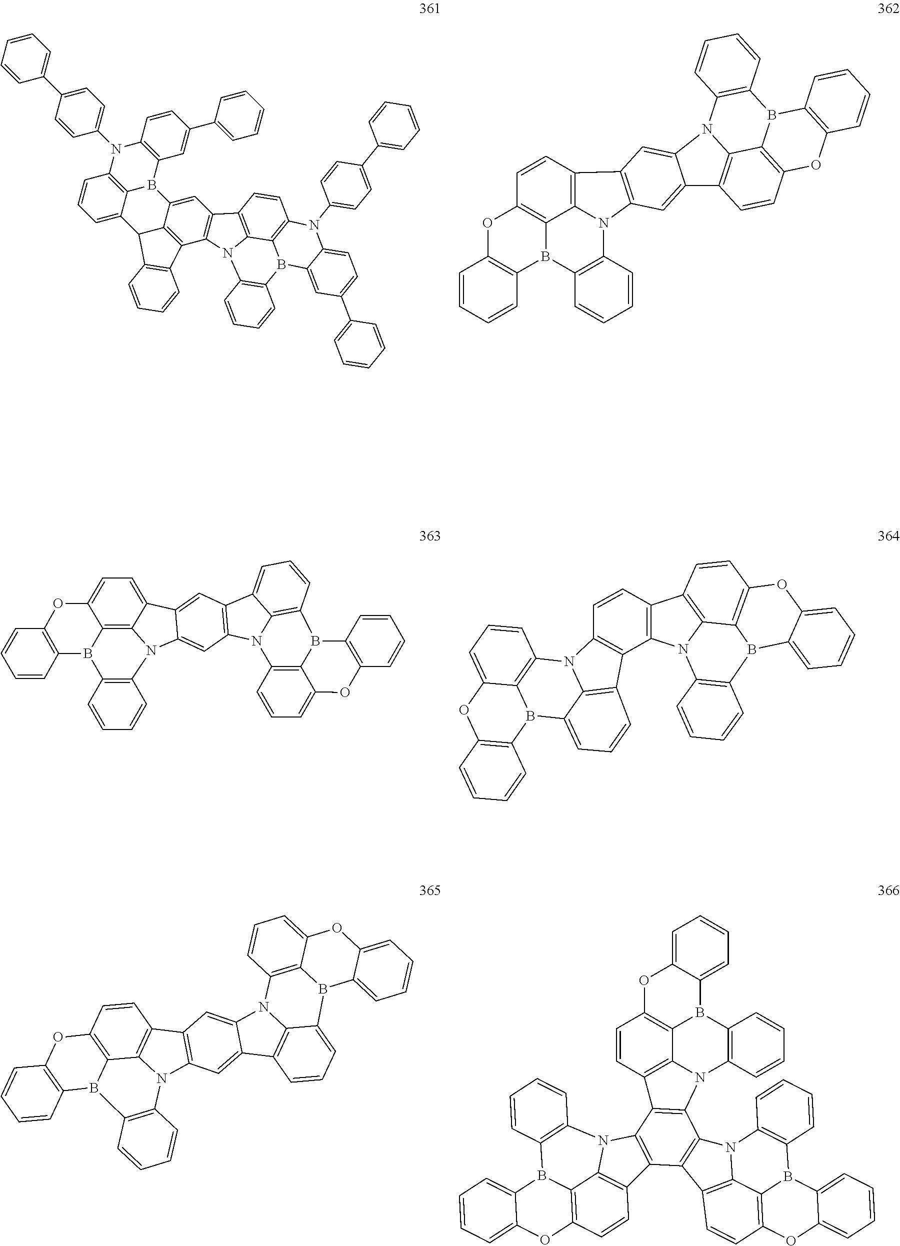

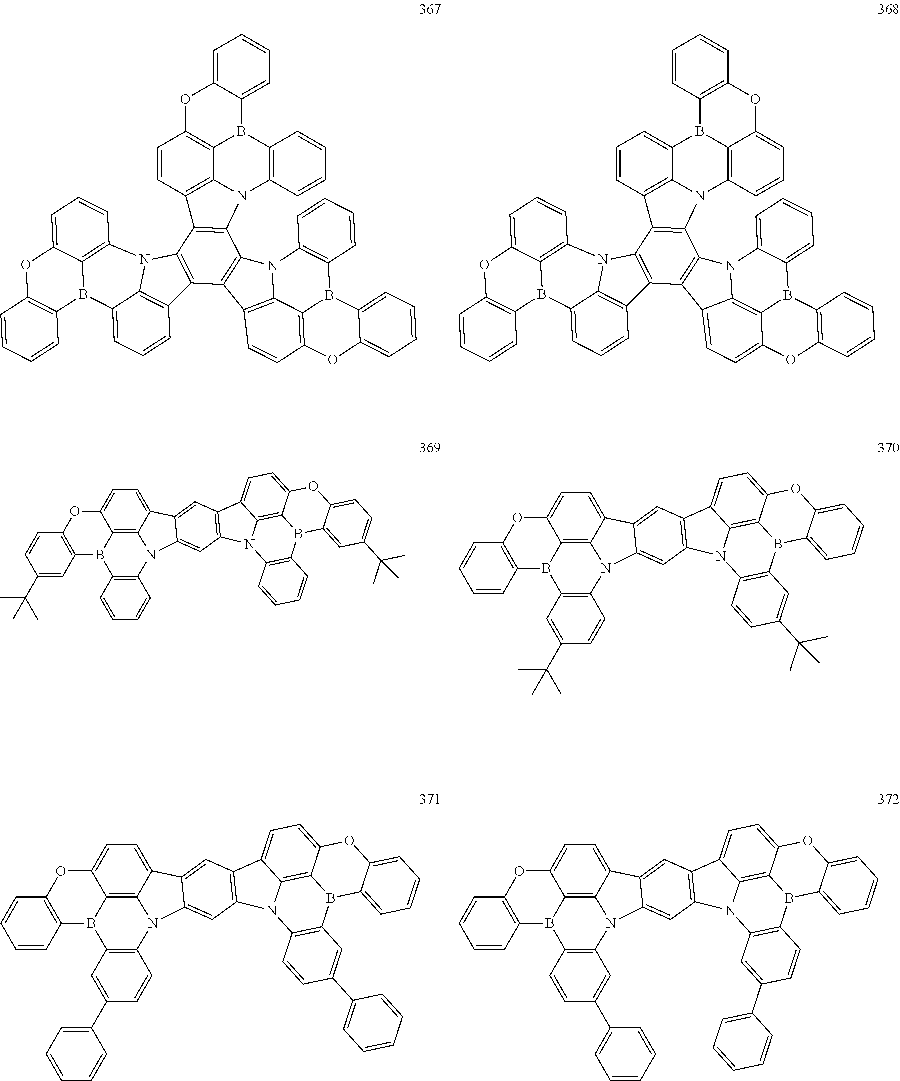

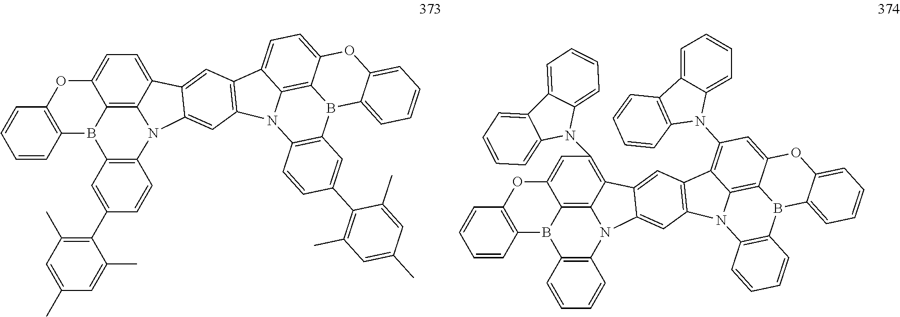 [SMILES: Cc1cc(C)c(-c2ccc3c(c2)B2c4ccccc4Oc4ccc5c6cc7c8ccc9c%10c8n(c7cc6n-3c5c42)-c2ccc(-c3c(C)cc(C)cc3C)cc2B%10c2ccccc2O9)c(C)c1 ; c1ccc2c(c1)Oc1cc(-n3c4ccccc4c4ccccc43)c3c4cc5c6c(-n7c8ccccc8c8ccccc87)cc7c8c6n(c5cc4n4c3c1B2c1ccccc1-4)-c1ccccc1B8c1ccccc1O7]

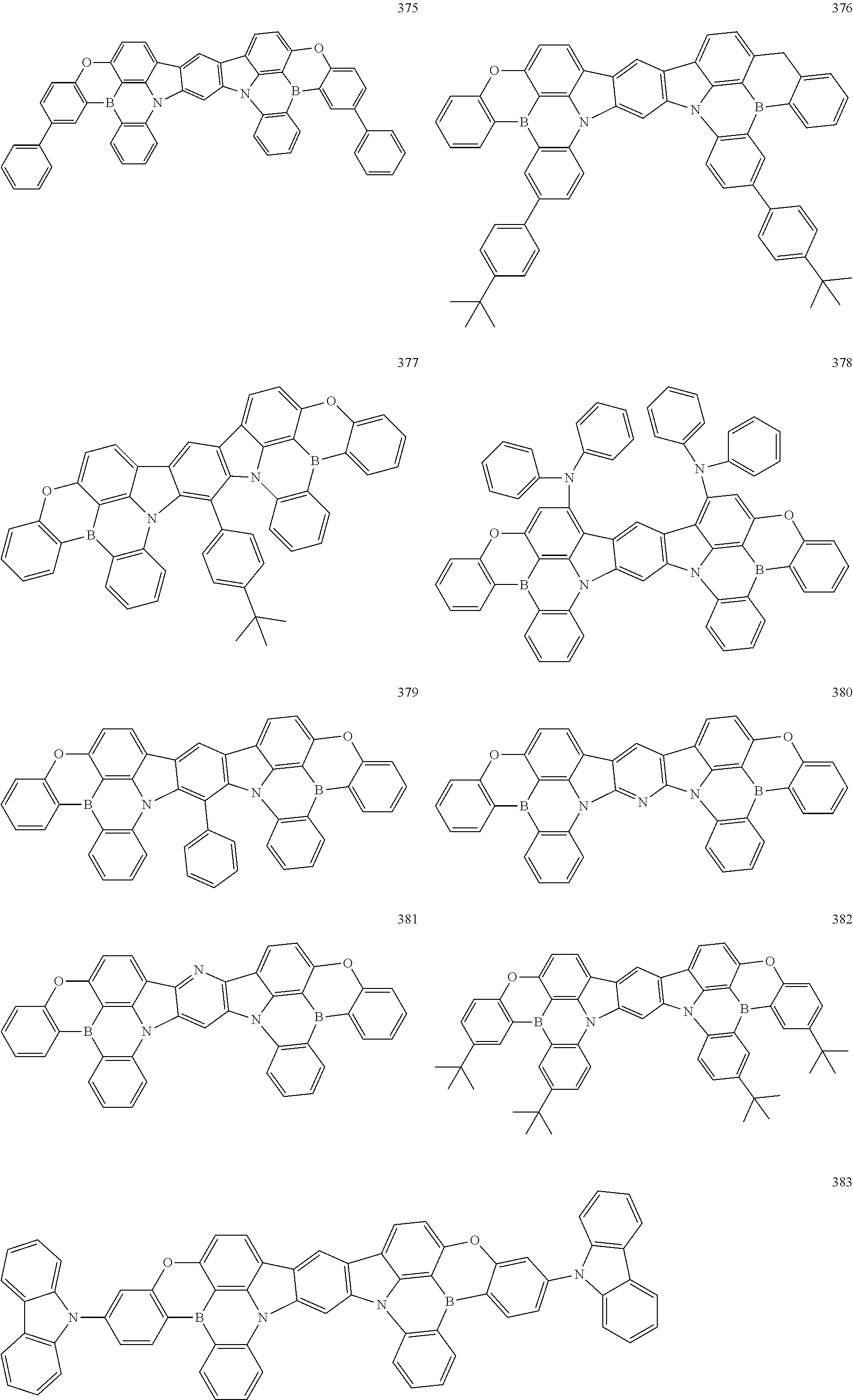

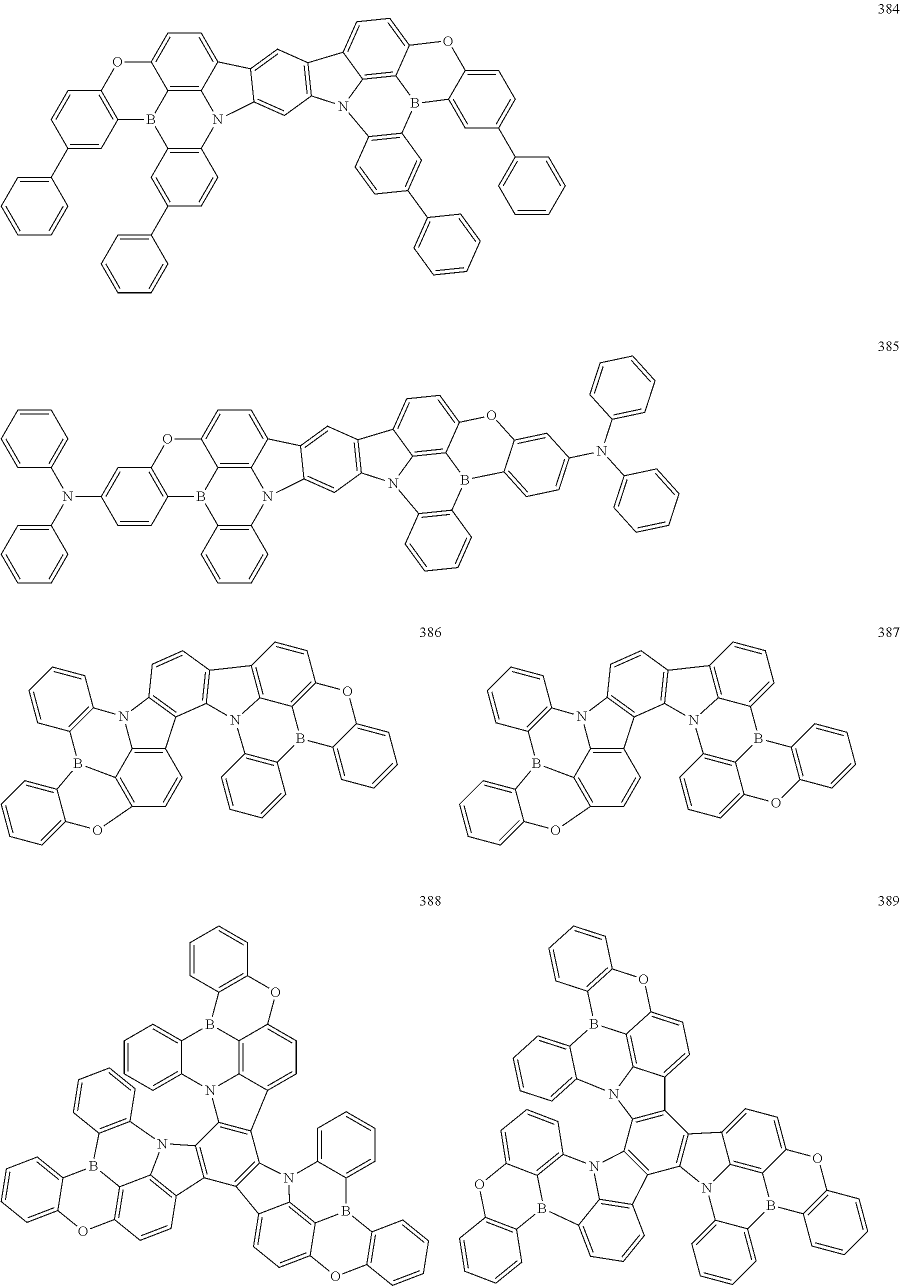

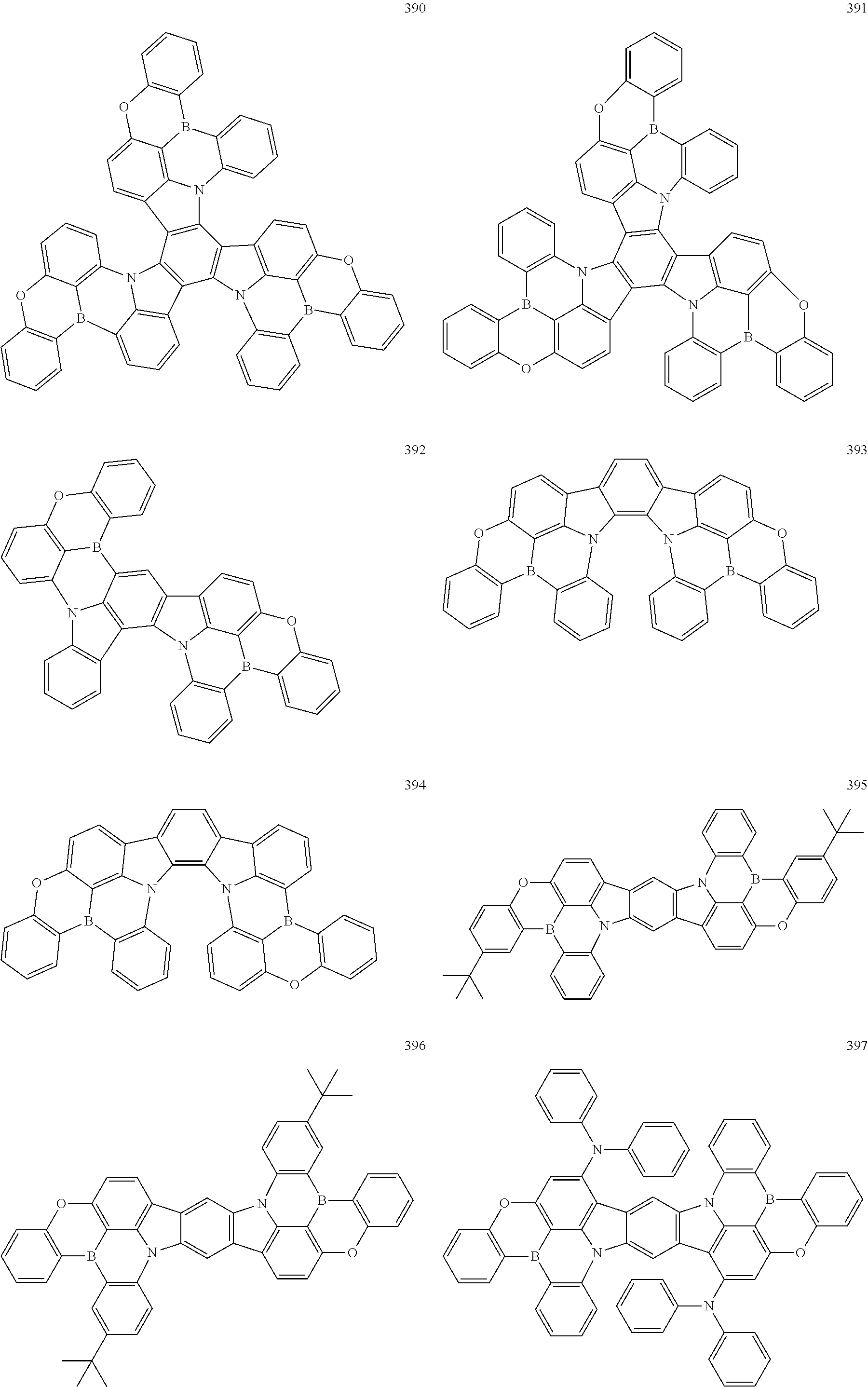

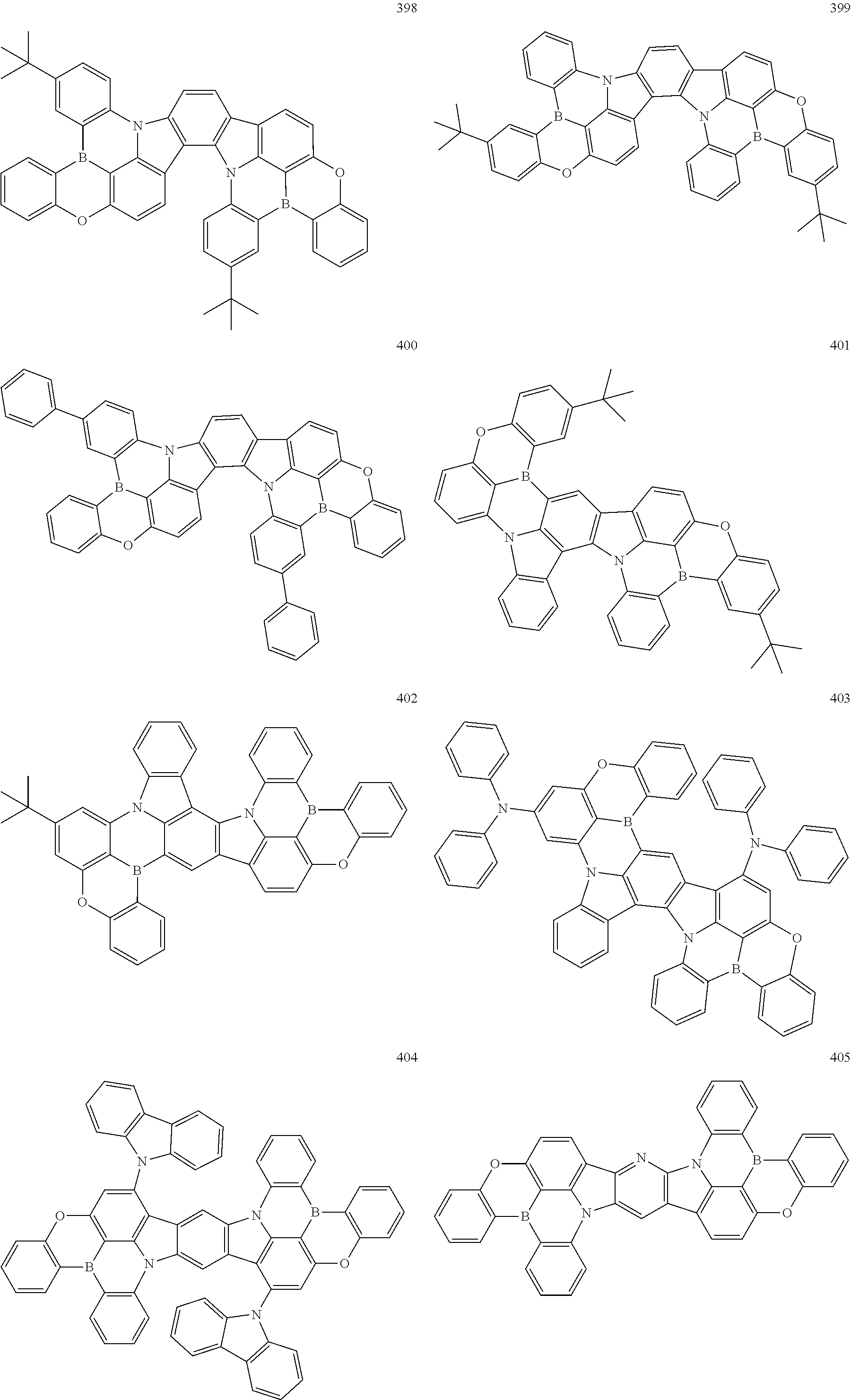

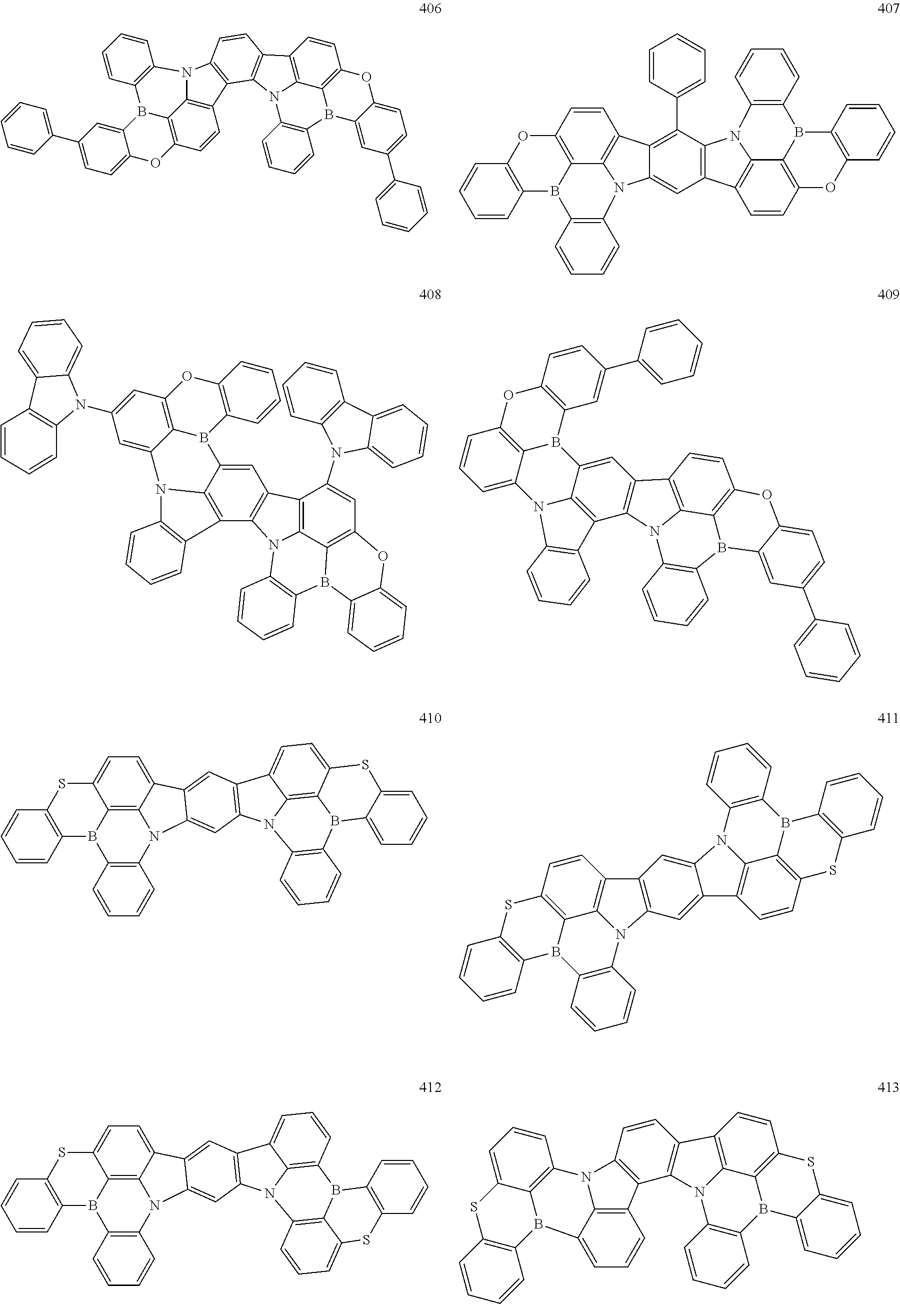

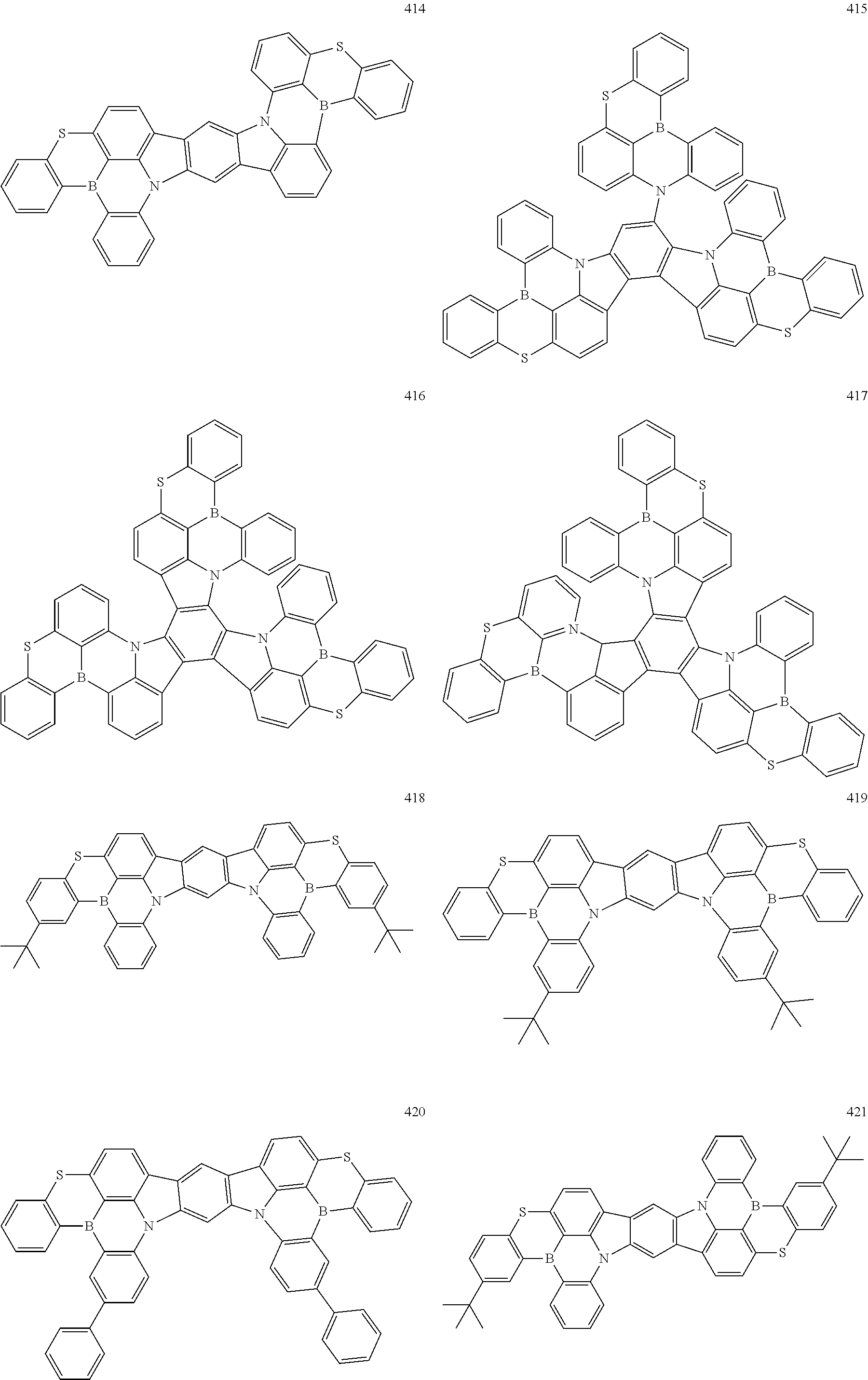

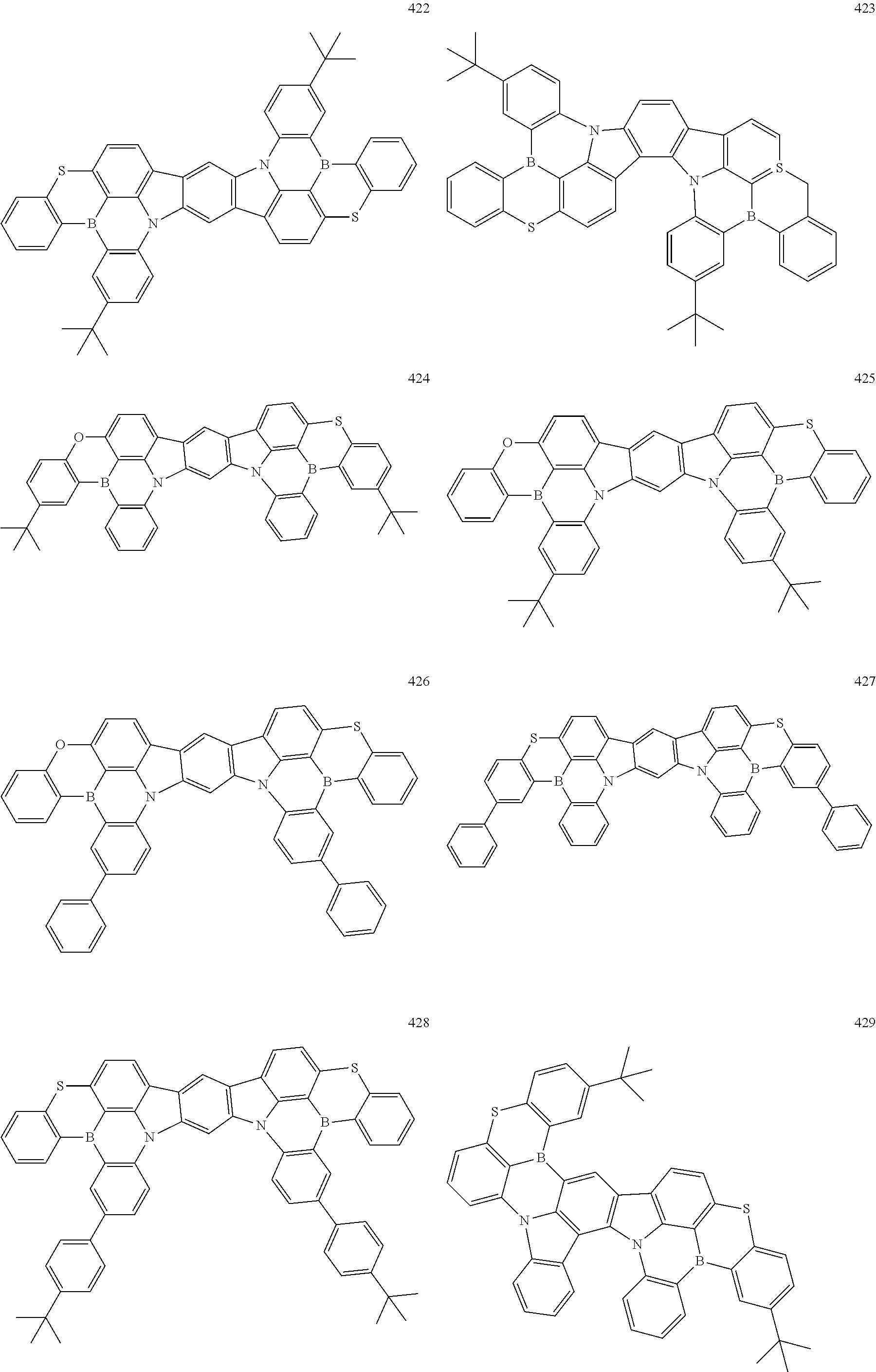

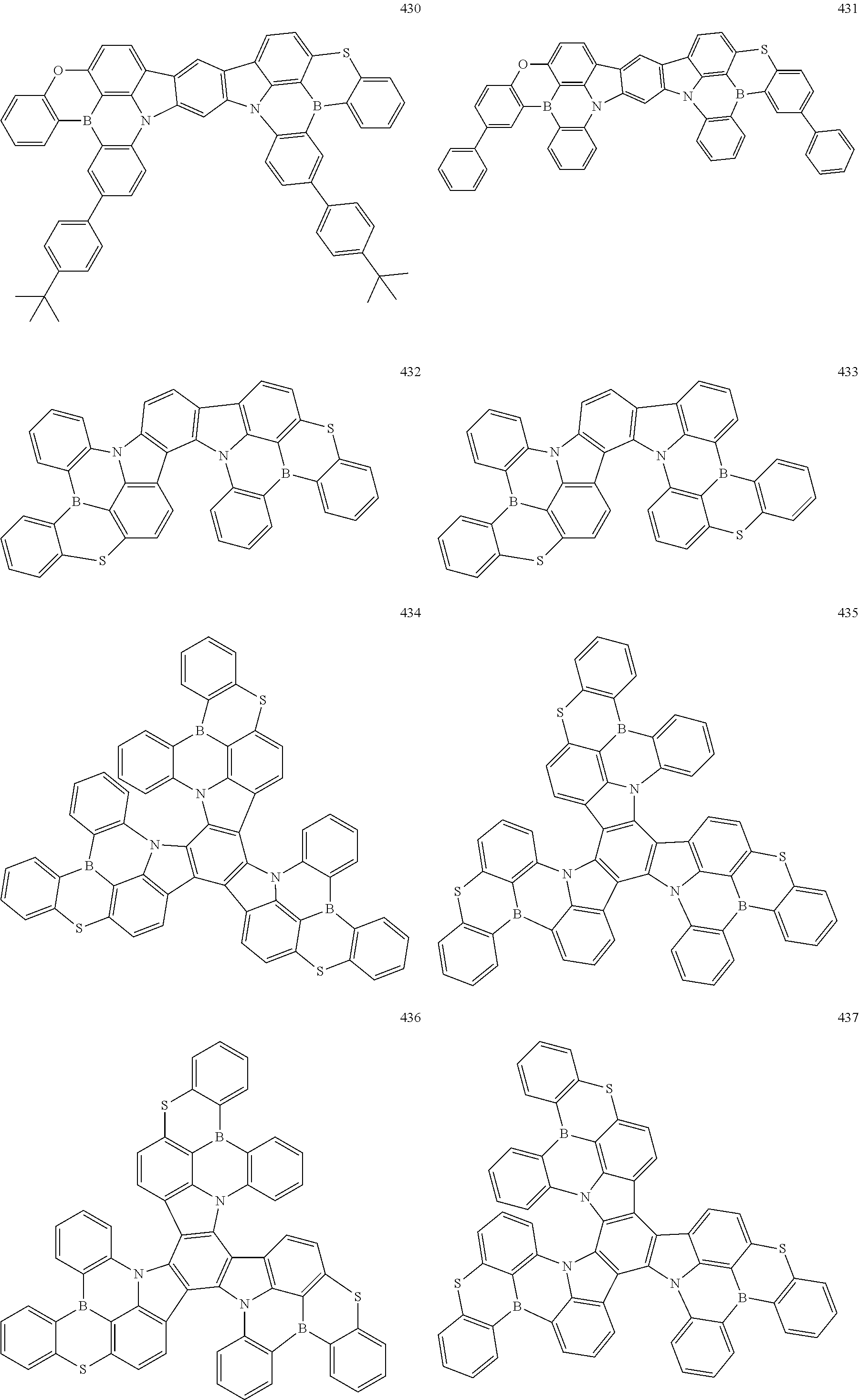

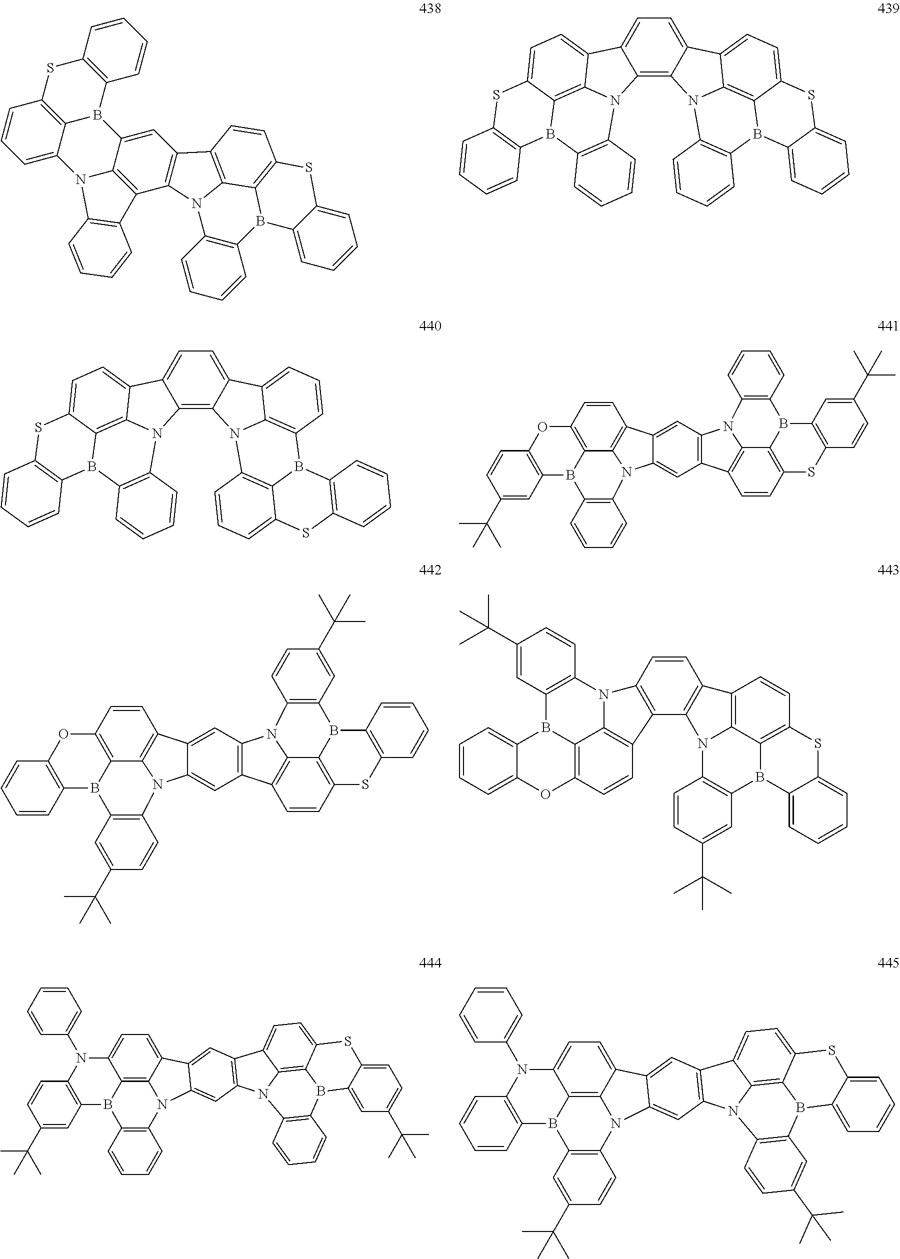

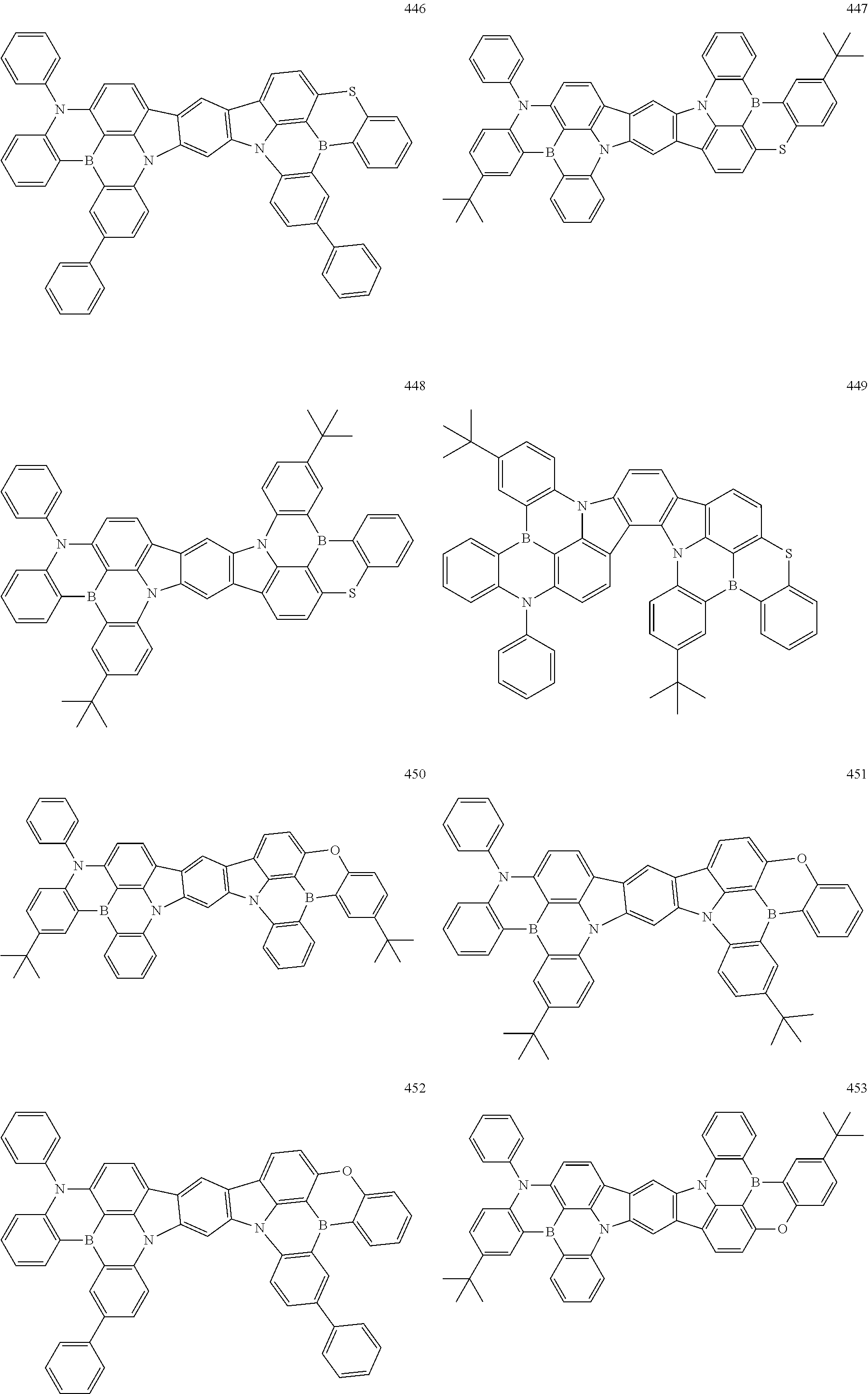

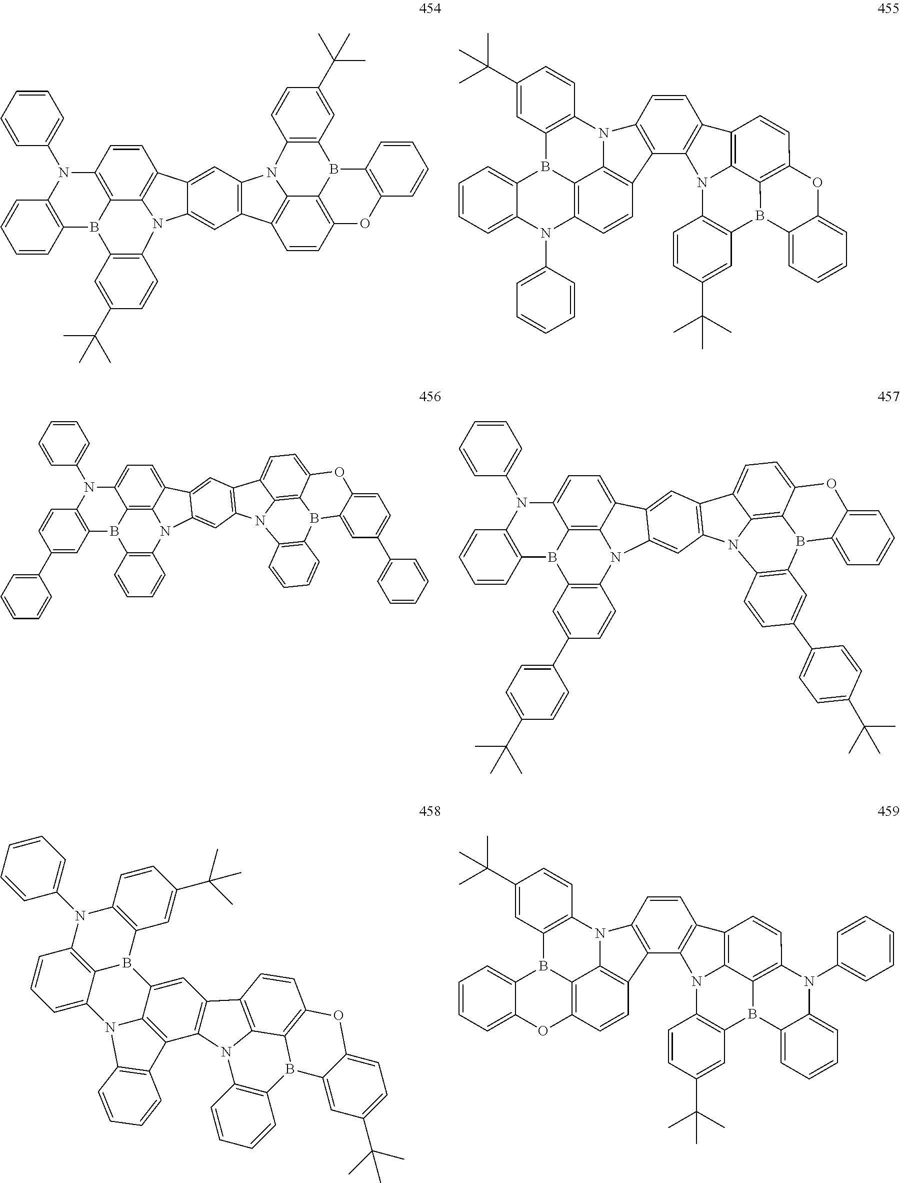

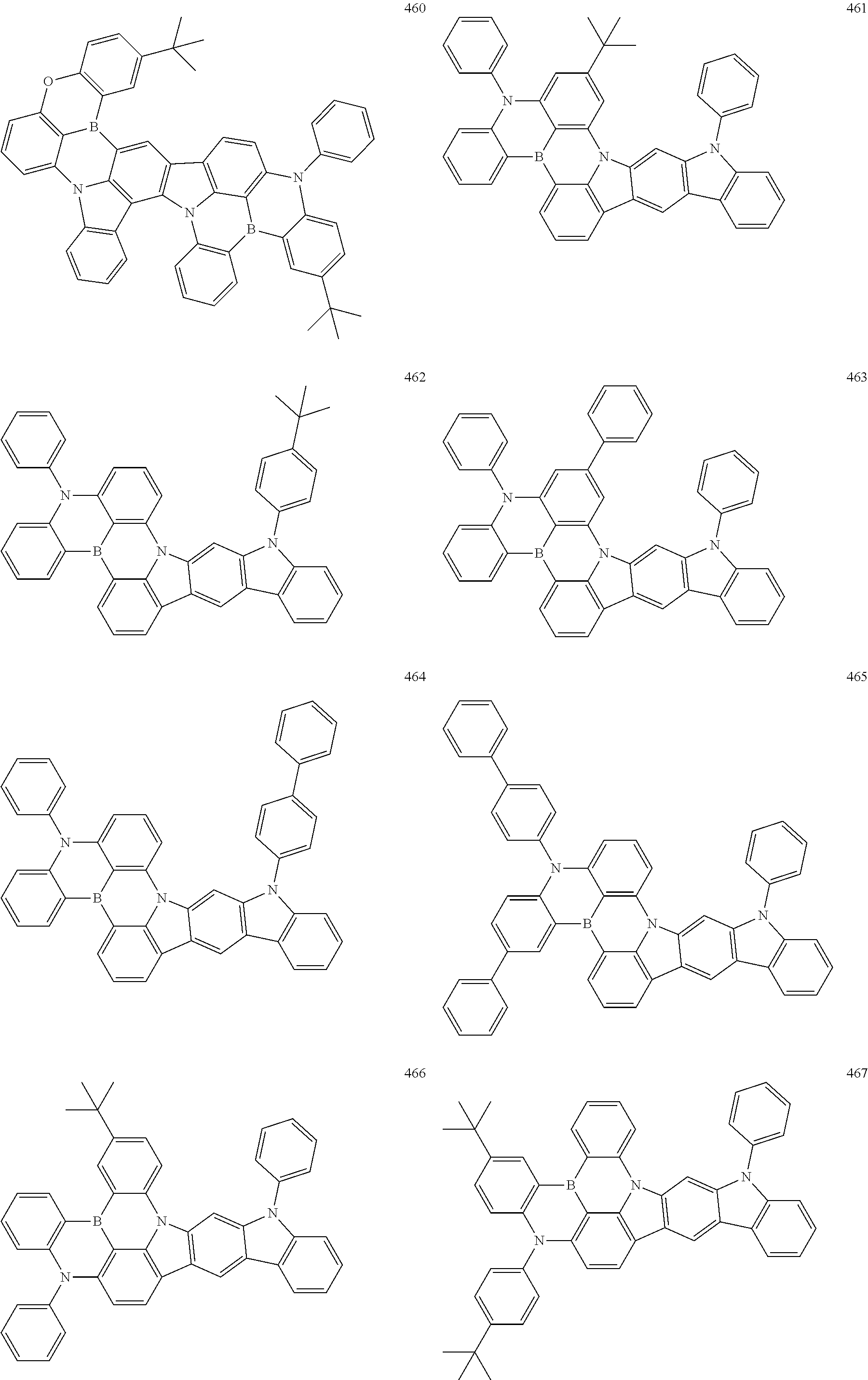

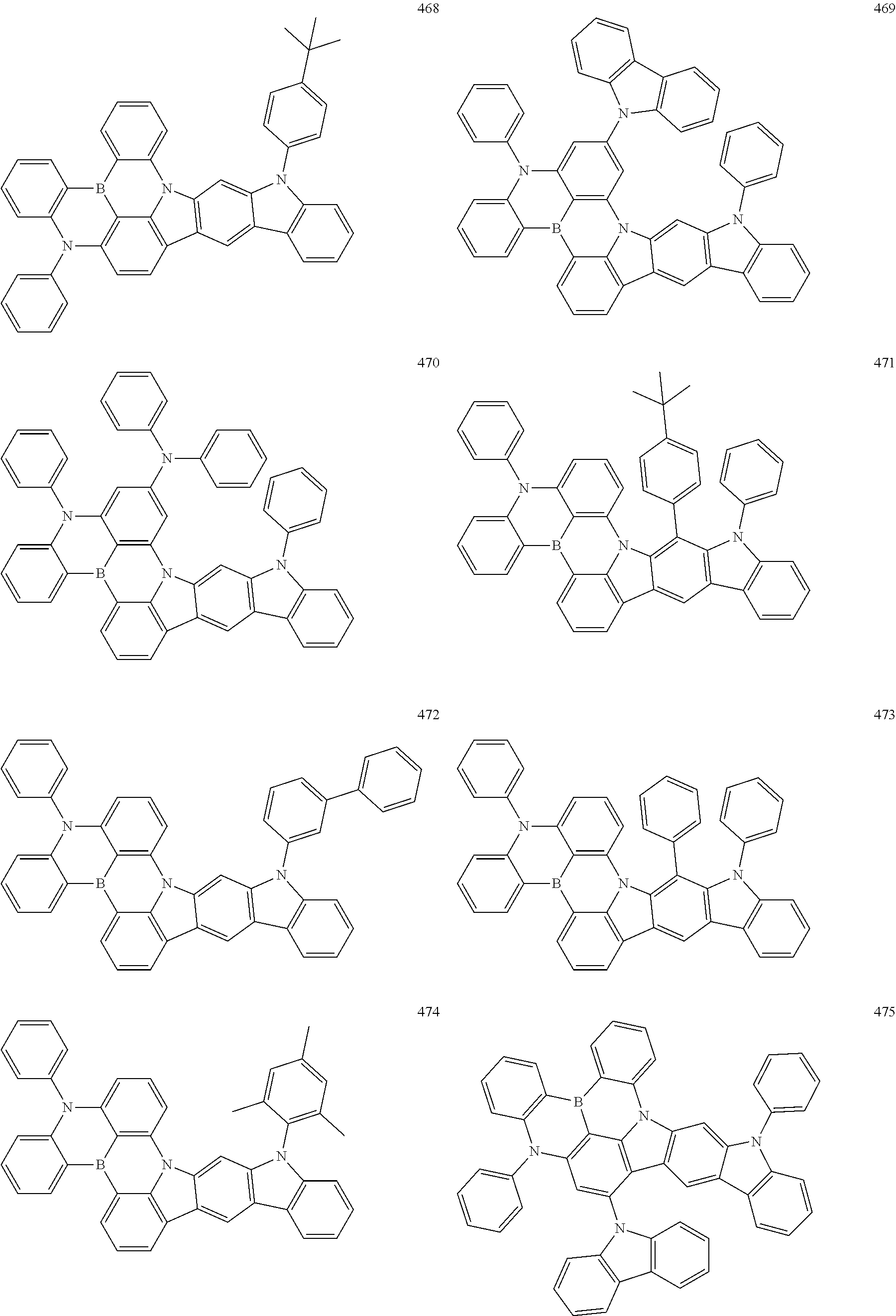

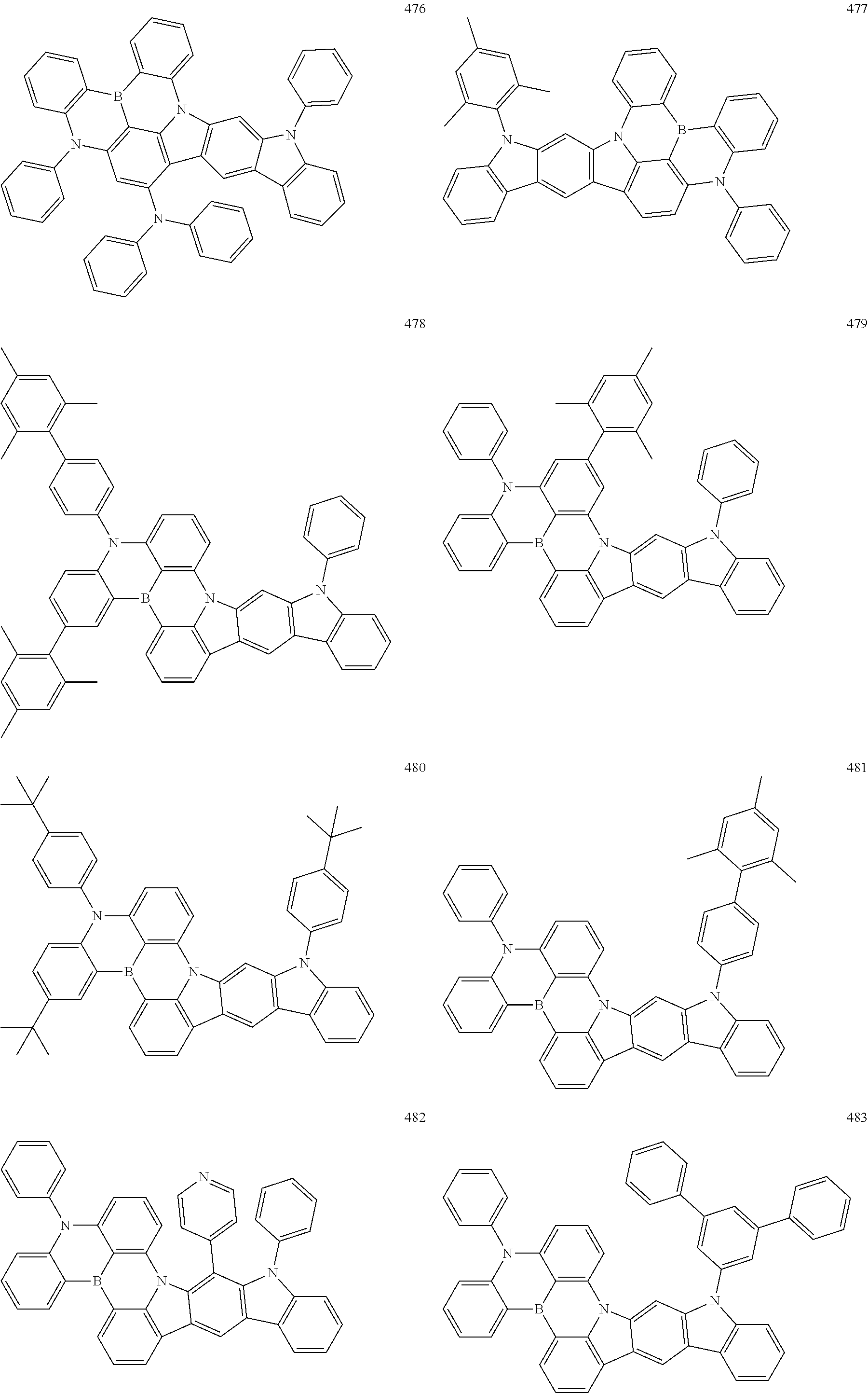

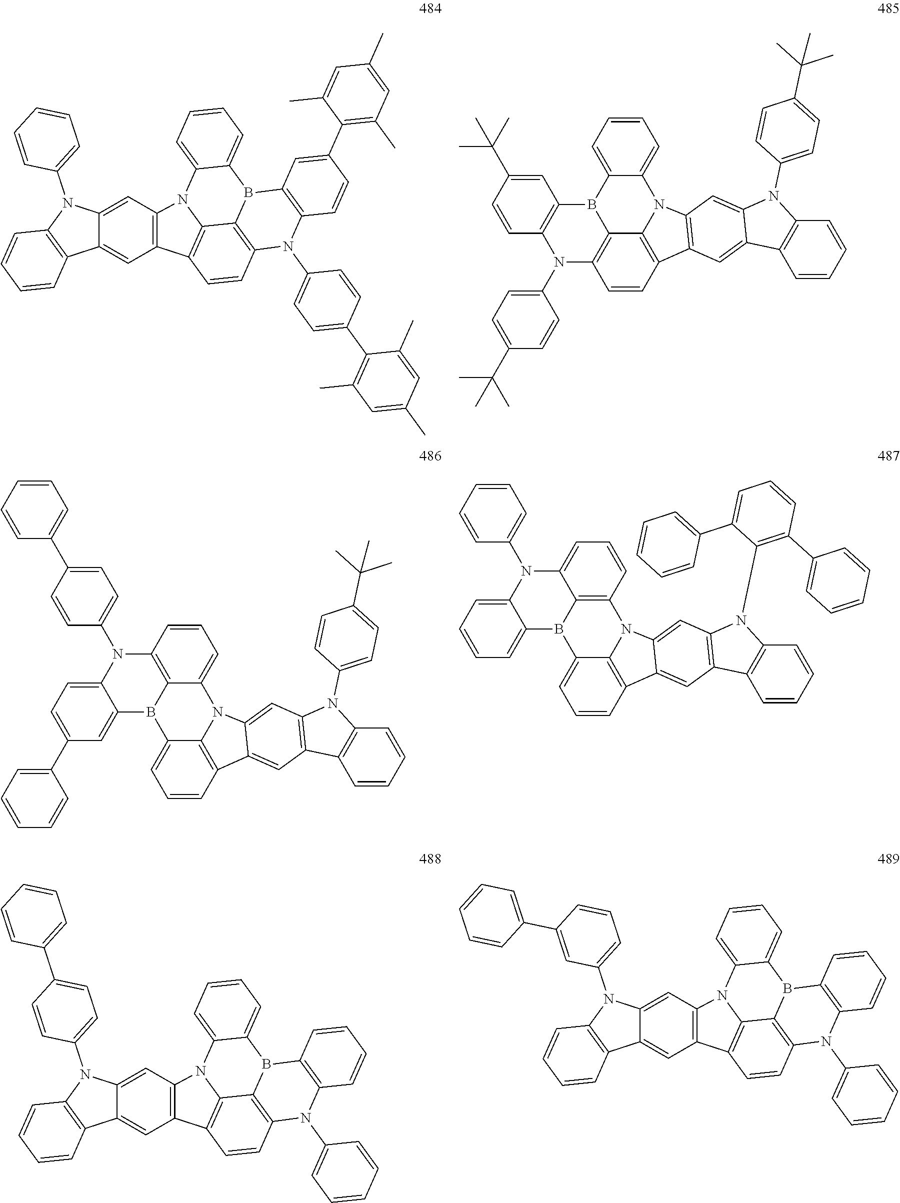

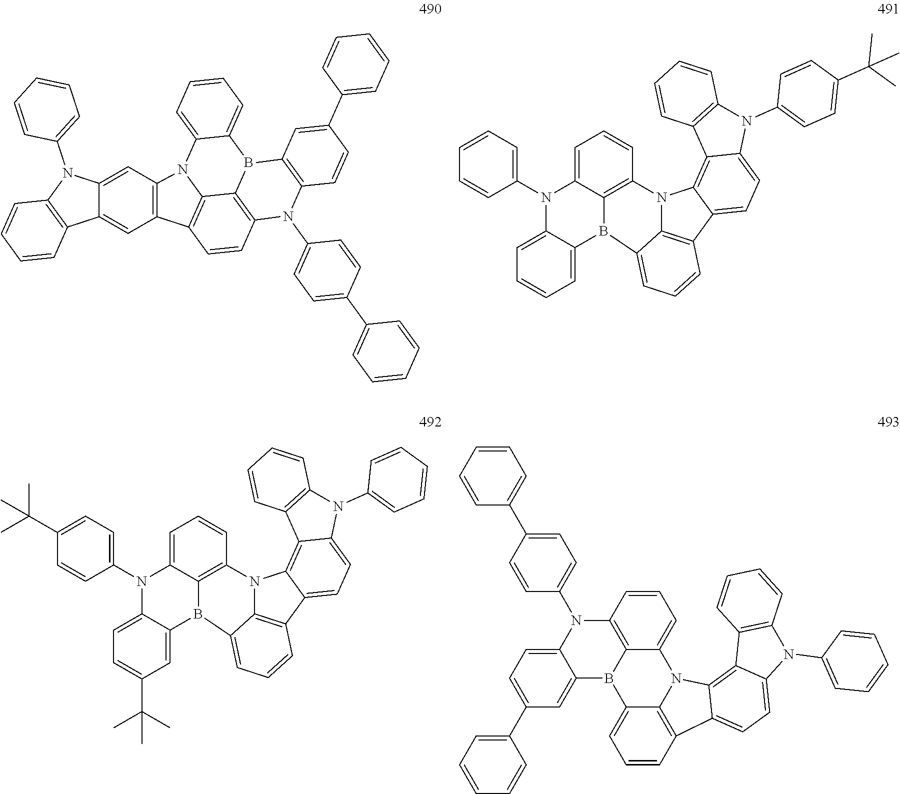

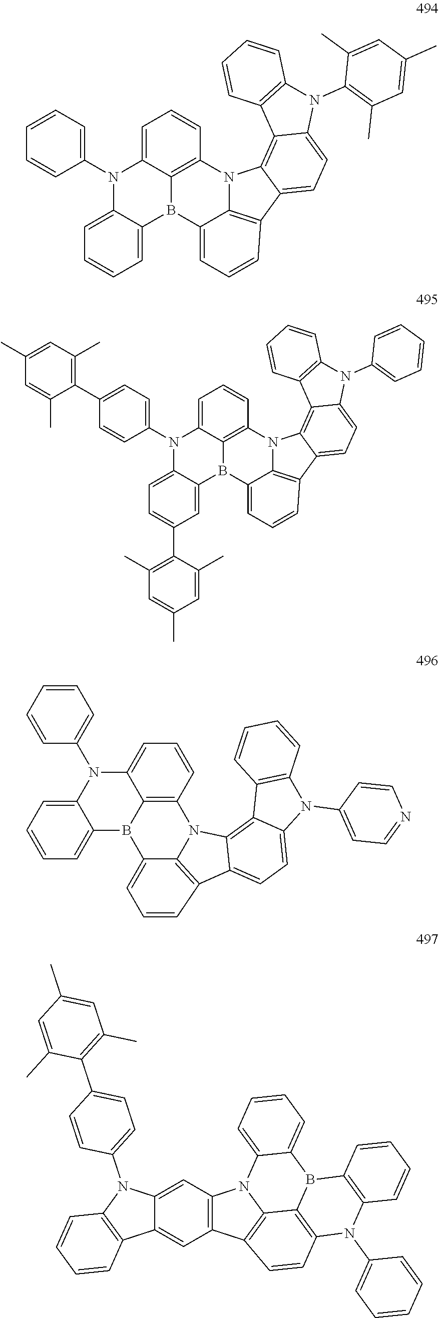

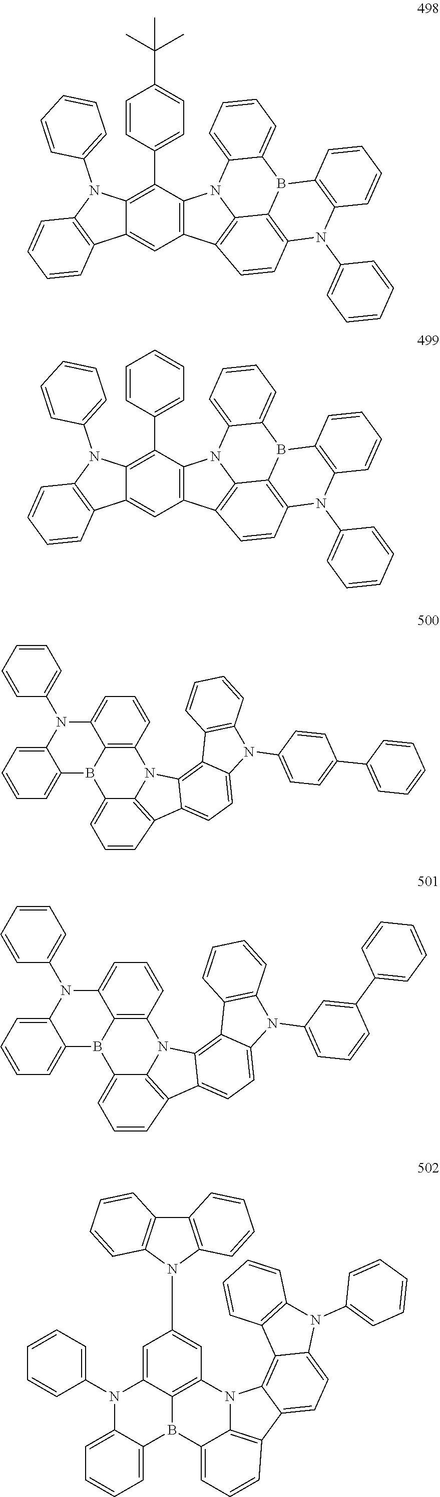 [SMILES: CC(C)(C)c1ccc(-c2c3c(cc4c5ccc6c7c5n(c24)-c2ccccc2B7c2ccccc2N6c2ccccc2)c2ccccc2n3-c2ccccc2)cc1 ; c1ccc(-c2c3c(cc4c5ccc6c7c5n(c24)-c2ccccc2B7c2ccccc2N6c2ccccc2)c2ccccc2n3-c2ccccc2)cc1 ; c1ccc(-c2ccc(-n3c4ccccc4c4c3ccc3c5cccc6c5n(c34)-c3cccc4c3B6c3ccccc3N4c3ccccc3)cc2)cc1 ; c1ccc(-c2cccc(-n3c4ccccc4c4c3ccc3c5cccc6c5n(c34)-c3cccc4c3B6c3ccccc3N4c3ccccc3)c2)cc1 ; c1ccc(N2c3ccccc3B3c4c2cc(-n2c5ccccc5c5ccccc52)cc4-n2c4c3cccc4c3ccc4c(c5ccccc5n4-c4ccccc4)c32)cc1]

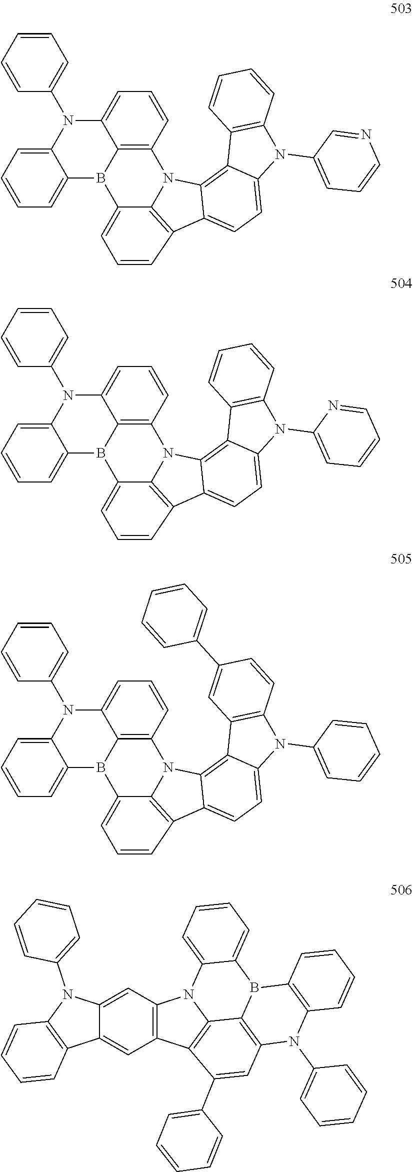 [SMILES: c1ccc(N2c3ccccc3B3c4c2cccc4-n2c4c3cccc4c3ccc4c(c5ccccc5n4-c4cccnc4)c32)cc1 ; c1ccc(N2c3ccccc3B3c4c2cccc4-n2c4c3cccc4c3ccc4c(c5ccccc5n4-c4ccccn4)c32)cc1 ; c1ccc(-c2ccc3c(c2)c2c(ccc4c5cccc6c5n(c42)-c2cccc4c2B6c2ccccc2N4c2ccccc2)n3-c2ccccc2)cc1 ; c1ccc(-c2cc3c4c5c2c2cc6c7ccccc7n(-c7ccccc7)c6cc2n5-c2ccccc2B4c2ccccc2N3c2ccccc2)cc1]

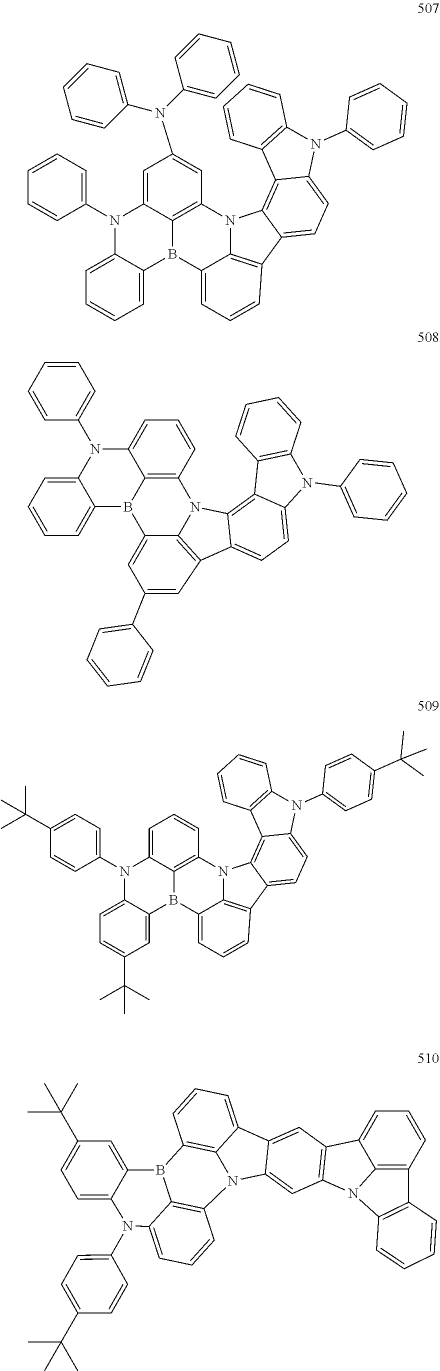

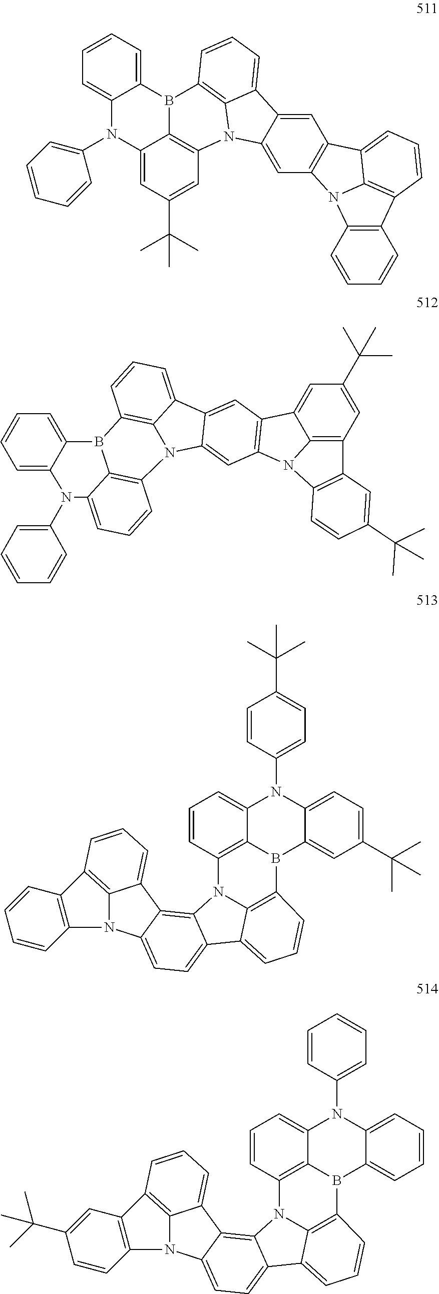

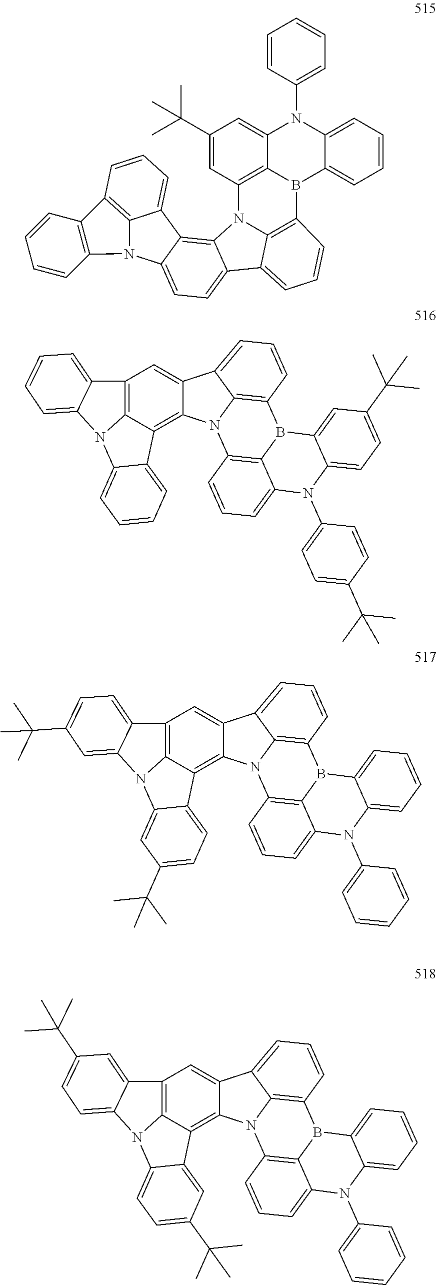

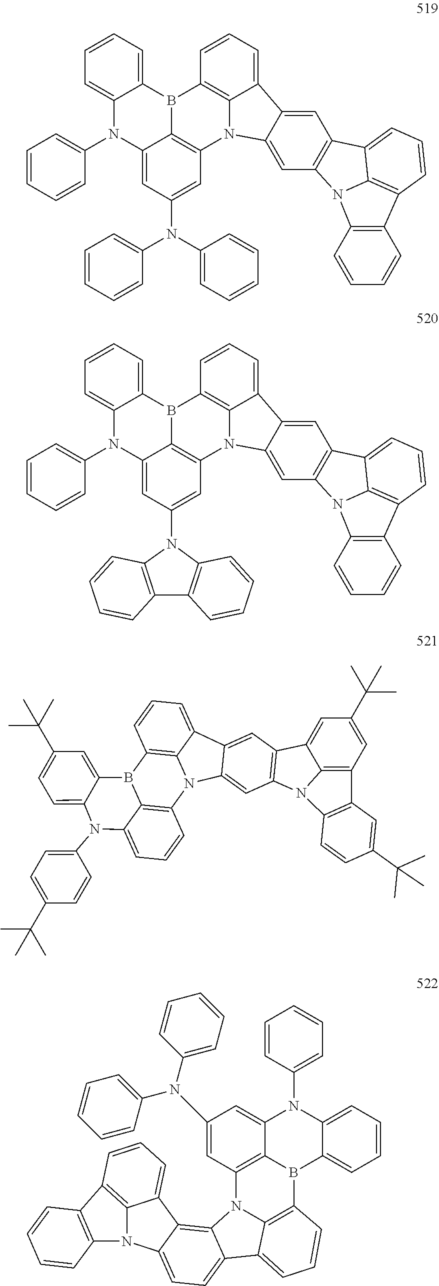

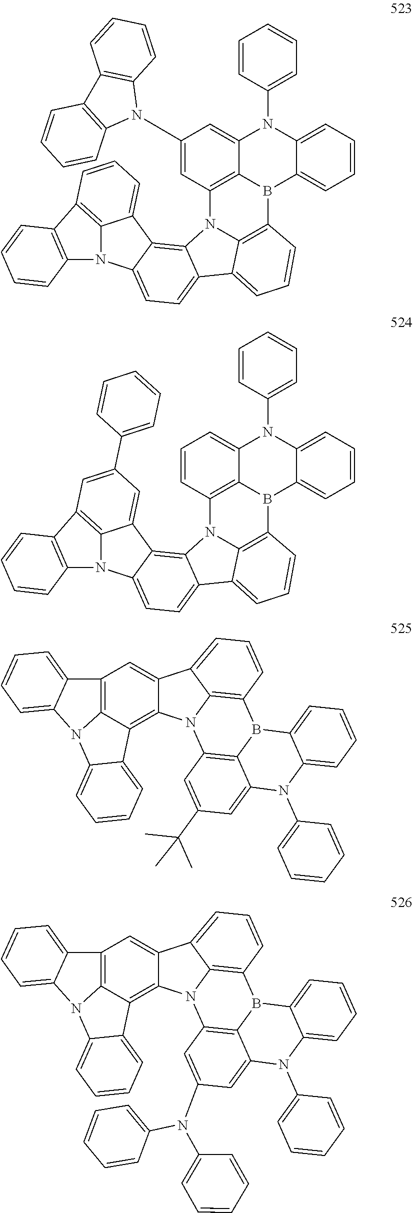

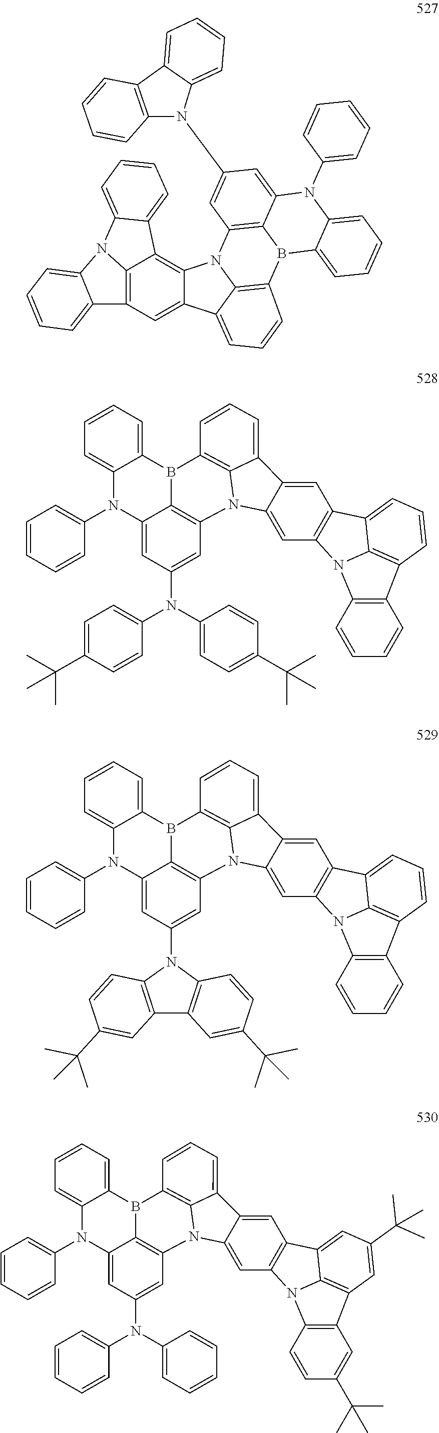 [SMILES: c1ccc(N2c3ccccc3B3c4c2cc(-n2c5ccccc5c5ccccc52)cc4-n2c4c3cccc4c3cc4c5ccccc5n5c6ccccc6c(c32)c45)cc1 ; CC(C)(C)c1ccc(N(c2ccc(C(C)(C)C)cc2)c2cc3c4c(c2)-n2c5cc6c(cc5c5cccc(c52)B4c2ccccc2N3c2ccccc2)c2cccc3c4ccccc4n6c32)cc1 ; CC(C)(C)c1ccc2c(c1)c1cc(C(C)(C)C)ccc1n2-c1cc2c3c(c1)-n1c4cc5c(cc4c4cccc(c41)B3c1ccccc1N2c1ccccc1)c1cccc2c3ccccc3n5c21 ; CC(C)(C)c1ccc2c(c1)c1cc(C(C)(C)C)cc3c4cc5c6cccc7c6n(c5cc4n2c13)-c1cc(N(c2ccccc2)c2ccccc2)cc2c1B7c1ccccc1N2c1ccccc1]

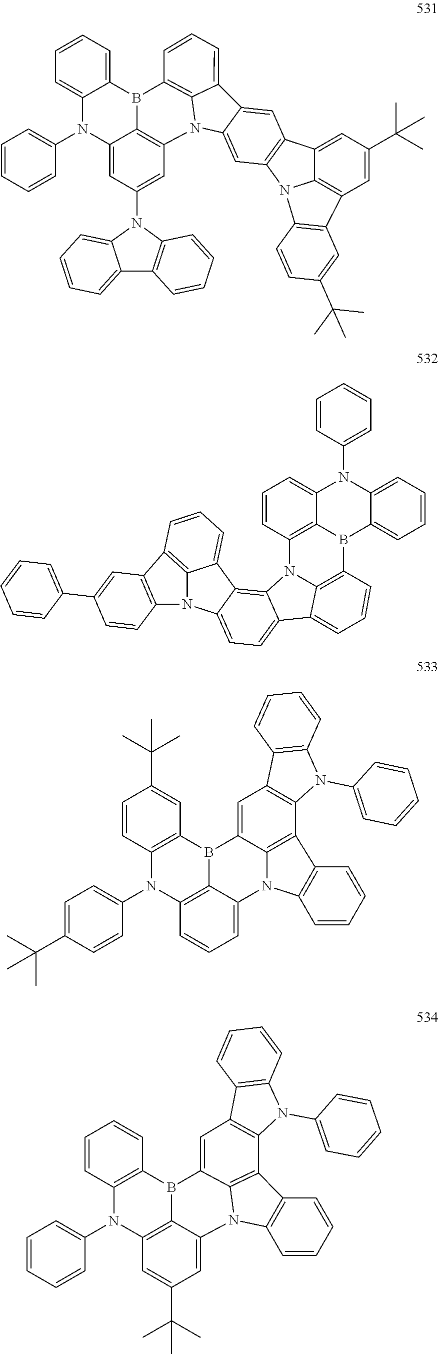

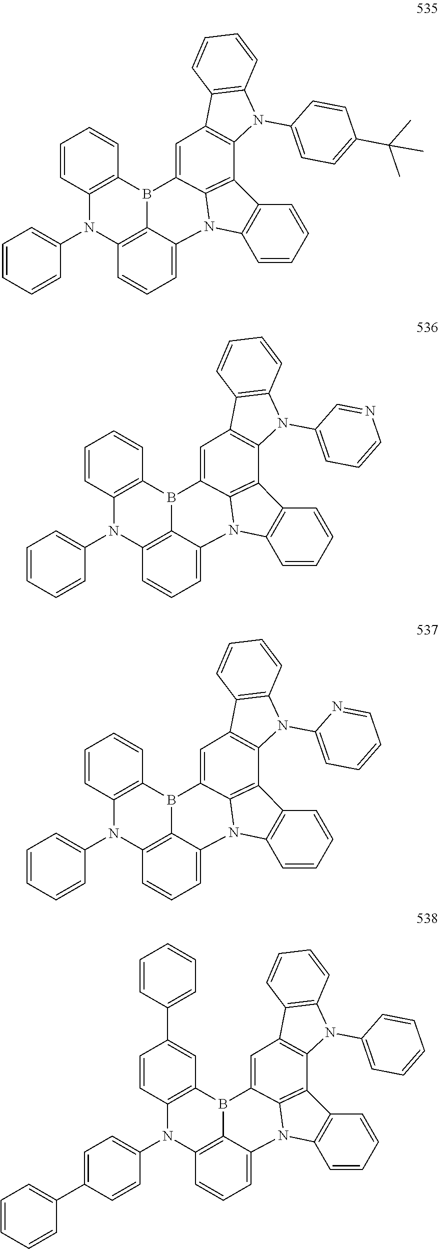

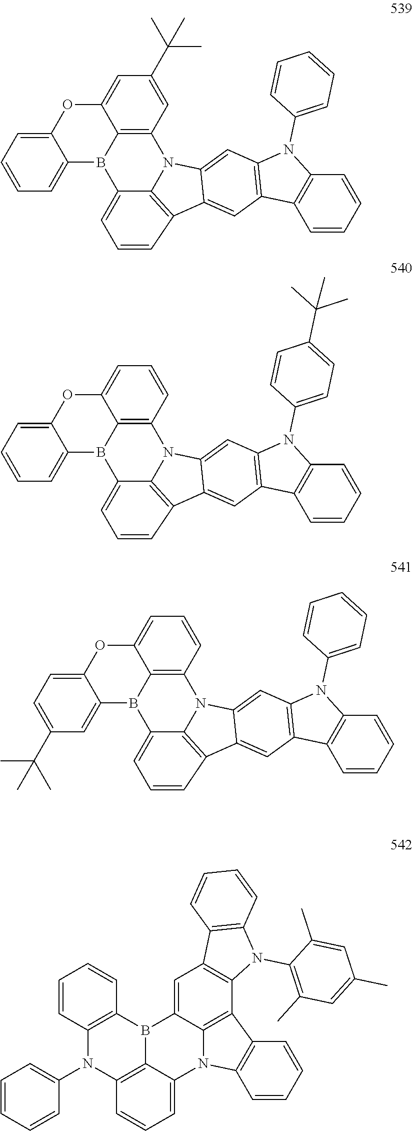 [SMILES: CC(C)(C)c1cc2c3c(c1)-n1c4cc5c(cc4c4cccc(c41)B3c1ccccc1O2)c1ccccc1n5-c1ccccc1 ; CC(C)(C)c1ccc(-n2c3ccccc3c3cc4c5cccc6c5n(c4cc32)-c2cccc3c2B6c2ccccc2O3)cc1 ; CC(C)(C)c1ccc2c(c1)B1c3c(cccc3-n3c4cc5c(cc4c4cccc1c43)c1ccccc1n5-c1ccccc1)O2 ; Cc1cc(C)c(-n2c3ccccc3c3cc4c5c(c6ccccc6n5-c5cccc6c5B4c4ccccc4N6c4ccccc4)c32)c(C)c1]

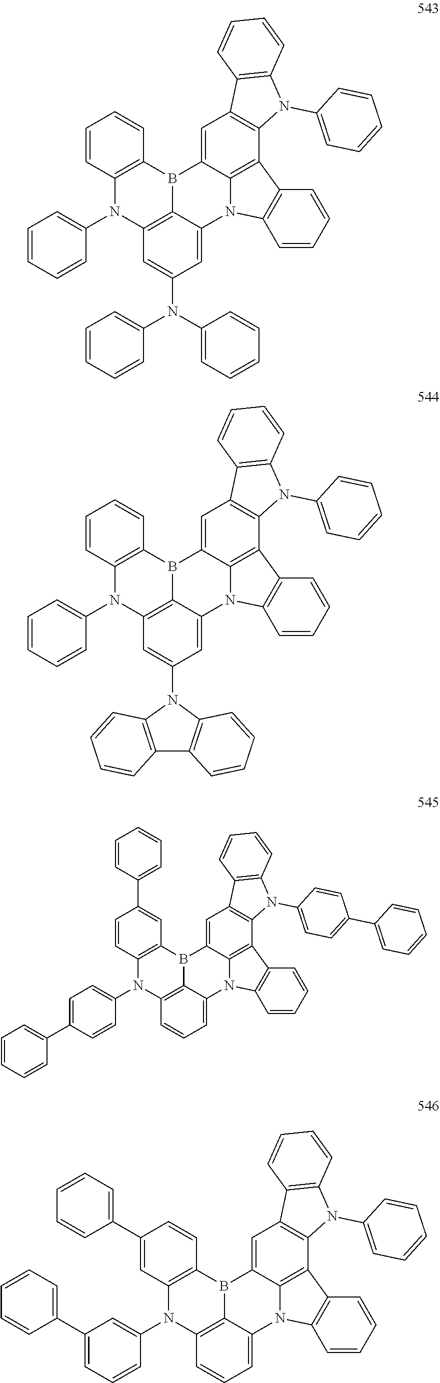

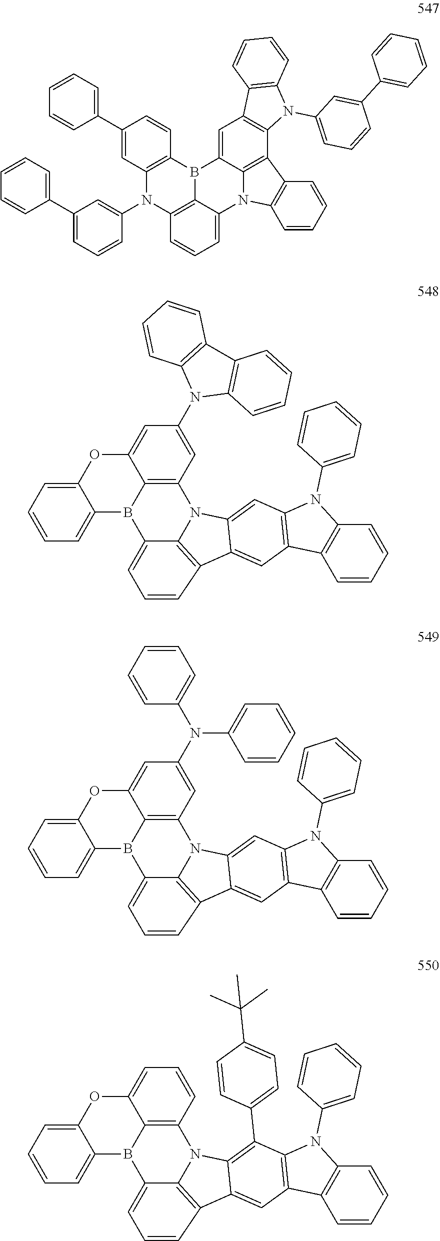 [SMILES: c1ccc(-c2cccc(N3c4cc(-c5ccccc5)ccc4B4c5c3cccc5-n3c5ccccc5c5c3c4cc3c4ccccc4n(-c4cccc(-c6ccccc6)c4)c35)c2)cc1 ; c1ccc(-n2c3ccccc3c3cc4c5cccc6c5n(c4cc32)-c2cc(-n3c4ccccc4c4ccccc43)cc3c2B6c2ccccc2O3)cc1 ; c1ccc(N(c2ccccc2)c2cc3c4c(c2)-n2c5cc6c(cc5c5cccc(c52)B4c2ccccc2O3)c2ccccc2n6-c2ccccc2)cc1 ; CC(C)(C)c1ccc(-c2c3c(cc4c5cccc6c5n(c24)-c2cccc4c2B6c2ccccc2O4)c2ccccc2n3-c2ccccc2)cc1]

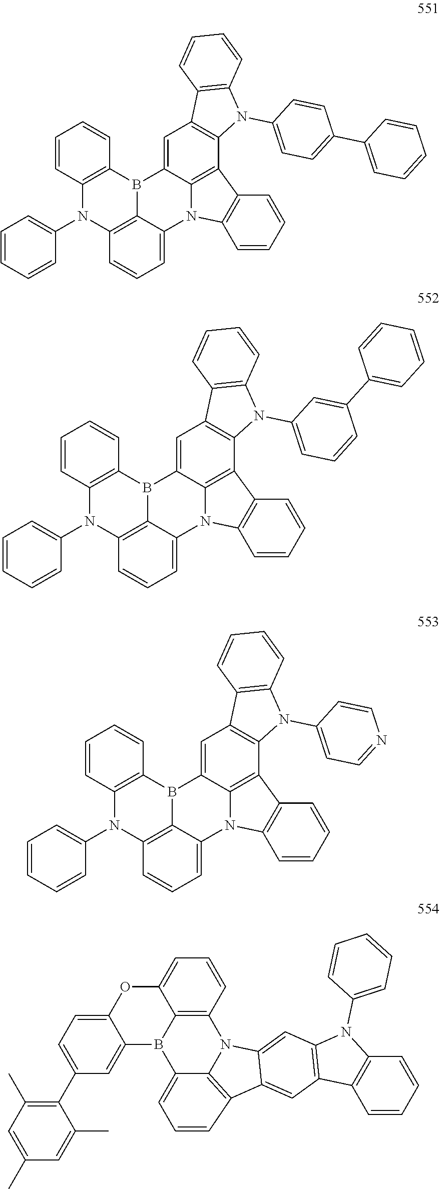 [SMILES: c1ccc(-c2ccc(-n3c4ccccc4c4cc5c6c(c7ccccc7n6-c6cccc7c6B5c5ccccc5N7c5ccccc5)c43)cc2)cc1 ; c1ccc(-c2cccc(-n3c4ccccc4c4cc5c6c(c7ccccc7n6-c6cccc7c6B5c5ccccc5N7c5ccccc5)c43)c2)cc1 ; c1ccc(N2c3ccccc3B3c4c2cccc4-n2c4ccccc4c4c2c3cc2c3ccccc3n(-c3ccncc3)c24)cc1 ; Cc1cc(C)c(-c2ccc3c(c2)B2c4c(cccc4-n4c5cc6c(cc5c5cccc2c54)c2ccccc2n6-c2ccccc2)O3)c(C)c1]

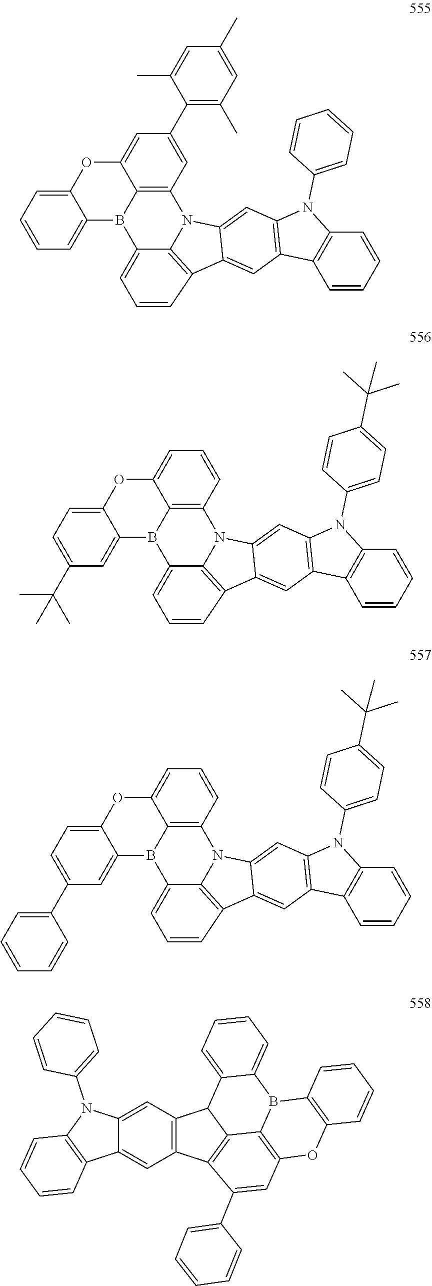

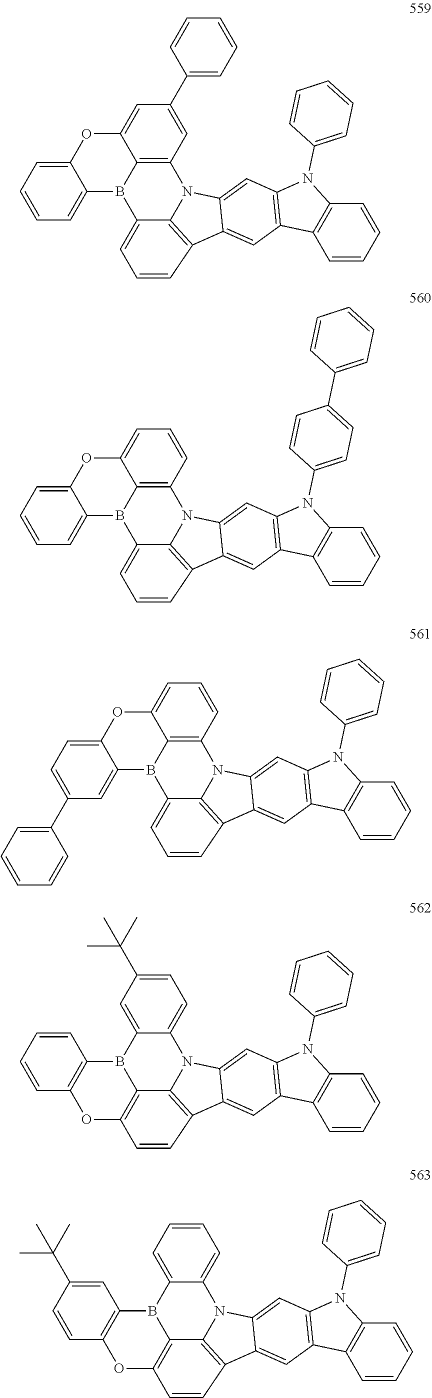 [SMILES: c1ccc(-c2cc3c4c(c2)-n2c5cc6c(cc5c5cccc(c52)B4c2ccccc2O3)c2ccccc2n6-c2ccccc2)cc1 ; c1ccc(-c2ccc(-n3c4ccccc4c4cc5c6cccc7c6n(c5cc43)-c3cccc4c3B7c3ccccc3O4)cc2)cc1 ; c1ccc(-c2ccc3c(c2)B2c4c(cccc4-n4c5cc6c(cc5c5cccc2c54)c2ccccc2n6-c2ccccc2)O3)cc1 ; CC(C)(C)c1ccc2c(c1)B1c3ccccc3Oc3ccc4c5cc6c7ccccc7n(-c7ccccc7)c6cc5n-2c4c31 ; CC(C)(C)c1ccc2c(c1)B1c3ccccc3-n3c4cc5c(cc4c4ccc(c1c43)O2)c1ccccc1n5-c1ccccc1]

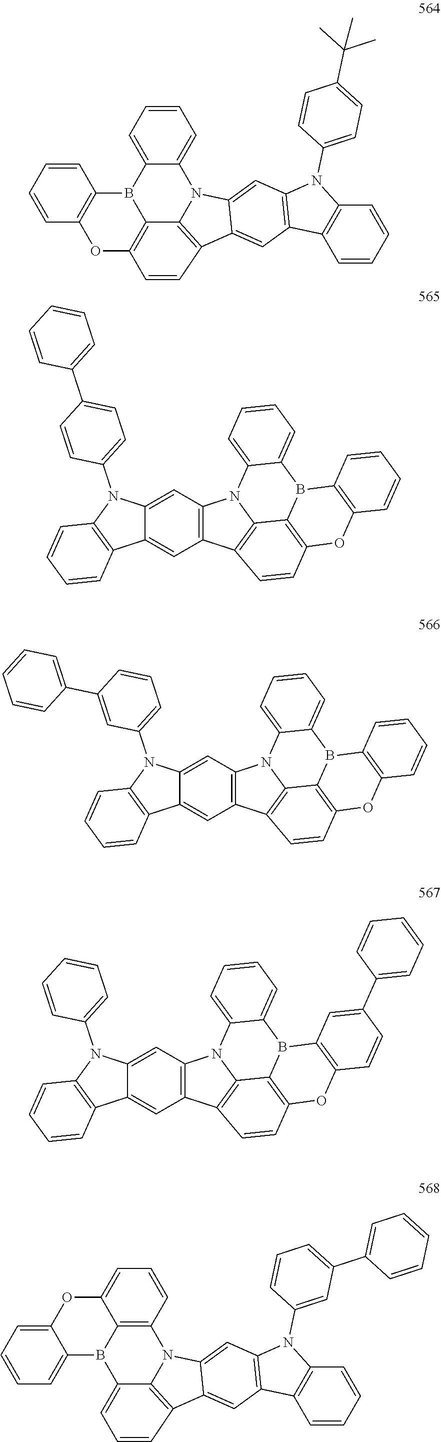 [SMILES: CC(C)(C)c1ccc(-n2c3ccccc3c3cc4c5ccc6c7c5n(c4cc32)-c2ccccc2B7c2ccccc2O6)cc1 ; c1ccc(-c2ccc(-n3c4ccccc4c4cc5c6ccc7c8c6n(c5cc43)-c3ccccc3B8c3ccccc3O7)cc2)cc1 ; c1ccc(-c2cccc(-n3c4ccccc4c4cc5c6ccc7c8c6n(c5cc43)-c3ccccc3B8c3ccccc3O7)c2)cc1 ; c1ccc(-c2ccc3c(c2)B2c4ccccc4-n4c5cc6c(cc5c5ccc(c2c54)O3)c2ccccc2n6-c2ccccc2)cc1 ; c1ccc(-c2cccc(-n3c4ccccc4c4cc5c6cccc7c6n(c5cc43)-c3cccc4c3B7c3ccccc3O4)c2)cc1]

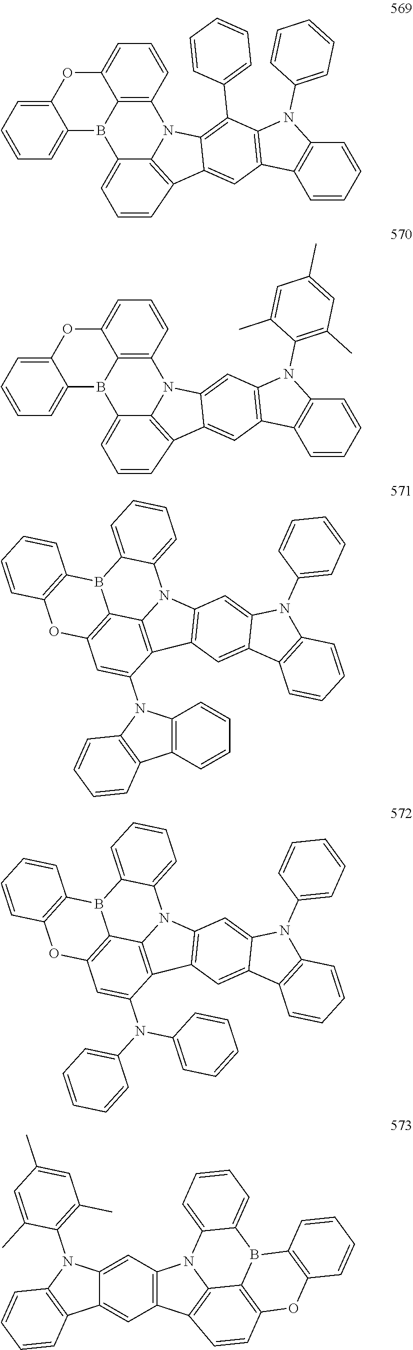

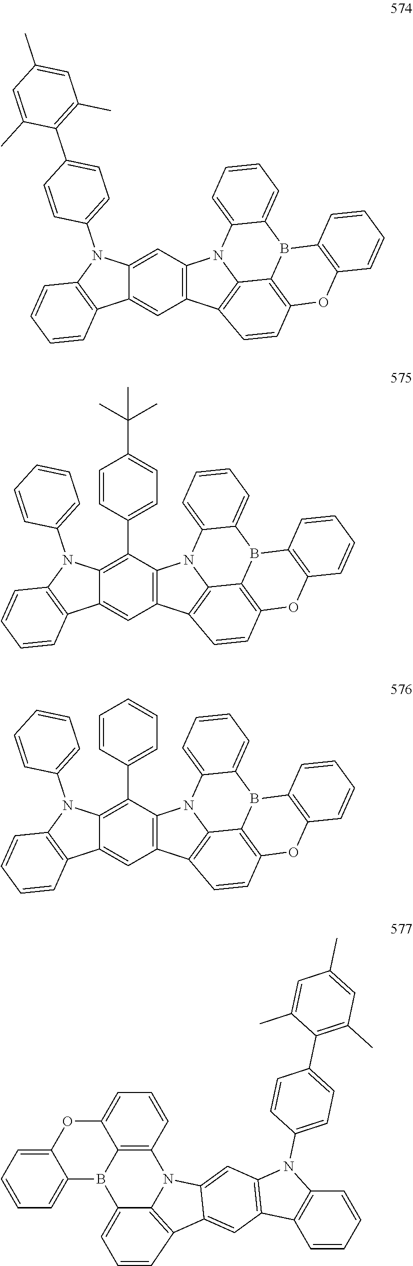 [SMILES: Cc1cc(C)c(-c2ccc(-n3c4ccccc4c4cc5c6ccc7c8c6n(c5cc43)-c3ccccc3B8c3ccccc3O7)cc2)c(C)c1 ; CC(C)(C)c1ccc(-c2c3c(cc4c5ccc6c7c5n(c24)-c2ccccc2B7c2ccccc2O6)c2ccccc2n3-c2ccccc2)cc1 ; c1ccc(-c2c3c(cc4c5ccc6c7c5n(c24)-c2ccccc2B7c2ccccc2O6)c2ccccc2n3-c2ccccc2)cc1 ; Cc1cc(C)c(-c2ccc(-n3c4ccccc4c4cc5c6cccc7c6n(c5cc43)-c3cccc4c3B7c3ccccc3O4)cc2)c(C)c1]

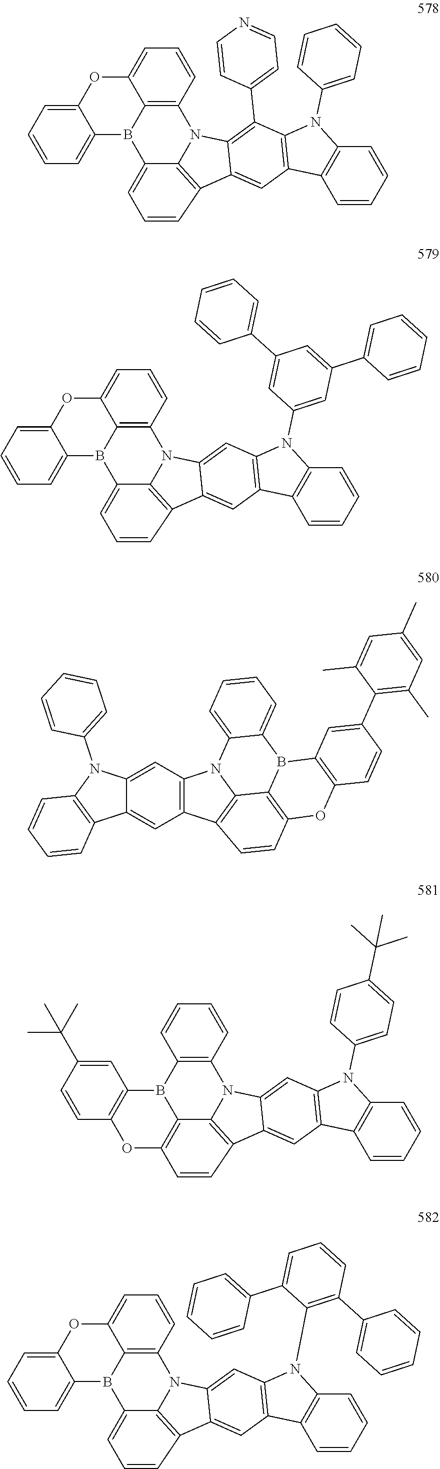

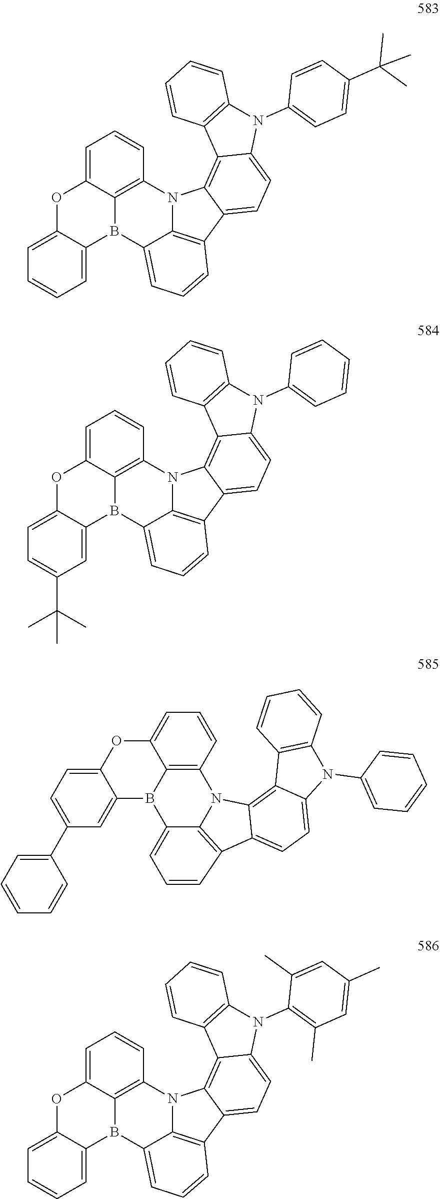

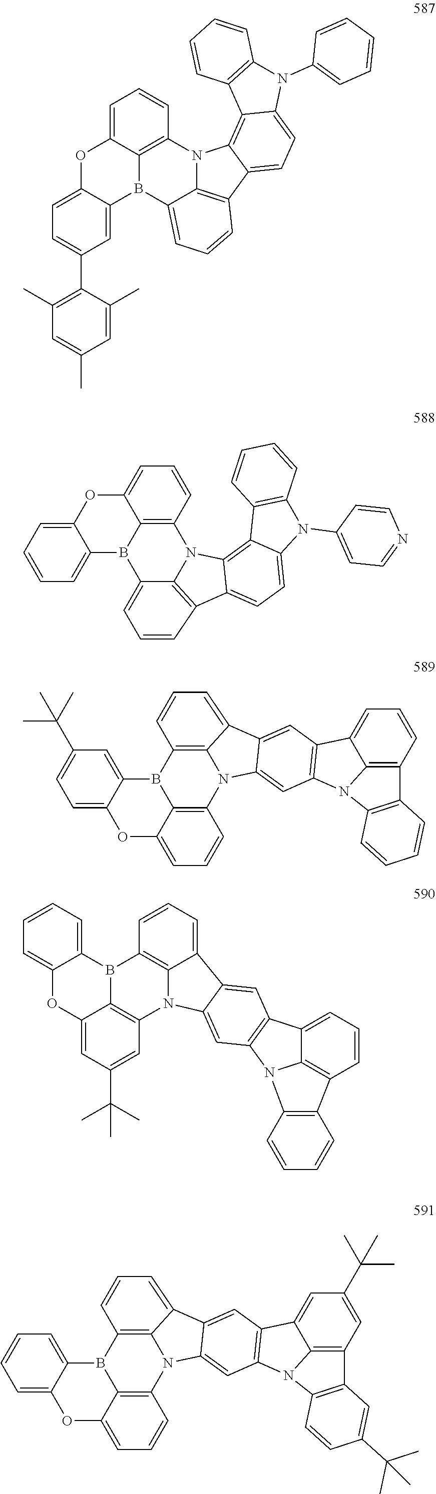

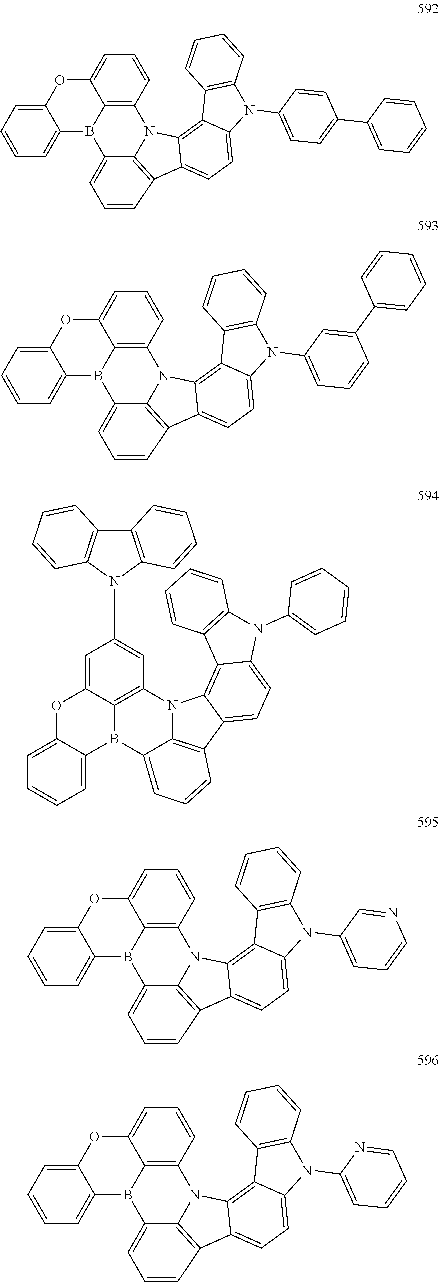

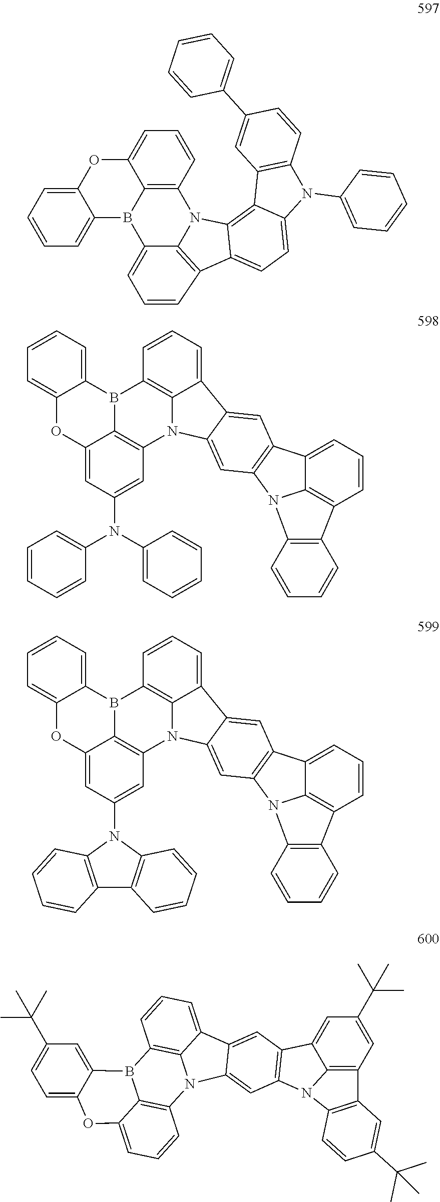

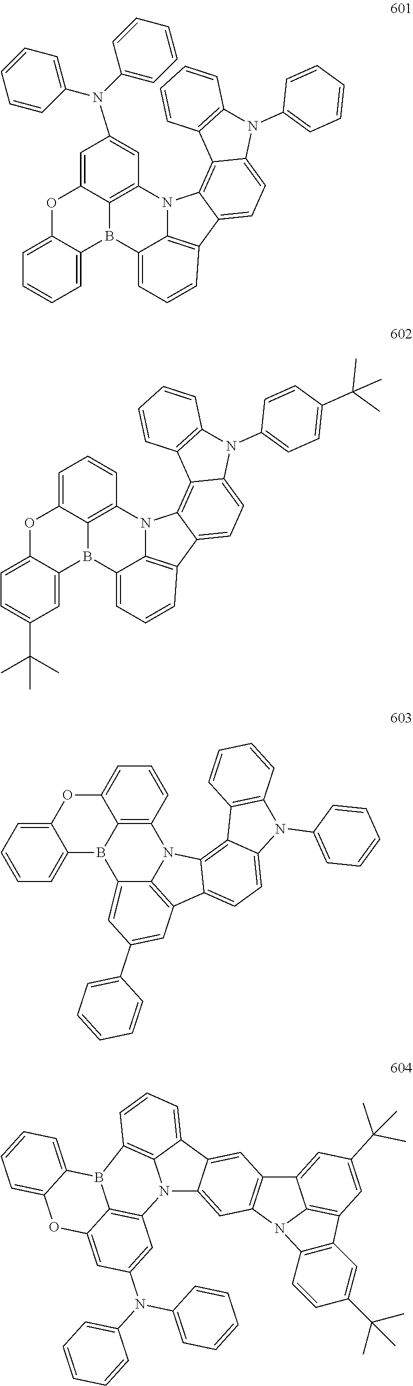 [SMILES: c1ccc(N(c2ccccc2)c2cc3c4c(c2)-n2c5c(cccc5c5ccc6c(c7ccccc7n6-c6ccccc6)c52)B4c2ccccc2O3)cc1 ; CC(C)(C)c1ccc(-n2c3ccccc3c3c2ccc2c4cccc5c4n(c23)-c2cccc3c2B5c2cc(C(C)(C)C)ccc2O3)cc1 ; c1ccc(-c2cc3c4c(c2)c2ccc5c(c6ccccc6n5-c5ccccc5)c2n4-c2cccc4c2B3c2ccccc2O4)cc1 ; CC(C)(C)c1ccc2c(c1)c1cc(C(C)(C)C)cc3c4cc5c6cccc7c6n(c5cc4n2c13)-c1cc(N(c2ccccc2)c2ccccc2)cc2c1B7c1ccccc1O2]

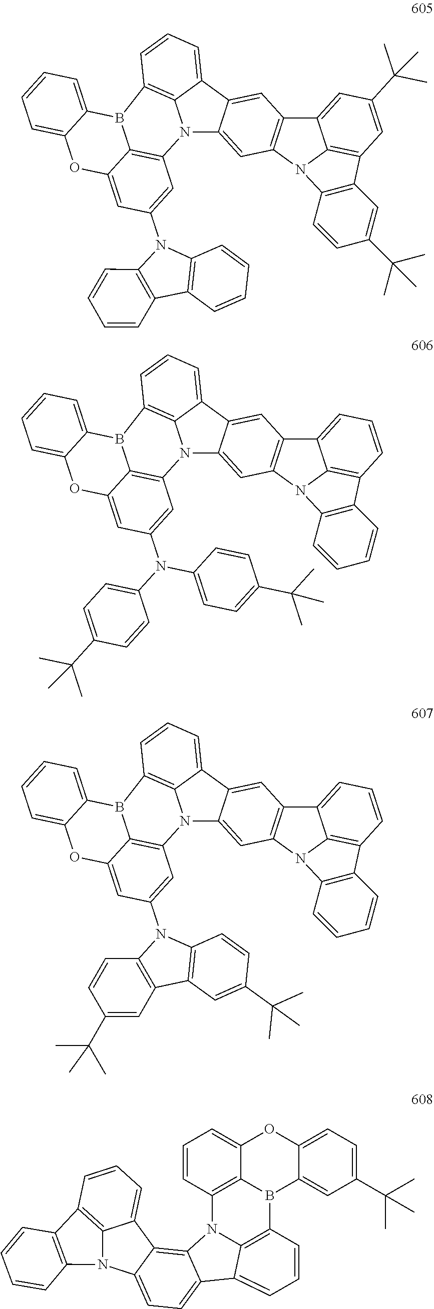

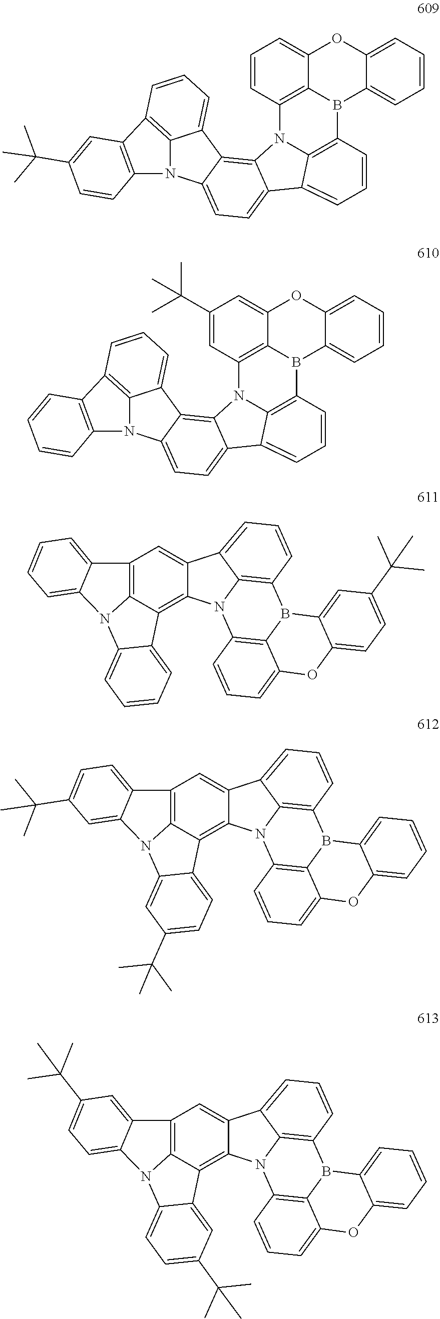

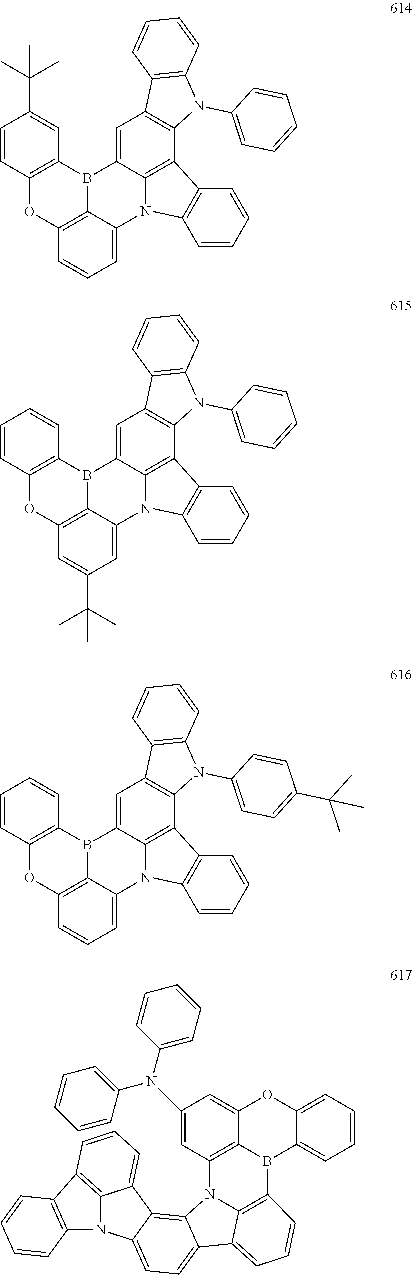 [SMILES: CC(C)(C)c1ccc2c(c1)B1c3c(cccc3-n3c4ccccc4c4c3c1cc1c3ccccc3n(-c3ccccc3)c14)O2 ; CC(C)(C)c1cc2c3c(c1)-n1c4ccccc4c4c1c(cc1c5ccccc5n(-c5ccccc5)c14)B3c1ccccc1O2 ; CC(C)(C)c1ccc(-n2c3ccccc3c3cc4c5c(c6ccccc6n5-c5cccc6c5B4c4ccccc4O6)c32)cc1 ; c1ccc(N(c2ccccc2)c2cc3c4c(c2)-n2c5c(cccc5c5ccc6c(c7cccc8c9ccccc9n6c87)c52)B4c2ccccc2O3)cc1]

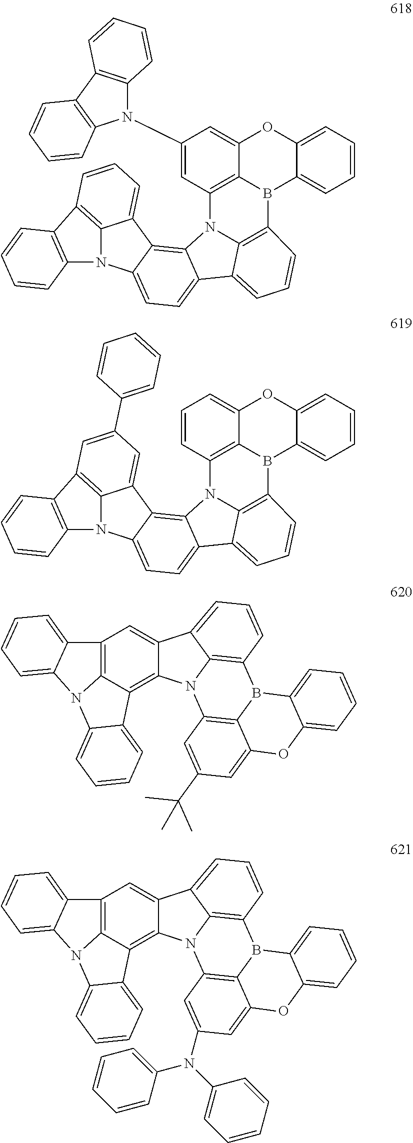

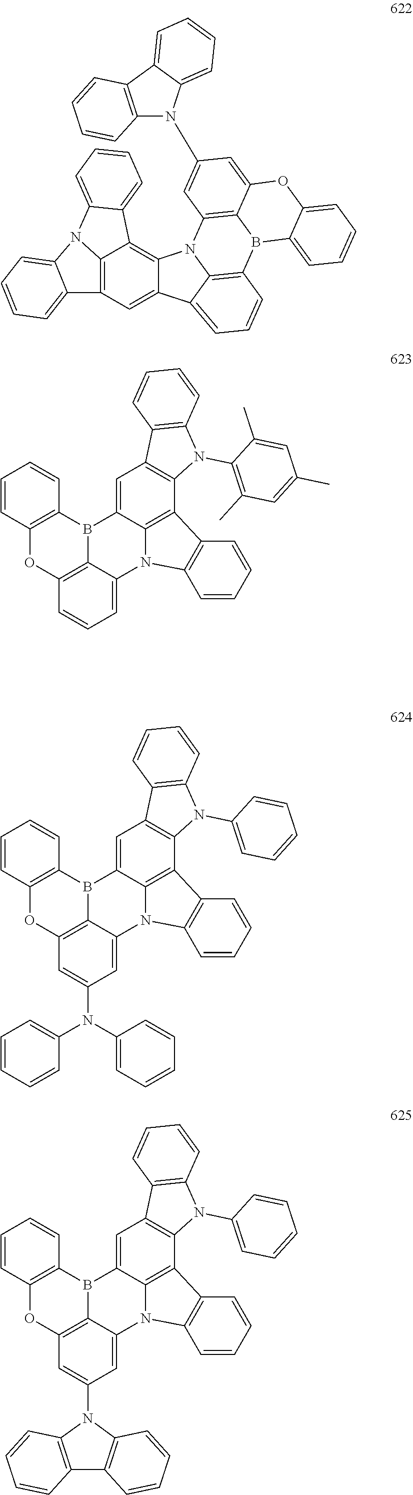

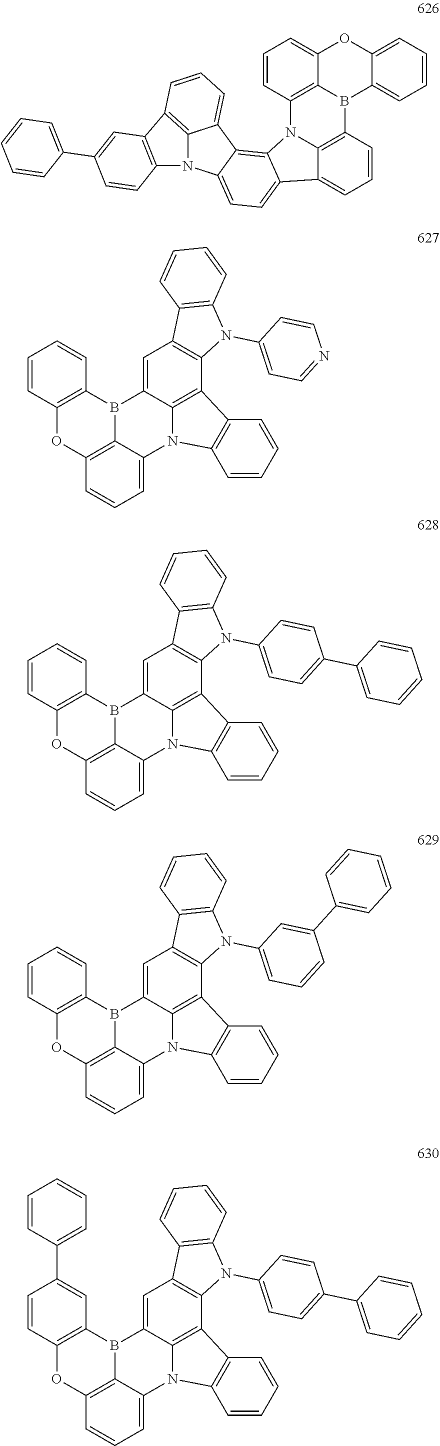 [SMILES: c1ccc(-c2ccc3c(c2)c2cccc4c5c6c(ccc5n3c24)c2cccc3c2n6-c2cccc4c2B3c2ccccc2O4)cc1 ; c1ccc2c(c1)Oc1cccc3c1B2c1cc2c4ccccc4n(-c4ccncc4)c2c2c4ccccc4n-3c12 ; c1ccc(-c2ccc(-n3c4ccccc4c4cc5c6c(c7ccccc7n6-c6cccc7c6B5c5ccccc5O7)c43)cc2)cc1 ; c1ccc(-c2cccc(-n3c4ccccc4c4cc5c6c(c7ccccc7n6-c6cccc7c6B5c5ccccc5O7)c43)c2)cc1 ; c1ccc(-c2ccc(-n3c4ccccc4c4cc5c6c(c7ccccc7n6-c6cccc7c6B5c5cc(-c6ccccc6)ccc5O7)c43)cc2)cc1]

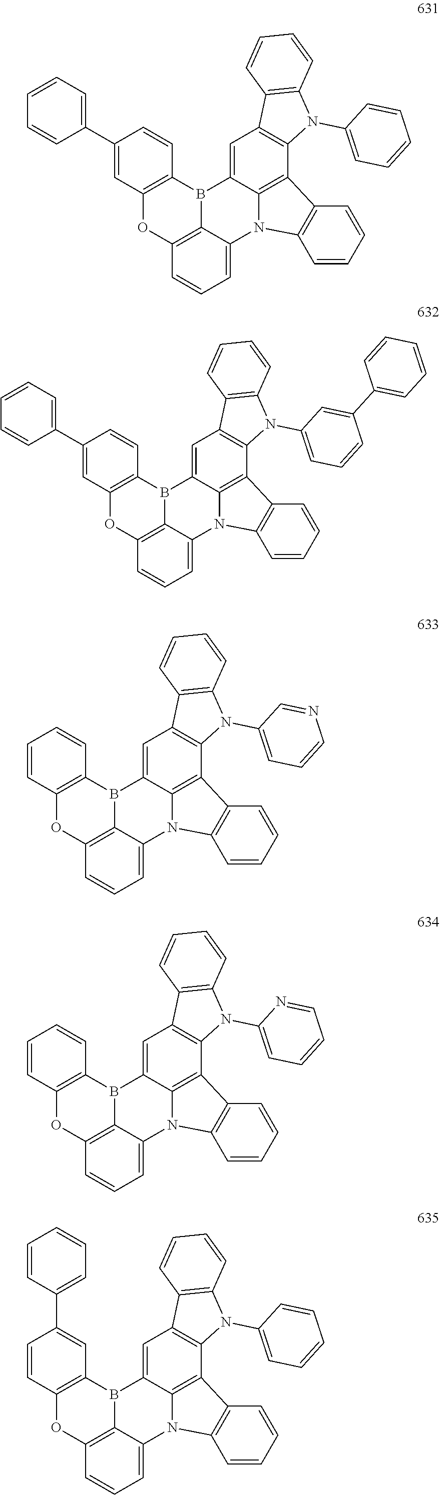 [SMILES: c1ccc(-c2ccc3c(c2)Oc2cccc4c2B3c2cc3c5ccccc5n(-c5ccccc5)c3c3c5ccccc5n-4c23)cc1 ; c1ccc(-c2cccc(-n3c4ccccc4c4cc5c6c(c7ccccc7n6-c6cccc7c6B5c5ccc(-c6ccccc6)cc5O7)c43)c2)cc1 ; c1cncc(-n2c3ccccc3c3cc4c5c(c6ccccc6n5-c5cccc6c5B4c4ccccc4O6)c32)c1 ; c1ccc(-n2c3ccccc3c3cc4c5c(c6ccccc6n5-c5cccc6c5B4c4ccccc4O6)c32)nc1 ; c1ccc(-c2ccc3c(c2)B2c4c(cccc4-n4c5ccccc5c5c4c2cc2c4ccccc4n(-c4ccccc4)c25)O3)cc1]

9. The heterocyclic compound of claim 1, wherein a highest occupied molecular orbital (HOMO) energy level of the heterocyclic compound is about −5.8 eV to about −4.6 eV, and
a lowest unoccupied molecular orbital (LUMO) energy level of the heterocyclic compound is about −2.4 eV to about −0.8 eV.

10. The heterocyclic compound of claim 1, wherein a peak of a fluorescence wavelength of the heterocyclic compound is about 360 nm to about 515 nm, and a full width at half maximum (FWHM) of a peak of a fluorescence spectrum of the heterocyclic compound is about 30 nm or less.

11. The heterocyclic compound of claim 1, wherein ΔE_{ST} of the heterocyclic compound is about 0.4 eV or less.

12. The heterocyclic compound of claim 1, wherein an oscillator strength of a stable structure in an adiabatic first excited singlet state of the heterocyclic compound is about 0.22 or more.

13. The light-emitting device of claim 1, wherein a reorganization energy of the heterocyclic compound is about 0.1 eV or less.

14. An organic light-emitting device comprising:
a first electrode; a second electrode; an organic layer comprising an emission layer located between the first electrode and the second electrode; and
the heterocyclic compound of claim 1.

15. The organic light-emitting device of claim 14, wherein the emission layer comprises the heterocyclic compound.

16. The organic light-emitting device of claim 15, wherein the emission layer further comprises a host,
the host is different from the heterocyclic compound, and
the emission layer consists of the host and the heterocyclic compound.

17. The organic light-emitting device of claim 16, wherein the host does not emit light, and the heterocyclic compound emits light.

18. The organic light-emitting device of claim 15, wherein the emission layer further comprises a host and a dopant,
the host, the dopant, and the heterocyclic compound are different from each other, and
the emission layer consists of the host, the dopant, and the heterocyclic compound.

19. The organic light-emitting device of claim 18, wherein the host and the heterocyclic compound do not each emit light, and the dopant emits light.

20. An electronic apparatus comprising the organic light-emitting device of claim 14.
